(19) United States
(12) Patent Application Publication
(10) Pub. No.: US 2018/0287090 A1
(43) Pub. Date: Oct. 4, 2018

(54) PHOSPHORUS-CONTAINING COMPOUND AND ORGANIC ELECTROLUMINESCENCE DEVICE INCLUDING THE SAME

(71) Applicants: SAMSUNG DISPLAY CO., LTD., Yongin-si (KR); KYUSHU UNIVERSITY, NATIONAL UNIVERSITY CORPORATION, Fukuoka-shi (JP)

(72) Inventors: Shuri SATO, Yokohama (JP); Nobutaka AKASHI, Yokohama (JP); Takuma YASUDA, Fukuoka (JP); Jiyoung LEE, Fukuoka (JP)

(21) Appl. No.: 15/838,654

(22) Filed: Dec. 12, 2017

(30) Foreign Application Priority Data
Mar. 30, 2017 (KR) 10-2017-0040848

(51) Int. Cl. H01L 51/50; C07F 9/6568; C07F 9/6571; C07F 9/53

(52) U.S. Cl. CPC H01L 51/5064; H01L 51/508; C07F 9/5325; C07F 9/657163; C07F 9/65685

(57) ABSTRACT

A phosphorus-containing compound and an organic electroluminescence device including the same, the phosphorus-containing compound being represented by the following Formula 1:

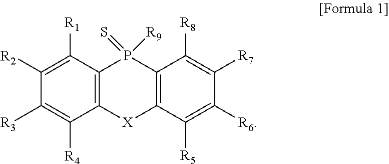

### CROSS-REFERENCE TO RELATED APPLICATION

Korean Patent Application No. 10-2017-0040848, filed on Mar. 30, 2017, in the Korean Intellectual Property Office, and entitled: “Phosphorus-Containing Compound and Organic Electroluminescence Device Including the Same,” is incorporated by reference herein in its entirety.

### BACKGROUND

### 1. Field

Embodiments relate to a phosphorus-containing compound and an organic electroluminescence device including the same.

### 2. Description of the Related Art

Recently, the development of an organic electroluminescence display device as an image display device is being actively conducted. Different from a liquid crystal display device, the organic electroluminescence display device is a self-luminescent display device in which holes and electrons injected from a first electrode and a second electrode recombine in an emission layer, and a light emission material including an organic compound in the emission layer emits light to attain display.

An organic electroluminescence device may include, e.g., a first electrode, a hole transport layer disposed on the first electrode, an emission layer disposed on the hole transport layer, an electron transport layer disposed on the emission layer, and a second electrode disposed on the electron transport layer. Holes are injected from the first electrode, and the injected holes move via the hole transport layer and are injected into the emission layer. Meanwhile, electrons are injected from the second electrode, and the injected electrons move via the electron transport layer and are injected into the emission layer. The holes and electrons injected to the emission layer recombine to generate excitons in the emission layer. The organic electroluminescence device emits light using light generated by the radiation deactivation of the excitons.

### SUMMARY

Embodiments are directed to a phosphorus-containing compound and an organic electroluminescence device including the same

The embodiments may be realized by providing a phosphorus-containing compound represented by the following Formula 1:

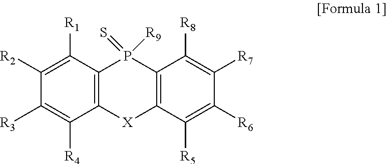

wherein, in Formula 1, X is O, S, NRₐ, CR_{b}R_{c}, SiR_{d}Rₑ, or GeR_{f}R_{g}, R₁ to R₈ are each independently a hydrogen atom, a deuterium atom, a halogen atom, a substituted or unsubstituted silyl group, a substituted or unsubstituted amino group, a substituted or unsubstituted alkyl group having 1 to 20 carbon atoms, a substituted or unsubstituted fluorenyl group, a substituted or unsubstituted aryl group having 6 to 30 ring carbon atoms, or a substituted or unsubstituted heteroaryl group having 4 to 30 ring carbon atoms, R₉ is a substituted or unsubstituted alkyl group having 1 to 20 carbon atoms, a substituted or unsubstituted aryl group having 6 to 30 ring carbon atoms, or a substituted or unsubstituted heteroaryl group having 4 to 30 ring carbon atoms, Rₐ to R_{g} are each independently a hydrogen atom, a deuterium atom, a halogen atom, a substituted or unsubstituted silyl group, a substituted or unsubstituted alkyl group having 1 to 20 carbon atoms, a substituted or unsubstituted aryl group having 6 to 30 ring carbon atoms, or a substituted or unsubstituted heteroaryl group having 4 to 30 ring carbon atoms, Rₐ to R_{g} are separate or combined with an adjacent group to form a ring, and at least one of R₁ to R₈ is a group represented by the following Formula 2:

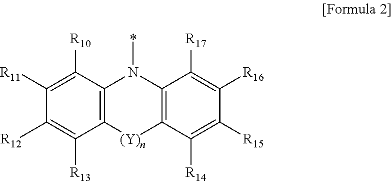

wherein, in Formula 2, n is 0 or 1, Y is direct linkage, O, S, CRₕRᵢ, SiRⱼRₖ, or GeRₗRₘ, R₁₀ to R₁₇ are each independently a hydrogen atom, a deuterium atom, a halogen atom, a substituted or unsubstituted silyl group, a substituted or unsubstituted amino group, a substituted or unsubstituted alkyl group having 1 to 20 carbon atoms, a substituted or unsubstituted fluorenyl group, a substituted or unsubstituted aryl group having 6 to 30 ring carbon atoms, or a substituted or unsubstituted heteroaryl group having 4 to 30 ring carbon atoms, Rₕ to Rₘ, are each independently a hydrogen atom, a deuterium atom, a halogen atom, a substituted or unsubstituted silyl group, a substituted or unsubstituted alkyl group having 1 to 20 carbon atoms, a substituted or unsubstituted aryl group having 6 to 30 ring carbon atoms, or a substituted or unsubstituted heteroaryl group having 4 to 30 ring carbon atoms, and Rₕ to Rₘ are separate or combined with an adjacent group to form a ring.

R₉ may be a substituted or unsubstituted phenyl group.

R₉ may be a substituted or unsubstituted pyridyl group or a substituted or unsubstituted naphthyl group.

One of R₁ to R₈ may be a group represented by Formula 2 and the remainder thereof may be a hydrogen atom.

The compound represented by Formula 1 may be represented by the following Formula 3:

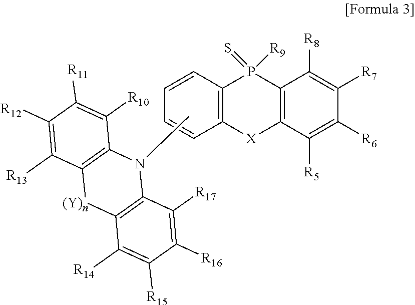

wherein, in Formula 3, R₅ to R₁₇, X, Y and n are defined the same as those of Formulae 1 and 2.

The compound represented by Formula 1 may be represented by one of the following Formulae 1-1 to 1-6:

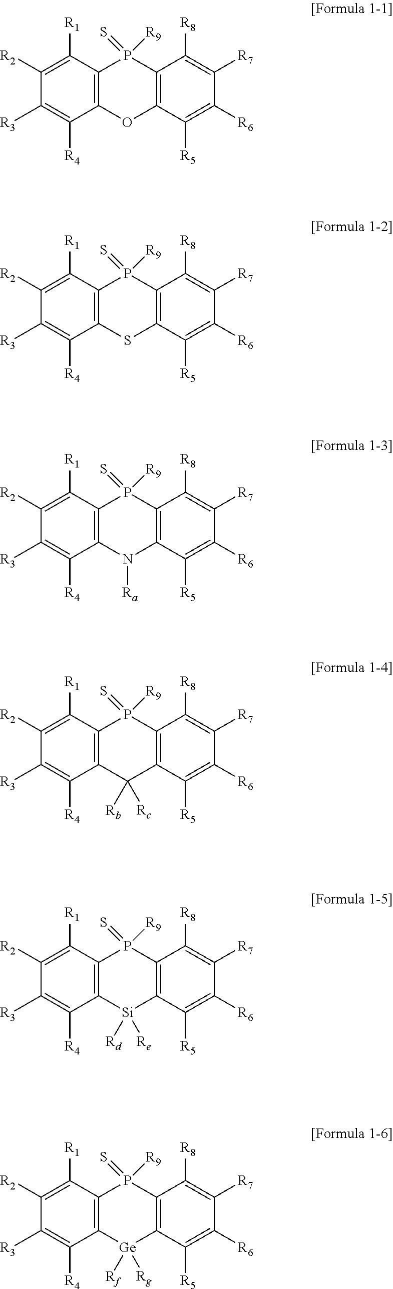

wherein, in Formulae 1-1 to 1-6, R₁ to R₉, and Rₐ to R_{g} are defined the same as those of Formula 1.

Rₐ may be a substituted or unsubstituted aryl group having 6 to 30 ring carbon atoms, and R_{b} to R_{g} may be a substituted or unsubstituted alkyl group having 1 to 20 carbon atoms or a substituted or unsubstituted aryl group having 6 to 30 ring carbon atoms.

The group represented by Formula 2 may be a group represented by one of the following Formulae 2-1 to 2-9:

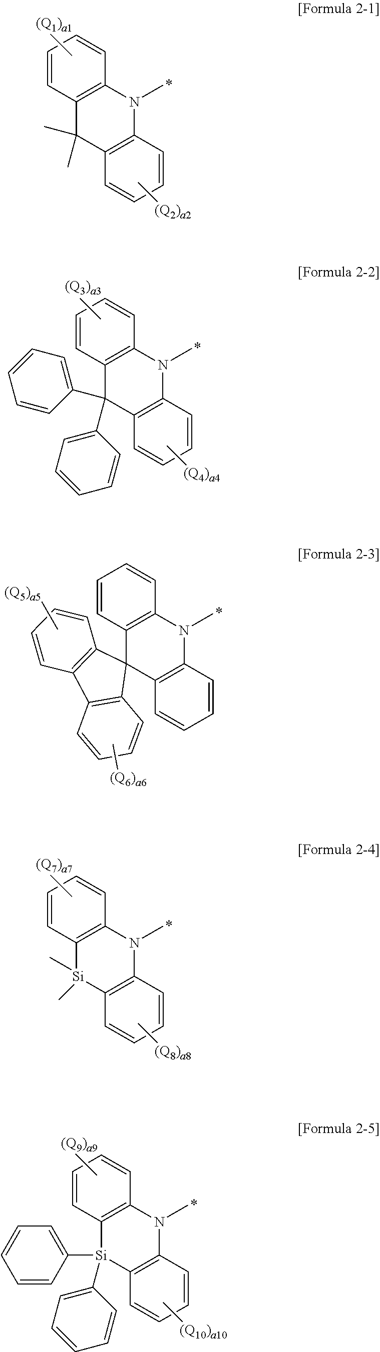

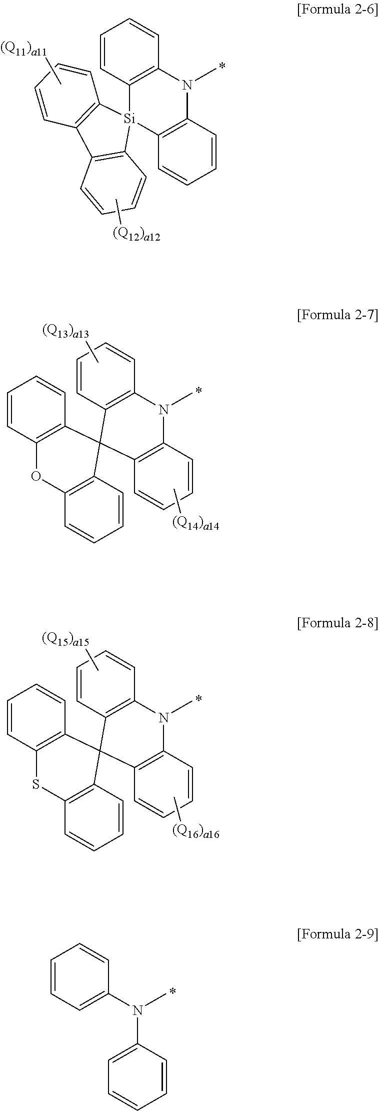

wherein, in Formulae 2-1 to 2-9, Q₁ to Q₁₆ may be a hydrogen atom, a deuterium atom, a halogen atom, a substituted or unsubstituted silyl group, or a substituted or unsubstituted alkyl group having 1 to 20 carbon atoms, and a₁ to a₁₆ may be an integer of 0 to 4.

The phosphorus-containing compound represented by Formula 1 may be a compound of the following Compound Group 1:

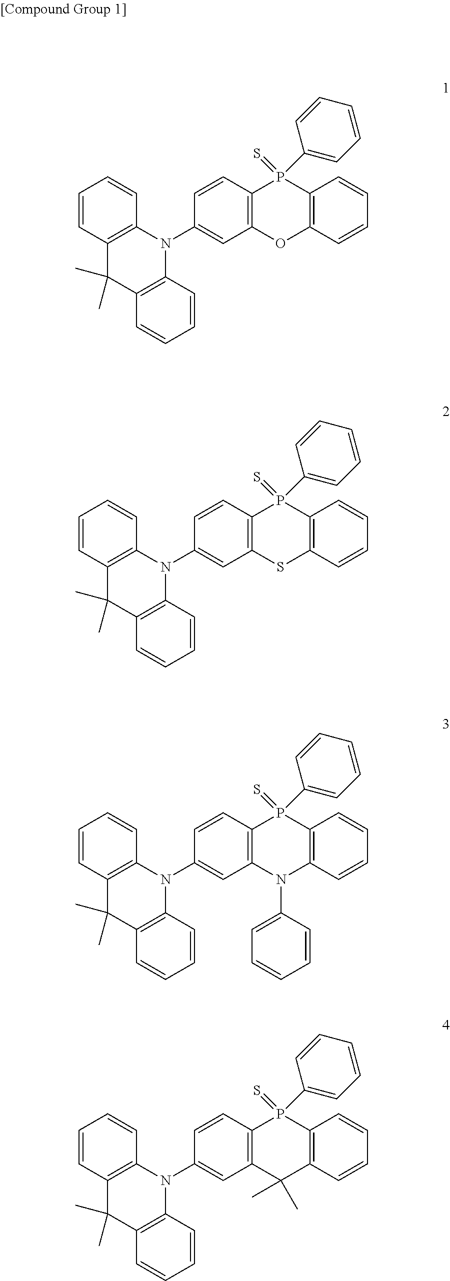 [SMILES: CC1(C)c2ccccc2N(c2ccc3c(c2)Oc2ccccc2P3(=S)c2ccccc2)c2ccccc21 ; CC1(C)c2ccccc2N(c2ccc3c(c2)Sc2ccccc2P3(=S)c2ccccc2)c2ccccc21 ; CC1(C)c2ccccc2N(c2ccc3c(c2)N(c2ccccc2)c2ccccc2P3(=S)c2ccccc2)c2ccccc21 ; CC1(C)c2ccccc2N(c2ccc3c(c2)C(C)(C)c2ccccc2P3(=S)c2ccccc2)c2ccccc21]

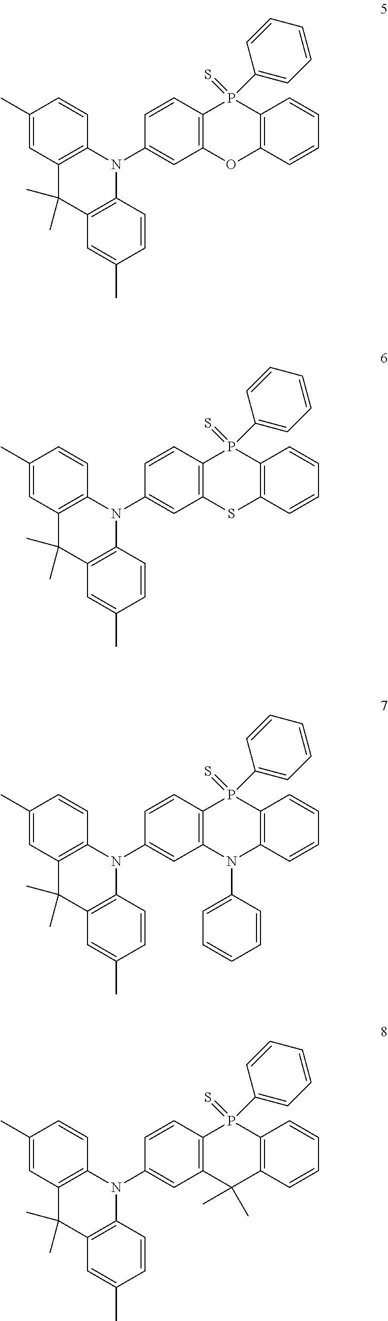 [SMILES: Cc1ccc2c(c1)C(C)(C)c1cc(C)ccc1N2c1ccc2c(c1)Oc1ccccc1P2(=S)c1ccccc1 ; Cc1ccc2c(c1)C(C)(C)c1cc(C)ccc1N2c1ccc2c(c1)Sc1ccccc1P2(=S)c1ccccc1 ; Cc1ccc2c(c1)C(C)(C)c1cc(C)ccc1N2c1ccc2c(c1)N(c1ccccc1)c1ccccc1P2(=S)c1ccccc1 ; Cc1ccc2c(c1)C(C)(C)c1cc(C)ccc1N2c1ccc2c(c1)C(C)(C)c1ccccc1P2(=S)c1ccccc1]

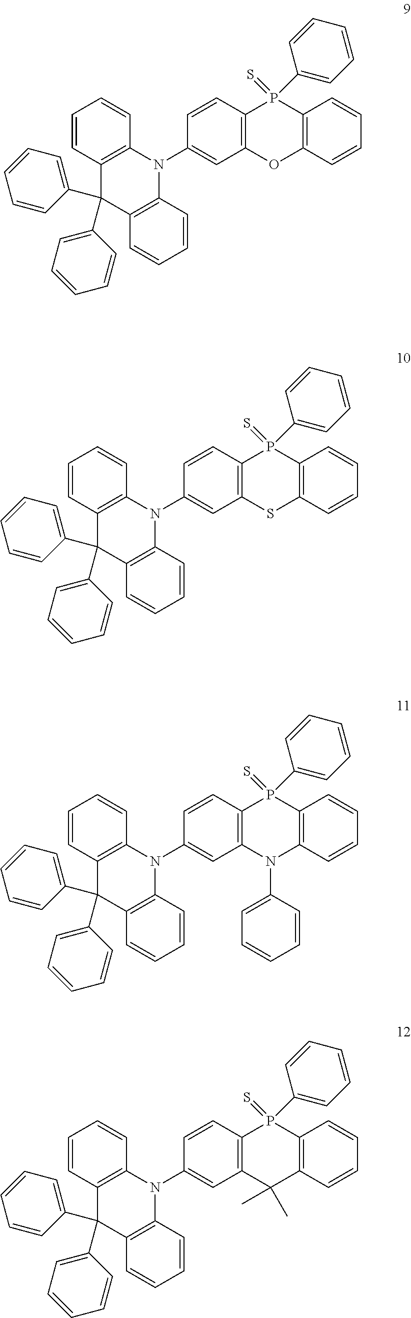 [SMILES: S=P1(c2ccccc2)c2ccccc2Oc2cc(N3c4ccccc4C(c4ccccc4)(c4ccccc4)c4ccccc43)ccc21 ; S=P1(c2ccccc2)c2ccccc2Sc2cc(N3c4ccccc4C(c4ccccc4)(c4ccccc4)c4ccccc43)ccc21 ; S=P1(c2ccccc2)c2ccccc2N(c2ccccc2)c2cc(N3c4ccccc4C(c4ccccc4)(c4ccccc4)c4ccccc43)ccc21 ; CC1(C)c2ccccc2P(=S)(c2ccccc2)c2ccc(N3c4ccccc4C(c4ccccc4)(c4ccccc4)c4ccccc43)cc21]

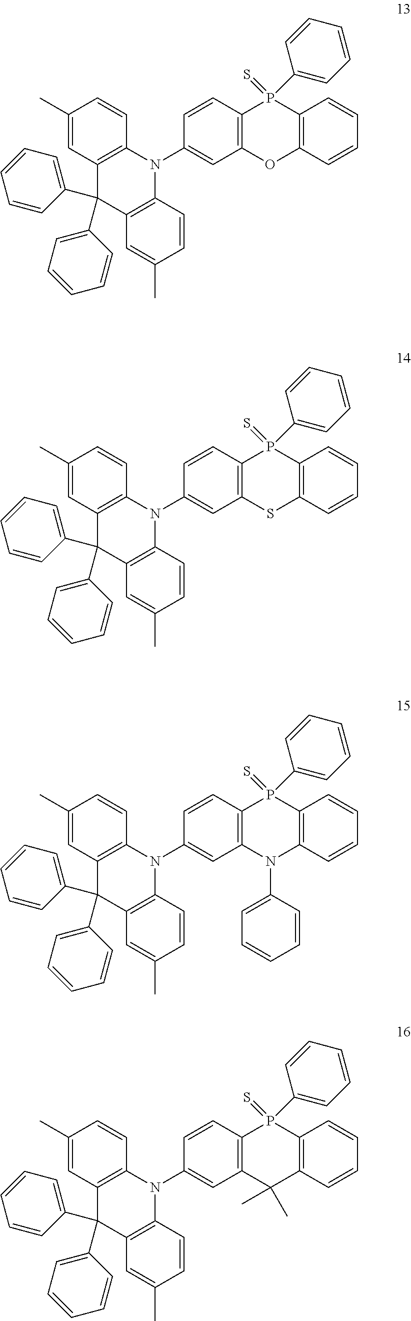 [SMILES: Cc1ccc2c(c1)C(c1ccccc1)(c1ccccc1)c1cc(C)ccc1N2c1ccc2c(c1)Oc1ccccc1P2(=S)c1ccccc1 ; Cc1ccc2c(c1)C(c1ccccc1)(c1ccccc1)c1cc(C)ccc1N2c1ccc2c(c1)Sc1ccccc1P2(=S)c1ccccc1 ; Cc1ccc2c(c1)C(c1ccccc1)(c1ccccc1)c1cc(C)ccc1N2c1ccc2c(c1)N(c1ccccc1)c1ccccc1P2(=S)c1ccccc1 ; Cc1ccc2c(c1)C(c1ccccc1)(c1ccccc1)c1cc(C)ccc1N2c1ccc2c(c1)C(C)(C)c1ccccc1P2(=S)c1ccccc1]

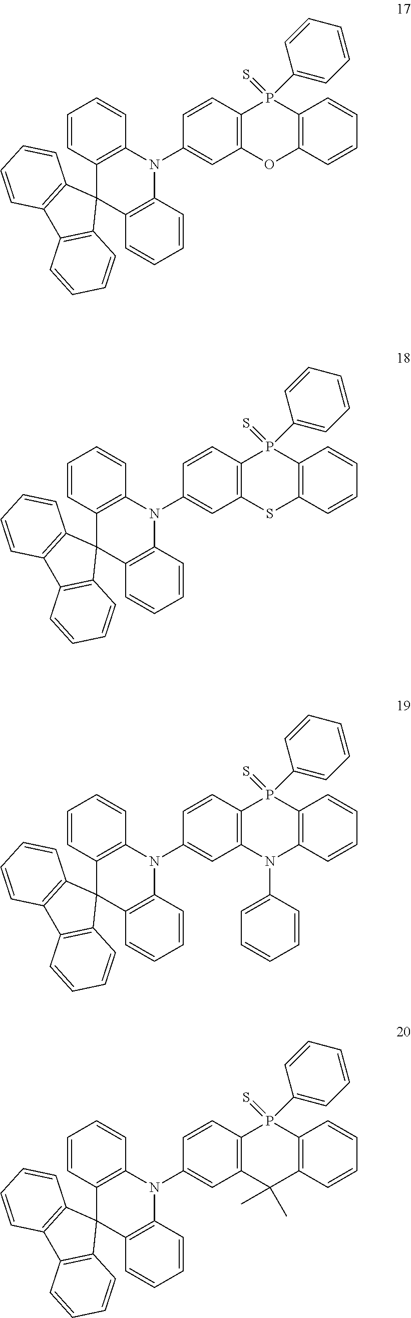 [SMILES: S=P1(c2ccccc2)c2ccccc2Oc2cc(N3c4ccccc4C4(c5ccccc5-c5ccccc54)c4ccccc43)ccc21 ; S=P1(c2ccccc2)c2ccccc2Sc2cc(N3c4ccccc4C4(c5ccccc5-c5ccccc54)c4ccccc43)ccc21 ; S=P1(c2ccccc2)c2ccccc2N(c2ccccc2)c2cc(N3c4ccccc4C4(c5ccccc5-c5ccccc54)c4ccccc43)ccc21 ; CC1(C)c2ccccc2P(=S)(c2ccccc2)c2ccc(N3c4ccccc4C4(c5ccccc5-c5ccccc54)c4ccccc43)cc21]

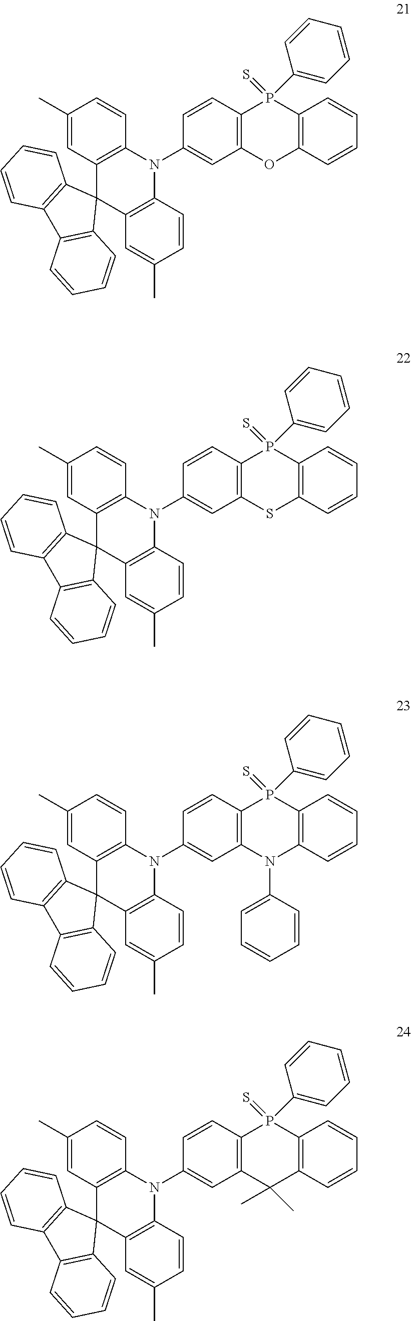 [SMILES: Cc1ccc2c(c1)C1(c3ccccc3-c3ccccc31)c1cc(C)ccc1N2c1ccc2c(c1)Oc1ccccc1P2(=S)c1ccccc1 ; Cc1ccc2c(c1)C1(c3ccccc3-c3ccccc31)c1cc(C)ccc1N2c1ccc2c(c1)Sc1ccccc1P2(=S)c1ccccc1 ; Cc1ccc2c(c1)C1(c3ccccc3-c3ccccc31)c1cc(C)ccc1N2c1ccc2c(c1)N(c1ccccc1)c1ccccc1P2(=S)c1ccccc1 ; Cc1ccc2c(c1)C1(c3ccccc3-c3ccccc31)c1cc(C)ccc1N2c1ccc2c(c1)C(C)(C)c1ccccc1P2(=S)c1ccccc1]

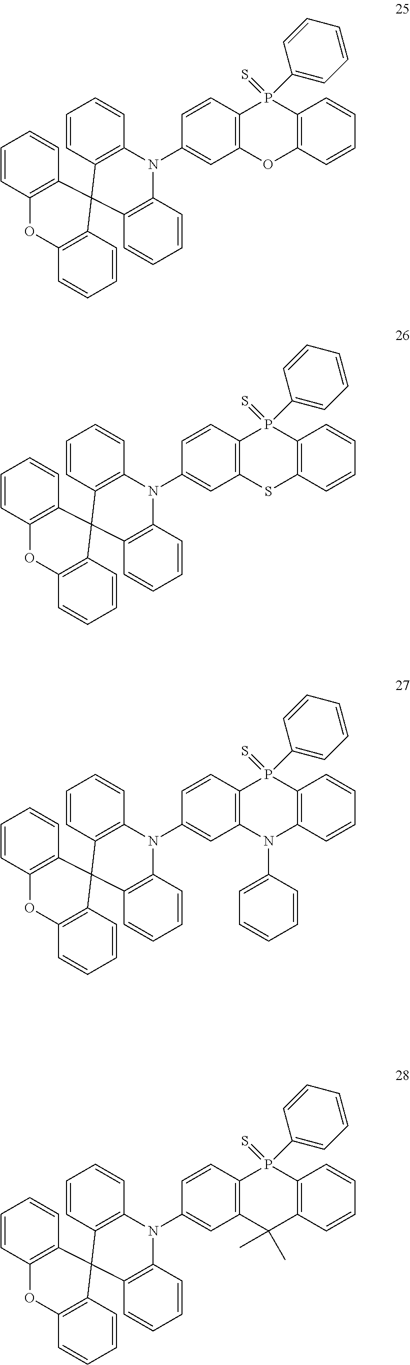 [SMILES: S=P1(c2ccccc2)c2ccccc2Oc2cc(N3c4ccccc4C4(c5ccccc5Oc5ccccc54)c4ccccc43)ccc21 ; S=P1(c2ccccc2)c2ccccc2Sc2cc(N3c4ccccc4C4(c5ccccc5Oc5ccccc54)c4ccccc43)ccc21 ; S=P1(c2ccccc2)c2ccccc2N(c2ccccc2)c2cc(N3c4ccccc4C4(c5ccccc5Oc5ccccc54)c4ccccc43)ccc21 ; CC1(C)c2ccccc2P(=S)(c2ccccc2)c2ccc(N3c4ccccc4C4(c5ccccc5Oc5ccccc54)c4ccccc43)cc21]

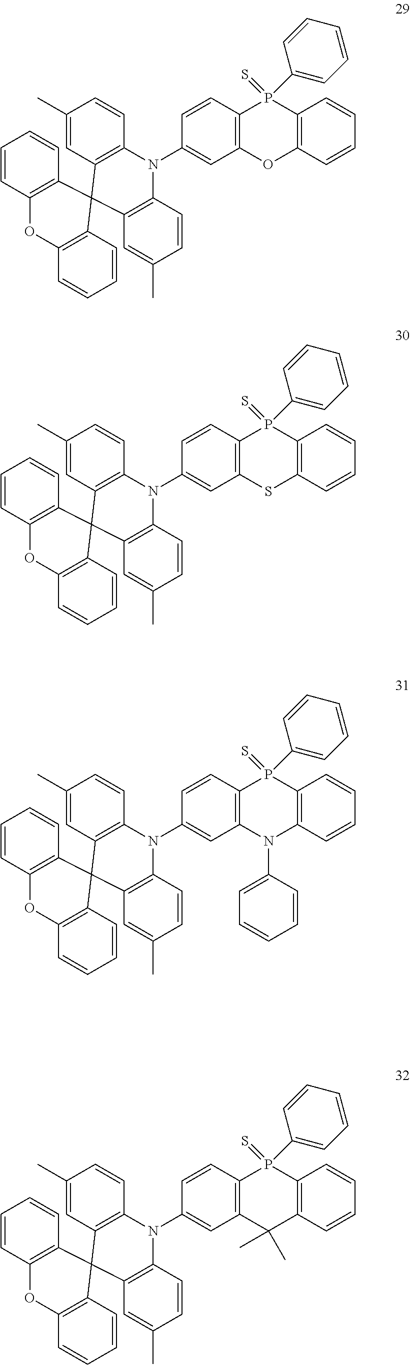 [SMILES: Cc1ccc2c(c1)C1(c3ccccc3Oc3ccccc31)c1cc(C)ccc1N2c1ccc2c(c1)Oc1ccccc1P2(=S)c1ccccc1 ; Cc1ccc2c(c1)C1(c3ccccc3Oc3ccccc31)c1cc(C)ccc1N2c1ccc2c(c1)Sc1ccccc1P2(=S)c1ccccc1 ; Cc1ccc2c(c1)C1(c3ccccc3Oc3ccccc31)c1cc(C)ccc1N2c1ccc2c(c1)N(c1ccccc1)c1ccccc1P2(=S)c1ccccc1 ; Cc1ccc2c(c1)C1(c3ccccc3Oc3ccccc31)c1cc(C)ccc1N2c1ccc2c(c1)C(C)(C)c1ccccc1P2(=S)c1ccccc1]

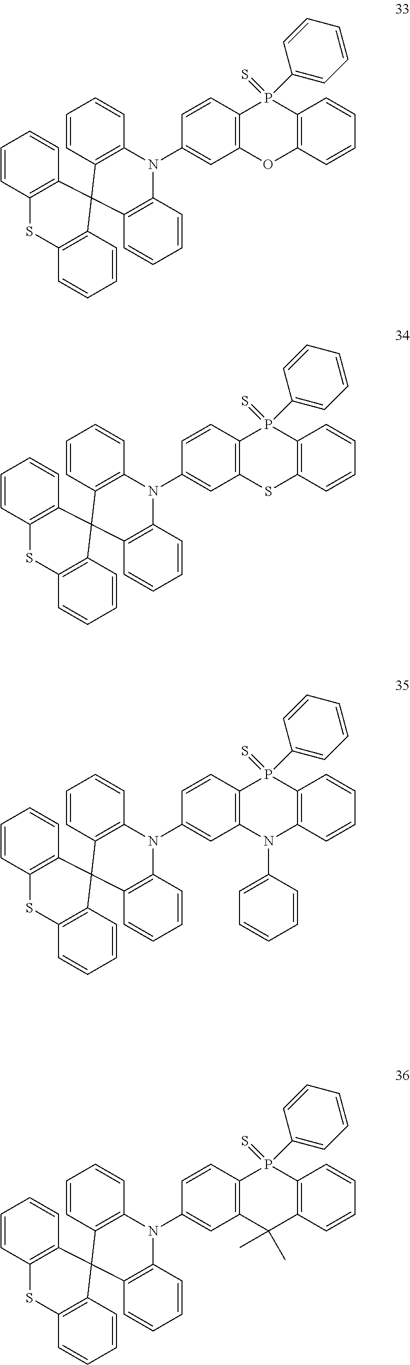 [SMILES: S=P1(c2ccccc2)c2ccccc2Oc2cc(N3c4ccccc4C4(c5ccccc5Sc5ccccc54)c4ccccc43)ccc21 ; S=P1(c2ccccc2)c2ccccc2Sc2cc(N3c4ccccc4C4(c5ccccc5Sc5ccccc54)c4ccccc43)ccc21 ; S=P1(c2ccccc2)c2ccccc2N(c2ccccc2)c2cc(N3c4ccccc4C4(c5ccccc5Sc5ccccc54)c4ccccc43)ccc21 ; CC1(C)c2ccccc2P(=S)(c2ccccc2)c2ccc(N3c4ccccc4C4(c5ccccc5Sc5ccccc54)c4ccccc43)cc21]

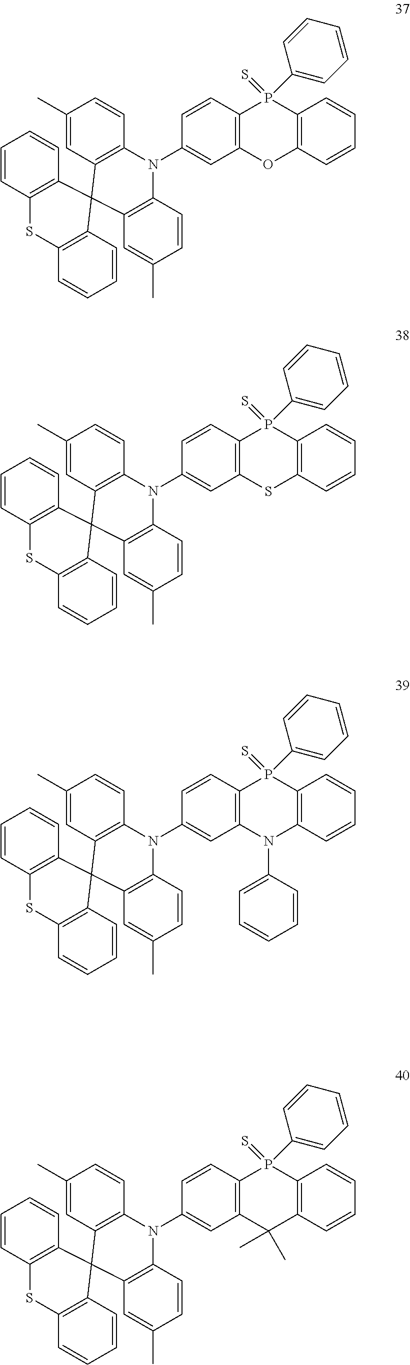 [SMILES: Cc1ccc2c(c1)C1(c3ccccc3Sc3ccccc31)c1cc(C)ccc1N2c1ccc2c(c1)Oc1ccccc1P2(=S)c1ccccc1 ; Cc1ccc2c(c1)C1(c3ccccc3Sc3ccccc31)c1cc(C)ccc1N2c1ccc2c(c1)Sc1ccccc1P2(=S)c1ccccc1 ; Cc1ccc2c(c1)C1(c3ccccc3Sc3ccccc31)c1cc(C)ccc1N2c1ccc2c(c1)N(c1ccccc1)c1ccccc1P2(=S)c1ccccc1 ; Cc1ccc2c(c1)C1(c3ccccc3Sc3ccccc31)c1cc(C)ccc1N2c1ccc2c(c1)C(C)(C)c1ccccc1P2(=S)c1ccccc1]

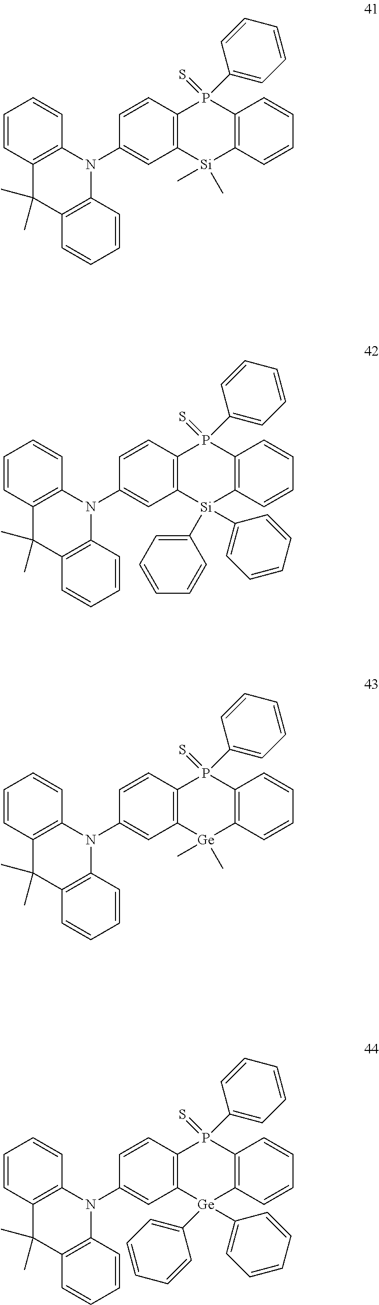

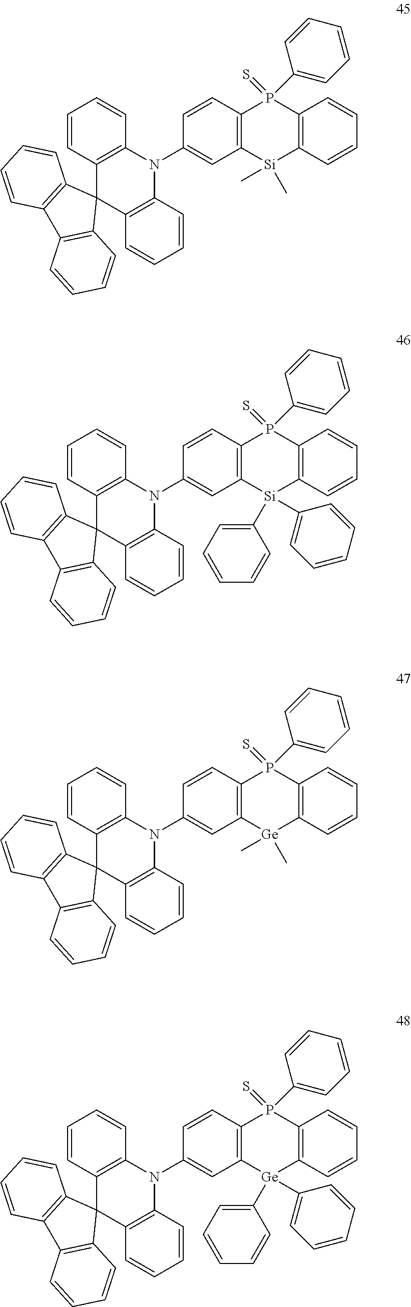

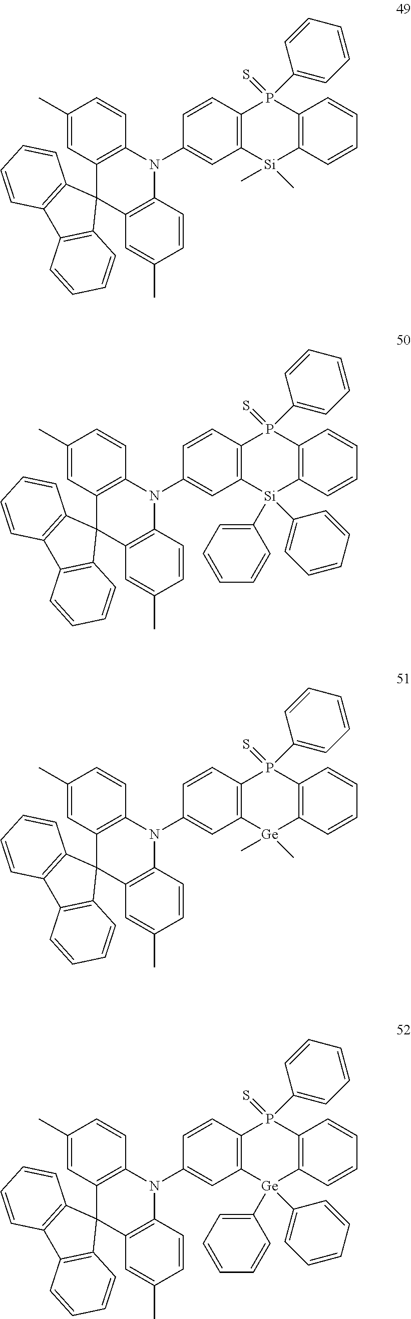

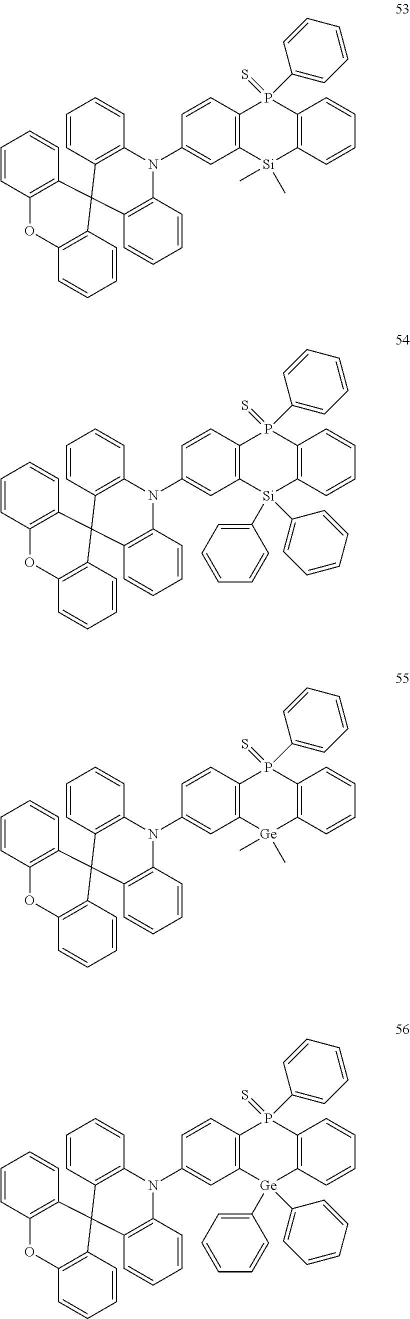

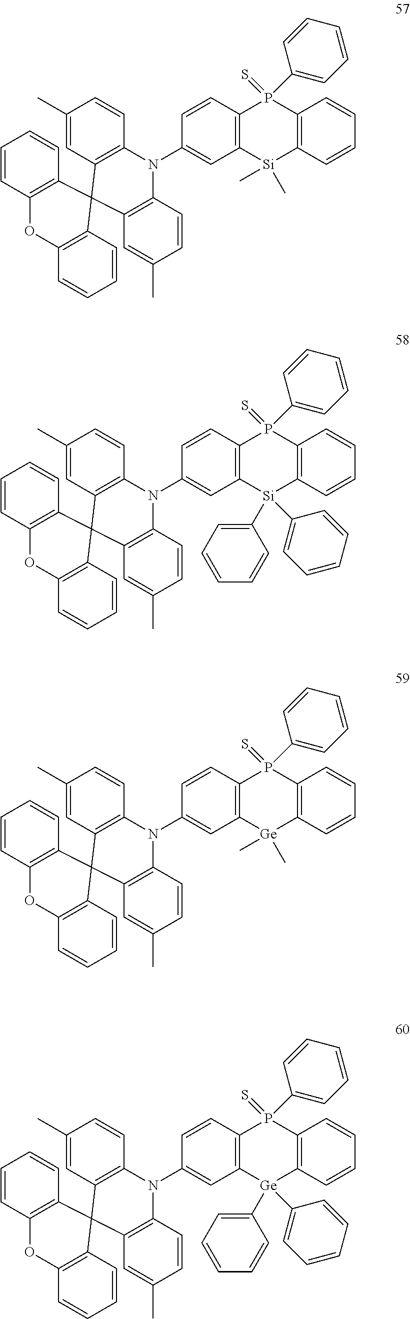

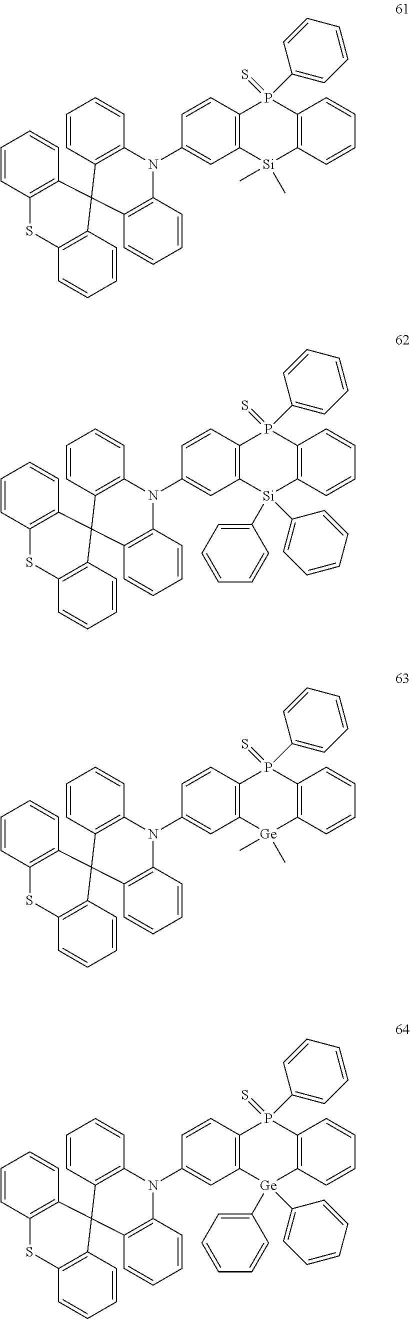

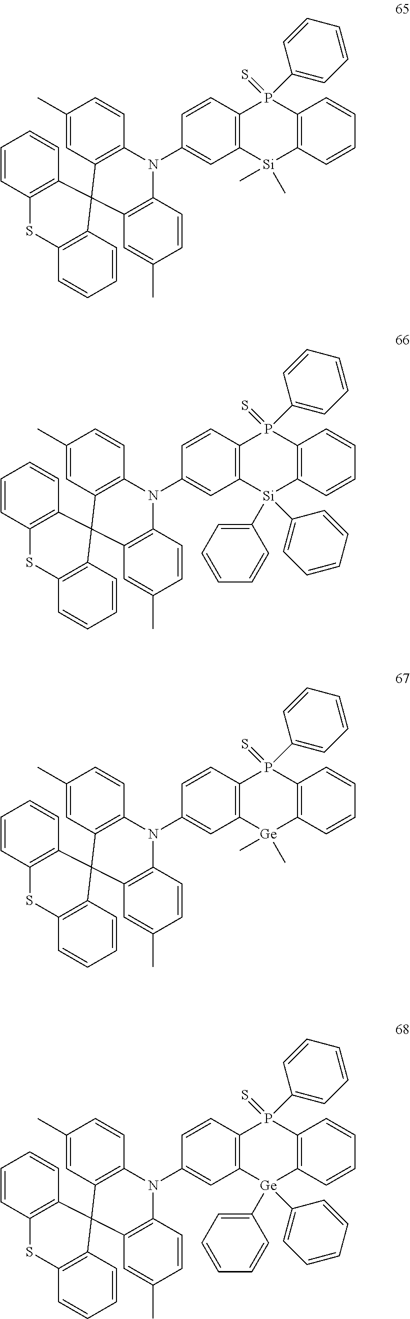

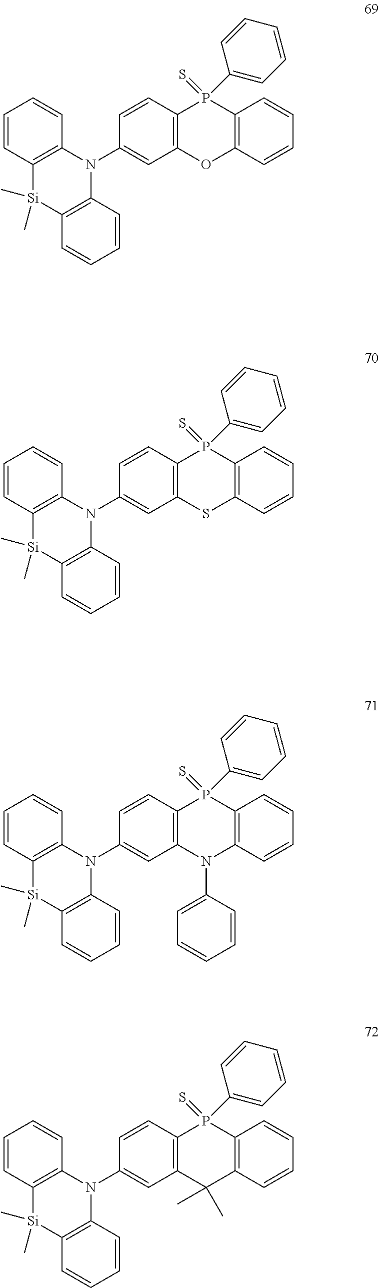 [SMILES: C[Si]1(C)c2ccccc2N(c2ccc3c(c2)Oc2ccccc2P3(=S)c2ccccc2)c2ccccc21 ; C[Si]1(C)c2ccccc2N(c2ccc3c(c2)Sc2ccccc2P3(=S)c2ccccc2)c2ccccc21 ; C[Si]1(C)c2ccccc2N(c2ccc3c(c2)N(c2ccccc2)c2ccccc2P3(=S)c2ccccc2)c2ccccc21 ; CC1(C)c2ccccc2P(=S)(c2ccccc2)c2ccc(N3c4ccccc4[Si](C)(C)c4ccccc43)cc21]

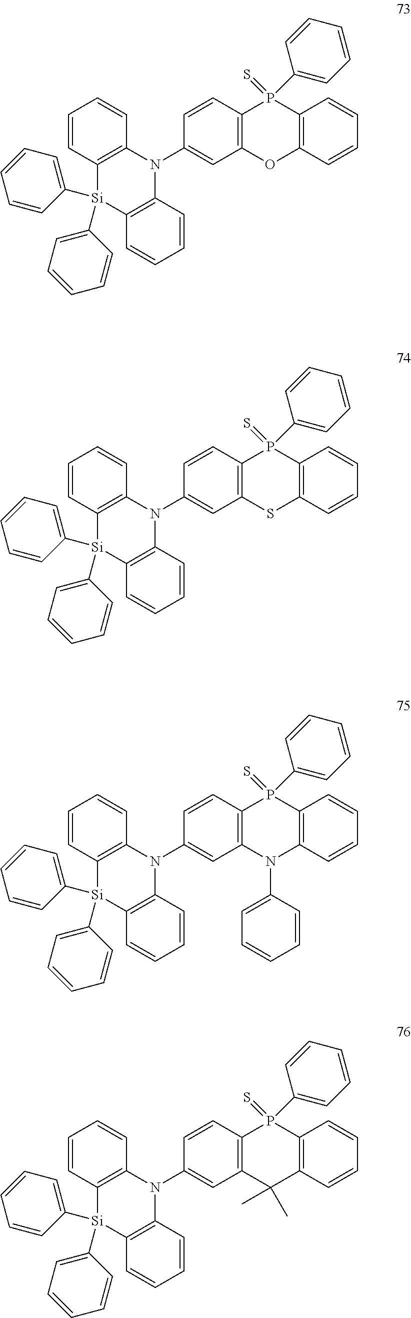 [SMILES: S=P1(c2ccccc2)c2ccccc2Oc2cc(N3c4ccccc4[Si](c4ccccc4)(c4ccccc4)c4ccccc43)ccc21 ; S=P1(c2ccccc2)c2ccccc2Sc2cc(N3c4ccccc4[Si](c4ccccc4)(c4ccccc4)c4ccccc43)ccc21 ; S=P1(c2ccccc2)c2ccccc2N(c2ccccc2)c2cc(N3c4ccccc4[Si](c4ccccc4)(c4ccccc4)c4ccccc43)ccc21 ; CC1(C)c2ccccc2P(=S)(c2ccccc2)c2ccc(N3c4ccccc4[Si](c4ccccc4)(c4ccccc4)c4ccccc43)cc21]

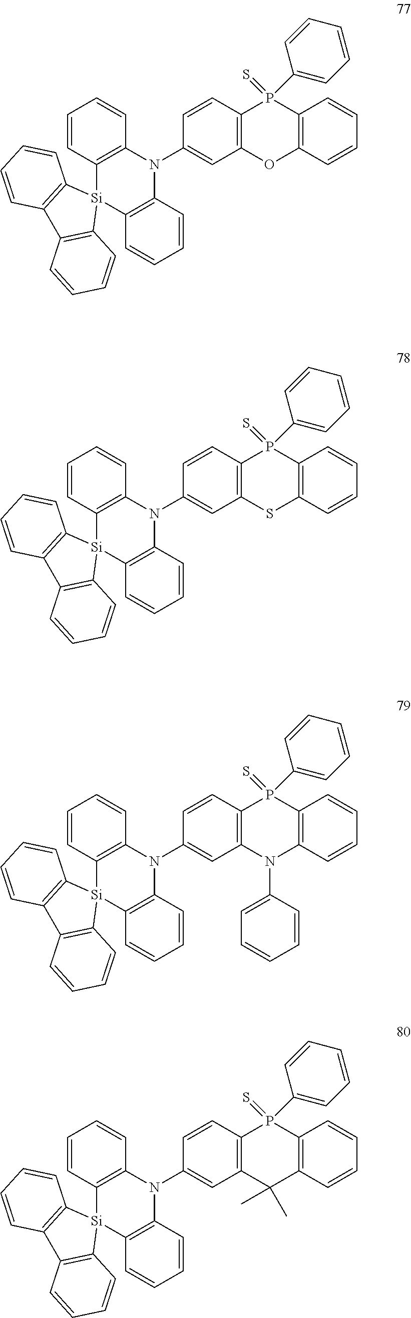 [SMILES: S=P1(c2ccccc2)c2ccccc2Oc2cc(N3c4ccccc4[Si]4(c5ccccc5-c5ccccc54)c4ccccc43)ccc21 ; S=P1(c2ccccc2)c2ccccc2Sc2cc(N3c4ccccc4[Si]4(c5ccccc5-c5ccccc54)c4ccccc43)ccc21 ; S=P1(c2ccccc2)c2ccccc2N(c2ccccc2)c2cc(N3c4ccccc4[Si]4(c5ccccc5-c5ccccc54)c4ccccc43)ccc21 ; CC1(C)c2ccccc2P(=S)(c2ccccc2)c2ccc(N3c4ccccc4[Si]4(c5ccccc5-c5ccccc54)c4ccccc43)cc21]

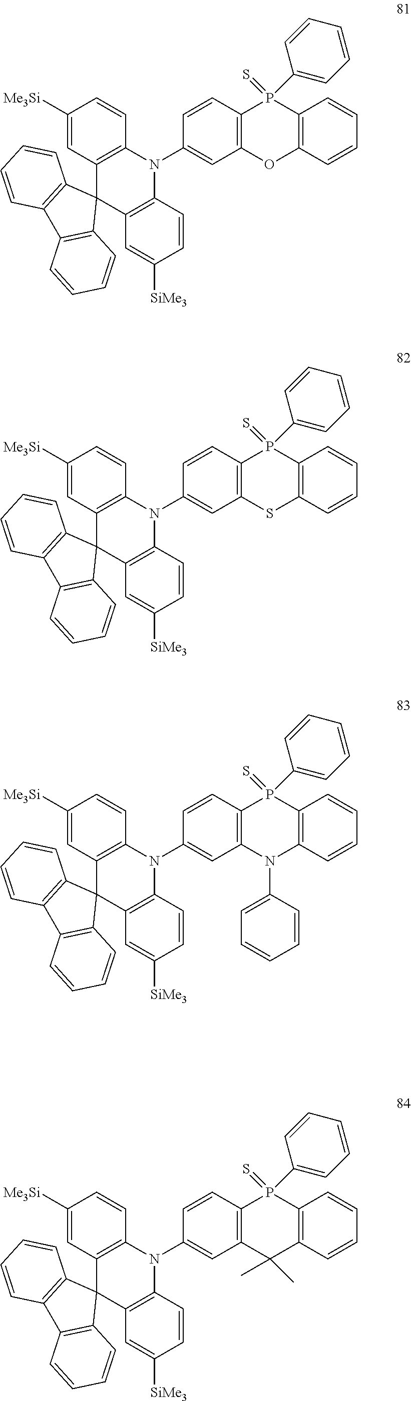 [SMILES: C[Si](C)(C)c1ccc2c(c1)C1(c3ccccc3-c3ccccc31)c1cc([Si](C)(C)C)ccc1N2c1ccc2c(c1)Oc1ccccc1P2(=S)c1ccccc1 ; C[Si](C)(C)c1ccc2c(c1)C1(c3ccccc3-c3ccccc31)c1cc([Si](C)(C)C)ccc1N2c1ccc2c(c1)Sc1ccccc1P2(=S)c1ccccc1 ; C[Si](C)(C)c1ccc2c(c1)C1(c3ccccc3-c3ccccc31)c1cc([Si](C)(C)C)ccc1N2c1ccc2c(c1)N(c1ccccc1)c1ccccc1P2(=S)c1ccccc1 ; CC1(C)c2ccccc2P(=S)(c2ccccc2)c2ccc(N3c4ccc([Si](C)(C)C)cc4C4(c5ccccc5-c5ccccc54)c4cc([Si](C)(C)C)ccc43)cc21]

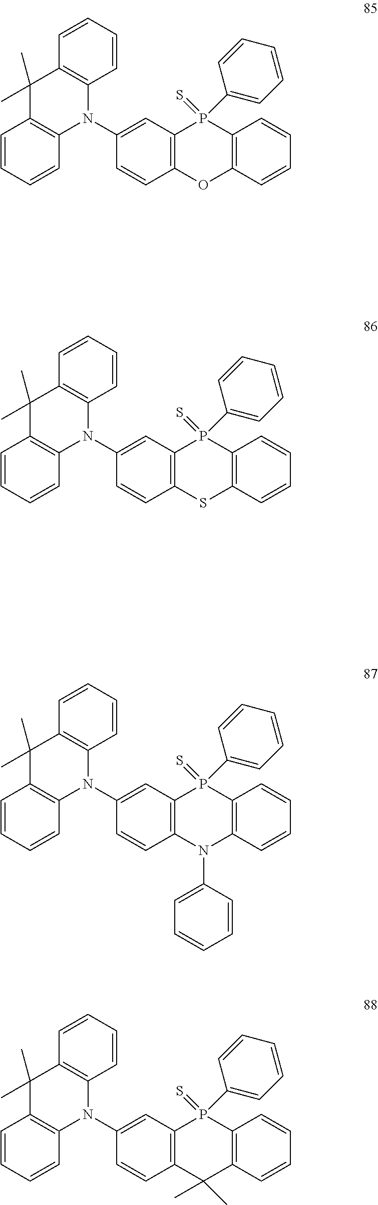 [SMILES: CC1(C)c2ccccc2N(c2ccc3c(c2)P(=S)(c2ccccc2)c2ccccc2O3)c2ccccc21 ; CC1(C)c2ccccc2N(c2ccc3c(c2)P(=S)(c2ccccc2)c2ccccc2S3)c2ccccc21 ; CC1(C)c2ccccc2N(c2ccc3c(c2)P(=S)(c2ccccc2)c2ccccc2N3c2ccccc2)c2ccccc21 ; CC1(C)c2ccccc2N(c2ccc3c(c2)P(=S)(c2ccccc2)c2ccccc2C3(C)C)c2ccccc21]

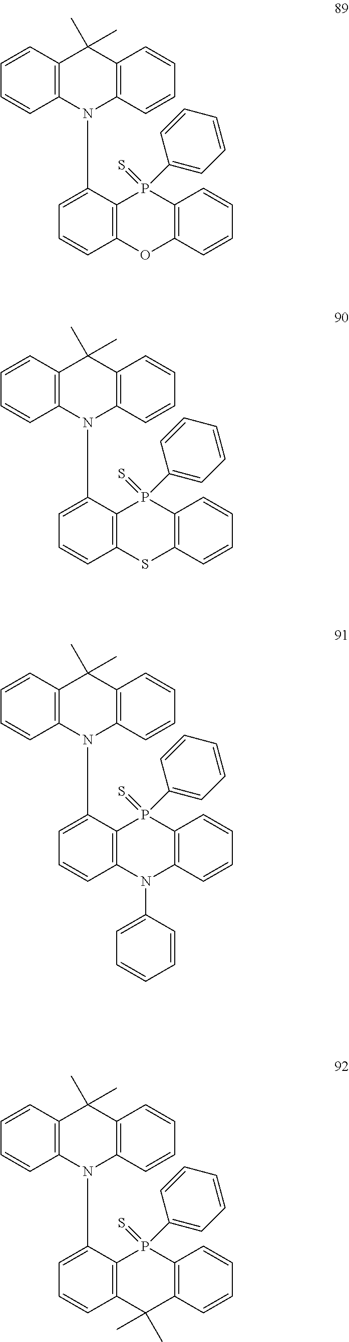 [SMILES: CC1(C)c2ccccc2N(c2cccc3c2P(=S)(c2ccccc2)c2ccccc2O3)c2ccccc21 ; CC1(C)c2ccccc2N(c2cccc3c2P(=S)(c2ccccc2)c2ccccc2S3)c2ccccc21 ; CC1(C)c2ccccc2N(c2cccc3c2P(=S)(c2ccccc2)c2ccccc2N3c2ccccc2)c2ccccc21 ; CC1(C)c2ccccc2N(c2cccc3c2P(=S)(c2ccccc2)c2ccccc2C3(C)C)c2ccccc21]

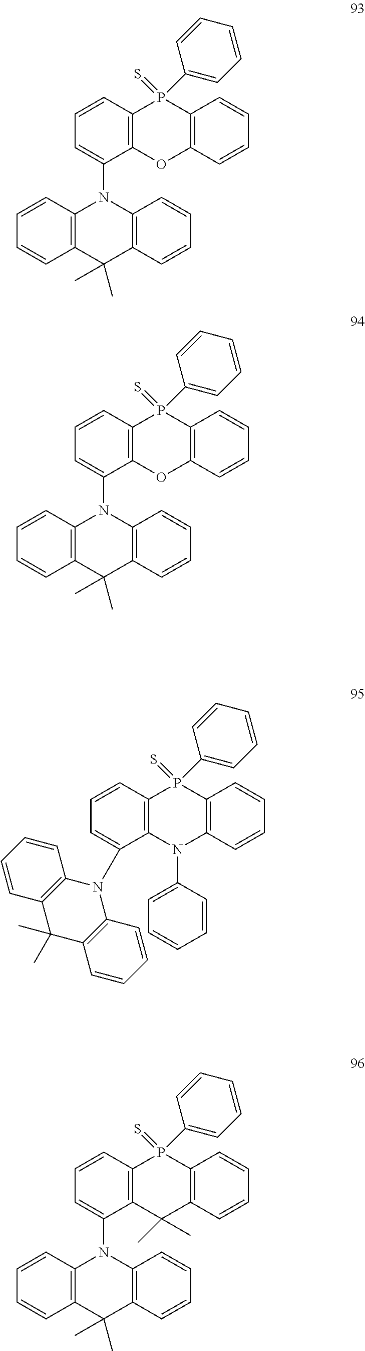 [SMILES: CC1(C)c2ccccc2N(c2cccc3c2Oc2ccccc2P3(=S)c2ccccc2)c2ccccc21 ; CC1(C)c2ccccc2N(c2cccc3c2Oc2ccccc2P3(=S)c2ccccc2)c2ccccc21 ; CC1(C)c2ccccc2N(c2cccc3c2N(c2ccccc2)c2ccccc2P3(=S)c2ccccc2)c2ccccc21 ; CC1(C)c2ccccc2N(c2cccc3c2C(C)(C)c2ccccc2P3(=S)c2ccccc2)c2ccccc21]

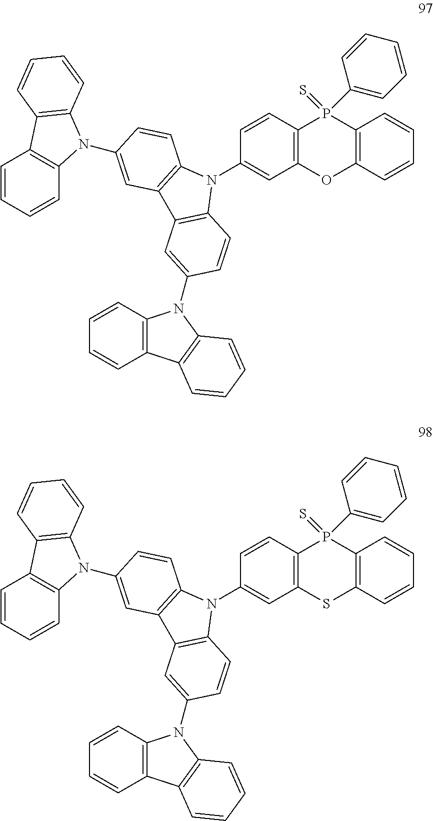 [SMILES: S=P1(c2ccccc2)c2ccccc2Oc2cc(-n3c4ccc(-n5c6ccccc6c6ccccc65)cc4c4cc(-n5c6ccccc6c6ccccc65)ccc43)ccc21 ; S=P1(c2ccccc2)c2ccccc2Sc2cc(-n3c4ccc(-n5c6ccccc6c6ccccc65)cc4c4cc(-n5c6ccccc6c6ccccc65)ccc43)ccc21]

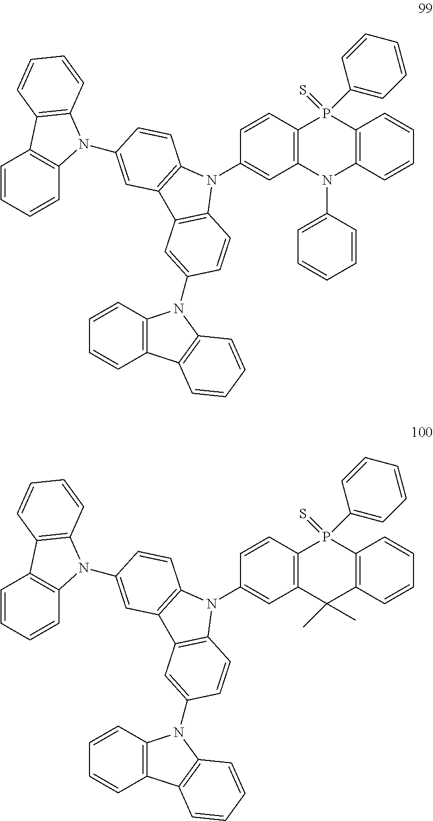 [SMILES: S=P1(c2ccccc2)c2ccccc2N(c2ccccc2)c2cc(-n3c4ccc(-n5c6ccccc6c6ccccc65)cc4c4cc(-n5c6ccccc6c6ccccc65)ccc43)ccc21 ; CC1(C)c2ccccc2P(=S)(c2ccccc2)c2ccc(-n3c4ccc(-n5c6ccccc6c6ccccc65)cc4c4cc(-n5c6ccccc6c6ccccc65)ccc43)cc21]

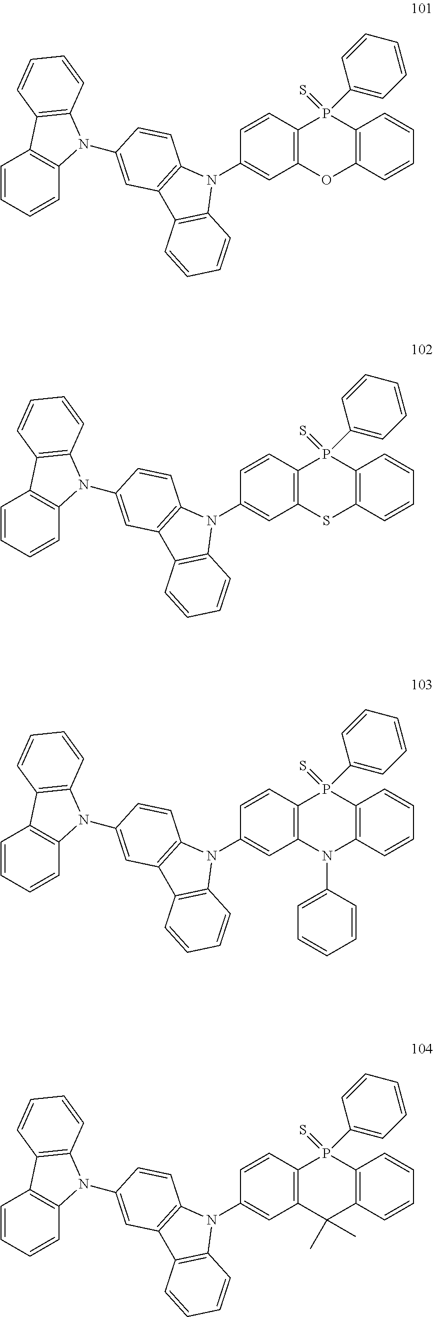 [SMILES: S=P1(c2ccccc2)c2ccccc2Oc2cc(-n3c4ccccc4c4cc(-n5c6ccccc6c6ccccc65)ccc43)ccc21 ; S=P1(c2ccccc2)c2ccccc2Sc2cc(-n3c4ccccc4c4cc(-n5c6ccccc6c6ccccc65)ccc43)ccc21 ; S=P1(c2ccccc2)c2ccccc2N(c2ccccc2)c2cc(-n3c4ccccc4c4cc(-n5c6ccccc6c6ccccc65)ccc43)ccc21 ; CC1(C)c2ccccc2P(=S)(c2ccccc2)c2ccc(-n3c4ccccc4c4cc(-n5c6ccccc6c6ccccc65)ccc43)cc21]

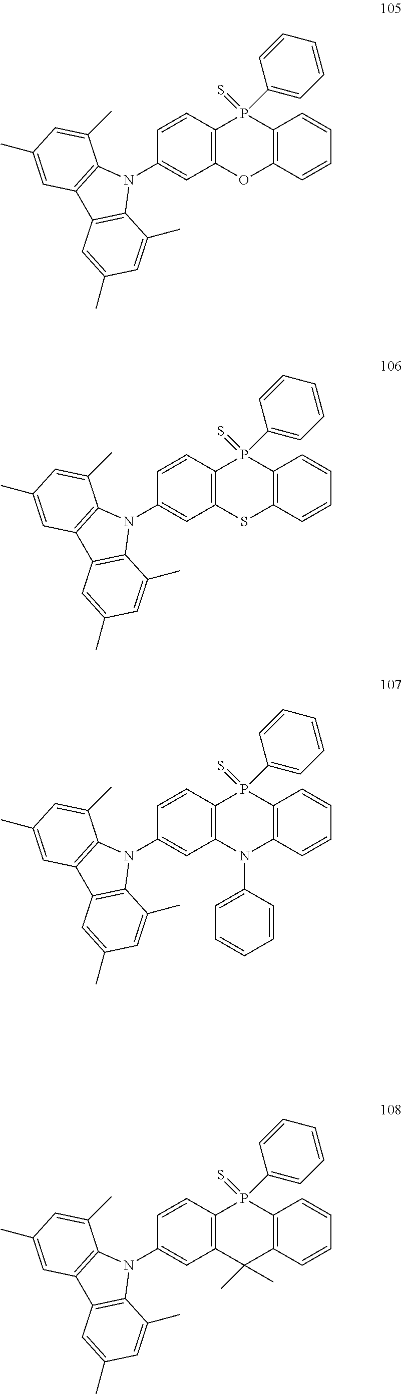 [SMILES: Cc1cc(C)c2c(c1)c1cc(C)cc(C)c1n2-c1ccc2c(c1)Oc1ccccc1P2(=S)c1ccccc1 ; Cc1cc(C)c2c(c1)c1cc(C)cc(C)c1n2-c1ccc2c(c1)Sc1ccccc1P2(=S)c1ccccc1 ; Cc1cc(C)c2c(c1)c1cc(C)cc(C)c1n2-c1ccc2c(c1)N(c1ccccc1)c1ccccc1P2(=S)c1ccccc1 ; Cc1cc(C)c2c(c1)c1cc(C)cc(C)c1n2-c1ccc2c(c1)C(C)(C)c1ccccc1P2(=S)c1ccccc1]

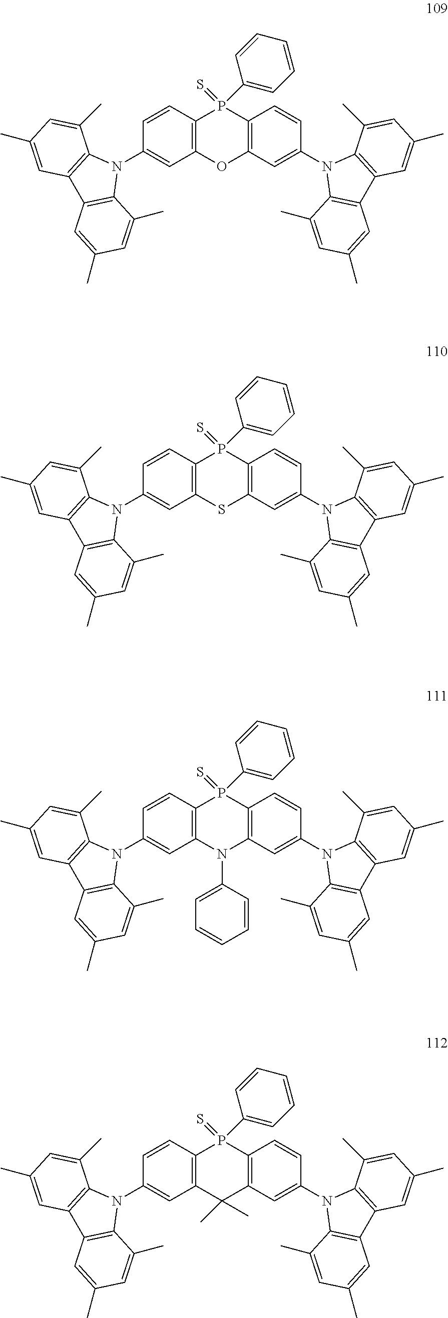

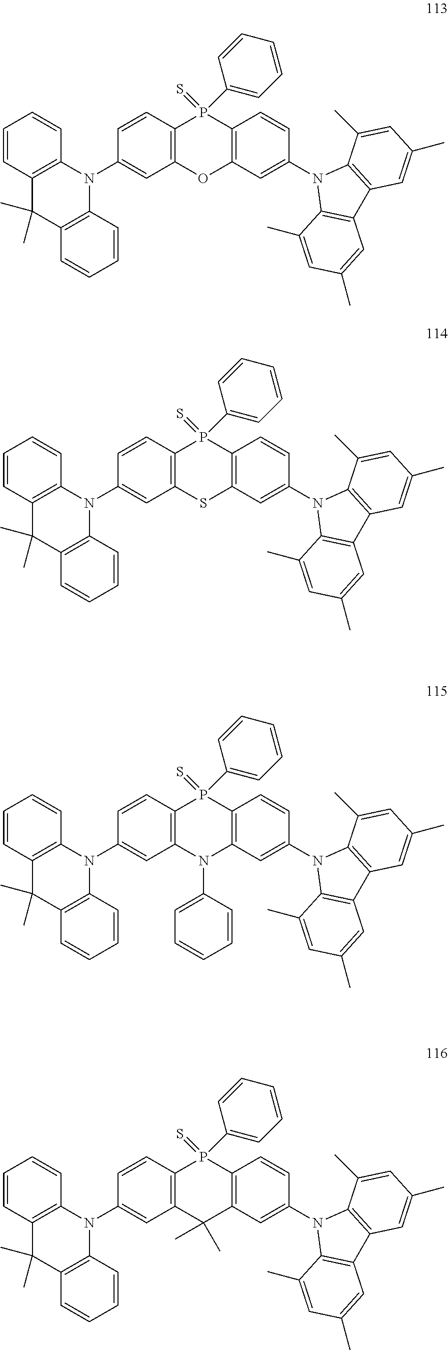

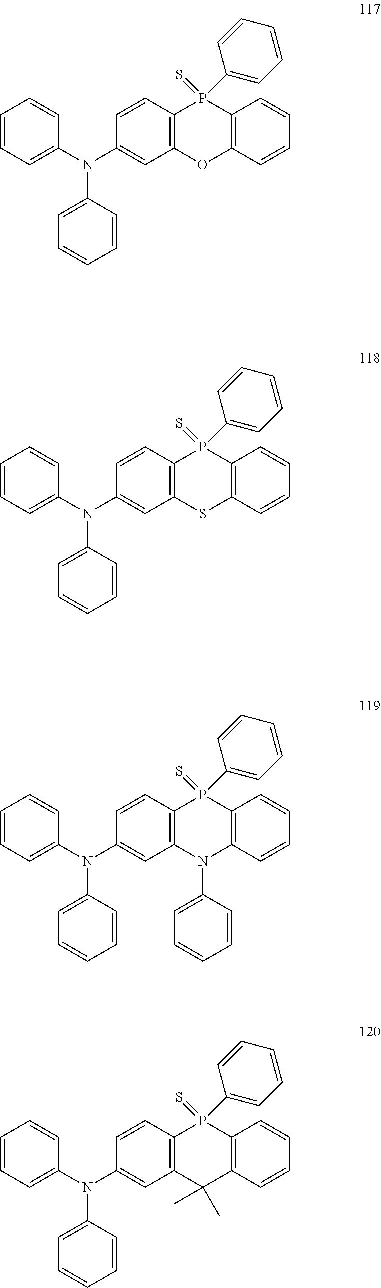 [SMILES: S=P1(c2ccccc2)c2ccccc2Oc2cc(N(c3ccccc3)c3ccccc3)ccc21 ; S=P1(c2ccccc2)c2ccccc2Sc2cc(N(c3ccccc3)c3ccccc3)ccc21 ; S=P1(c2ccccc2)c2ccccc2N(c2ccccc2)c2cc(N(c3ccccc3)c3ccccc3)ccc21 ; CC1(C)c2ccccc2P(=S)(c2ccccc2)c2ccc(N(c3ccccc3)c3ccccc3)cc21]

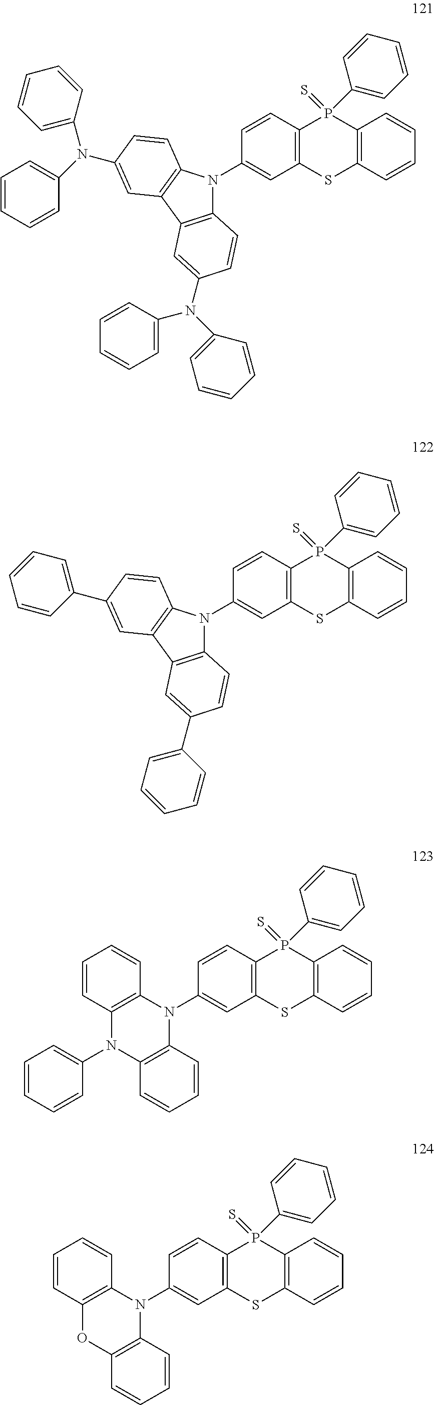 [SMILES: S=P1(c2ccccc2)c2ccccc2Sc2cc(-n3c4ccc(N(c5ccccc5)c5ccccc5)cc4c4cc(N(c5ccccc5)c5ccccc5)ccc43)ccc21 ; S=P1(c2ccccc2)c2ccccc2Sc2cc(-n3c4ccc(-c5ccccc5)cc4c4cc(-c5ccccc5)ccc43)ccc21 ; S=P1(c2ccccc2)c2ccccc2Sc2cc(N3c4ccccc4N(c4ccccc4)c4ccccc43)ccc21 ; S=P1(c2ccccc2)c2ccccc2Sc2cc(N3c4ccccc4Oc4ccccc43)ccc21]

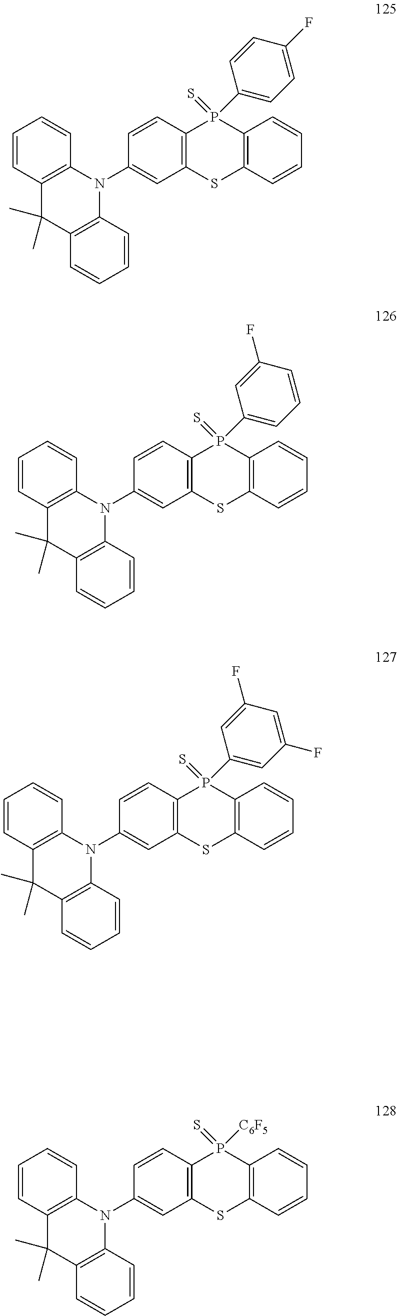

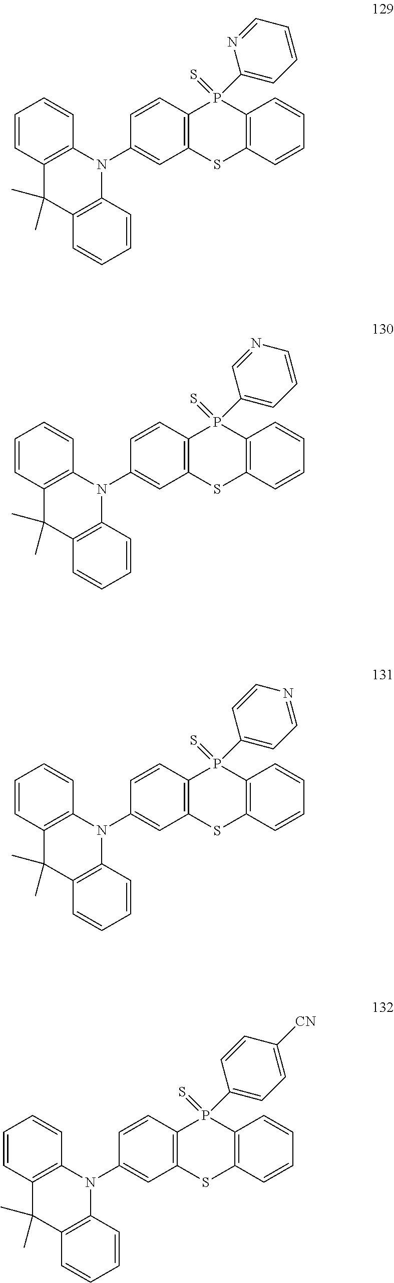 [SMILES: CC1(C)c2ccccc2N(c2ccc3c(c2)Sc2ccccc2P3(=S)c2ccccn2)c2ccccc21 ; CC1(C)c2ccccc2N(c2ccc3c(c2)Sc2ccccc2P3(=S)c2cccnc2)c2ccccc21 ; CC1(C)c2ccccc2N(c2ccc3c(c2)Sc2ccccc2P3(=S)c2ccncc2)c2ccccc21 ; CC1(C)c2ccccc2N(c2ccc3c(c2)Sc2ccccc2P3(=S)c2ccc(C#N)cc2)c2ccccc21]

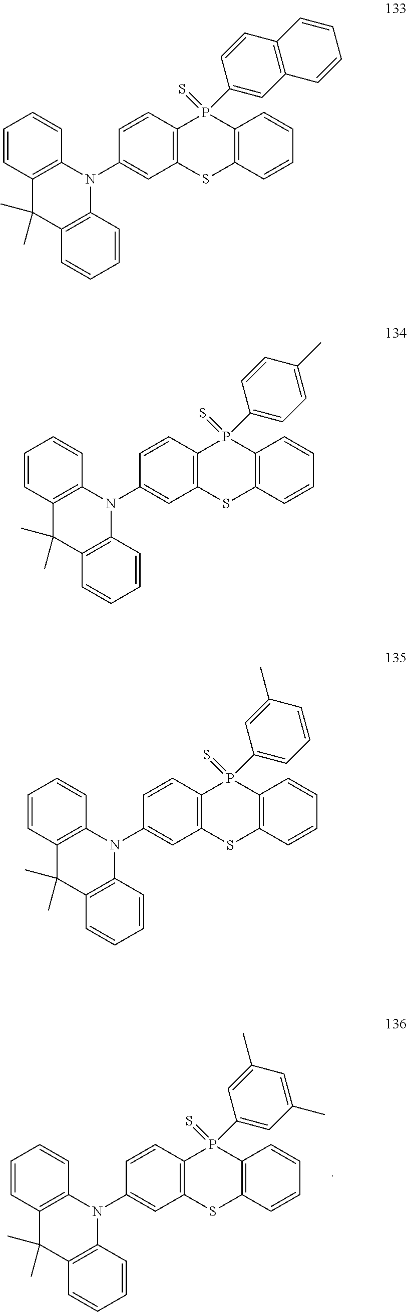

The embodiments may be realized by providing an organic electroluminescence device including a first electrode; a hole transport region on the first electrode; an emission layer on the hole transport region; an electron transport region on the emission layer; and a second electrode on the electron transport region, wherein the emission layer includes a phosphorus-containing compound represented by the following Formula 1:

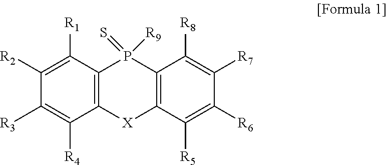

wherein, in Formula 1, X is O, S, NRₐ, CR_{b}R_{c}, SiR_{d}Rₑ, or GeR_{f}R_{g}, R₁ to R₈ are each independently a hydrogen atom, a deuterium atom, a halogen atom, a substituted or unsubstituted silyl group, a substituted or unsubstituted amino group, a substituted or unsubstituted alkyl group having 1 to 20 carbon atoms, a substituted or unsubstituted aryl group having 6 to 30 ring carbon atoms, or a substituted or unsubstituted heteroaryl group having 4 to 30 ring carbon atoms, R₉ is a substituted or unsubstituted alkyl group having 1 to 20 carbon atoms, a substituted or unsubstituted fluorenyl group, a substituted or unsubstituted aryl group having 6 to 30 ring carbon atoms, or a substituted or unsubstituted heteroaryl group having 4 to 30 ring carbon atoms, Rₐ to R_{g} are each independently a hydrogen atom, a deuterium atom, a halogen atom, a substituted or unsubstituted silyl group, a substituted or unsubstituted alkyl group having 1 to 20 carbon atoms, a substituted or unsubstituted aryl group having 6 to 30 ring carbon atoms, or a substituted or unsubstituted heteroaryl group having 4 to 30 ring carbon atoms, R₁ to R₈ are separate or combined with an adjacent group to form a ring, and at least one of R₁ to R₈ is a group represented by the following Formula 2:

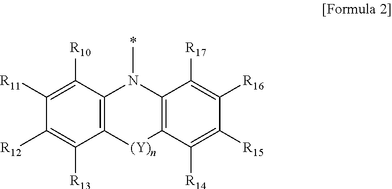

wherein, in Formula 2, n is 0 or 1, Y is direct linkage, O, S, CRₕRᵢ, SiRⱼRₖ, or GeRₗRₘ, R₁₀ to R₁₇ are each independently a hydrogen atom, a deuterium atom, a halogen atom, a substituted or unsubstituted silyl group, a substituted or unsubstituted amino group, a substituted or unsubstituted alkyl group having 1 to 20 carbon atoms, a substituted or unsubstituted aryl group having 6 to 30 ring carbon atoms, or a substituted or unsubstituted heteroaryl group having 4 to 30 ring carbon atoms, Rₕ to Rₘ are each independently a hydrogen atom, a deuterium atom, a halogen atom, a substituted or unsubstituted silyl group, a substituted or unsubstituted alkyl group having 1 to 20 carbon atoms, a substituted or unsubstituted aryl group having 6 to 30 ring carbon atoms, or a substituted or unsubstituted heteroaryl group having 4 to 30 ring carbon atoms, and Rₕ to Rₘ are separate or combined with an adjacent group to form a ring.

The phosphorus-containing compound may be a thermally activated delayed fluorescence material.

The compound represented by Formula 1 may be represented by the following Formula 3:

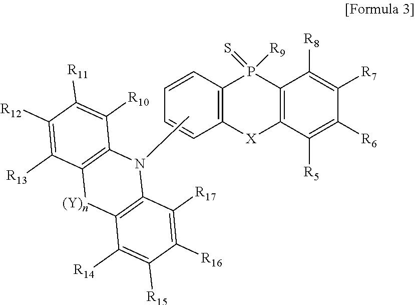

wherein, in Formula 3, R₅ to R₁₇, X, Y and n are defined the same as those of Formulae 1 and 2.

R₉ may be a substituted or unsubstituted phenyl group, a substituted or unsubstituted pyridyl group, or a substituted or unsubstituted naphthyl group.

The group represented by Formula 2 may be a group represented by one of the following Formulae 2-1 to 2-9:

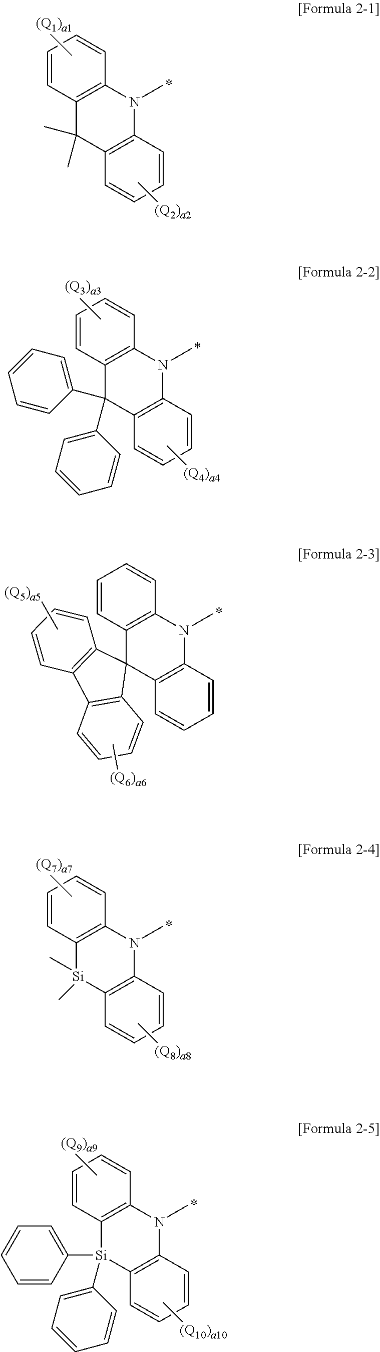

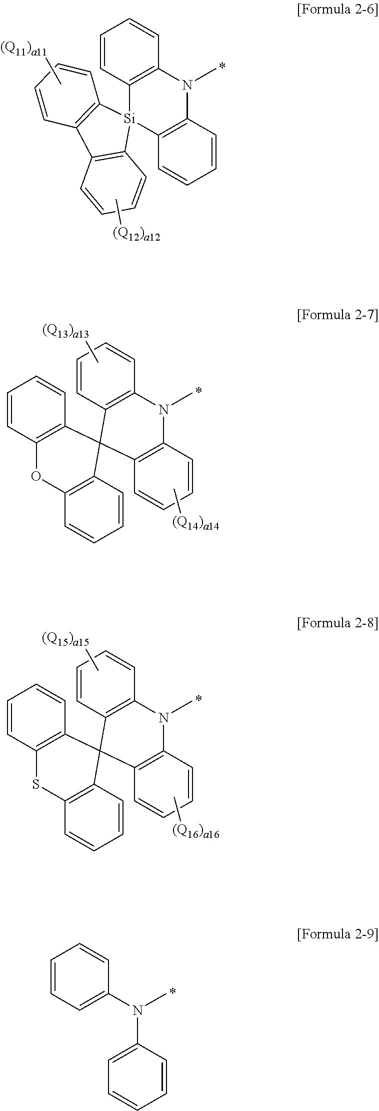

wherein, in Formulae 2-1 to 2-9, Q₁ to Q₁₆ may be a hydrogen atom, a deuterium atom, a halogen atom, a substituted or unsubstituted silyl group, or a substituted or unsubstituted alkyl group having 1 to 20 carbon atoms, and a₁ to a₁₆ may be an integer of 0 to 4.

The phosphorus-containing compound represented by Formula 1 may be a compound of the following Compound Group 1:

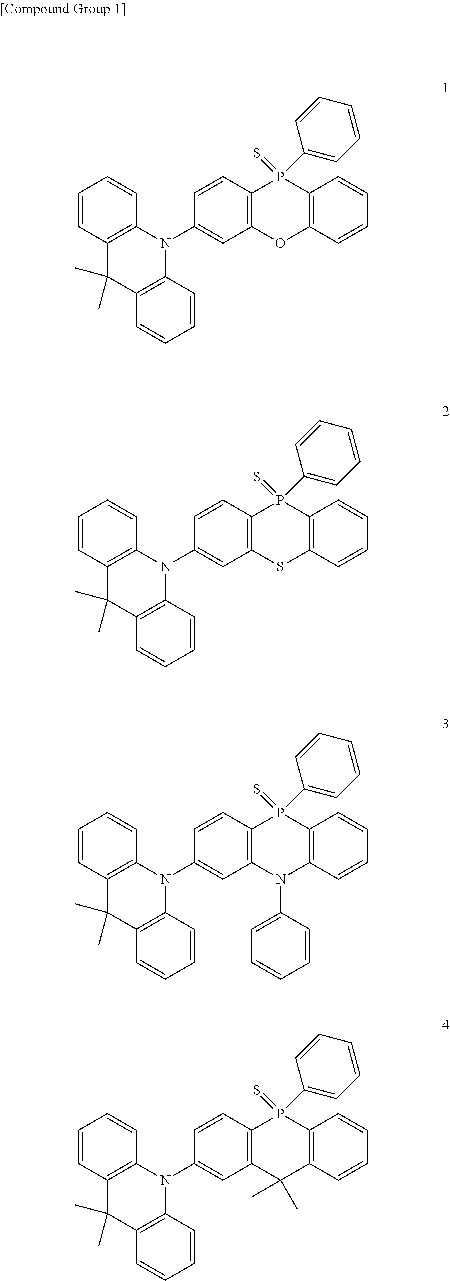 [SMILES: CC1(C)c2ccccc2N(c2ccc3c(c2)Oc2ccccc2P3(=S)c2ccccc2)c2ccccc21 ; CC1(C)c2ccccc2N(c2ccc3c(c2)Sc2ccccc2P3(=S)c2ccccc2)c2ccccc21 ; CC1(C)c2ccccc2N(c2ccc3c(c2)N(c2ccccc2)c2ccccc2P3(=S)c2ccccc2)c2ccccc21 ; CC1(C)c2ccccc2N(c2ccc3c(c2)C(C)(C)c2ccccc2P3(=S)c2ccccc2)c2ccccc21]

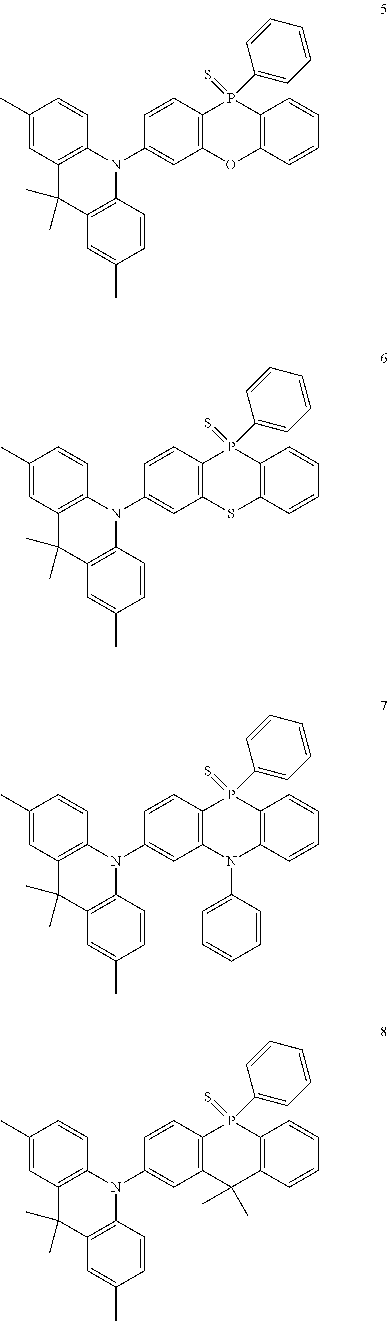 [SMILES: Cc1ccc2c(c1)C(C)(C)c1cc(C)ccc1N2c1ccc2c(c1)Oc1ccccc1P2(=S)c1ccccc1 ; Cc1ccc2c(c1)C(C)(C)c1cc(C)ccc1N2c1ccc2c(c1)Sc1ccccc1P2(=S)c1ccccc1 ; Cc1ccc2c(c1)C(C)(C)c1cc(C)ccc1N2c1ccc2c(c1)N(c1ccccc1)c1ccccc1P2(=S)c1ccccc1 ; Cc1ccc2c(c1)C(C)(C)c1cc(C)ccc1N2c1ccc2c(c1)C(C)(C)c1ccccc1P2(=S)c1ccccc1]

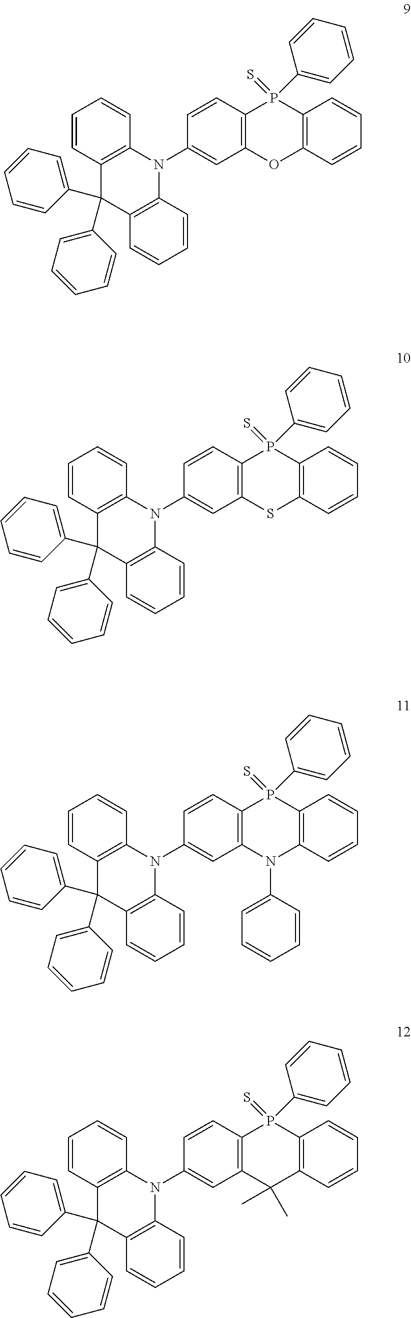 [SMILES: S=P1(c2ccccc2)c2ccccc2Oc2cc(N3c4ccccc4C(c4ccccc4)(c4ccccc4)c4ccccc43)ccc21 ; S=P1(c2ccccc2)c2ccccc2Sc2cc(N3c4ccccc4C(c4ccccc4)(c4ccccc4)c4ccccc43)ccc21 ; S=P1(c2ccccc2)c2ccccc2N(c2ccccc2)c2cc(N3c4ccccc4C(c4ccccc4)(c4ccccc4)c4ccccc43)ccc21 ; CC1(C)c2ccccc2P(=S)(c2ccccc2)c2ccc(N3c4ccccc4C(c4ccccc4)(c4ccccc4)c4ccccc43)cc21]

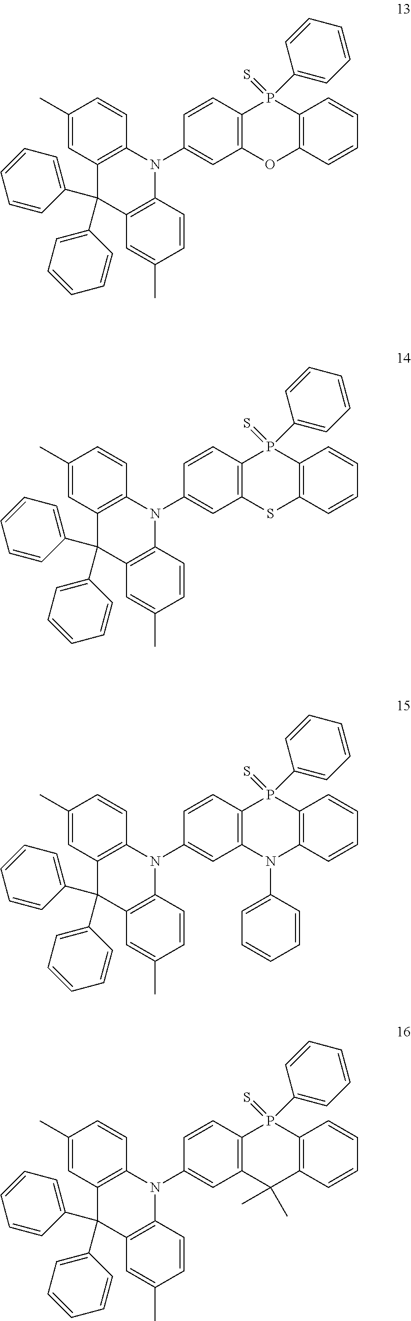 [SMILES: Cc1ccc2c(c1)C(c1ccccc1)(c1ccccc1)c1cc(C)ccc1N2c1ccc2c(c1)Oc1ccccc1P2(=S)c1ccccc1 ; Cc1ccc2c(c1)C(c1ccccc1)(c1ccccc1)c1cc(C)ccc1N2c1ccc2c(c1)Sc1ccccc1P2(=S)c1ccccc1 ; Cc1ccc2c(c1)C(c1ccccc1)(c1ccccc1)c1cc(C)ccc1N2c1ccc2c(c1)N(c1ccccc1)c1ccccc1P2(=S)c1ccccc1 ; Cc1ccc2c(c1)C(c1ccccc1)(c1ccccc1)c1cc(C)ccc1N2c1ccc2c(c1)C(C)(C)c1ccccc1P2(=S)c1ccccc1]

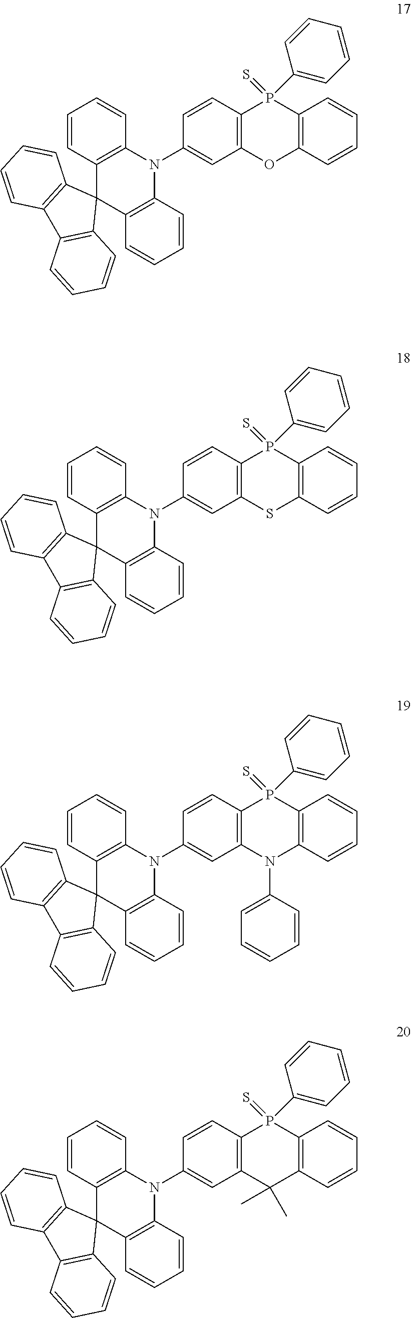 [SMILES: S=P1(c2ccccc2)c2ccccc2Oc2cc(N3c4ccccc4C4(c5ccccc5-c5ccccc54)c4ccccc43)ccc21 ; S=P1(c2ccccc2)c2ccccc2Sc2cc(N3c4ccccc4C4(c5ccccc5-c5ccccc54)c4ccccc43)ccc21 ; S=P1(c2ccccc2)c2ccccc2N(c2ccccc2)c2cc(N3c4ccccc4C4(c5ccccc5-c5ccccc54)c4ccccc43)ccc21 ; CC1(C)c2ccccc2P(=S)(c2ccccc2)c2ccc(N3c4ccccc4C4(c5ccccc5-c5ccccc54)c4ccccc43)cc21]

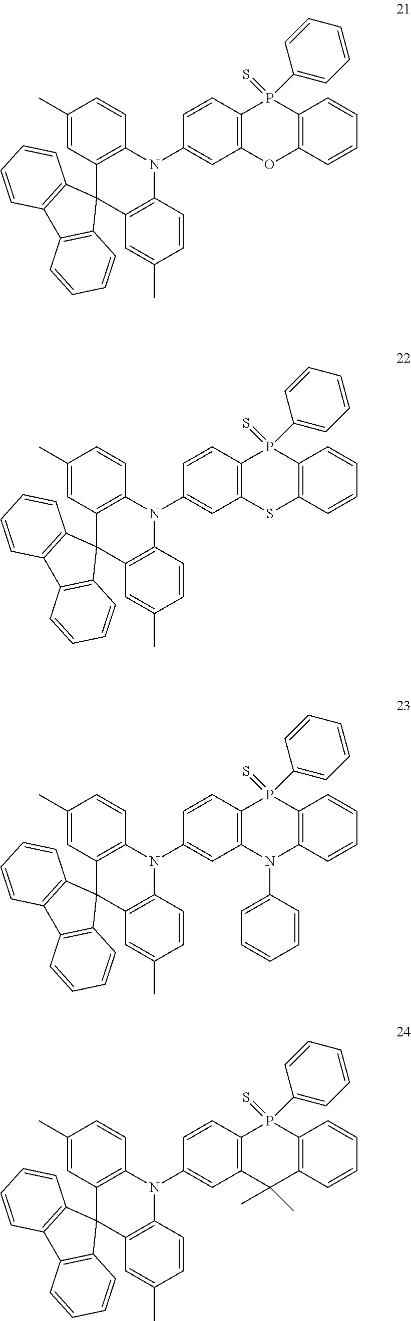 [SMILES: Cc1ccc2c(c1)C1(c3ccccc3-c3ccccc31)c1cc(C)ccc1N2c1ccc2c(c1)Oc1ccccc1P2(=S)c1ccccc1 ; Cc1ccc2c(c1)C1(c3ccccc3-c3ccccc31)c1cc(C)ccc1N2c1ccc2c(c1)Sc1ccccc1P2(=S)c1ccccc1 ; Cc1ccc2c(c1)C1(c3ccccc3-c3ccccc31)c1cc(C)ccc1N2c1ccc2c(c1)N(c1ccccc1)c1ccccc1P2(=S)c1ccccc1 ; Cc1ccc2c(c1)C1(c3ccccc3-c3ccccc31)c1cc(C)ccc1N2c1ccc2c(c1)C(C)(C)c1ccccc1P2(=S)c1ccccc1]

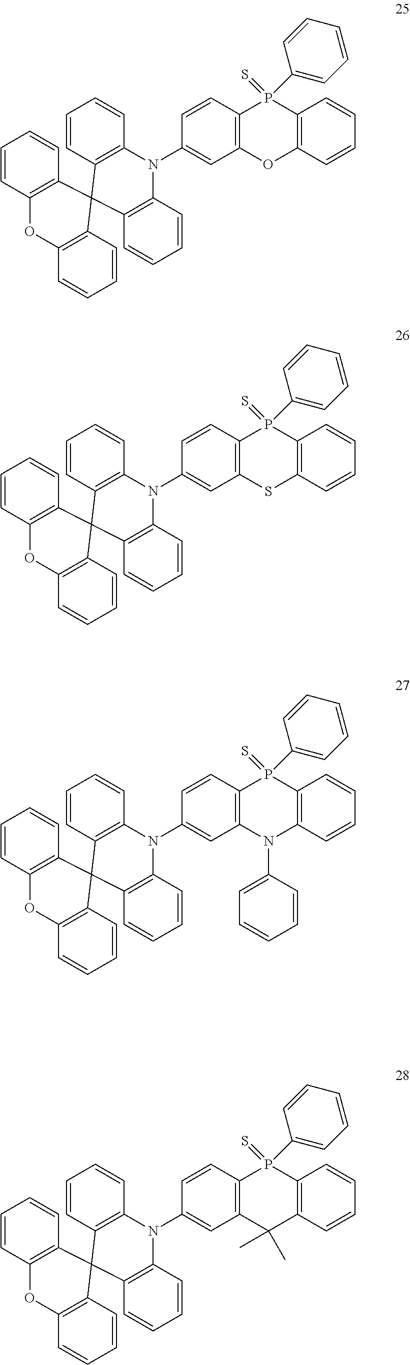 [SMILES: S=P1(c2ccccc2)c2ccccc2Oc2cc(N3c4ccccc4C4(c5ccccc5Oc5ccccc54)c4ccccc43)ccc21 ; S=P1(c2ccccc2)c2ccccc2Sc2cc(N3c4ccccc4C4(c5ccccc5Oc5ccccc54)c4ccccc43)ccc21 ; S=P1(c2ccccc2)c2ccccc2N(c2ccccc2)c2cc(N3c4ccccc4C4(c5ccccc5Oc5ccccc54)c4ccccc43)ccc21 ; CC1(C)c2ccccc2P(=S)(c2ccccc2)c2ccc(N3c4ccccc4C4(c5ccccc5Oc5ccccc54)c4ccccc43)cc21]

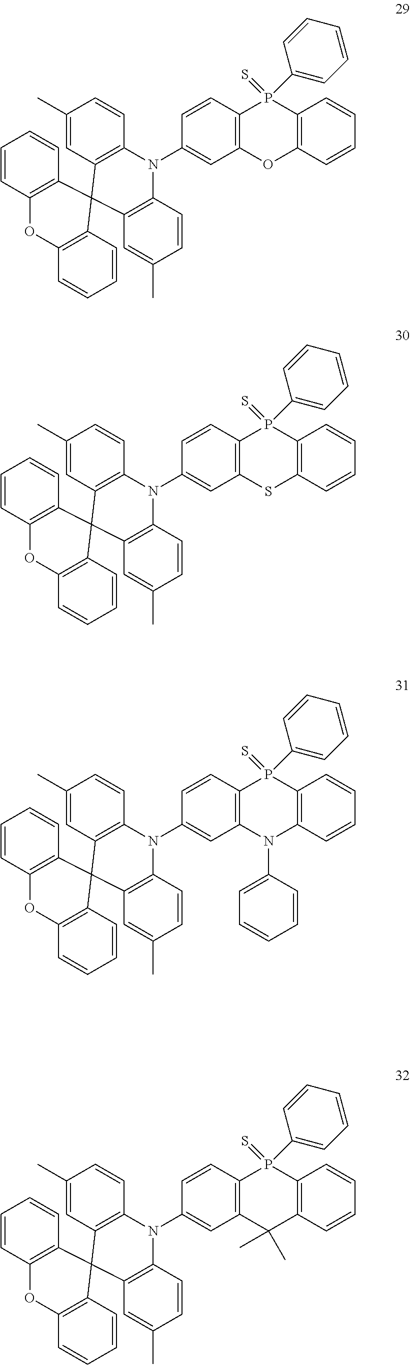 [SMILES: Cc1ccc2c(c1)C1(c3ccccc3Oc3ccccc31)c1cc(C)ccc1N2c1ccc2c(c1)Oc1ccccc1P2(=S)c1ccccc1 ; Cc1ccc2c(c1)C1(c3ccccc3Oc3ccccc31)c1cc(C)ccc1N2c1ccc2c(c1)Sc1ccccc1P2(=S)c1ccccc1 ; Cc1ccc2c(c1)C1(c3ccccc3Oc3ccccc31)c1cc(C)ccc1N2c1ccc2c(c1)N(c1ccccc1)c1ccccc1P2(=S)c1ccccc1 ; Cc1ccc2c(c1)C1(c3ccccc3Oc3ccccc31)c1cc(C)ccc1N2c1ccc2c(c1)C(C)(C)c1ccccc1P2(=S)c1ccccc1]

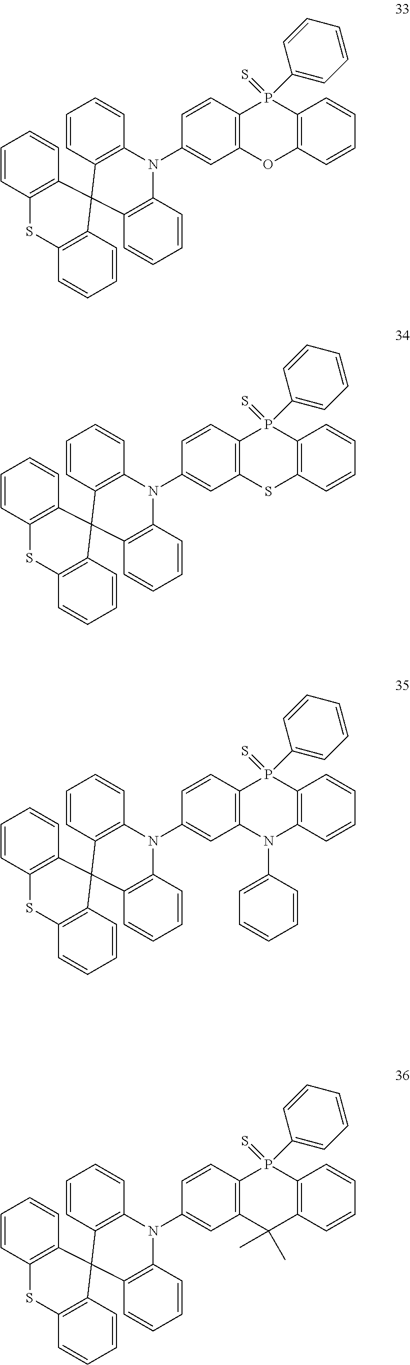 [SMILES: S=P1(c2ccccc2)c2ccccc2Oc2cc(N3c4ccccc4C4(c5ccccc5Sc5ccccc54)c4ccccc43)ccc21 ; S=P1(c2ccccc2)c2ccccc2Sc2cc(N3c4ccccc4C4(c5ccccc5Sc5ccccc54)c4ccccc43)ccc21 ; S=P1(c2ccccc2)c2ccccc2N(c2ccccc2)c2cc(N3c4ccccc4C4(c5ccccc5Sc5ccccc54)c4ccccc43)ccc21 ; CC1(C)c2ccccc2P(=S)(c2ccccc2)c2ccc(N3c4ccccc4C4(c5ccccc5Sc5ccccc54)c4ccccc43)cc21]

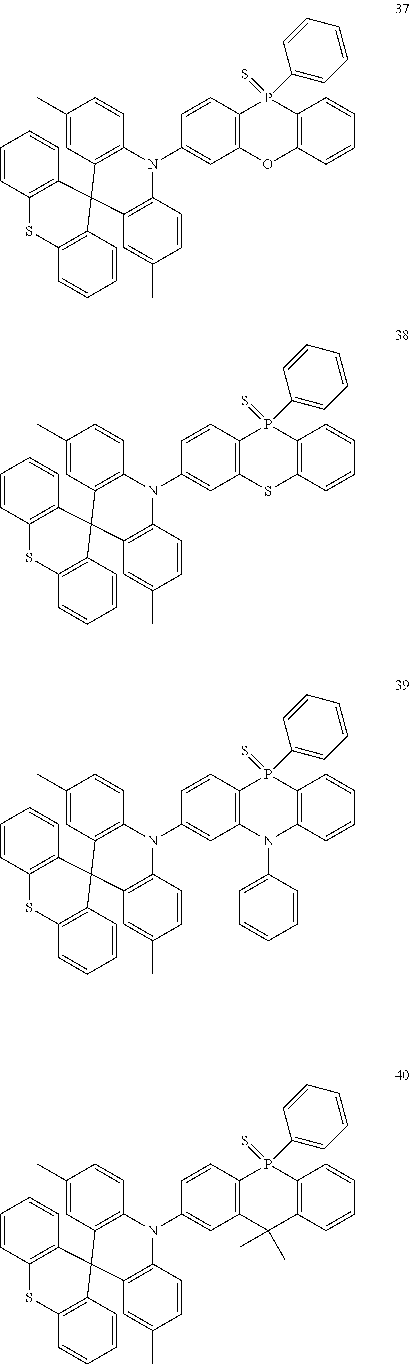 [SMILES: Cc1ccc2c(c1)C1(c3ccccc3Sc3ccccc31)c1cc(C)ccc1N2c1ccc2c(c1)Oc1ccccc1P2(=S)c1ccccc1 ; Cc1ccc2c(c1)C1(c3ccccc3Sc3ccccc31)c1cc(C)ccc1N2c1ccc2c(c1)Sc1ccccc1P2(=S)c1ccccc1 ; Cc1ccc2c(c1)C1(c3ccccc3Sc3ccccc31)c1cc(C)ccc1N2c1ccc2c(c1)N(c1ccccc1)c1ccccc1P2(=S)c1ccccc1 ; Cc1ccc2c(c1)C1(c3ccccc3Sc3ccccc31)c1cc(C)ccc1N2c1ccc2c(c1)C(C)(C)c1ccccc1P2(=S)c1ccccc1]

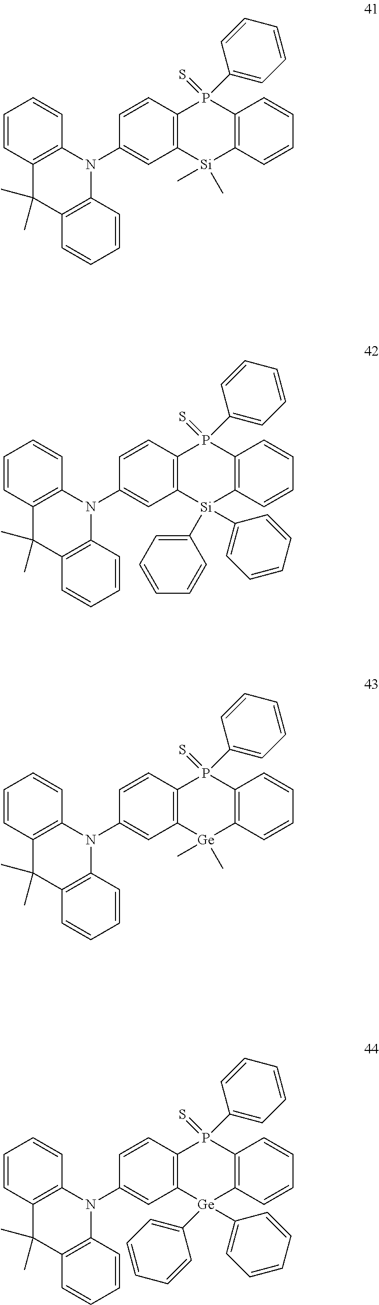

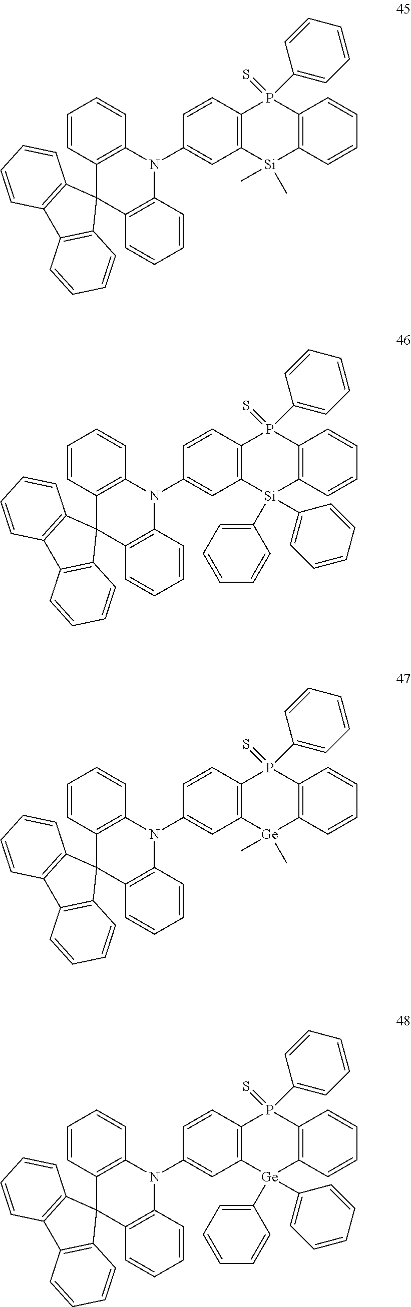

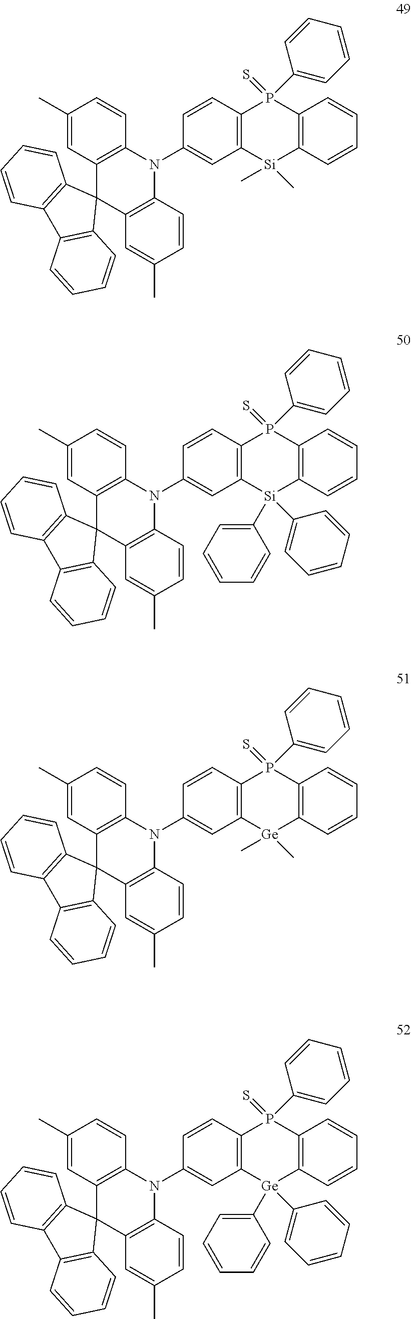

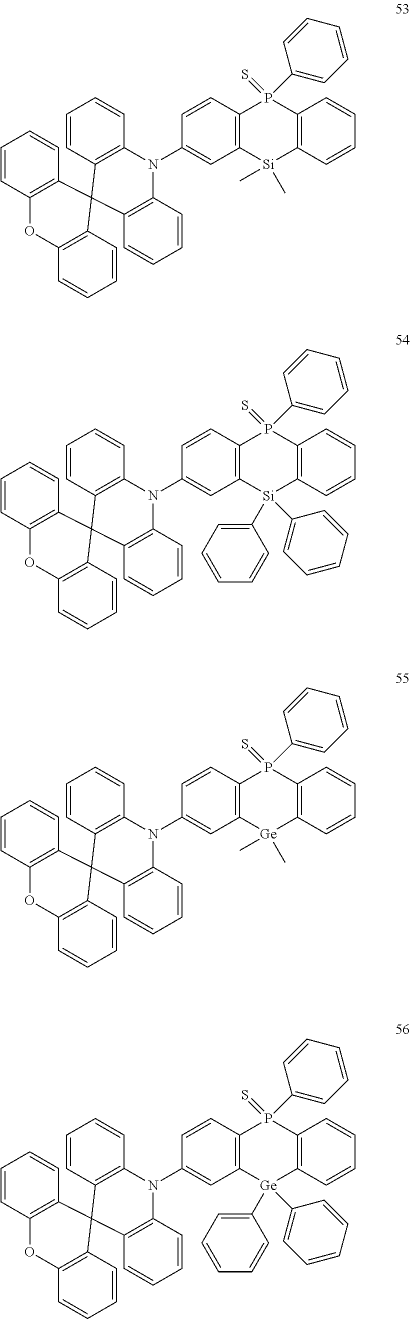

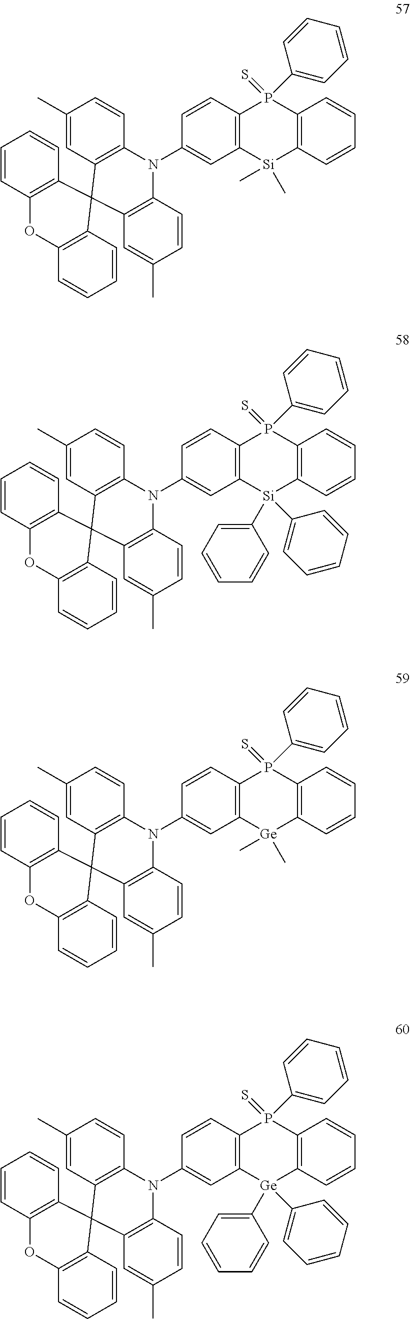

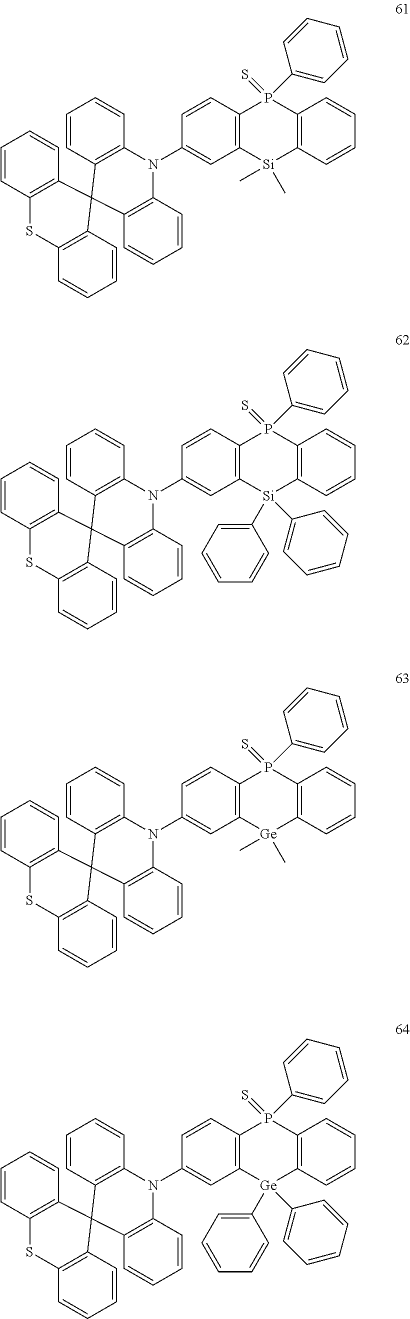

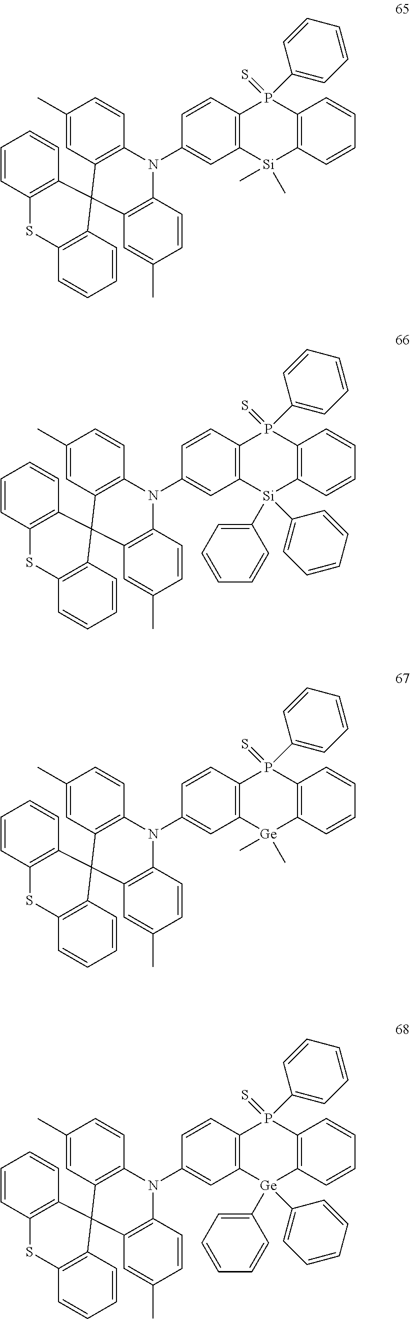

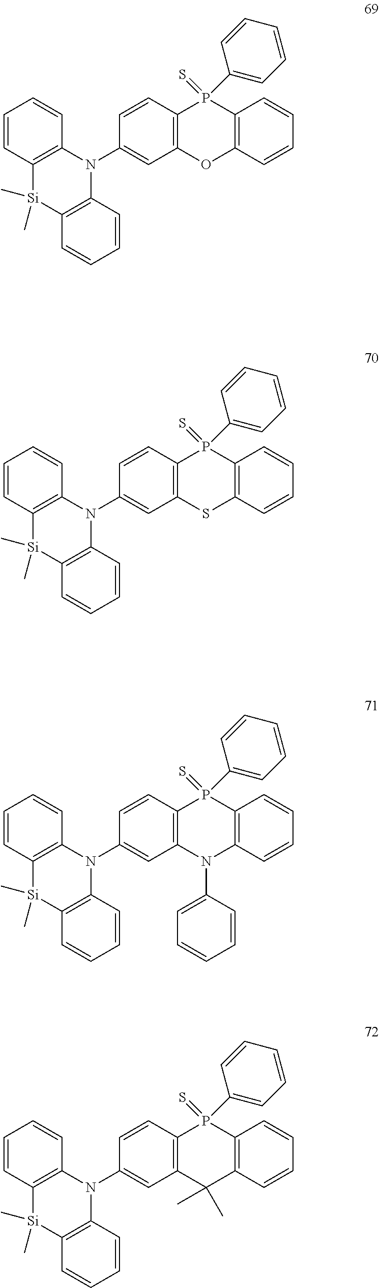 [SMILES: C[Si]1(C)c2ccccc2N(c2ccc3c(c2)Oc2ccccc2P3(=S)c2ccccc2)c2ccccc21 ; C[Si]1(C)c2ccccc2N(c2ccc3c(c2)Sc2ccccc2P3(=S)c2ccccc2)c2ccccc21 ; C[Si]1(C)c2ccccc2N(c2ccc3c(c2)N(c2ccccc2)c2ccccc2P3(=S)c2ccccc2)c2ccccc21 ; CC1(C)c2ccccc2P(=S)(c2ccccc2)c2ccc(N3c4ccccc4[Si](C)(C)c4ccccc43)cc21]

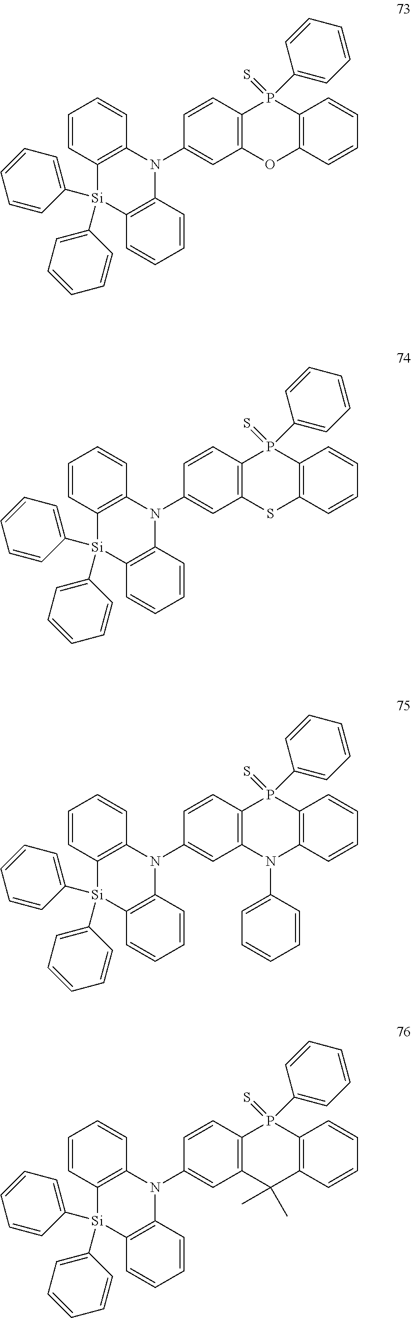 [SMILES: S=P1(c2ccccc2)c2ccccc2Oc2cc(N3c4ccccc4[Si](c4ccccc4)(c4ccccc4)c4ccccc43)ccc21 ; S=P1(c2ccccc2)c2ccccc2Sc2cc(N3c4ccccc4[Si](c4ccccc4)(c4ccccc4)c4ccccc43)ccc21 ; S=P1(c2ccccc2)c2ccccc2N(c2ccccc2)c2cc(N3c4ccccc4[Si](c4ccccc4)(c4ccccc4)c4ccccc43)ccc21 ; CC1(C)c2ccccc2P(=S)(c2ccccc2)c2ccc(N3c4ccccc4[Si](c4ccccc4)(c4ccccc4)c4ccccc43)cc21]

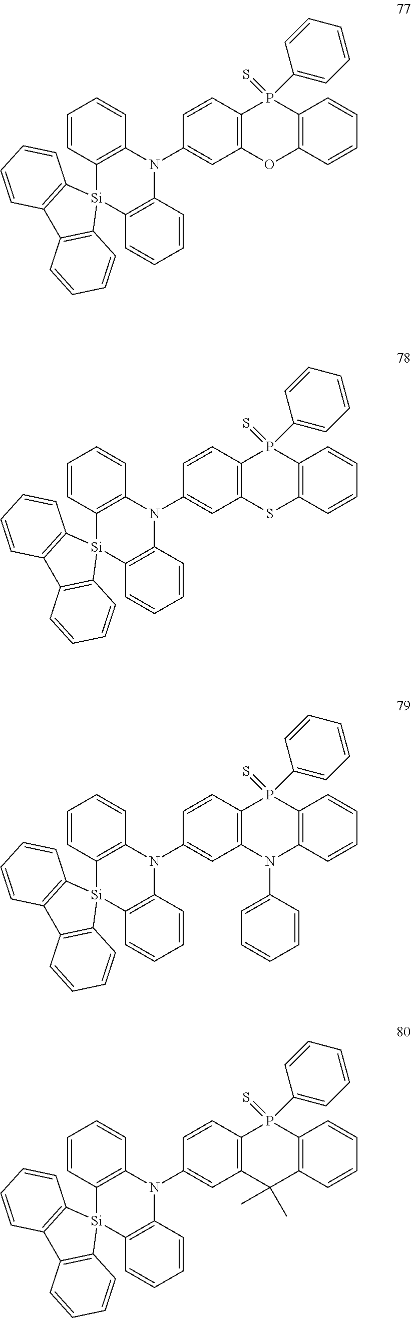 [SMILES: S=P1(c2ccccc2)c2ccccc2Oc2cc(N3c4ccccc4[Si]4(c5ccccc5-c5ccccc54)c4ccccc43)ccc21 ; S=P1(c2ccccc2)c2ccccc2Sc2cc(N3c4ccccc4[Si]4(c5ccccc5-c5ccccc54)c4ccccc43)ccc21 ; S=P1(c2ccccc2)c2ccccc2N(c2ccccc2)c2cc(N3c4ccccc4[Si]4(c5ccccc5-c5ccccc54)c4ccccc43)ccc21 ; CC1(C)c2ccccc2P(=S)(c2ccccc2)c2ccc(N3c4ccccc4[Si]4(c5ccccc5-c5ccccc54)c4ccccc43)cc21]

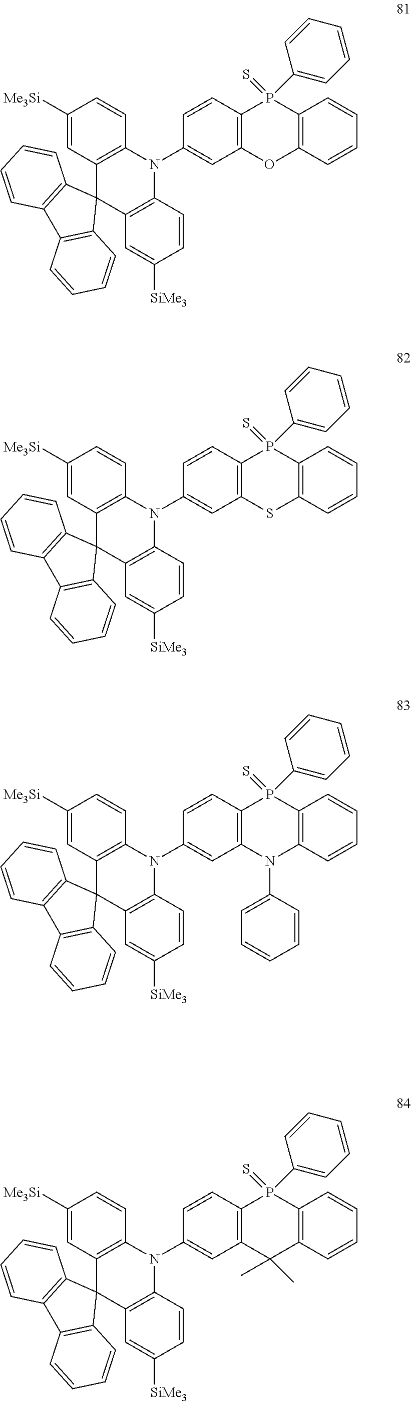 [SMILES: C[Si](C)(C)c1ccc2c(c1)C1(c3ccccc3-c3ccccc31)c1cc([Si](C)(C)C)ccc1N2c1ccc2c(c1)Oc1ccccc1P2(=S)c1ccccc1 ; C[Si](C)(C)c1ccc2c(c1)C1(c3ccccc3-c3ccccc31)c1cc([Si](C)(C)C)ccc1N2c1ccc2c(c1)Sc1ccccc1P2(=S)c1ccccc1 ; C[Si](C)(C)c1ccc2c(c1)C1(c3ccccc3-c3ccccc31)c1cc([Si](C)(C)C)ccc1N2c1ccc2c(c1)N(c1ccccc1)c1ccccc1P2(=S)c1ccccc1 ; CC1(C)c2ccccc2P(=S)(c2ccccc2)c2ccc(N3c4ccc([Si](C)(C)C)cc4C4(c5ccccc5-c5ccccc54)c4cc([Si](C)(C)C)ccc43)cc21]

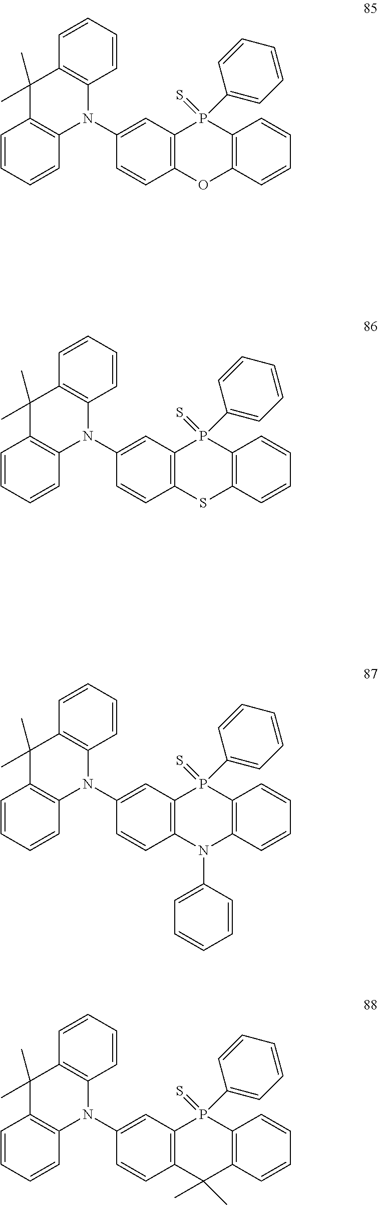 [SMILES: CC1(C)c2ccccc2N(c2ccc3c(c2)P(=S)(c2ccccc2)c2ccccc2O3)c2ccccc21 ; CC1(C)c2ccccc2N(c2ccc3c(c2)P(=S)(c2ccccc2)c2ccccc2S3)c2ccccc21 ; CC1(C)c2ccccc2N(c2ccc3c(c2)P(=S)(c2ccccc2)c2ccccc2N3c2ccccc2)c2ccccc21 ; CC1(C)c2ccccc2N(c2ccc3c(c2)P(=S)(c2ccccc2)c2ccccc2C3(C)C)c2ccccc21]

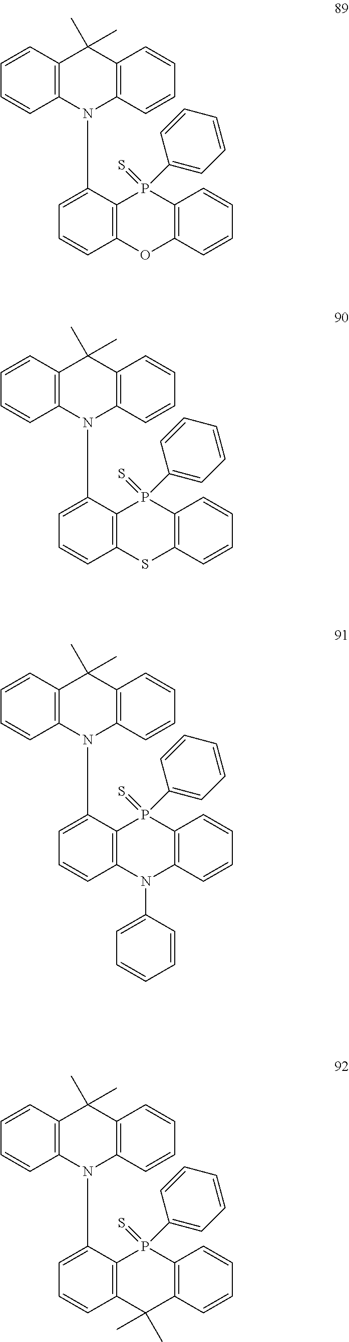 [SMILES: CC1(C)c2ccccc2N(c2cccc3c2P(=S)(c2ccccc2)c2ccccc2O3)c2ccccc21 ; CC1(C)c2ccccc2N(c2cccc3c2P(=S)(c2ccccc2)c2ccccc2S3)c2ccccc21 ; CC1(C)c2ccccc2N(c2cccc3c2P(=S)(c2ccccc2)c2ccccc2N3c2ccccc2)c2ccccc21 ; CC1(C)c2ccccc2N(c2cccc3c2P(=S)(c2ccccc2)c2ccccc2C3(C)C)c2ccccc21]

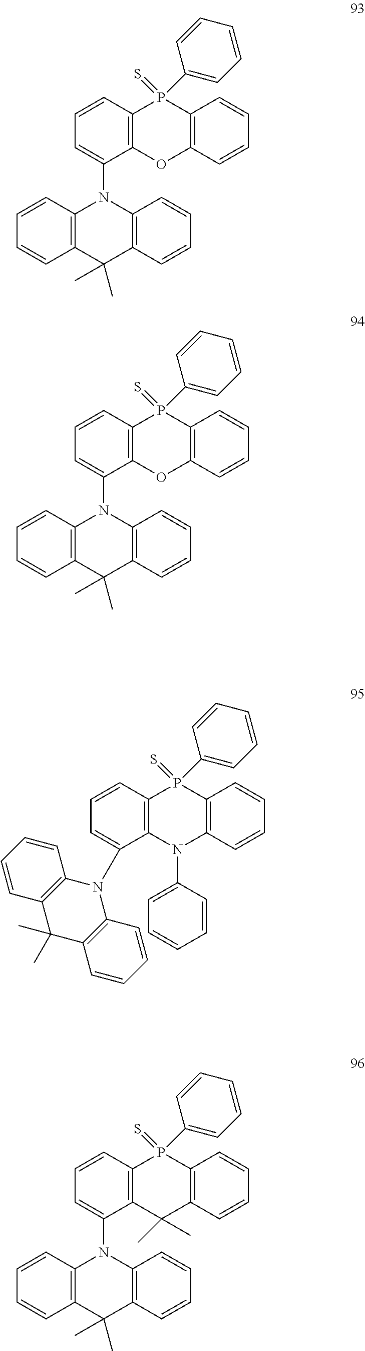 [SMILES: CC1(C)c2ccccc2N(c2cccc3c2Oc2ccccc2P3(=S)c2ccccc2)c2ccccc21 ; CC1(C)c2ccccc2N(c2cccc3c2Oc2ccccc2P3(=S)c2ccccc2)c2ccccc21 ; CC1(C)c2ccccc2N(c2cccc3c2N(c2ccccc2)c2ccccc2P3(=S)c2ccccc2)c2ccccc21 ; CC1(C)c2ccccc2N(c2cccc3c2C(C)(C)c2ccccc2P3(=S)c2ccccc2)c2ccccc21]

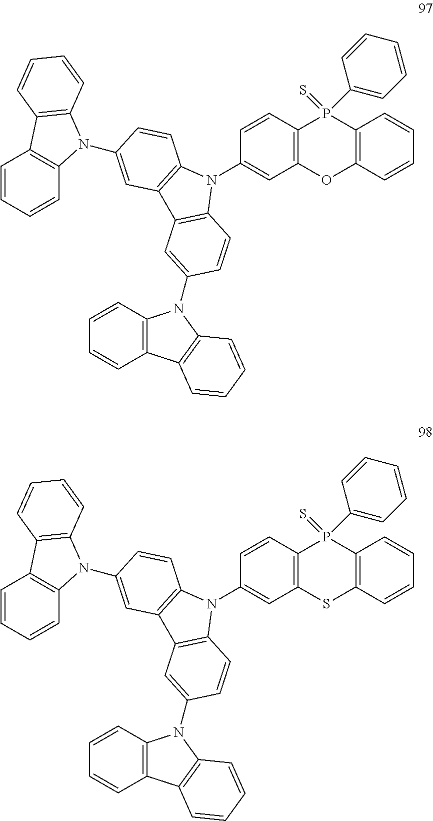 [SMILES: S=P1(c2ccccc2)c2ccccc2Oc2cc(-n3c4ccc(-n5c6ccccc6c6ccccc65)cc4c4cc(-n5c6ccccc6c6ccccc65)ccc43)ccc21 ; S=P1(c2ccccc2)c2ccccc2Sc2cc(-n3c4ccc(-n5c6ccccc6c6ccccc65)cc4c4cc(-n5c6ccccc6c6ccccc65)ccc43)ccc21]

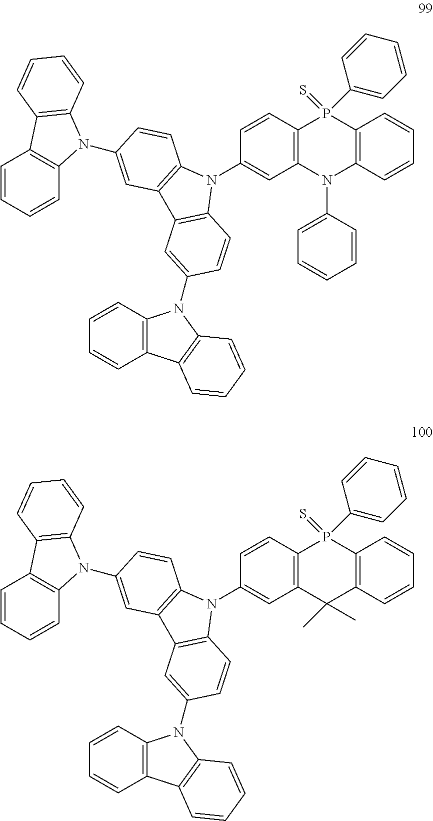 [SMILES: S=P1(c2ccccc2)c2ccccc2N(c2ccccc2)c2cc(-n3c4ccc(-n5c6ccccc6c6ccccc65)cc4c4cc(-n5c6ccccc6c6ccccc65)ccc43)ccc21 ; CC1(C)c2ccccc2P(=S)(c2ccccc2)c2ccc(-n3c4ccc(-n5c6ccccc6c6ccccc65)cc4c4cc(-n5c6ccccc6c6ccccc65)ccc43)cc21]

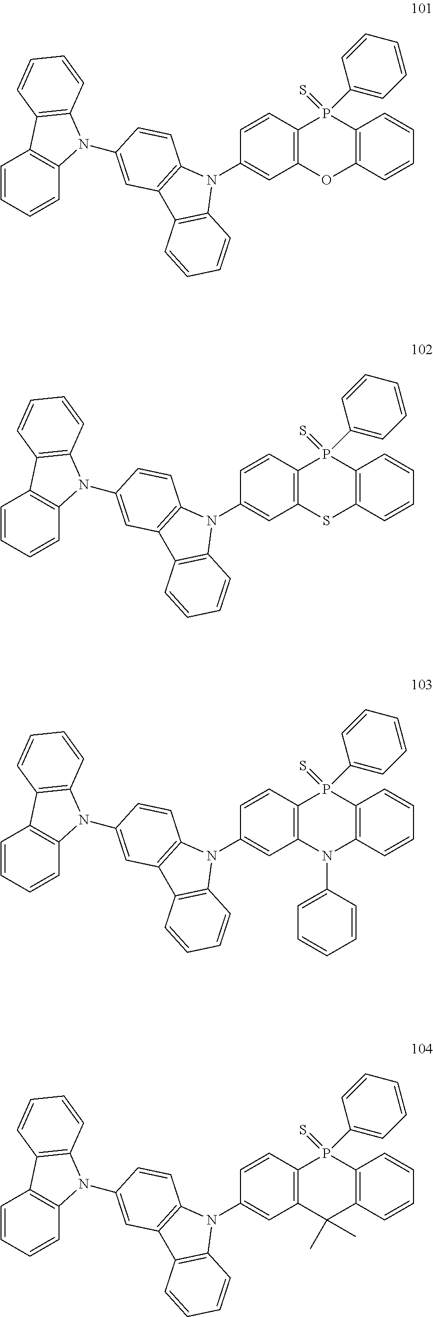 [SMILES: S=P1(c2ccccc2)c2ccccc2Oc2cc(-n3c4ccccc4c4cc(-n5c6ccccc6c6ccccc65)ccc43)ccc21 ; S=P1(c2ccccc2)c2ccccc2Sc2cc(-n3c4ccccc4c4cc(-n5c6ccccc6c6ccccc65)ccc43)ccc21 ; S=P1(c2ccccc2)c2ccccc2N(c2ccccc2)c2cc(-n3c4ccccc4c4cc(-n5c6ccccc6c6ccccc65)ccc43)ccc21 ; CC1(C)c2ccccc2P(=S)(c2ccccc2)c2ccc(-n3c4ccccc4c4cc(-n5c6ccccc6c6ccccc65)ccc43)cc21]

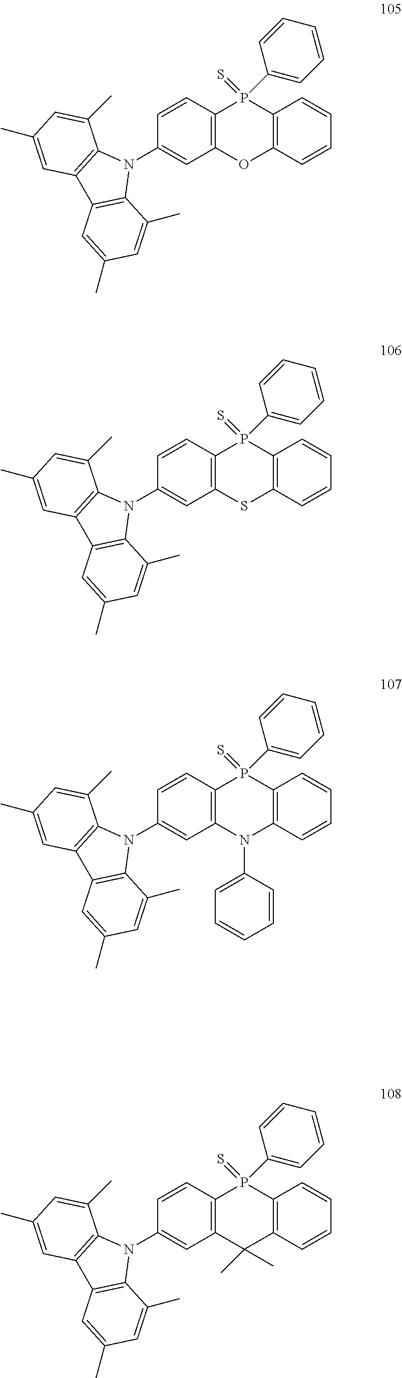 [SMILES: Cc1cc(C)c2c(c1)c1cc(C)cc(C)c1n2-c1ccc2c(c1)Oc1ccccc1P2(=S)c1ccccc1 ; Cc1cc(C)c2c(c1)c1cc(C)cc(C)c1n2-c1ccc2c(c1)Sc1ccccc1P2(=S)c1ccccc1 ; Cc1cc(C)c2c(c1)c1cc(C)cc(C)c1n2-c1ccc2c(c1)N(c1ccccc1)c1ccccc1P2(=S)c1ccccc1 ; Cc1cc(C)c2c(c1)c1cc(C)cc(C)c1n2-c1ccc2c(c1)C(C)(C)c1ccccc1P2(=S)c1ccccc1]

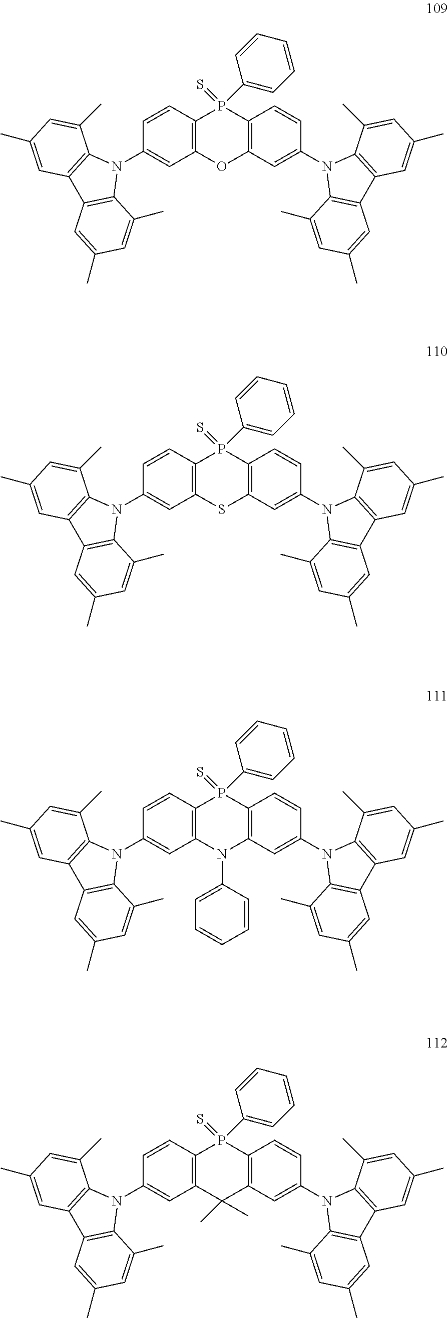

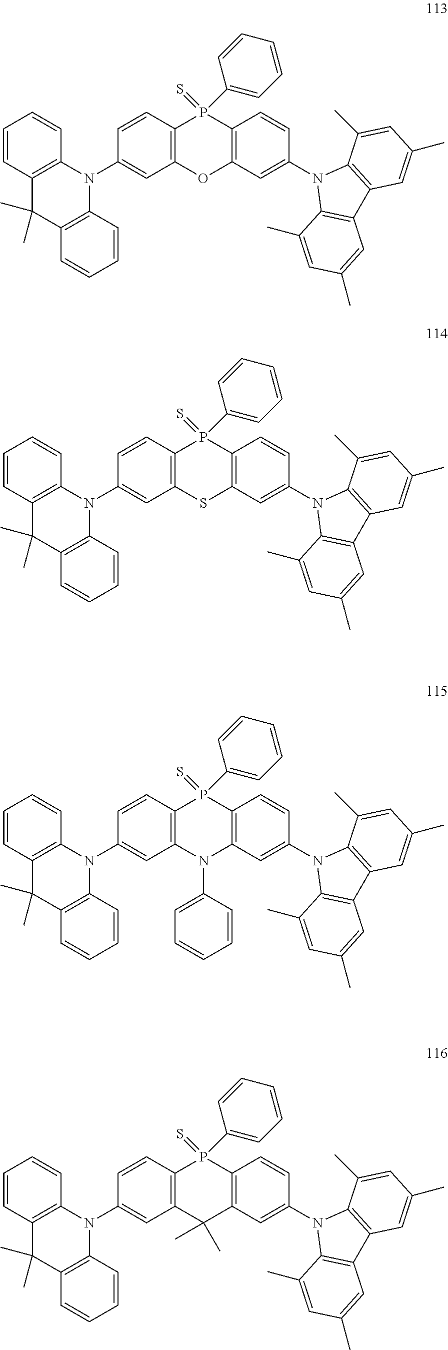

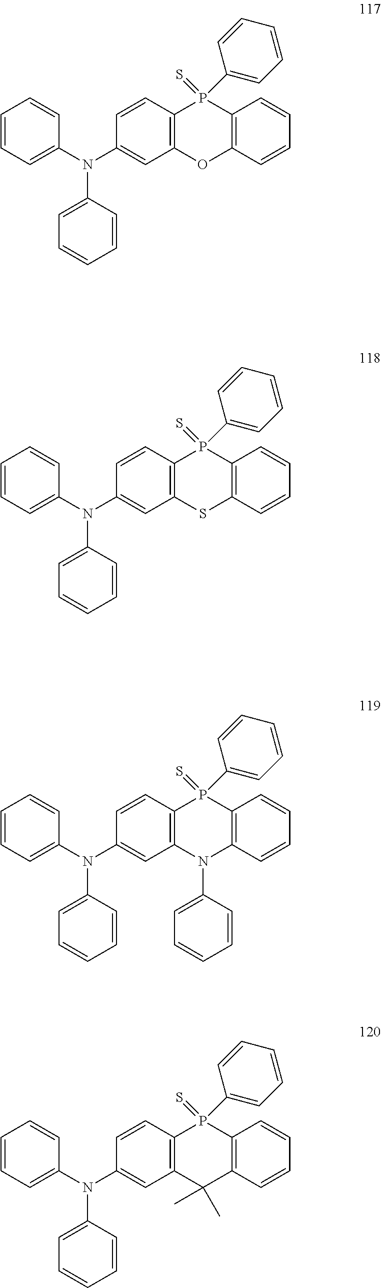 [SMILES: S=P1(c2ccccc2)c2ccccc2Oc2cc(N(c3ccccc3)c3ccccc3)ccc21 ; S=P1(c2ccccc2)c2ccccc2Sc2cc(N(c3ccccc3)c3ccccc3)ccc21 ; S=P1(c2ccccc2)c2ccccc2N(c2ccccc2)c2cc(N(c3ccccc3)c3ccccc3)ccc21 ; CC1(C)c2ccccc2P(=S)(c2ccccc2)c2ccc(N(c3ccccc3)c3ccccc3)cc21]

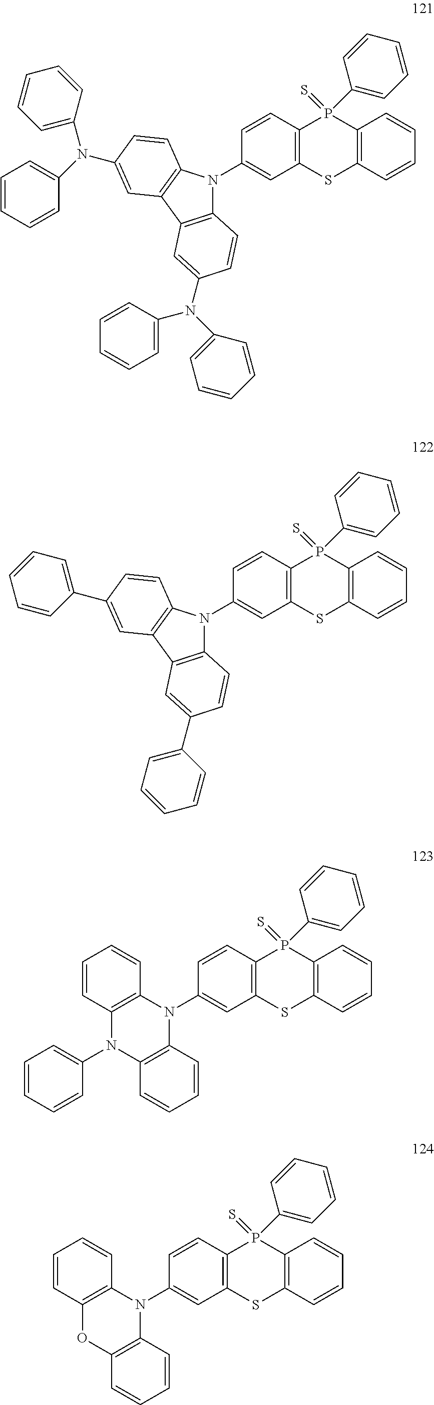 [SMILES: S=P1(c2ccccc2)c2ccccc2Sc2cc(-n3c4ccc(N(c5ccccc5)c5ccccc5)cc4c4cc(N(c5ccccc5)c5ccccc5)ccc43)ccc21 ; S=P1(c2ccccc2)c2ccccc2Sc2cc(-n3c4ccc(-c5ccccc5)cc4c4cc(-c5ccccc5)ccc43)ccc21 ; S=P1(c2ccccc2)c2ccccc2Sc2cc(N3c4ccccc4N(c4ccccc4)c4ccccc43)ccc21 ; S=P1(c2ccccc2)c2ccccc2Sc2cc(N3c4ccccc4Oc4ccccc43)ccc21]

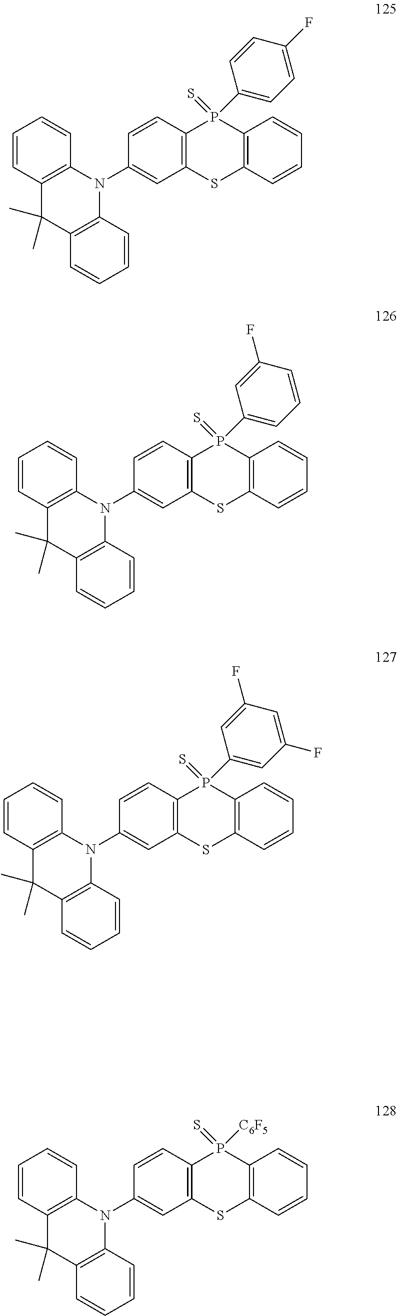

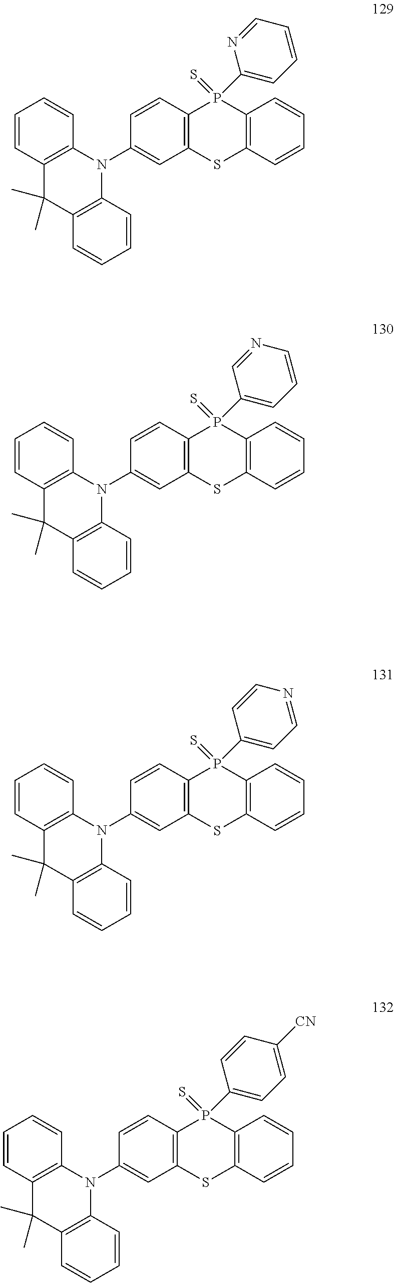 [SMILES: CC1(C)c2ccccc2N(c2ccc3c(c2)Sc2ccccc2P3(=S)c2ccccn2)c2ccccc21 ; CC1(C)c2ccccc2N(c2ccc3c(c2)Sc2ccccc2P3(=S)c2cccnc2)c2ccccc21 ; CC1(C)c2ccccc2N(c2ccc3c(c2)Sc2ccccc2P3(=S)c2ccncc2)c2ccccc21 ; CC1(C)c2ccccc2N(c2ccc3c(c2)Sc2ccccc2P3(=S)c2ccc(C#N)cc2)c2ccccc21]

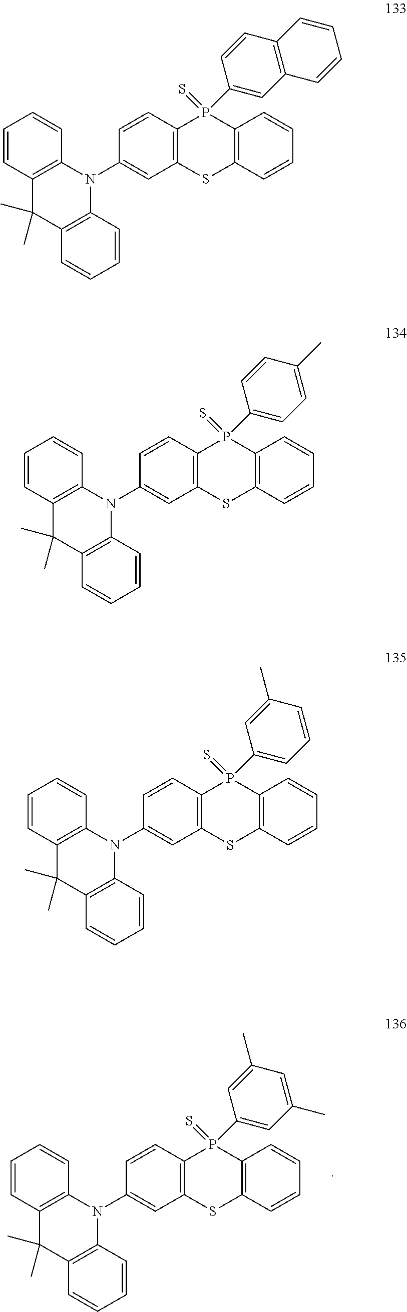

### BRIEF DESCRIPTION OF THE DRAWINGS

Features will be apparent to those of skill in the art by describing in detail exemplary embodiments with reference to the attached drawings in which:

FIG. 1 illustrates a cross-sectional view of an organic electroluminescence device according to an embodiment; and

FIG. 2 illustrates a cross-sectional view of an organic electroluminescence device according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or element, it can be directly on the other layer or element, or intervening layers may also be present. In addition, it will also be understood that when a layer is referred to as being “between” two layers, it can be the only layer between the two layers, or one or more intervening layers may also be present. The term “or” is not an exclusive term, e.g., “A or B” would include any and all combinations thereof, viz., A, B, or A and B.

Like reference numerals refer to like elements throughout. It will be understood that, although the terms first, second, etc. may be used herein to describe various elements, these elements should not be limited by these terms. These terms are only used to distinguish one element from another element. Thus, a first element could be termed a second element without departing from the teachings herein. Similarly, a second element could be termed a first element. As used herein, the singular forms are intended to include the plural forms as well, unless the context clearly indicates otherwise.

It will be further understood that the terms “includes.” “including,” “comprises” and/or “comprising,” when used in this specification, specify the presence of stated features, numerals, steps, operations, elements, parts, or the combination thereof, but do not preclude the presence or addition of one or more other features, numerals, steps, operations, elements, parts, or the combination thereof.

In the description, “-*” means a connecting position or a bonding location.

In the description, the term “substituted or unsubstituted” corresponds to a group being unsubstituted or substituted with at least one substituent selected from the group of a deuterium atom, a halogen atom, a nitro group, an amino group, a silyl group, a boron group, a phosphine oxide group, a phosphine sulfide group, an alkyl group, an alkenyl group, an aryl group, and a heterocyclic group. In addition, each of the substituents may be substituted or unsubstituted. For example, a biphenyl group may be interpreted as an aryl group or a phenyl group substituted with a phenyl group.

In the description, the description of a group forming a ring via the combination with an adjacent group may mean forming a substituted or unsubstituted hydrocarbon ring, or substituted or unsubstituted heterocycle via the combination with an adjacent group. The hydrocarbon ring may include an aliphatic hydrocarbon ring and an aromatic hydrocarbon ring. The heterocycle may include an aliphatic heterocycle and an aromatic heterocycle. The hydrocarbon ring and the heterocycle may be monocyclic or polycyclic. In addition, the ring formed via the combination with an adjacent group may be combined with another ring to form a spiro structure.

In the description, the terms “an adjacent group” may mean a substituent substituted for an atom which is directly combined with an atom substituted with a corresponding substituent, another substituent substituted for an atom which is substituted with a corresponding substituent, or a substituent sterically positioned at the nearest position to a corresponding substituent. For example, in 1,2-dimethylbenzene, two methyl groups may be interpreted as “adjacent groups” to each other, and in 1,1-diethylcyclopentene, two ethyl groups may be interpreted as “adjacent groups” to each other.

In the description, the halogen atom may include a fluorine atom, a chlorine atom, a bromine atom, or an iodine atom.

In the description, the alkyl may be linear, branched, or cyclic. The carbon number of the alkyl may be from 1 to 50, from 1 to 30, from 1 to 20, from 1 to 10, or from 1 to 6. The alkyl may include methyl, ethyl, n-propyl, isopropyl, n-butyl, s-butyl, t-butyl, i-butyl, 2-ethylbutyl, 3,3-dimethylbutyl, n-pentyl, i-pentyl, neopentyl, t-pentyl, cyclopentyl, 1-methylpentyl, 3-methylpentyl, 2-ethylpentyl, 4-methyl-2-pentyl, n-hexyl, I-methylhexyl, 2-ethylhexyl, 2-butylhexyl, cyclohexyl, 4-methylcyclohexyl, 4-t-butylcyclohexyl, n-heptyl, 1-methylheptyl, 2,2-dimethylheptyl, 2-ethylheptyl, 2-butylheptyl, n-octyl, t-octyl, 2-ethyloctyl, 2-butyloctyl, 2-hexyloctyl, 3,7-dimethyloctyl, cyclooctyl, n-nonyl, n-decyl, adamantyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldocecyl, 2-octyldodecyl, n-tridecyl, n-tetradecyl, c-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-eicosyl, 2-ethyleicosyl, 2-butyleicosyl, 2-hexyleicosyl, 2-octyleicosyl, n-henicosyl, n-docosyl, n-tricosyl, n-tetracosyl, n-pentacosyl, n-hexacosyl, n-heptacosyl, n-octacosyl, n-nonacosyl, n-triacontyl, etc.

In the description, the aryl group means a group or substituent derived from an aromatic hydrocarbon ring. The aryl group may be a monocyclic aryl group or a polycyclic aryl group. The carbon number for forming a ring in the aryl group may be 6 to 30, 6 to 20, or 6 to 15. Examples of the aryl group may include phenyl, naphthyl, fluorenyl, anthracenyl, phenanthryl, biphenyl, terphenyl, quaterphenyl, quinqphenyl, sexiphenyl, triphenylene, pyrenyl, benzofluoranthenyl, chrysenyl, etc.

In the description, the fluorenyl group may be substituted, and two substituents may be combined with each other to form a spiro structure.

In the description, the heteroaryl may be a heteroaryl including at least one of O, N, P, Si, or S as a heteroatom. The carbon number for forming a ring of the heteroaryl may be 2 to 30, or 2 to 20. The heteroaryl may be monocyclic heteroaryl or polycyclic heteroaryl. Examples of the polycyclic heteroaryl may have dicyclic or tricyclic structure. Examples of the heteroaryl may include thiophene, furan, pyrrole, imidazole, thiazole, oxazole, oxadiazole, triazole, pyridyl, bipyridyl, pyrimidyl, triazine, triazole, acridyl, pyridazine, pyrazinyl, quinolinyl, quinazoline, quinoxalinyl, phenoxazyl, phthalazinyl, pyrido pyrimidinyl, pyrido pyrazinyl, pyrazino pyrazinyl, isoquinoline, indole, carbazole, N-arylcarbazole, N-heteroarylcarbazole, N-alkylcarbazole, benzoxazole, benzoimidazole, benzothiazole, benzocarbazole, benzothiophene, dibenzothiophene, thienothiophene, benzofuranyl, phenanthroline, thiazolyl, isooxazolyl, oxadiazolyl, thiadiazolyl, benzothiazolyl, phenothiazinyl, dibenzosilole, dibenzofuranyl, etc.

In the description, explanation on the aryl may be applied to the arylene except that the arylene is a divalent group.

In the description, explanation on the heteroaryl may be applied to the heteroarylene except that the heteroarylene is a divalent group.

In the description, the carbon number of the amino group is not specifically limited, and may be 1 to 30. The amino group may include an alkylamino group and an arylamino group. Examples of the amino group may include a methylamino group, a dimethylamino group, a phenylamino group, a diphenylamino group, a naphthylamino group, a 9-methyl-anthracenylamino group, a triphenylamino group, etc.

Hereinafter, a phosphorus-containing compound according to an embodiment will be explained.

A phosphorus-containing compound according to an embodiment may be represented by the following Formula 1.

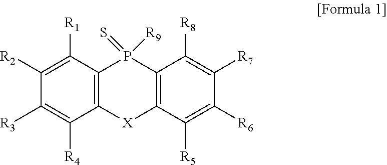

In Formula 1, X may be, e.g., O, S, NRₐ, CR_{b}R_{c}, SiR_{d}Rₑ, or GeR_{f}R_{g}. In an implementation, Rₐ to R_{g} may each independently be or include, e.g., a hydrogen atom, a deuterium atom, a halogen atom, a substituted or unsubstituted silyl group, a substituted or unsubstituted alkyl group having 1 to 20 carbon atoms, a substituted or unsubstituted fluorenyl group, a substituted or unsubstituted aryl group having 6 to 30 ring carbon atoms, or a substituted or unsubstituted heteroaryl group having 4 to 30 ring carbon atoms. In an implementation, Rₐ to R_{g} may be separate or may be combined with an adjacent group to form a ring.

R₁ to R₈ may each independently be or include, e.g., a hydrogen atom, a deuterium atom, a halogen atom, a substituted or unsubstituted silyl group, a substituted or unsubstituted amino group, a substituted or unsubstituted alkyl group having 1 to 20 carbon atoms, a substituted or unsubstituted aryl group having 6 to 30 ring carbon atoms, or a substituted or unsubstituted heteroaryl group having 4 to 30 ring carbon atoms.

R₉ may be or may include, e.g., a substituted or unsubstituted alkyl group having 1 to 20 carbon atoms, a substituted or unsubstituted aryl group having 6 to 30 ring carbon atoms, or a substituted or unsubstituted heteroaryl group having 4 to 30 ring carbon atoms. In an implementation, R₉ may be a group not forming a ring with a neighboring substituent. In an implementation, R₉ may not form a ring via the combination with neighboring R₈.

In an implementation, in Formula 1, at least one of R₁ to R₈ may be, e.g., a group represented by the following Formula 2. For example, the group represented by Formula 2 may correspond with the substituted or unsubstituted heteroaryl group having 4 to 30 ring carbon atoms.

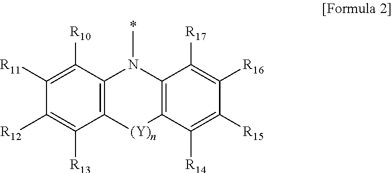

In Formula 2, n may be, e.g., 0 or 1. In an implementation, in a case where n is 1, Y may be, e.g., a direct linkage, O, S, CRₕRᵢ, SiRⱼRₖ, or GeRₗRₘ. The direct linkage may be, e.g., a single bond. For example, in a case where Y is a direct linkage, Formula 2 may be a substituted or unsubstituted carbazole group. In an implementation, when n is 0, the only linkage between the phenyl groups of Formula 2 may be through the nitrogen atom (e.g., the group represented by Formula 2 may be a diphenyl amine group).

Rₕ to Rₘ may each independently be or include, e.g., a hydrogen atom, a deuterium atom, a halogen atom, a substituted or unsubstituted silyl group, a substituted or unsubstituted alkyl group having 1 to 20 carbon atoms, a substituted or unsubstituted fluorenyl group, a substituted or unsubstituted aryl group having 6 to 30 ring carbon atoms, or a substituted or unsubstituted heteroaryl group having 4 to 30 ring carbon atoms. In an implementation, Rₕ to Rₘ may be separate or may be combined with an adjacent group to form a ring.

In Formula 2, R₁₀ to R₁₇ may each independently be or include, e.g., a hydrogen atom, a deuterium atom, a halogen atom, a substituted or unsubstituted silyl group, a substituted or unsubstituted amino group, a substituted or unsubstituted alkyl group having 1 to 20 carbon atoms, a substituted or unsubstituted aryl group having 6 to 30 ring carbon atoms, or a substituted or unsubstituted heteroaryl group having 4 to 30 ring carbon atoms. In an implementation, in Formula 2, R₁₀ to R₁₇ may each independently be or include, e.g., a hydrogen atom, or a substituted or unsubstituted alkyl group having 1 to 20 carbon atoms. In an implementation, in Formula 2, R₁₀ to R₁₇ may each independently be, e.g., a hydrogen atom or a methyl group.

In an implementation, in Formula 1, at least one of R₁ to R₈ may be a group represented by Formula 2, and the remainder thereof may each independently be or include, e.g., a hydrogen atom, a deuterium atom, a halogen atom, a substituted or unsubstituted silyl group, a substituted or unsubstituted amino group, a substituted or unsubstituted alkyl group having 1 to 20 carbon atoms, a substituted or unsubstituted aryl group having 6 to 30 ring carbon atoms, or a substituted or unsubstituted heteroaryl group having 4 to 30 ring carbon atoms. In an implementation, in Formula 1, one of R₁ to R₈ may be represented by the above Formula 2, and the remainder thereof may each independently be or include, e.g., a hydrogen atom, a deuterium atom, a halogen atom, a substituted or unsubstituted silyl group, a substituted or unsubstituted amino group, a substituted or unsubstituted alkyl group having 1 to 20 carbon atoms, a substituted or unsubstituted aryl group having 6 to 30 ring carbon atoms, or a substituted or unsubstituted heteroaryl group having 4 to 30 ring carbon atoms.

In an implementation, in the phosphorus-containing compound represented by Formula 1 according to an embodiment, at least one of R₁ to R₈ may be represented by the above Formula 2, and the remainder thereof may each be, e.g., a hydrogen atom. In an implementation, in the phosphorus-containing compound represented by Formula 1 according to an embodiment, one of R₁ to R₈ may be represented by the above Formula 2, and the remainder thereof may each be a hydrogen atom. In an implementation, in the phosphorus-containing compound according to an embodiment, R₃ may be represented by Formula 2, and R₁, R₂, and R₄ to R₈ may each be a hydrogen atom. In an implementation, in the phosphorus-containing compound according to an embodiment, one of R₁, R₂ and R₄ may be represented by Formula 2, and the remainder including R₃ may each be a hydrogen atom.

In an implementation, the phosphorus-containing compound represented by Formula 1 may be a compound represented by the following Formula 3.

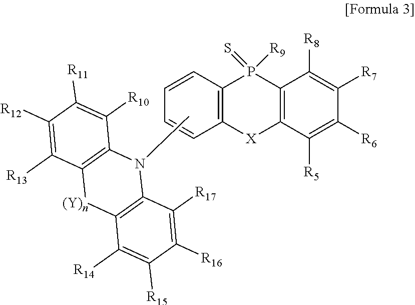

In Formula 3, the same explanation in the above Formula 1 and Formula 2 may be applied for R₅ to R₁₇, X, Y and n.

Formula 3 represents a phosphorus-containing compound of Formula 1 where one of R₁ to R₄ is represented by Formula 2. For example, Formula 3 is represented by Formula 1 where one of R₁ to R₄ is represented by Formula 2, and the remaining R₅ to R₈ may be hydrogen atoms.

In an implementation, the phosphorus-containing compound represented by Formula 1 may be a compound represented by the following Formula 4.

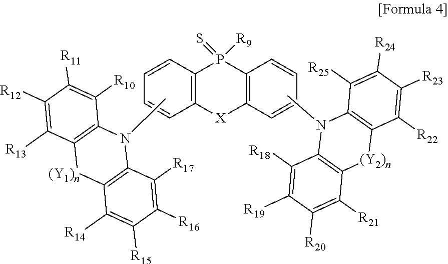

In Formula 4, the same explanation in Formula 1 and Formula 2 may be applied for R₉ to R₁₇, X and n.

In an implementation, R₁₈ to R₂₄ in Formula 4 may each independently be or include, e.g., a hydrogen atom, a deuterium atom, a halogen atom, a substituted or unsubstituted silyl group, a substituted or unsubstituted amino group, a substituted or unsubstituted alkyl group having 1 to 20 carbon atoms, a substituted or unsubstituted aryl group having 6 to 30 ring carbon atoms, or a substituted or unsubstituted heteroaryl group having 4 to 30 ring carbon atoms.

Y₁ and Y₂ may each independently be, e.g., a direct linkage, O, S, CRₕRᵢ, SiRⱼRₖ, or GeRₗRₘ, Rₕ to Rₘ may each independently be or include, e.g., a hydrogen atom, a deuterium atom, a halogen atom, a substituted or unsubstituted silyl group, a substituted or unsubstituted alkyl group having 1 to 20 carbon atoms, a substituted or unsubstituted fluorenyl group, a substituted or unsubstituted aryl group having 6 to 30 ring carbon atoms, or a substituted or unsubstituted heteroaryl group having 4 to 30 ring carbon atoms. In an implementation, Rₕ to Rₘ may be separate or may be combined with an adjacent group to form a ring.

In an implementation, the compound represented by Formula 1 may be represented by one of the following Formula 1-1 to Formula 1-6.

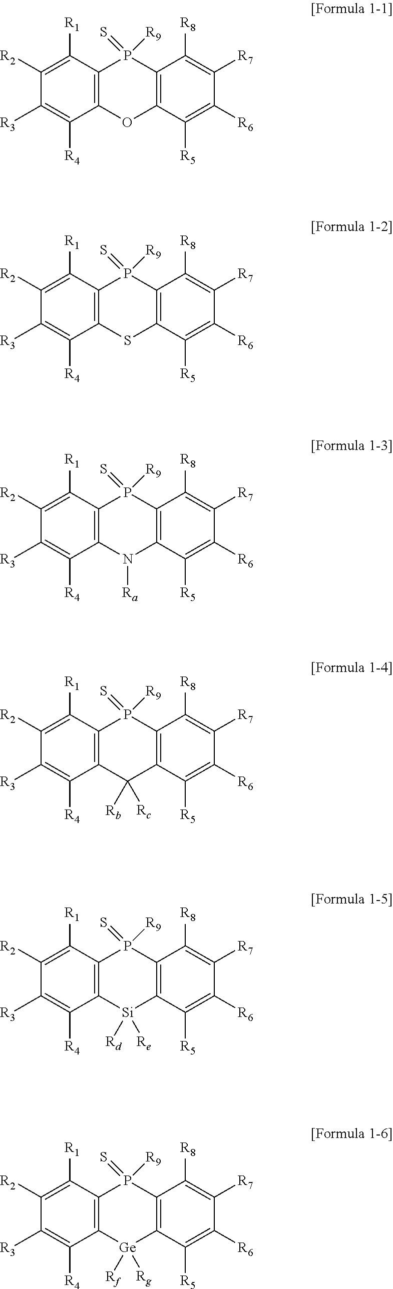

In Formula 1-1 to Formula 1-6, the same explanation in Formula 1 may be applied for R₁ to R₉, and Rₐ to R_{g}. In an implementation, in Formula 1-1 to Formula 1-6, R₉ may be or may include. e.g., a substituted or unsubstituted aryl group having 6 to 30 ring carbon atoms, or a substituted or unsubstituted heteroaryl group having 4 to 30 ring carbon atoms, and R₁ to R₈ may be hydrogen atoms.

Formula 1-1 represents a case when X is O, and Formula 1-2 represents a case when X is S. Formula 1-3 and Formula 1-4 each independently represents a case when X is NRₐ and CR_{b}R_{c}, respectively. In addition, Formula 1-5 and Formula 1-6 each independently represents a case when X is SiR_{d}Rₑ and GeR_{f}R_{g}, respectively.

In an implementation, in the case where Formula 1 is Formula 1-3 where X is NRₑ, Rₐ may be or may include a substituted or unsubstituted aryl group. In an implementation, Rₐ may be or may include, e.g., a substituted or unsubstituted phenyl group. In an implementation, Rₐ may be an unsubstituted phenyl group.

In the case where Formula 1 is Formula 1-4 where X is CR_{b}R_{c}, R_{b} and R_{c} may be the same or different. In an implementation, R_{b} and R_{c} may each independently be or include, e.g., a hydrogen atom, a deuterium atom, a halogen atom, a substituted or unsubstituted silyl group, a substituted or unsubstituted alkyl group having 1 to 20 carbon atoms, a substituted or unsubstituted fluorenyl group, a substituted or unsubstituted aryl group having 6 to 30 ring carbon atoms, or a substituted or unsubstituted heteroaryl group having 4 to 30 ring carbon atoms ring. In an implementation, R_{b} and R_{c} may be combined with each other to form a ring, or may be combined with an adjacent group to form a ring.

In an implementation, R_{b} and R_{c} of CR_{b}R_{c} may each independently be or include, e.g., a substituted or unsubstituted alkyl group having 1 to 20 carbon atoms. In an implementation, both R_{b} and R_{c} may be methyl groups. In an implementation, R_{b} and R_{c} of CR_{b}R_{c} may each independently be or include, e.g., a substituted or unsubstituted aryl group having 6 to 30 ring carbon atoms. In an implementation, both R_{b} and R_{c} may be phenyl groups.

In an implementation, in Formula 1-5 where X is SiR_{d}Rₑ and Formula 1-6 where X is GeR_{f}R_{g}, R_{d} to R_{g} may each independently be or include, e.g., a hydrogen atom, a deuterium atom, a halogen atom, a substituted or unsubstituted silyl group, a substituted or unsubstituted alkyl group having 1 to 20 carbon atoms, a substituted or unsubstituted fluorenyl group, a substituted or unsubstituted aryl group having 6 to 30 ring carbon atoms, or a substituted or unsubstituted heteroaryl group having 4 to 30 ring carbon atoms. In Formula 1-5, R_{d} and R_{g} may be the same or different. In an implementation, R_{d} and Rₑ may be combined with each other to form a ring, or may be combined with an adjacent group to form a ring. In Formula 1-6, R_{f} and R_{g} may be the same or different. In an implementation, R_{f} and R_{g} may be combined with each other to form a ring, or may be combined with an adjacent group to form a ring.

In the phosphorus-containing compound represented by Formula 1 according to an embodiment, R₉ may be or may include, e.g., a substituted or unsubstituted aryl group having 6 to 30 ring carbon atoms. In an implementation, R₉ may be, e.g., a substituted or unsubstituted phenyl group. In an implementation, R₉ may be, e.g., an unsubstituted phenyl group. In an implementation, R₉ may be, e.g., a phenyl group substituted with a halogen atom, a phenyl group substituted with an alkyl group, or a phenyl group substituted with a cyano group. In an implementation, R₉ may be, e.g., a phenyl group in which at least one hydrogen atom is substituted with fluorine (F). In an implementation. R₉ may be, e.g., a phenyl group in which at least one hydrogen atom is substituted with a methyl group.

In an implementation, in the phosphorus-containing compound represented by Formula 1 according to an embodiment, R₉ may be or may include, e.g., a substituted or unsubstituted pyridyl group or a substituted or unsubstituted naphthyl group. In an implementation, in the phosphorus-containing compound according to an embodiment, R₉ may be, e.g., an unsubstituted pyridyl group or an unsubstituted naphthyl group.

In an implementation, in Formula 2, Y may be a direct linkage or CRₕRᵢ, Rₕ and Rᵢ may be the same or different. In an implementation, Rₕ to Rᵢ may each independently be or include, e.g., a hydrogen atom, a deuterium atom, a halogen atom, a substituted or unsubstituted silyl group, a substituted or unsubstituted alkyl group having 1 to 20 carbon atoms, a substituted or unsubstituted fluorenyl group, a substituted or unsubstituted aryl group having 6 to 30 ring carbon atoms, or a substituted or unsubstituted heteroaryl group having 4 to 30 ring carbon atoms. In an implementation, Rₕ to Rᵢ may be separate or may be combined with an adjacent group to form a ring. In an implementation, Rₕ and Rᵢ may be combined with each other to form a ring. In an implementation. Rₕ and Rᵢ may be combined with each other to form a fluorene ring. In an implementation. Rₕ and Rᵢ may be combined with each other to form a heterocycle. In an implementation, Rₕ and Rᵢ may be combined with each other to form a xanthene ring.

In an implementation, the group represented by Formula 2 may be a group represented by one of the following Formula 2-1 to Formula 2-9.

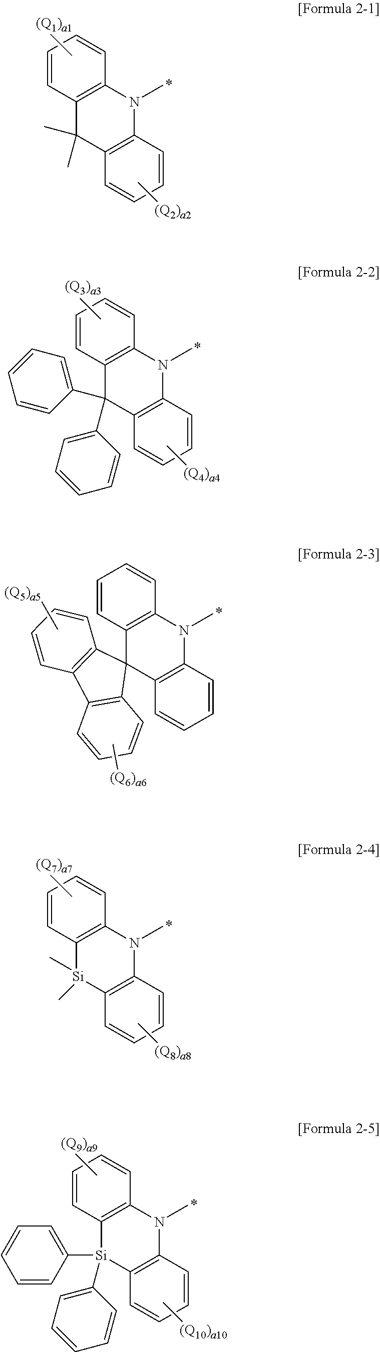

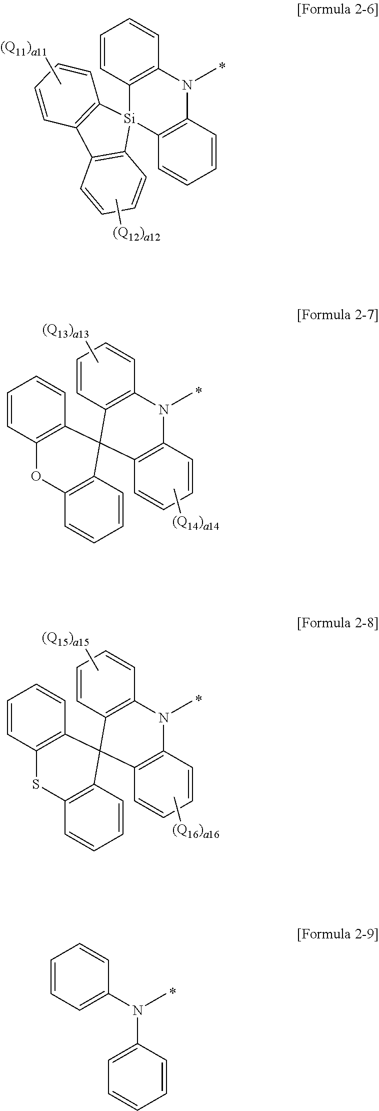

In Formula 2-1 to Formula 2-8, Q₁ to Q₁₆ may each independently be or include, e.g., a hydrogen atom, a deuterium atom, a halogen atom, a substituted or unsubstituted silyl group, or a substituted or unsubstituted alkyl group having 1 to 20 carbon atoms, and a₁ to a₁₆ may each independently be, e.g., an integer of 0 to 4. In an implementation, Formula 2-1 to Formula 2-8 correspond to Formula 2 where n=1, and Formula 2-9 corresponds to Formula 2 where n=0.

In an implementation, the phosphorus-containing compound represented by Formula 1 may be, e.g., a compound of the following Compound Group 1.

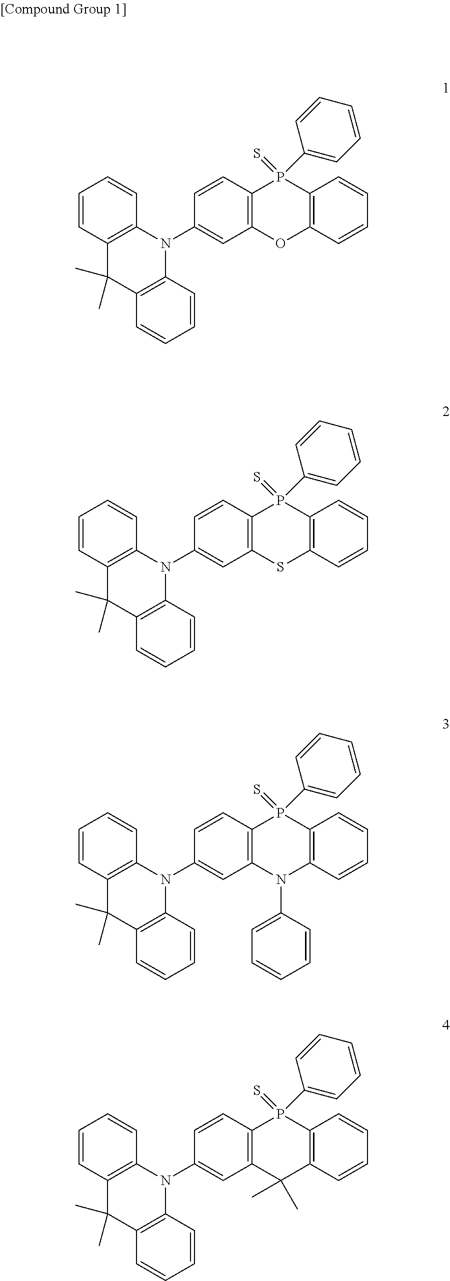 [SMILES: CC1(C)c2ccccc2N(c2ccc3c(c2)Oc2ccccc2P3(=S)c2ccccc2)c2ccccc21 ; CC1(C)c2ccccc2N(c2ccc3c(c2)Sc2ccccc2P3(=S)c2ccccc2)c2ccccc21 ; CC1(C)c2ccccc2N(c2ccc3c(c2)N(c2ccccc2)c2ccccc2P3(=S)c2ccccc2)c2ccccc21 ; CC1(C)c2ccccc2N(c2ccc3c(c2)C(C)(C)c2ccccc2P3(=S)c2ccccc2)c2ccccc21]

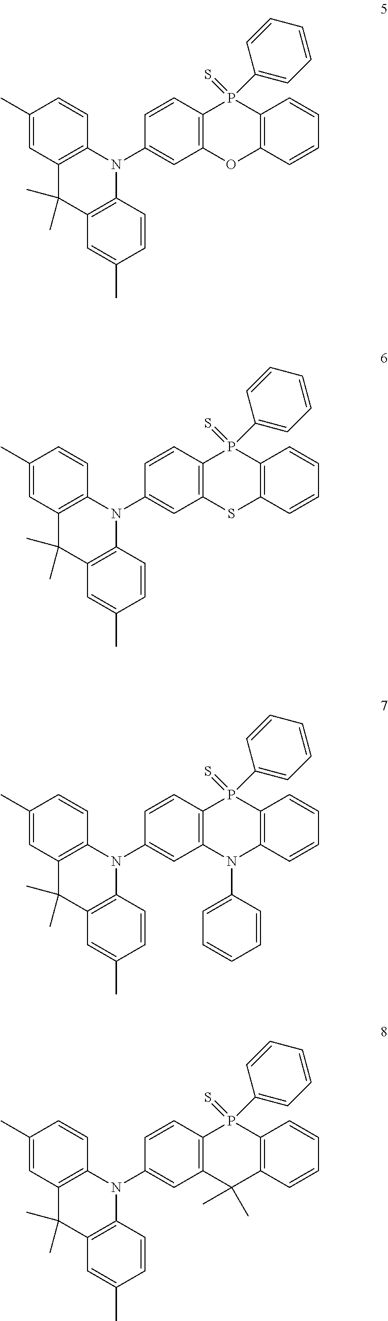 [SMILES: Cc1ccc2c(c1)C(C)(C)c1cc(C)ccc1N2c1ccc2c(c1)Oc1ccccc1P2(=S)c1ccccc1 ; Cc1ccc2c(c1)C(C)(C)c1cc(C)ccc1N2c1ccc2c(c1)Sc1ccccc1P2(=S)c1ccccc1 ; Cc1ccc2c(c1)C(C)(C)c1cc(C)ccc1N2c1ccc2c(c1)N(c1ccccc1)c1ccccc1P2(=S)c1ccccc1 ; Cc1ccc2c(c1)C(C)(C)c1cc(C)ccc1N2c1ccc2c(c1)C(C)(C)c1ccccc1P2(=S)c1ccccc1]

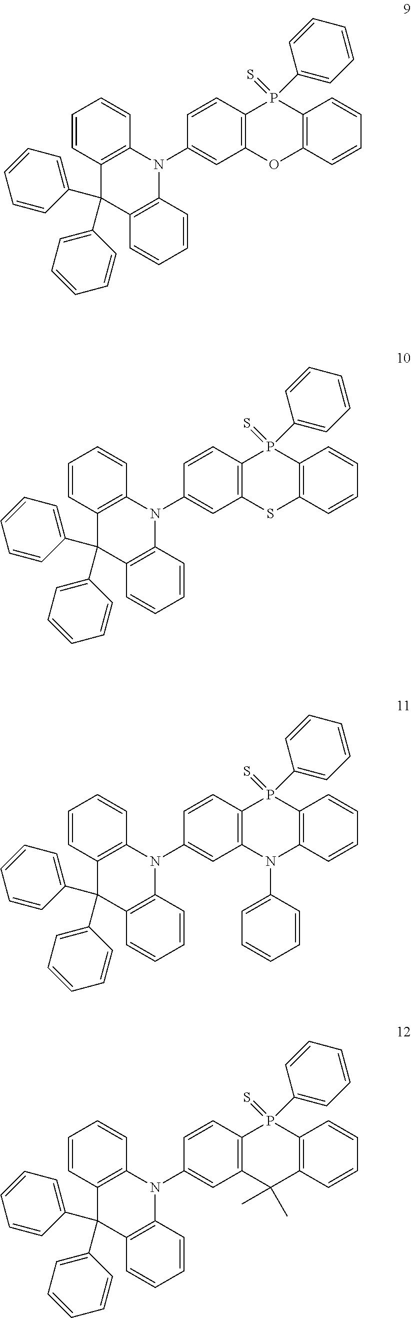 [SMILES: S=P1(c2ccccc2)c2ccccc2Oc2cc(N3c4ccccc4C(c4ccccc4)(c4ccccc4)c4ccccc43)ccc21 ; S=P1(c2ccccc2)c2ccccc2Sc2cc(N3c4ccccc4C(c4ccccc4)(c4ccccc4)c4ccccc43)ccc21 ; S=P1(c2ccccc2)c2ccccc2N(c2ccccc2)c2cc(N3c4ccccc4C(c4ccccc4)(c4ccccc4)c4ccccc43)ccc21 ; CC1(C)c2ccccc2P(=S)(c2ccccc2)c2ccc(N3c4ccccc4C(c4ccccc4)(c4ccccc4)c4ccccc43)cc21]

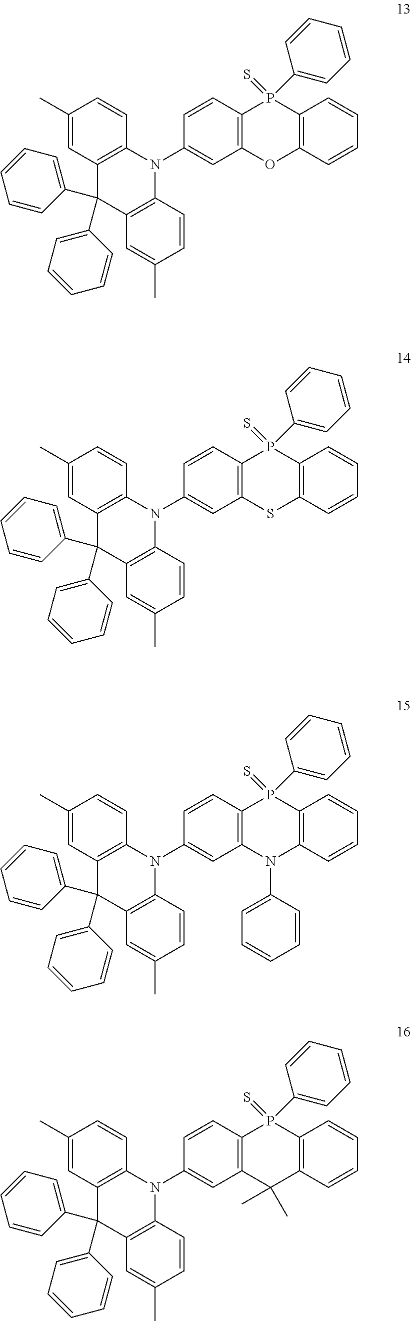 [SMILES: Cc1ccc2c(c1)C(c1ccccc1)(c1ccccc1)c1cc(C)ccc1N2c1ccc2c(c1)Oc1ccccc1P2(=S)c1ccccc1 ; Cc1ccc2c(c1)C(c1ccccc1)(c1ccccc1)c1cc(C)ccc1N2c1ccc2c(c1)Sc1ccccc1P2(=S)c1ccccc1 ; Cc1ccc2c(c1)C(c1ccccc1)(c1ccccc1)c1cc(C)ccc1N2c1ccc2c(c1)N(c1ccccc1)c1ccccc1P2(=S)c1ccccc1 ; Cc1ccc2c(c1)C(c1ccccc1)(c1ccccc1)c1cc(C)ccc1N2c1ccc2c(c1)C(C)(C)c1ccccc1P2(=S)c1ccccc1]

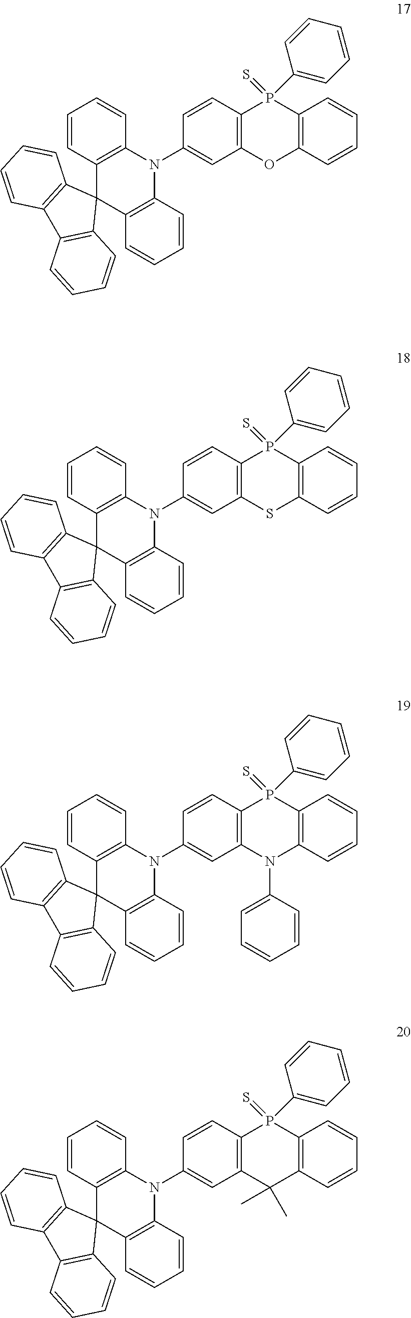 [SMILES: S=P1(c2ccccc2)c2ccccc2Oc2cc(N3c4ccccc4C4(c5ccccc5-c5ccccc54)c4ccccc43)ccc21 ; S=P1(c2ccccc2)c2ccccc2Sc2cc(N3c4ccccc4C4(c5ccccc5-c5ccccc54)c4ccccc43)ccc21 ; S=P1(c2ccccc2)c2ccccc2N(c2ccccc2)c2cc(N3c4ccccc4C4(c5ccccc5-c5ccccc54)c4ccccc43)ccc21 ; CC1(C)c2ccccc2P(=S)(c2ccccc2)c2ccc(N3c4ccccc4C4(c5ccccc5-c5ccccc54)c4ccccc43)cc21]

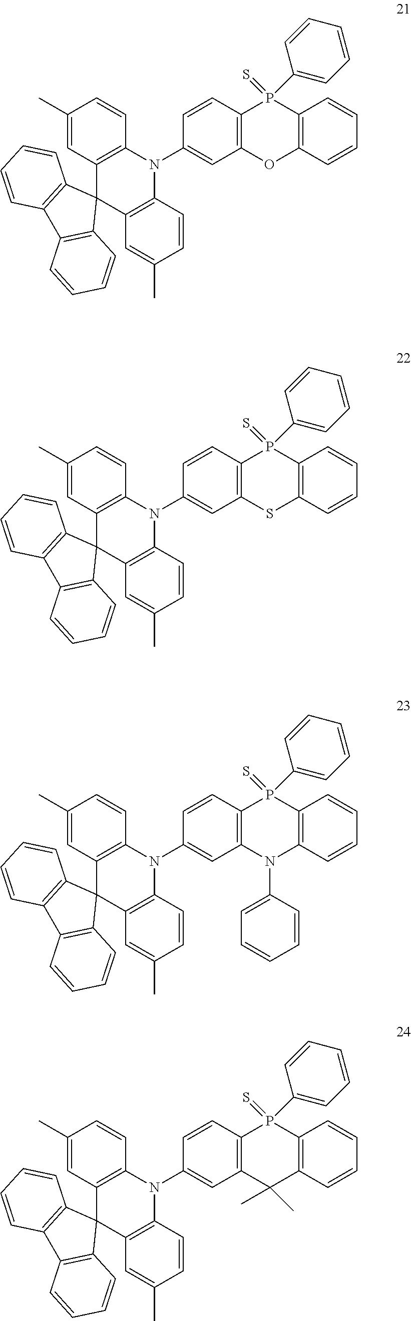 [SMILES: Cc1ccc2c(c1)C1(c3ccccc3-c3ccccc31)c1cc(C)ccc1N2c1ccc2c(c1)Oc1ccccc1P2(=S)c1ccccc1 ; Cc1ccc2c(c1)C1(c3ccccc3-c3ccccc31)c1cc(C)ccc1N2c1ccc2c(c1)Sc1ccccc1P2(=S)c1ccccc1 ; Cc1ccc2c(c1)C1(c3ccccc3-c3ccccc31)c1cc(C)ccc1N2c1ccc2c(c1)N(c1ccccc1)c1ccccc1P2(=S)c1ccccc1 ; Cc1ccc2c(c1)C1(c3ccccc3-c3ccccc31)c1cc(C)ccc1N2c1ccc2c(c1)C(C)(C)c1ccccc1P2(=S)c1ccccc1]

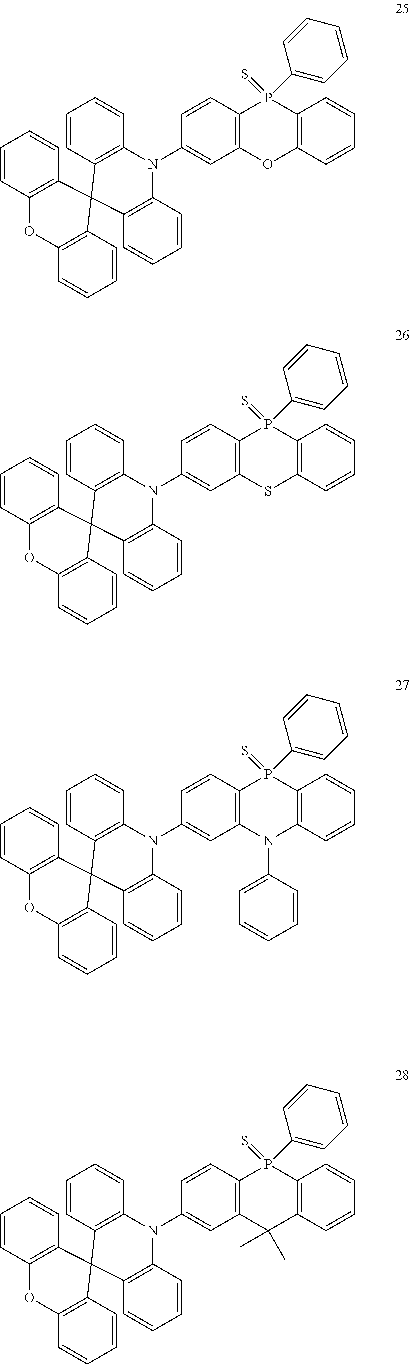 [SMILES: S=P1(c2ccccc2)c2ccccc2Oc2cc(N3c4ccccc4C4(c5ccccc5Oc5ccccc54)c4ccccc43)ccc21 ; S=P1(c2ccccc2)c2ccccc2Sc2cc(N3c4ccccc4C4(c5ccccc5Oc5ccccc54)c4ccccc43)ccc21 ; S=P1(c2ccccc2)c2ccccc2N(c2ccccc2)c2cc(N3c4ccccc4C4(c5ccccc5Oc5ccccc54)c4ccccc43)ccc21 ; CC1(C)c2ccccc2P(=S)(c2ccccc2)c2ccc(N3c4ccccc4C4(c5ccccc5Oc5ccccc54)c4ccccc43)cc21]

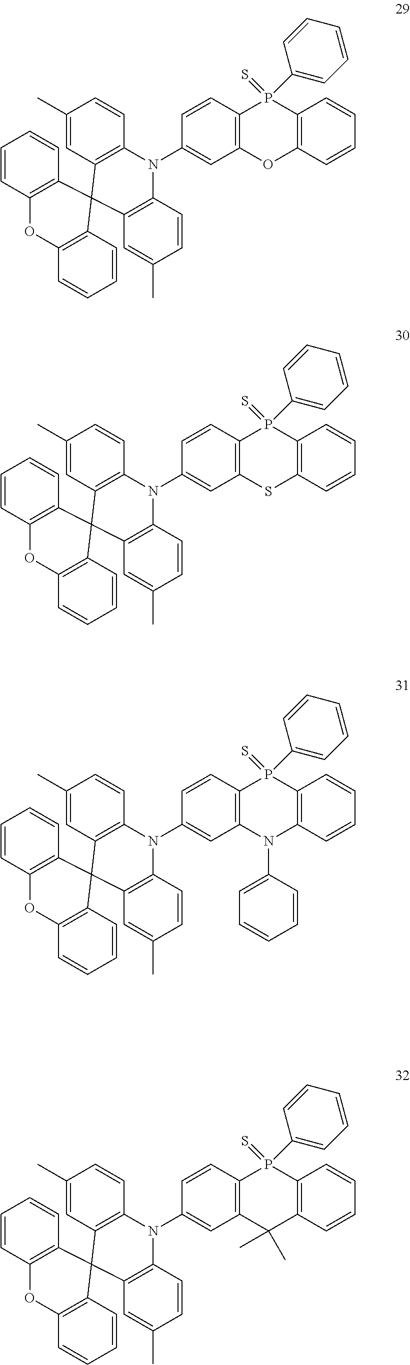 [SMILES: Cc1ccc2c(c1)C1(c3ccccc3Oc3ccccc31)c1cc(C)ccc1N2c1ccc2c(c1)Oc1ccccc1P2(=S)c1ccccc1 ; Cc1ccc2c(c1)C1(c3ccccc3Oc3ccccc31)c1cc(C)ccc1N2c1ccc2c(c1)Sc1ccccc1P2(=S)c1ccccc1 ; Cc1ccc2c(c1)C1(c3ccccc3Oc3ccccc31)c1cc(C)ccc1N2c1ccc2c(c1)N(c1ccccc1)c1ccccc1P2(=S)c1ccccc1 ; Cc1ccc2c(c1)C1(c3ccccc3Oc3ccccc31)c1cc(C)ccc1N2c1ccc2c(c1)C(C)(C)c1ccccc1P2(=S)c1ccccc1]

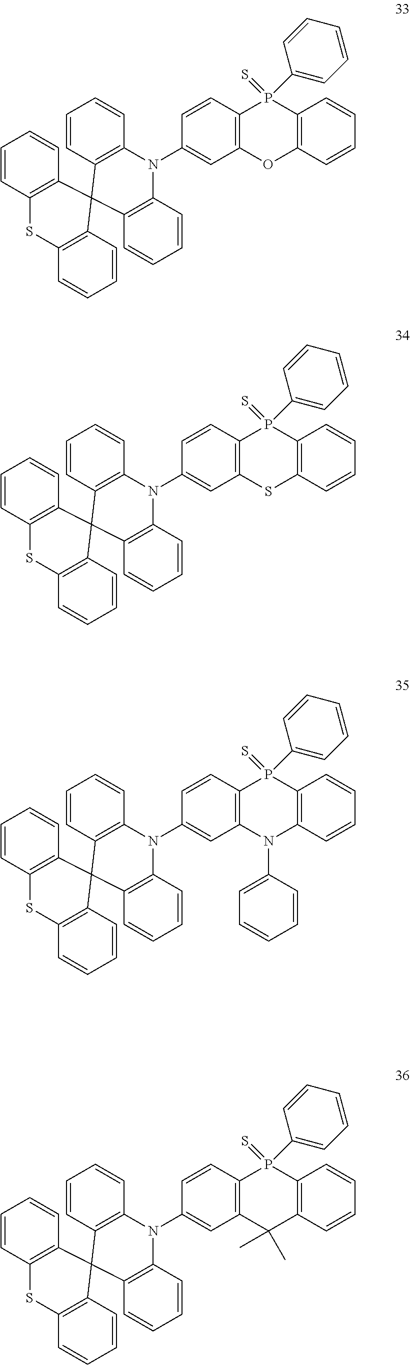 [SMILES: S=P1(c2ccccc2)c2ccccc2Oc2cc(N3c4ccccc4C4(c5ccccc5Sc5ccccc54)c4ccccc43)ccc21 ; S=P1(c2ccccc2)c2ccccc2Sc2cc(N3c4ccccc4C4(c5ccccc5Sc5ccccc54)c4ccccc43)ccc21 ; S=P1(c2ccccc2)c2ccccc2N(c2ccccc2)c2cc(N3c4ccccc4C4(c5ccccc5Sc5ccccc54)c4ccccc43)ccc21 ; CC1(C)c2ccccc2P(=S)(c2ccccc2)c2ccc(N3c4ccccc4C4(c5ccccc5Sc5ccccc54)c4ccccc43)cc21]

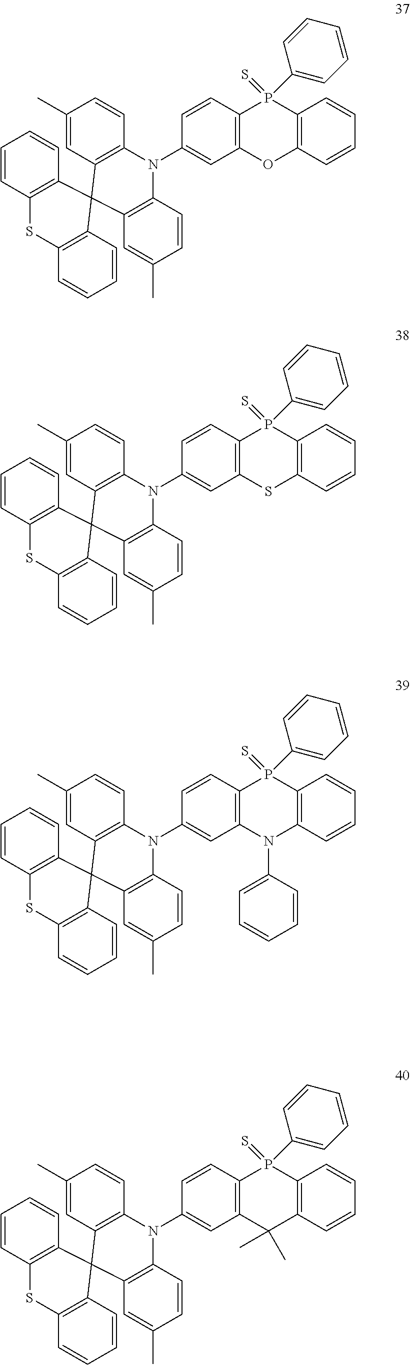 [SMILES: Cc1ccc2c(c1)C1(c3ccccc3Sc3ccccc31)c1cc(C)ccc1N2c1ccc2c(c1)Oc1ccccc1P2(=S)c1ccccc1 ; Cc1ccc2c(c1)C1(c3ccccc3Sc3ccccc31)c1cc(C)ccc1N2c1ccc2c(c1)Sc1ccccc1P2(=S)c1ccccc1 ; Cc1ccc2c(c1)C1(c3ccccc3Sc3ccccc31)c1cc(C)ccc1N2c1ccc2c(c1)N(c1ccccc1)c1ccccc1P2(=S)c1ccccc1 ; Cc1ccc2c(c1)C1(c3ccccc3Sc3ccccc31)c1cc(C)ccc1N2c1ccc2c(c1)C(C)(C)c1ccccc1P2(=S)c1ccccc1]

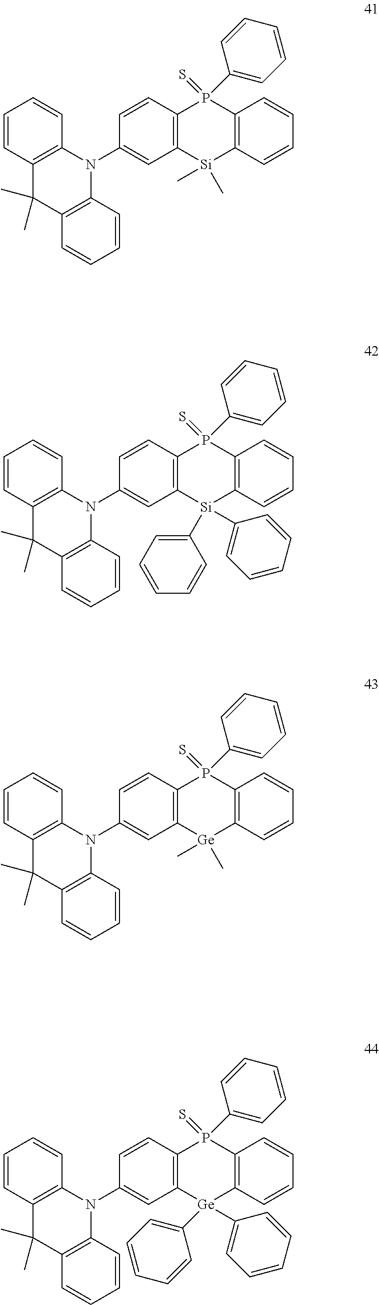

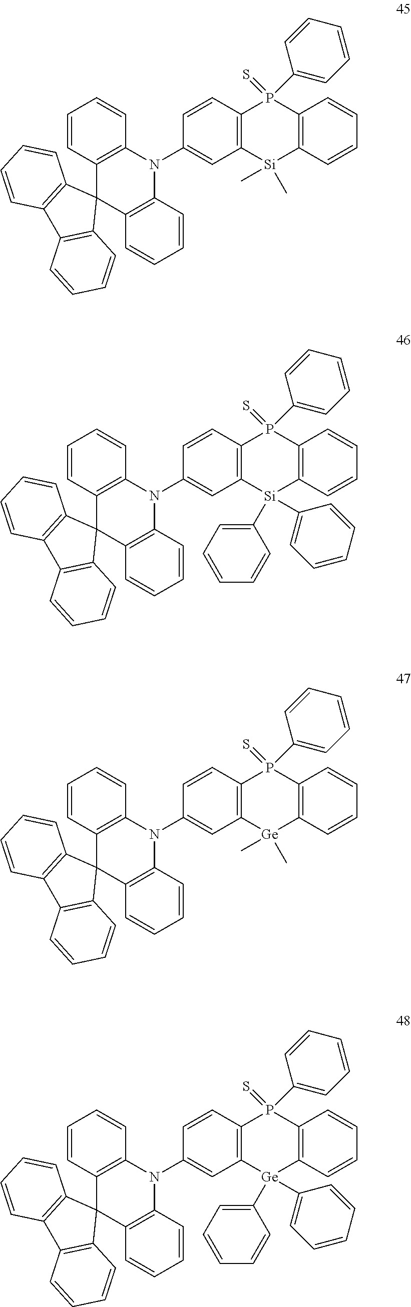

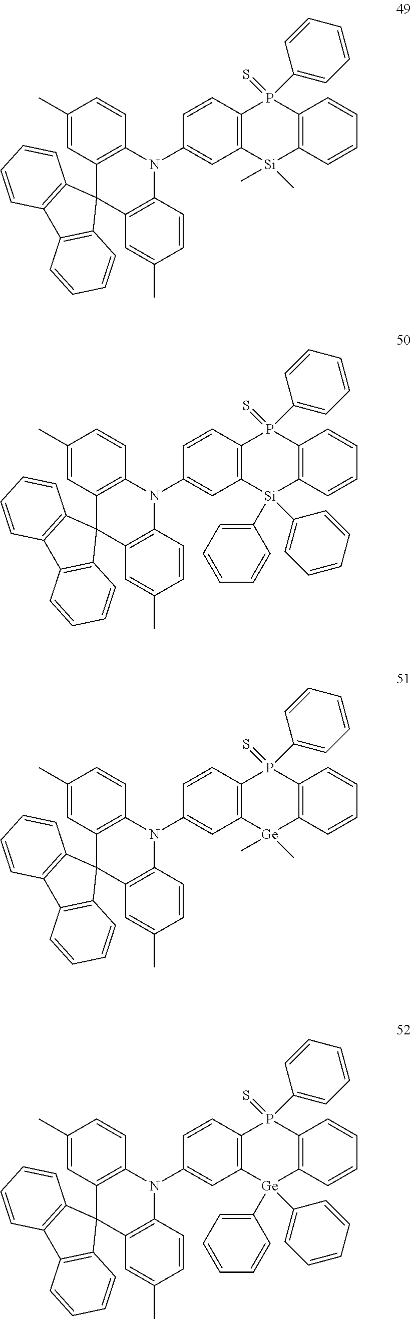

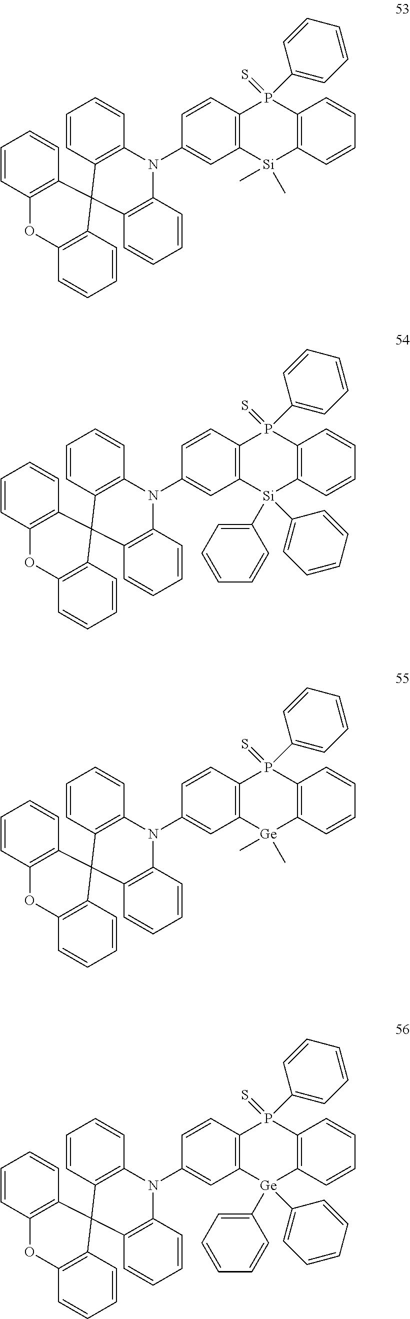

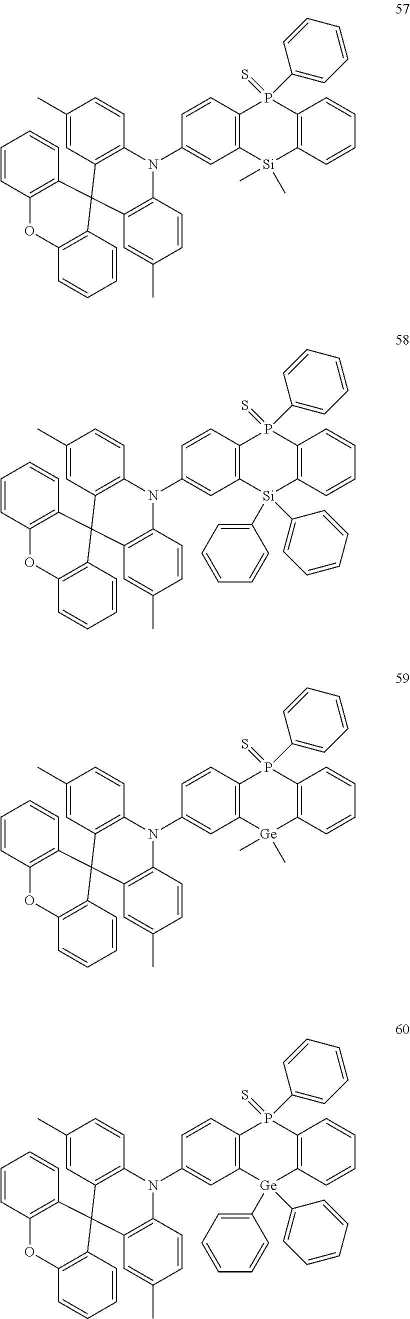

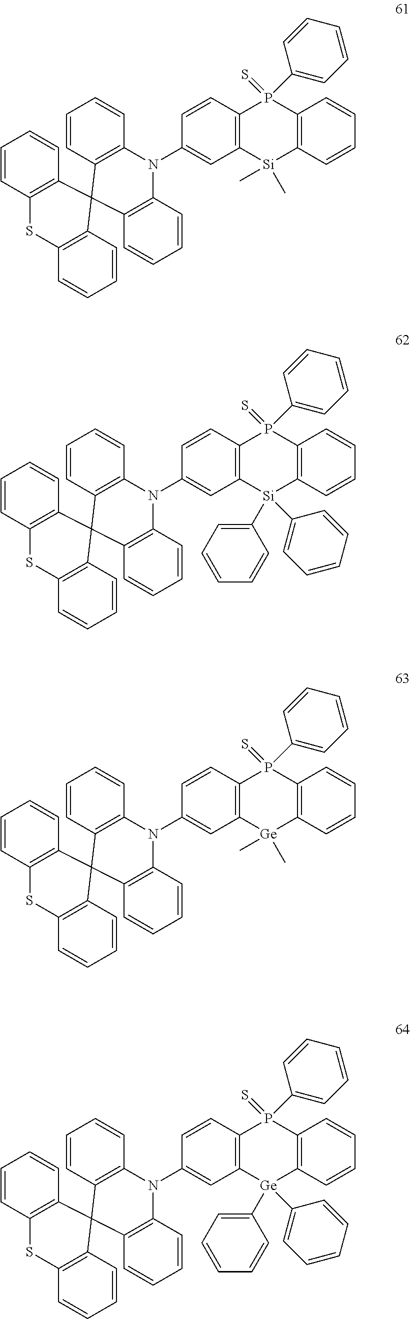

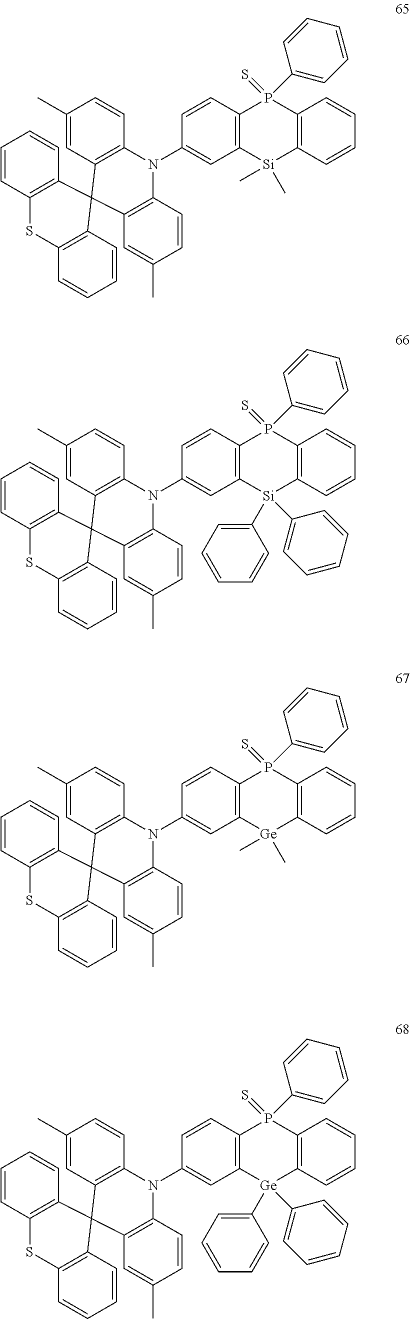

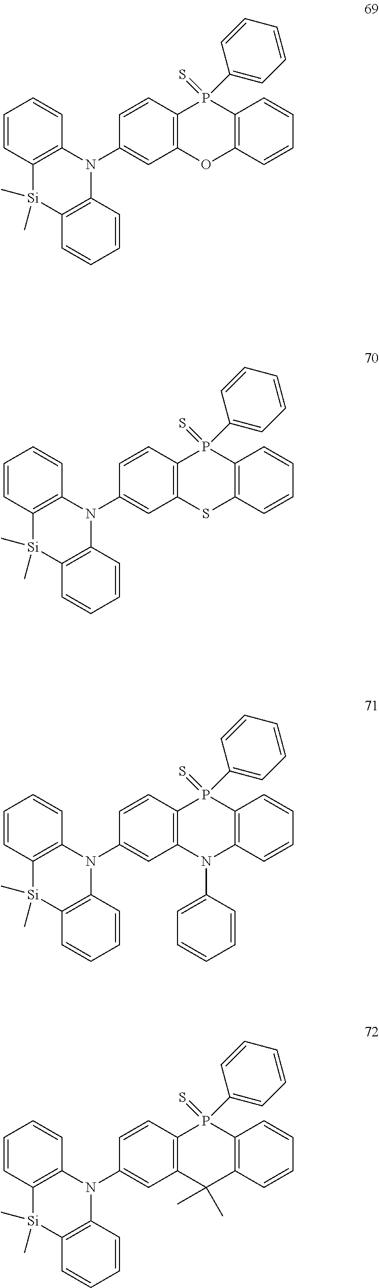 [SMILES: C[Si]1(C)c2ccccc2N(c2ccc3c(c2)Oc2ccccc2P3(=S)c2ccccc2)c2ccccc21 ; C[Si]1(C)c2ccccc2N(c2ccc3c(c2)Sc2ccccc2P3(=S)c2ccccc2)c2ccccc21 ; C[Si]1(C)c2ccccc2N(c2ccc3c(c2)N(c2ccccc2)c2ccccc2P3(=S)c2ccccc2)c2ccccc21 ; CC1(C)c2ccccc2P(=S)(c2ccccc2)c2ccc(N3c4ccccc4[Si](C)(C)c4ccccc43)cc21]

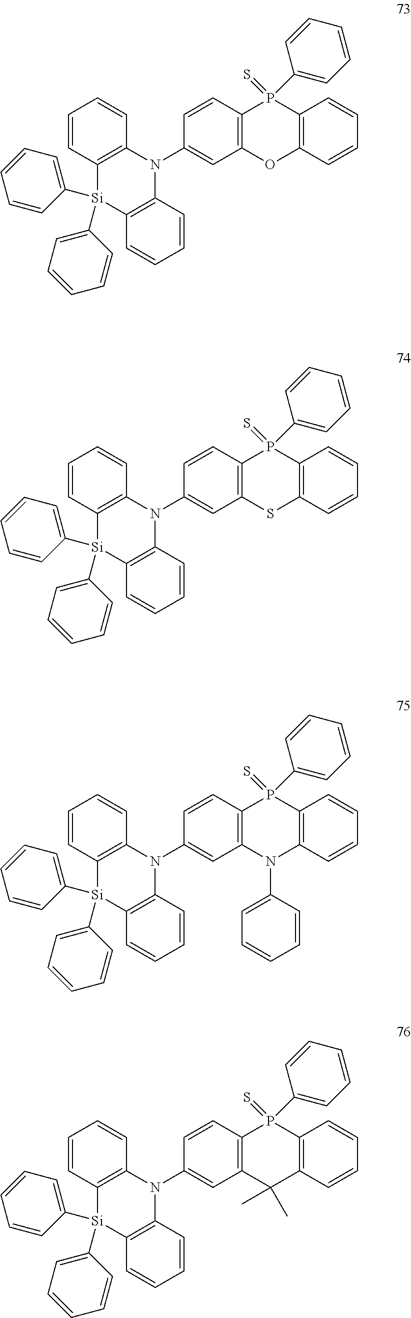 [SMILES: S=P1(c2ccccc2)c2ccccc2Oc2cc(N3c4ccccc4[Si](c4ccccc4)(c4ccccc4)c4ccccc43)ccc21 ; S=P1(c2ccccc2)c2ccccc2Sc2cc(N3c4ccccc4[Si](c4ccccc4)(c4ccccc4)c4ccccc43)ccc21 ; S=P1(c2ccccc2)c2ccccc2N(c2ccccc2)c2cc(N3c4ccccc4[Si](c4ccccc4)(c4ccccc4)c4ccccc43)ccc21 ; CC1(C)c2ccccc2P(=S)(c2ccccc2)c2ccc(N3c4ccccc4[Si](c4ccccc4)(c4ccccc4)c4ccccc43)cc21]

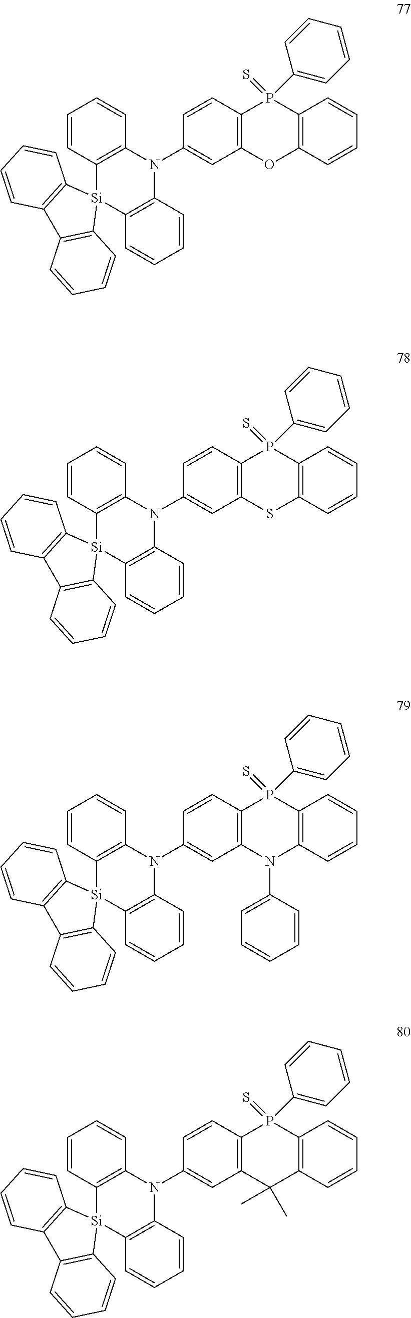 [SMILES: S=P1(c2ccccc2)c2ccccc2Oc2cc(N3c4ccccc4[Si]4(c5ccccc5-c5ccccc54)c4ccccc43)ccc21 ; S=P1(c2ccccc2)c2ccccc2Sc2cc(N3c4ccccc4[Si]4(c5ccccc5-c5ccccc54)c4ccccc43)ccc21 ; S=P1(c2ccccc2)c2ccccc2N(c2ccccc2)c2cc(N3c4ccccc4[Si]4(c5ccccc5-c5ccccc54)c4ccccc43)ccc21 ; CC1(C)c2ccccc2P(=S)(c2ccccc2)c2ccc(N3c4ccccc4[Si]4(c5ccccc5-c5ccccc54)c4ccccc43)cc21]

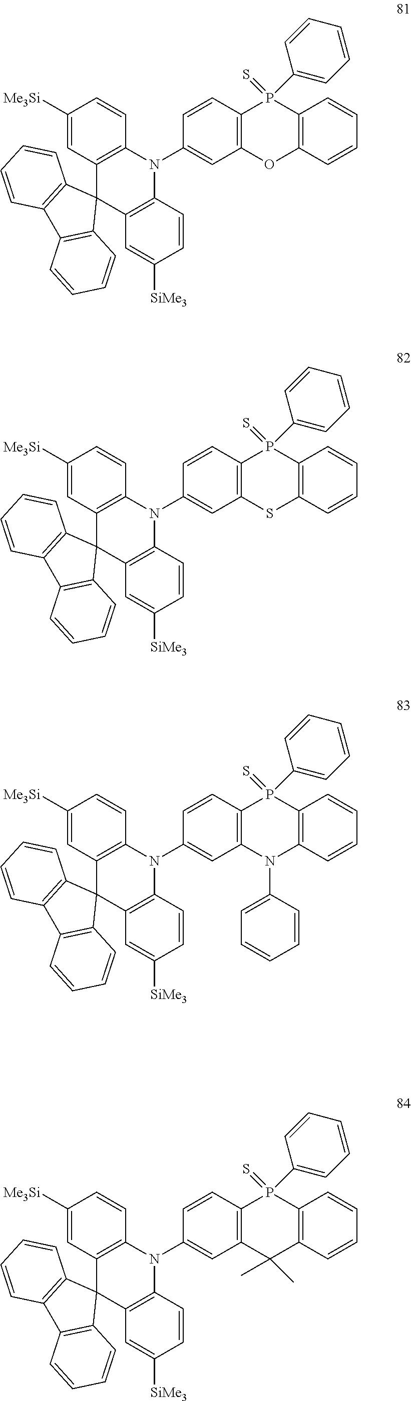 [SMILES: C[Si](C)(C)c1ccc2c(c1)C1(c3ccccc3-c3ccccc31)c1cc([Si](C)(C)C)ccc1N2c1ccc2c(c1)Oc1ccccc1P2(=S)c1ccccc1 ; C[Si](C)(C)c1ccc2c(c1)C1(c3ccccc3-c3ccccc31)c1cc([Si](C)(C)C)ccc1N2c1ccc2c(c1)Sc1ccccc1P2(=S)c1ccccc1 ; C[Si](C)(C)c1ccc2c(c1)C1(c3ccccc3-c3ccccc31)c1cc([Si](C)(C)C)ccc1N2c1ccc2c(c1)N(c1ccccc1)c1ccccc1P2(=S)c1ccccc1 ; CC1(C)c2ccccc2P(=S)(c2ccccc2)c2ccc(N3c4ccc([Si](C)(C)C)cc4C4(c5ccccc5-c5ccccc54)c4cc([Si](C)(C)C)ccc43)cc21]

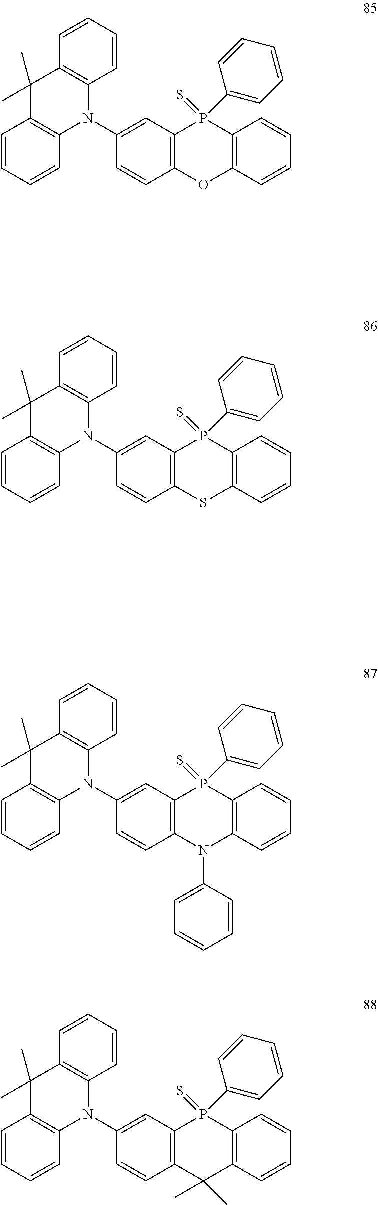 [SMILES: CC1(C)c2ccccc2N(c2ccc3c(c2)P(=S)(c2ccccc2)c2ccccc2O3)c2ccccc21 ; CC1(C)c2ccccc2N(c2ccc3c(c2)P(=S)(c2ccccc2)c2ccccc2S3)c2ccccc21 ; CC1(C)c2ccccc2N(c2ccc3c(c2)P(=S)(c2ccccc2)c2ccccc2N3c2ccccc2)c2ccccc21 ; CC1(C)c2ccccc2N(c2ccc3c(c2)P(=S)(c2ccccc2)c2ccccc2C3(C)C)c2ccccc21]

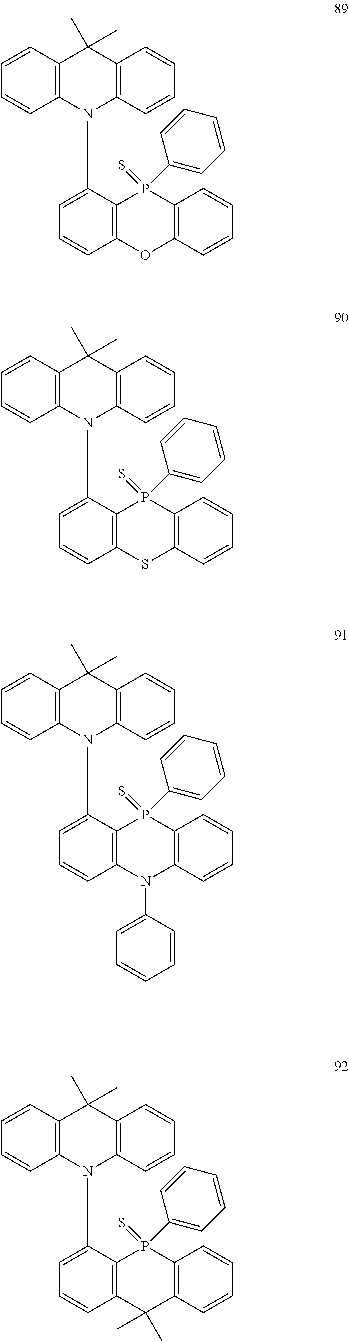 [SMILES: CC1(C)c2ccccc2N(c2cccc3c2P(=S)(c2ccccc2)c2ccccc2O3)c2ccccc21 ; CC1(C)c2ccccc2N(c2cccc3c2P(=S)(c2ccccc2)c2ccccc2S3)c2ccccc21 ; CC1(C)c2ccccc2N(c2cccc3c2P(=S)(c2ccccc2)c2ccccc2N3c2ccccc2)c2ccccc21 ; CC1(C)c2ccccc2N(c2cccc3c2P(=S)(c2ccccc2)c2ccccc2C3(C)C)c2ccccc21]

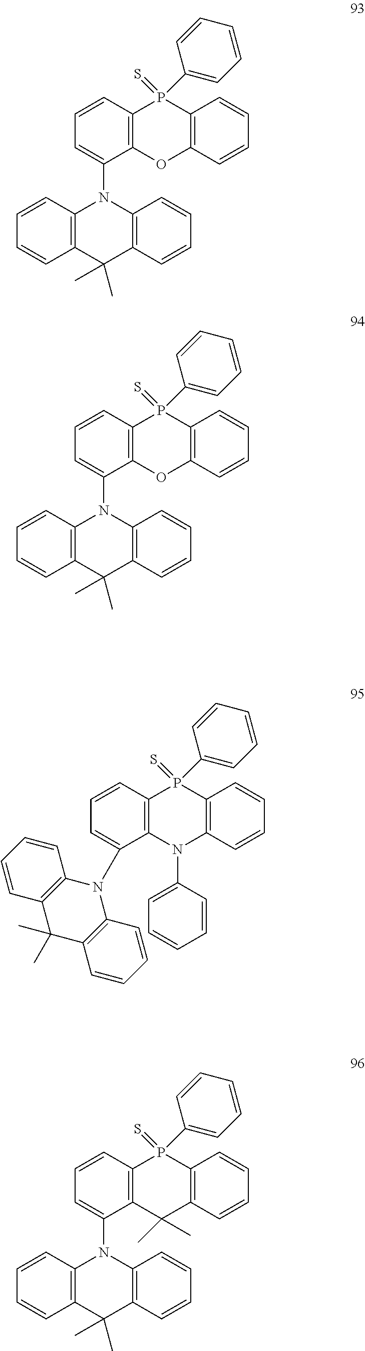 [SMILES: CC1(C)c2ccccc2N(c2cccc3c2Oc2ccccc2P3(=S)c2ccccc2)c2ccccc21 ; CC1(C)c2ccccc2N(c2cccc3c2Oc2ccccc2P3(=S)c2ccccc2)c2ccccc21 ; CC1(C)c2ccccc2N(c2cccc3c2N(c2ccccc2)c2ccccc2P3(=S)c2ccccc2)c2ccccc21 ; CC1(C)c2ccccc2N(c2cccc3c2C(C)(C)c2ccccc2P3(=S)c2ccccc2)c2ccccc21]

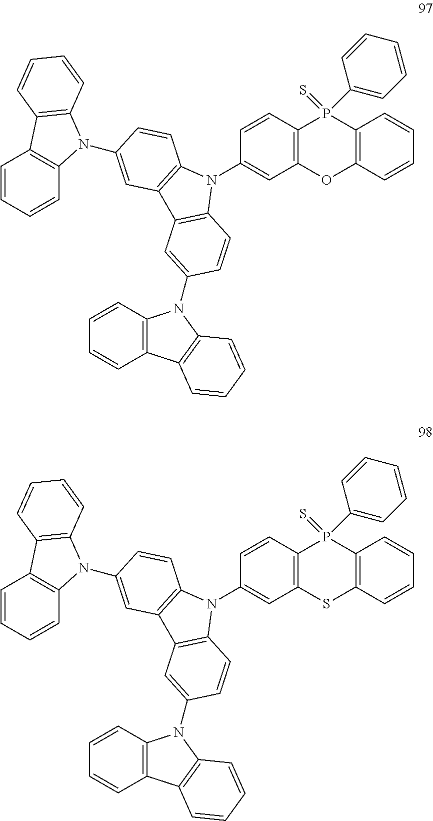 [SMILES: S=P1(c2ccccc2)c2ccccc2Oc2cc(-n3c4ccc(-n5c6ccccc6c6ccccc65)cc4c4cc(-n5c6ccccc6c6ccccc65)ccc43)ccc21 ; S=P1(c2ccccc2)c2ccccc2Sc2cc(-n3c4ccc(-n5c6ccccc6c6ccccc65)cc4c4cc(-n5c6ccccc6c6ccccc65)ccc43)ccc21]

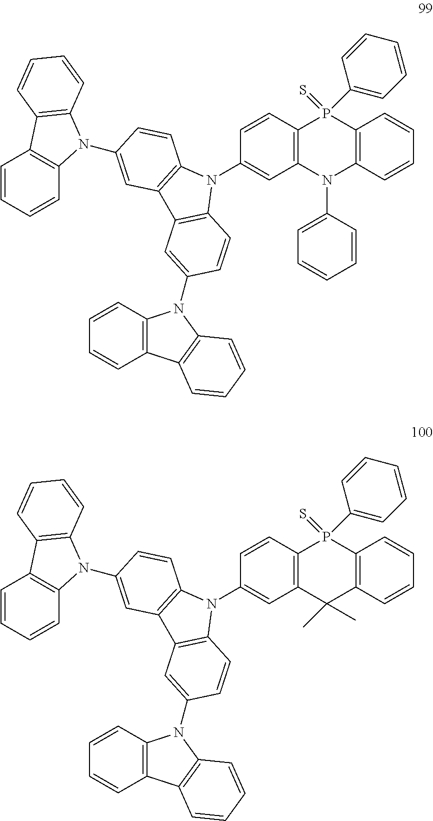 [SMILES: S=P1(c2ccccc2)c2ccccc2N(c2ccccc2)c2cc(-n3c4ccc(-n5c6ccccc6c6ccccc65)cc4c4cc(-n5c6ccccc6c6ccccc65)ccc43)ccc21 ; CC1(C)c2ccccc2P(=S)(c2ccccc2)c2ccc(-n3c4ccc(-n5c6ccccc6c6ccccc65)cc4c4cc(-n5c6ccccc6c6ccccc65)ccc43)cc21]

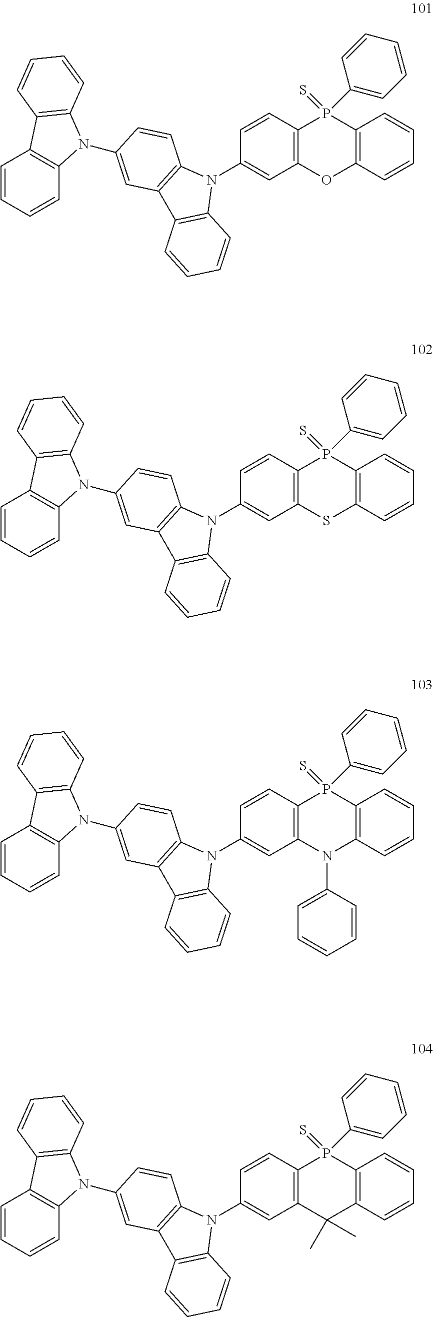 [SMILES: S=P1(c2ccccc2)c2ccccc2Oc2cc(-n3c4ccccc4c4cc(-n5c6ccccc6c6ccccc65)ccc43)ccc21 ; S=P1(c2ccccc2)c2ccccc2Sc2cc(-n3c4ccccc4c4cc(-n5c6ccccc6c6ccccc65)ccc43)ccc21 ; S=P1(c2ccccc2)c2ccccc2N(c2ccccc2)c2cc(-n3c4ccccc4c4cc(-n5c6ccccc6c6ccccc65)ccc43)ccc21 ; CC1(C)c2ccccc2P(=S)(c2ccccc2)c2ccc(-n3c4ccccc4c4cc(-n5c6ccccc6c6ccccc65)ccc43)cc21]

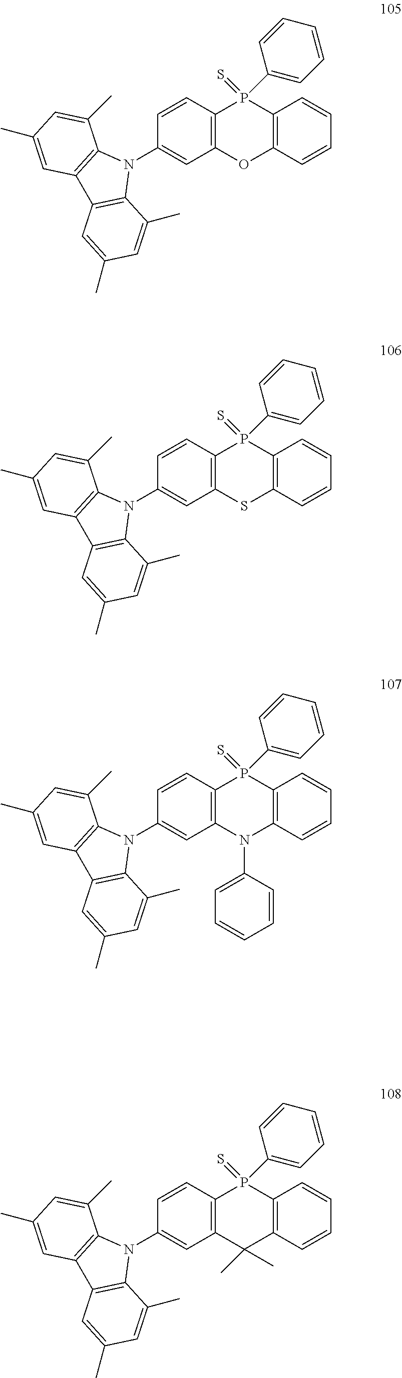 [SMILES: Cc1cc(C)c2c(c1)c1cc(C)cc(C)c1n2-c1ccc2c(c1)Oc1ccccc1P2(=S)c1ccccc1 ; Cc1cc(C)c2c(c1)c1cc(C)cc(C)c1n2-c1ccc2c(c1)Sc1ccccc1P2(=S)c1ccccc1 ; Cc1cc(C)c2c(c1)c1cc(C)cc(C)c1n2-c1ccc2c(c1)N(c1ccccc1)c1ccccc1P2(=S)c1ccccc1 ; Cc1cc(C)c2c(c1)c1cc(C)cc(C)c1n2-c1ccc2c(c1)C(C)(C)c1ccccc1P2(=S)c1ccccc1]

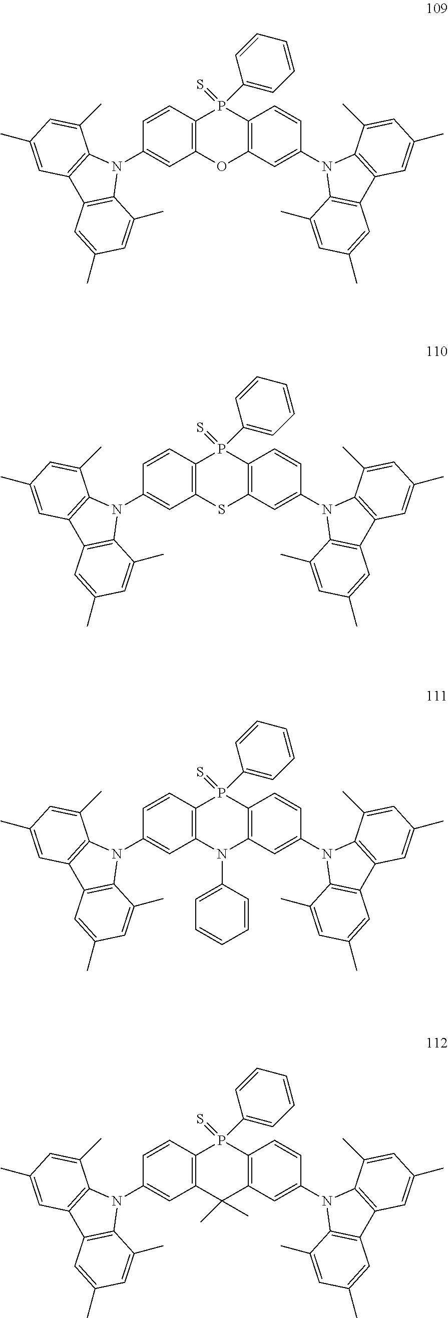

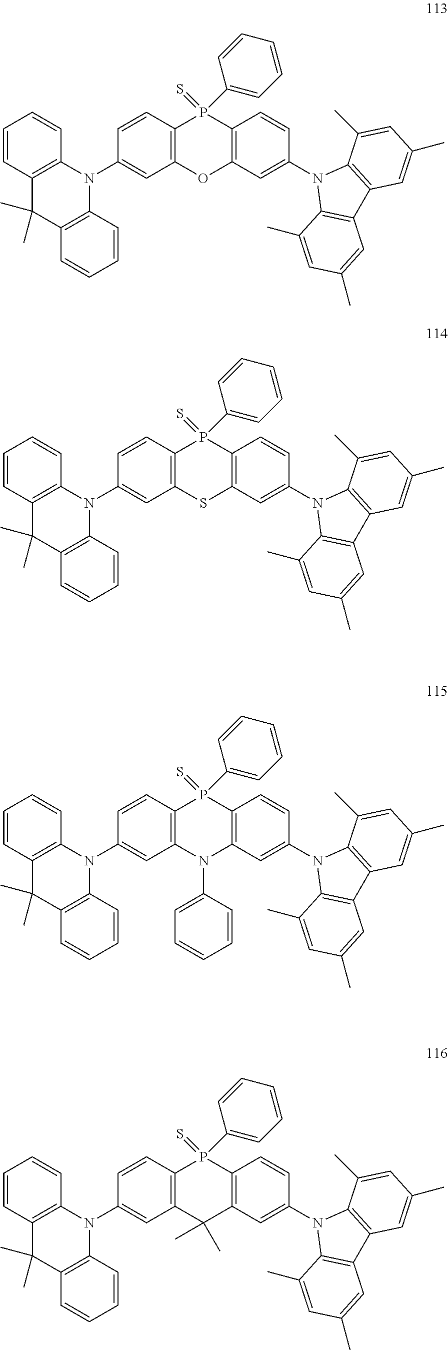

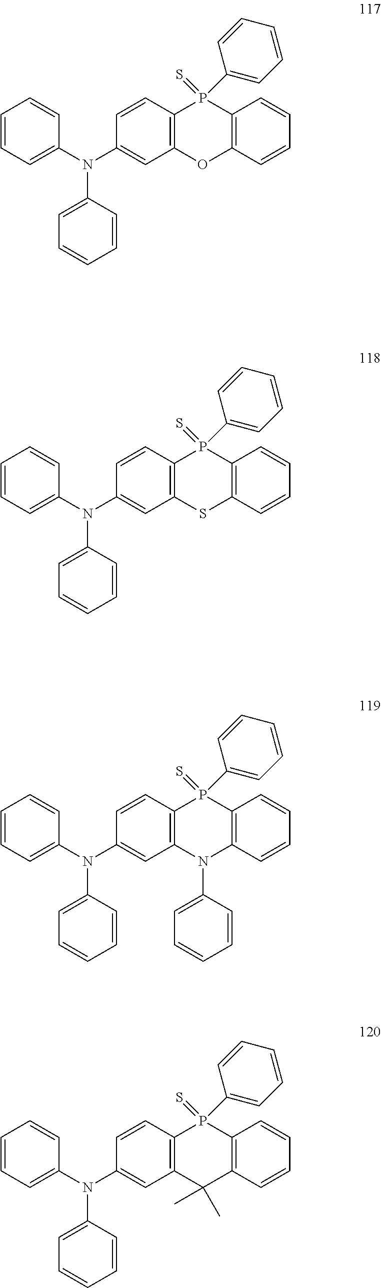 [SMILES: S=P1(c2ccccc2)c2ccccc2Oc2cc(N(c3ccccc3)c3ccccc3)ccc21 ; S=P1(c2ccccc2)c2ccccc2Sc2cc(N(c3ccccc3)c3ccccc3)ccc21 ; S=P1(c2ccccc2)c2ccccc2N(c2ccccc2)c2cc(N(c3ccccc3)c3ccccc3)ccc21 ; CC1(C)c2ccccc2P(=S)(c2ccccc2)c2ccc(N(c3ccccc3)c3ccccc3)cc21]

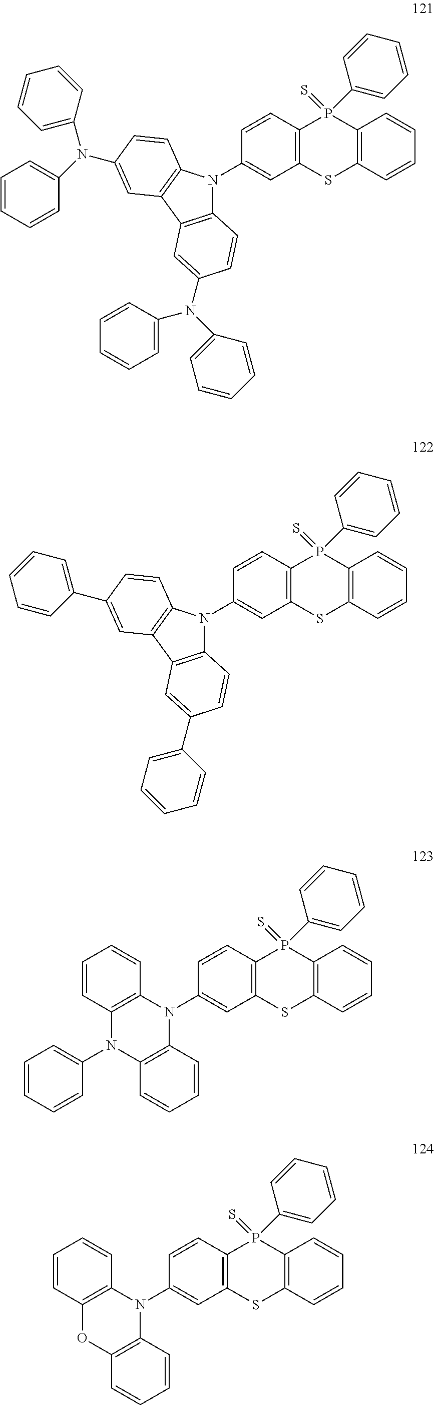 [SMILES: S=P1(c2ccccc2)c2ccccc2Sc2cc(-n3c4ccc(N(c5ccccc5)c5ccccc5)cc4c4cc(N(c5ccccc5)c5ccccc5)ccc43)ccc21 ; S=P1(c2ccccc2)c2ccccc2Sc2cc(-n3c4ccc(-c5ccccc5)cc4c4cc(-c5ccccc5)ccc43)ccc21 ; S=P1(c2ccccc2)c2ccccc2Sc2cc(N3c4ccccc4N(c4ccccc4)c4ccccc43)ccc21 ; S=P1(c2ccccc2)c2ccccc2Sc2cc(N3c4ccccc4Oc4ccccc43)ccc21]

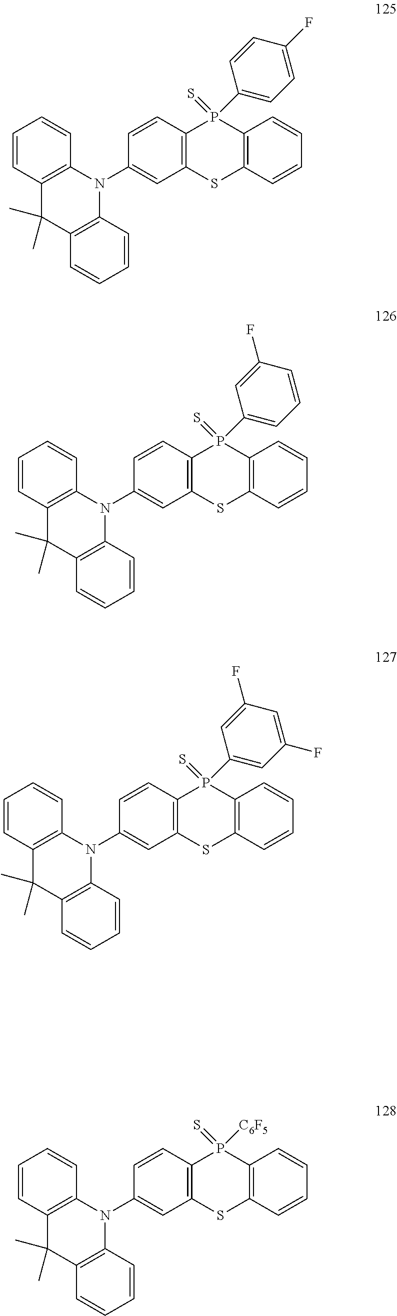

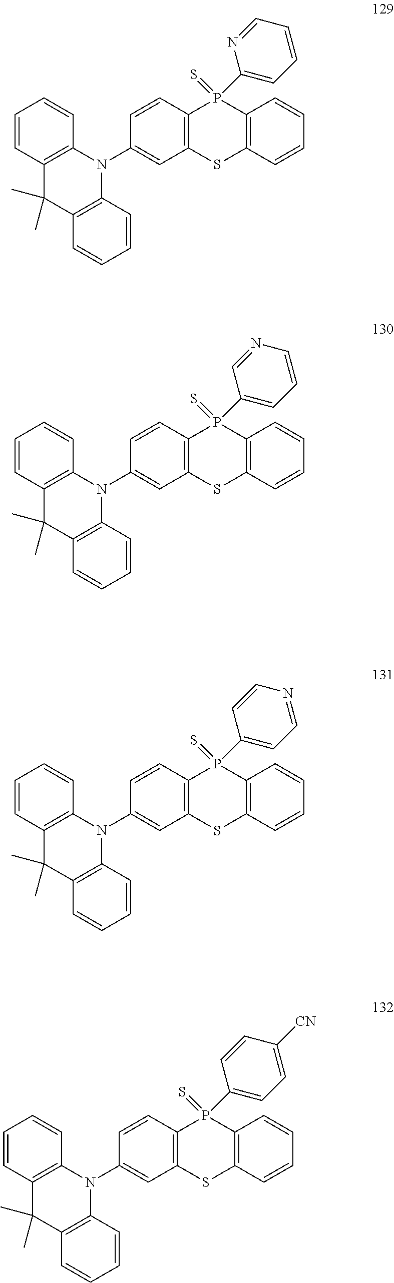 [SMILES: CC1(C)c2ccccc2N(c2ccc3c(c2)Sc2ccccc2P3(=S)c2ccccn2)c2ccccc21 ; CC1(C)c2ccccc2N(c2ccc3c(c2)Sc2ccccc2P3(=S)c2cccnc2)c2ccccc21 ; CC1(C)c2ccccc2N(c2ccc3c(c2)Sc2ccccc2P3(=S)c2ccncc2)c2ccccc21 ; CC1(C)c2ccccc2N(c2ccc3c(c2)Sc2ccccc2P3(=S)c2ccc(C#N)cc2)c2ccccc21]

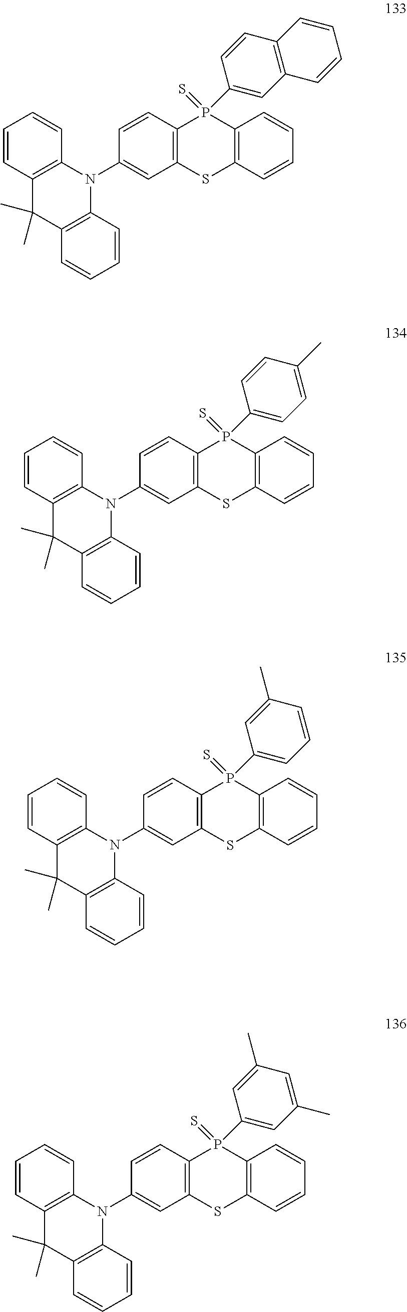

The phosphorus-containing compound of an embodiment may include an electron acceptor and an electron donor. For example, a part represented by Formula 1 may be an electron acceptor and a part represented by Formula 2 may be an electron donor.

For example, in an embodiment, a

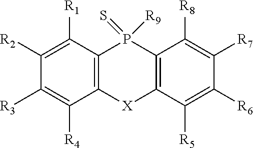

moiety may correspond to an electron acceptor, and a

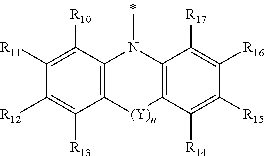

moiety, which is one of R₁ to R₈, may correspond to an electron donor.

In an implementation, the phosphorus-containing compound of an embodiment may be a thermally activated delayed fluorescence (TADF) emission material.

The phosphorus-containing compound of an embodiment may be used as a material for an organic electroluminescence device, and may help lower the driving voltage and decrease the full width at half maximum of light emission of the organic electroluminescence device. The phosphorus-containing compound of an embodiment may be included in an emission layer of an organic electroluminescence device as an emission material of thermally activated delayed fluorescence.

In an implementation, the phosphorus-containing compound of an embodiment may include a sulfur (S) atom, which has a large radius in a

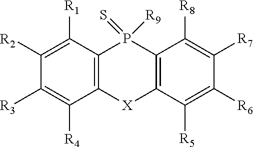

moiety and which corresponds to an electron acceptor, thereby helping to inhibit stacking between adjacent molecules and restraining the interaction between the adjacent molecules. Accordingly, the phosphorus-containing compound of an embodiment including a sulfur atom may be used as a material for an organic electroluminescence device and may help decrease the full width at half maximum of light emission of the organic electroluminescence device, thereby improving color purity and attaining a low voltage driving.

Hereinafter, an organic electroluminescence device according to an embodiment will be explained. Hereinafter, the above-described phosphorus-containing compound according to an embodiment may not be re-explained, and unexplained parts will follow the above explanation on the phosphorus-containing compound according to an embodiment.

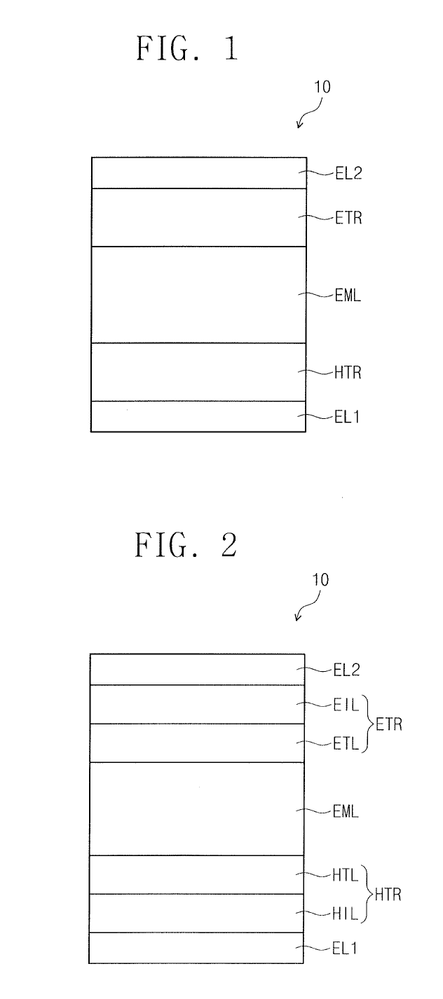

FIG. 1 illustrates a cross-sectional view of an organic electroluminescence device according to an embodiment. FIG. 2 illustrates a cross-sectional view of an organic electroluminescence device according to an embodiment.

Referring to FIGS. 1 and 2, an organic electroluminescence device 10 according to an embodiment may include a first electrode EL1, a hole transport region HTR, an emission layer EML, an electron transport region ETR, and a second electrode EL2 laminated one by one.

The first electrode EL1 and the second electrode EL2 may be oppositely disposed to each other, and a plurality of organic layers may be disposed between the first electrode EL1 and the second electrode EL2. The plurality of the organic layers may include the hole transport region HTR, the emission layer EML, and the electron transport region ETR.

The organic electroluminescence device 10 according to an embodiment may include the phosphorus-containing compound in the emission layer EML.

In the explanation on the organic electroluminescence device 10 below, a case where the phosphorus-containing compound of an embodiment is included in the emission layer EML will be explained. In an implementation, the phosphorus-containing compound of an embodiment may be included in at least one the plurality of organic layers disposed between the first electrode EL1 and the second electrode EL2. For example, the phosphorus-containing compound according to an embodiment may be included in the hole transport region HTR.

The first electrode EL has conductivity. The first electrode EL1 may be formed using a metal alloy or a conductive compound. The first electrode EL1 may be an anode.

The first electrode EL1 may be a transmissive electrode, a transflective electrode, or a reflective electrode. In the case where the first electrode EL1 is the transmissive electrode, the first electrode EL1 may be formed using a transparent metal oxide, e.g., indium tin oxide (ITO), indium zinc oxide (IZO), zinc oxide (ZnO), or indium tin zinc oxide (ITZO). In the case where the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca, LiF/Al, Mo, Ti, a compound thereof, or a mixture thereof (for example, a mixture of Ag and Mg). In an implementation, the first electrode EL1 may include a plurality of layers including a reflective layer, or a transflective layer formed using the above materials, and a transmissive layer formed using ITO, IZO, ZnO, or ITZO.

The hole transport region HTR may be provided on the first electrode EL1. The hole transport region HTR may include at least one of a hole injection layer HIL, a hole transport layer HTL, a hole buffer layer, or an electron blocking layer. The thickness of the hole transport region HTR may be, e.g., from about 300 Å to about 1,500 Å.

The hole transport region HTR may have a single layer formed using a single material, a single layer formed using a plurality of different materials, or a multilayer structure including a plurality of layers formed using a plurality of different materials.

For example, the hole transport region HTR may have the structure of a single layer such as a hole injection layer HIL, or a hole transport layer HTL, and may have a structure of a single layer formed using a hole injection material and a hole transport material. In an implementation, the hole transport region HTR may have a structure of a single layer formed using a plurality of different materials, or a structure laminated from the first electrode EL1 of hole injection layer HIL/hole transport layer HTL, hole injection layer HIL/hole transport layer HTL/hole buffer layer, hole injection layer HIL/hole buffer layer, hole transport layer HTL/hole buffer layer, or hole injection layer HIL/hole transport layer HTL/electron blocking layer.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

In the case that the hole transport region HTR includes the hole injection layer HIL and the hole transport layer HTL, the hole injection layer HIL may include a suitable hole injection material.

Examples of the hole injection material may include triphenylamine-containing polyetherketone (TPAPEK), 4-isopropyl-4′-methyldiphenyliodoniumtetrakis(pentafluorophenyl)borate (PPBL), N,N′-diphenyl-N,N′-bis-[4-(phenyl-m-tolyl-amino)-phenyl]-phenyl-4,4′-diamine (DNTPD), a phthalocyanine compound such as copper phthalocyanine, 4,4′,4″-tris(3-methylphenylphenylamino)triphenylamine (m-MTDATA), N,N′-di(1-naphthyl)-N,N′-diphenylbenzidine (NPB), 4,4′,4″-tris(N,N-diphenylamino)triphenylamine (TDATA), 4,4′,4″-tris(N,N-2-naphthyphenylamino)triphenylamine (2-TNATA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), or polyaniline/poly(4-styrenesulfonate) (PANI/PSS).

In the case where the hole transport region HTR includes the hole injection layer HIL and the hole transport layer HTL, the hole transport layer HTL may include a suitable hole transport material.

Examples of the hole transport material may include 1,1-bis[(di-4-trileamino)phenyl]cyclohexane (TAPC), carbazole derivatives such as N-phenyl carbazole and polyvinyl carbazole, N,N′-bis(3-methylphenyl)-N,N′-diphenyl-[1,1-biphenyl]-4,4′-diamine (TPD), 4,4′,4″-tris(N-carbazolyl)triphenylamine (TCTA), N,N′-di(1-naphtyl)-N,N′-diphenylbenzidine (NPB), etc.

The thickness of the hole transport region HTR may be from about 100 Å to about 10,000 Å, e.g., from about 100 Å to about 1,000 Å. In the case where the hole transport region HTR includes both the hole injection layer HIL and the hole transport layer HTL, the thickness of the hole injection layer HIL may be from about 100 Å to about 10,000 Å, e.g., from about 100 Å to about 1,000 Å, and the thickness of the hole transport layer HTL may be from about 30 Å to about 1,000 Å. In the case where the thicknesses of the hole transport region HTR, the hole injection layer HIL, and the hole transport layer HTL satisfy the above-described ranges, satisfactory hole transport properties may be obtained without substantial increase of a driving voltage.

The hole transport region HTR may further include a charge generating material in addition to the above-described materials to increase conductivity. The charge generating material may be dispersed uniformly or non-uniformly in the hole transport region HTR. The charge generating material may be, e.g., a p-dopant. The p-dopant may be, e.g., one of a quinone derivative, a metal oxide, or a cyano group-containing compound. Examples of the p-dopant may include quinone derivatives such as tetracyanoquinodimethane (TCNQ) and 2,3,5,6-tetrafluoro-tetracyanoquinodimethane (F4-TCNQ), a metal oxide such as tungsten oxide, and molybdenum oxide.

As described above, the hole transport region HTR may further include at least one of a hole buffer layer or an electron blocking layer in addition to the hole injection layer HIL and the hole transport layer HTL. The hole buffer layer may compensate an optical resonance distance according to the wavelength of light emitted from the emission layer EML and increase light emission efficiency. Materials included in the hole transport region HTR may be used as materials included in the hole buffer layer. The electron blocking layer is a layer preventing electron injection from the electron transport region ETR to the hole transport region HTR.

The emission layer EML may be provided on the hole transport region HTR. The thickness of the emission layer EML may be from about 100 Å to about 1,000 Å. The emission layer EML may have a single layer formed using a single material, a single layer formed using a plurality of different materials, or a multilayer structure having a plurality of layers formed using a plurality of different materials.

The emission layer EML may include the phosphorus-containing compound according to an embodiment. For example, the emission layer EML may include the phosphorus-containing compound represented by the following Formula 1.

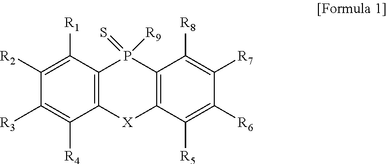

In Formula 1, X may be, e.g., O, S, NRₐ, CR_{b}R_{c}, SiR_{d}Rₑ, or GeR_{f}R_{g}. In an implementation, Rₐ to R_{g} may each independently be or include, e.g., a hydrogen atom, a deuterium atom, a halogen atom, a substituted or unsubstituted silyl group, a substituted or unsubstituted alkyl group having 1 to 20 carbon atoms, a substituted or unsubstituted fluorenyl group, a substituted or unsubstituted aryl group having 6 to 30 ring carbon atoms, or a substituted or unsubstituted heteroaryl group having 4 to 30 ring carbon atoms. In an implementation, Rₐ to R_{g} may be separate or may be combined with an adjacent group to form a ring.

R₁ to R₈ may each independently be or include, e.g., a hydrogen atom, a deuterium atom, a halogen atom, a substituted or unsubstituted silyl group, a substituted or unsubstituted amino group, a substituted or unsubstituted alkyl group having 1 to 20 carbon atoms, a substituted or unsubstituted aryl group having 6 to 30 ring carbon atoms, or a substituted or unsubstituted heteroaryl group having 4 to 30 ring carbon atoms.

R₉ may be or may include, e.g., a substituted or unsubstituted alkyl group having 1 to 20 carbon atoms, a substituted or unsubstituted aryl group having 6 to 30 ring carbon atoms, or a substituted or unsubstituted heteroaryl group having 4 to 30 ring carbon atoms.

In an implementation, in Formula 1, at least one of R₁ to R₈ may be a group represented by the following Formula 2.

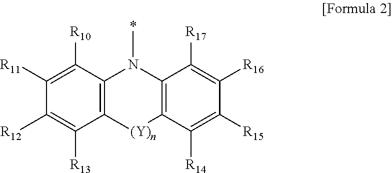

In Formula 2, n may be 0 or 1. In a case where n is 1, Y may be, e.g., a direct linkage, O, S, CRₕRᵢ, SiRⱼRₖ, or GeRₗRₘ. The direct linkage may be, e.g., a single bond. For example, in a case where Y is a direct linkage, Formula 2 may be a substituted or unsubstituted carbazole group.

Rₕ to Rₘ may each independently be or include, e.g., a hydrogen atom, a deuterium atom, a halogen atom, a substituted or unsubstituted silyl group, a substituted or unsubstituted alkyl group having 1 to 20 carbon atoms, a substituted or unsubstituted fluorenyl group, a substituted or unsubstituted aryl group having 6 to 30 ring carbon atoms, or a substituted or unsubstituted heteroaryl group having 4 to 30 ring carbon atoms. In an implementation, Rₕ to Rₘ may be separate or may be combined with an adjacent group to form a ring.

In Formula 2, R₁₀ to R₁₇ may each independently be or include, e.g., a hydrogen atom, a deuterium atom, a halogen atom, a substituted or unsubstituted silyl group, a substituted or unsubstituted amino group, a substituted or unsubstituted alkyl group having 1 to 20 carbon atoms, a substituted or unsubstituted aryl group having 6 to 30 ring carbon atoms, or a substituted or unsubstituted heteroaryl group having 4 to 30 ring carbon atoms.

In Formula land Formula 2, the same explanation on the phosphorus-containing compound according to an embodiment may be applied for X, Y, and R₁ to R₁₇.

The emission layer EML may include one or more different kinds of the phosphorus-containing compound represented by Formula 1. The phosphorus-containing compound represented by Formula 1 may be included in the emission layer EML of the organic electroluminescence device and may emit thermally activated delayed fluorescence.

In an implementation, the emission layer EML may include one or more different kinds of a compound represented by the following Formula 3 or Formula 4.

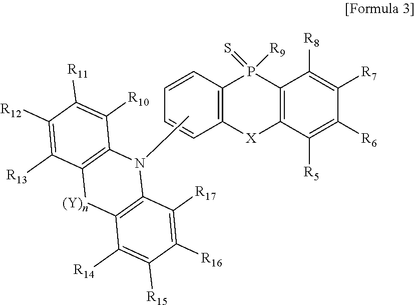

In Formula 3, the same explanation on the above phosphorus-containing compound according to an embodiment may be applied for X, Y and R₅ to R₁₇. In an implementation, in the phosphorus-containing compound represented by Formula 1 or Formula 3, R₉ may be a substituted or unsubstituted phenyl group. In an implementation, in Formula 3, R₅ to R₈ may be hydrogen atoms.

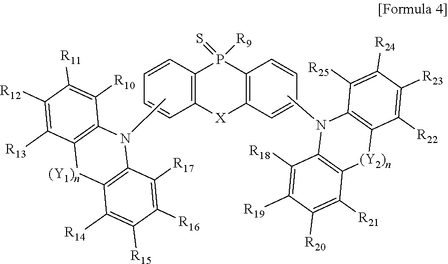

In Formula 4, the same explanation in Formula 1 and Formula 2 may be applied for R₉ to R₁₇, X and n.

In an implementation, R₁₈ to R₂₄ in Formula 4 may each independently be or include, e.g., a hydrogen atom, a deuterium atom, a halogen atom, a substituted or unsubstituted silyl group, a substituted or unsubstituted amino group, a substituted or unsubstituted alkyl group having 1 to 20 carbon atoms, a substituted or unsubstituted aryl group having 6 to 30 ring carbon atoms, or a substituted or unsubstituted heteroaryl group having 4 to 30 ring carbon atoms.

Y₁ and Y₂ may each independently be, e.g., a direct linkage, O, S, CRₕRᵢ, SiRⱼRₖ, or GeRₗRₘ. In an implementation, Rₕ to Rₘ may each independently be or include, e.g., a hydrogen atom, a deuterium atom, a halogen atom, a substituted or unsubstituted silyl group, a substituted or unsubstituted alkyl group having 1 to 20 carbon atoms, a substituted or unsubstituted fluorenyl group, a substituted or unsubstituted aryl group having 6 to 30 ring carbon atoms, or a substituted or unsubstituted heteroaryl group having 4 to 30 ring carbon atoms. In an implementation, Rₕ to Rₘ may be separate or may be combined with an adjacent group to form a ring.

In an implementation, the group represented by Formula 2 may be a group represented by one of the following Formula 2-1 to Formula 2-9.

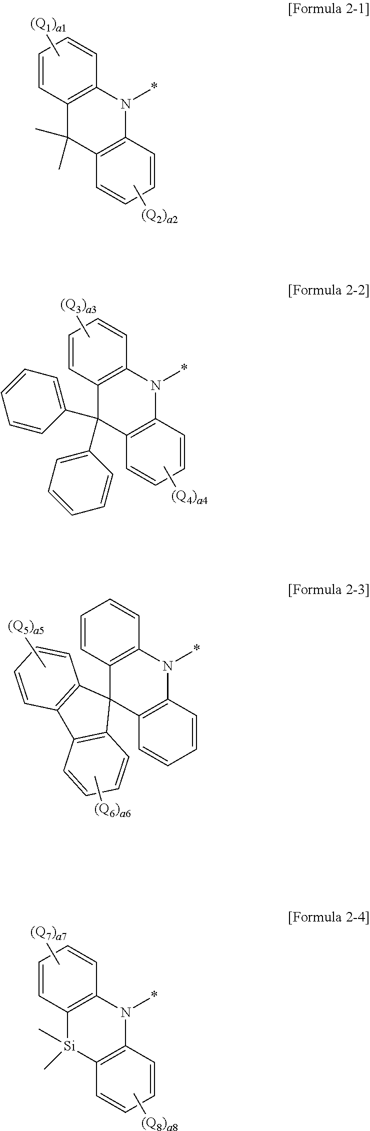

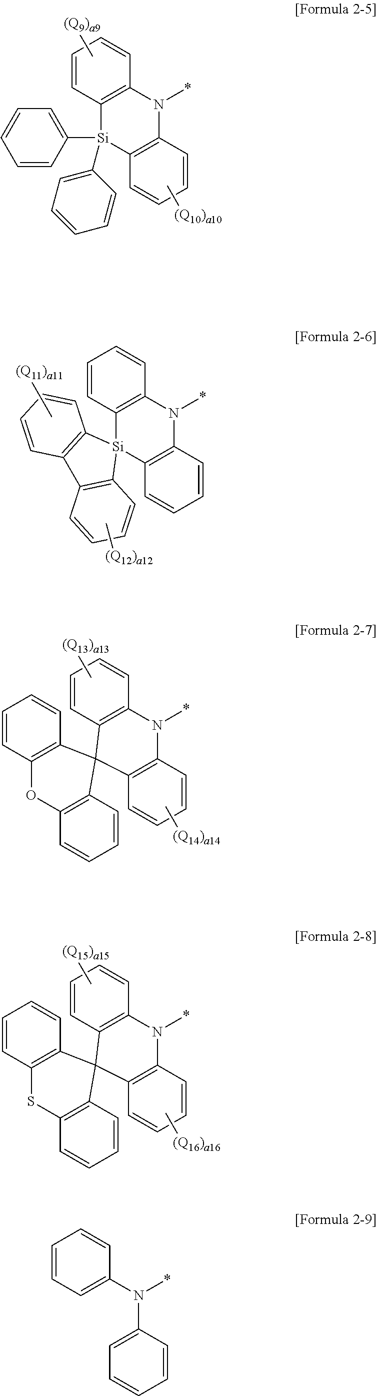

In Formula 2-1 to Formula 2-8, Q₁ to Q₁₆ may each independently be or include, e.g., a hydrogen atom, a deuterium atom, a halogen atom, a substituted or unsubstituted silyl group, or a substituted or unsubstituted alkyl group having 1 to 20 carbon atoms, and a₁ to a₁₆ may each independently be an integer of 0 to 4. In an implementation, Formula 2-1 to Formula 2-8 correspond to Formula 2 where n=1, and Formula 2-9 corresponds to Formula 2 where n=0.

In an implementation, the emission layer EML may include at least one compound of the following Compound Group 1.

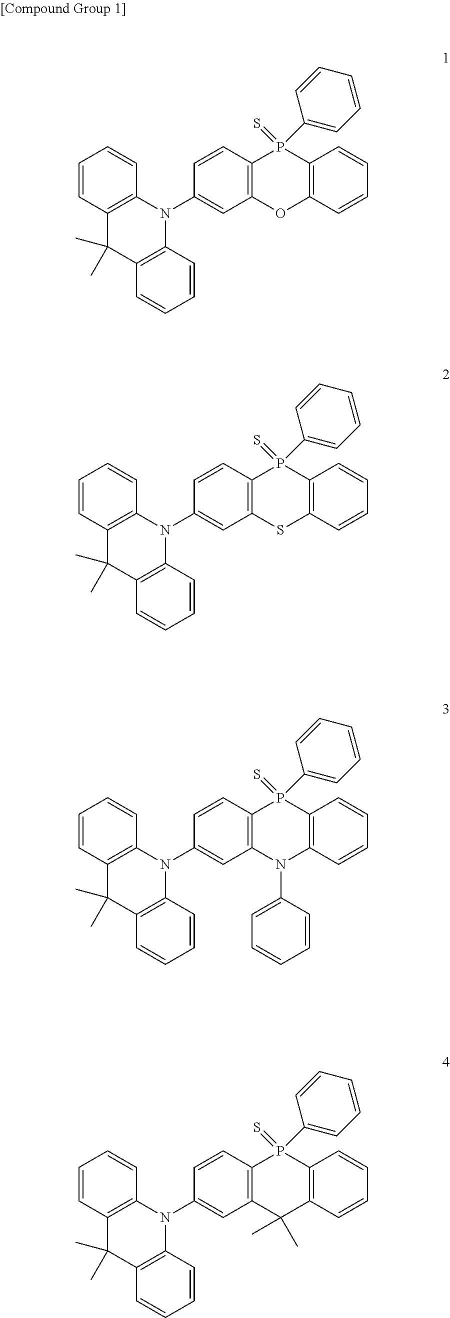 [SMILES: CC1(C)c2ccccc2N(c2ccc3c(c2)Oc2ccccc2P3(=S)c2ccccc2)c2ccccc21 ; CC1(C)c2ccccc2N(c2ccc3c(c2)Sc2ccccc2P3(=S)c2ccccc2)c2ccccc21 ; CC1(C)c2ccccc2N(c2ccc3c(c2)N(c2ccccc2)c2ccccc2P3(=S)c2ccccc2)c2ccccc21 ; CC1(C)c2ccccc2N(c2ccc3c(c2)C(C)(C)c2ccccc2P3(=S)c2ccccc2)c2ccccc21]

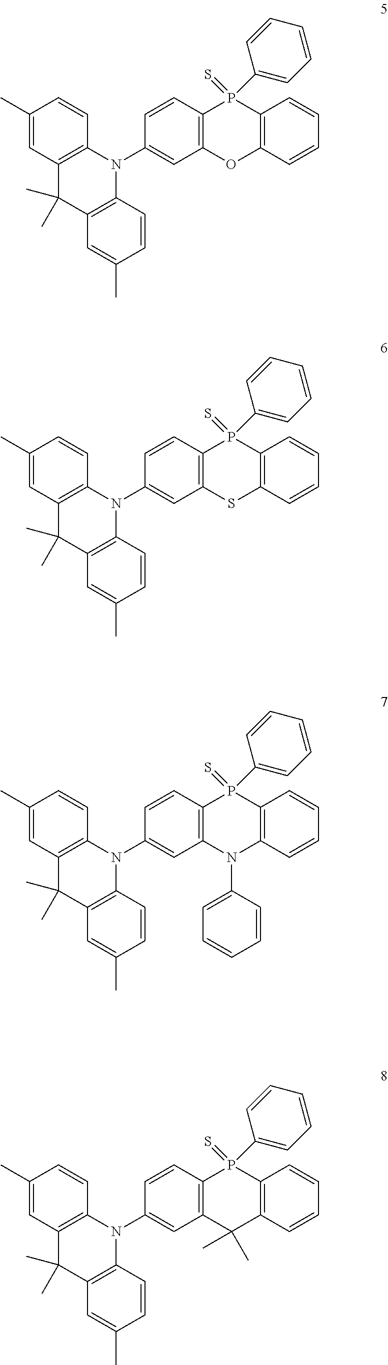 [SMILES: Cc1ccc2c(c1)C(C)(C)c1cc(C)ccc1N2c1ccc2c(c1)Oc1ccccc1P2(=S)c1ccccc1 ; Cc1ccc2c(c1)C(C)(C)c1cc(C)ccc1N2c1ccc2c(c1)Sc1ccccc1P2(=S)c1ccccc1 ; Cc1ccc2c(c1)C(C)(C)c1cc(C)ccc1N2c1ccc2c(c1)N(c1ccccc1)c1ccccc1P2(=S)c1ccccc1 ; Cc1ccc2c(c1)C(C)(C)c1cc(C)ccc1N2c1ccc2c(c1)C(C)(C)c1ccccc1P2(=S)c1ccccc1]

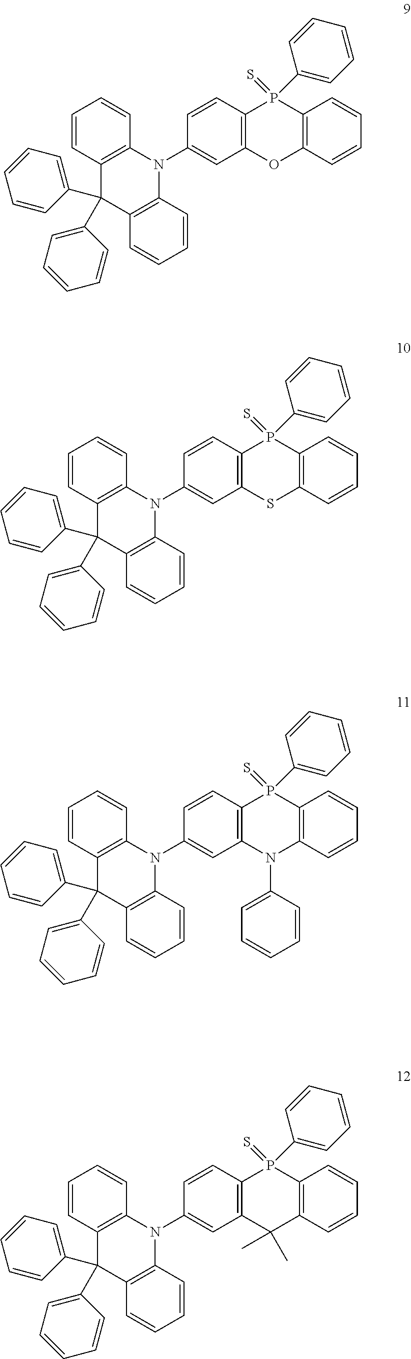 [SMILES: S=P1(c2ccccc2)c2ccccc2Oc2cc(N3c4ccccc4C(c4ccccc4)(c4ccccc4)c4ccccc43)ccc21 ; S=P1(c2ccccc2)c2ccccc2Sc2cc(N3c4ccccc4C(c4ccccc4)(c4ccccc4)c4ccccc43)ccc21 ; S=P1(c2ccccc2)c2ccccc2N(c2ccccc2)c2cc(N3c4ccccc4C(c4ccccc4)(c4ccccc4)c4ccccc43)ccc21 ; CC1(C)c2ccccc2P(=S)(c2ccccc2)c2ccc(N3c4ccccc4C(c4ccccc4)(c4ccccc4)c4ccccc43)cc21]

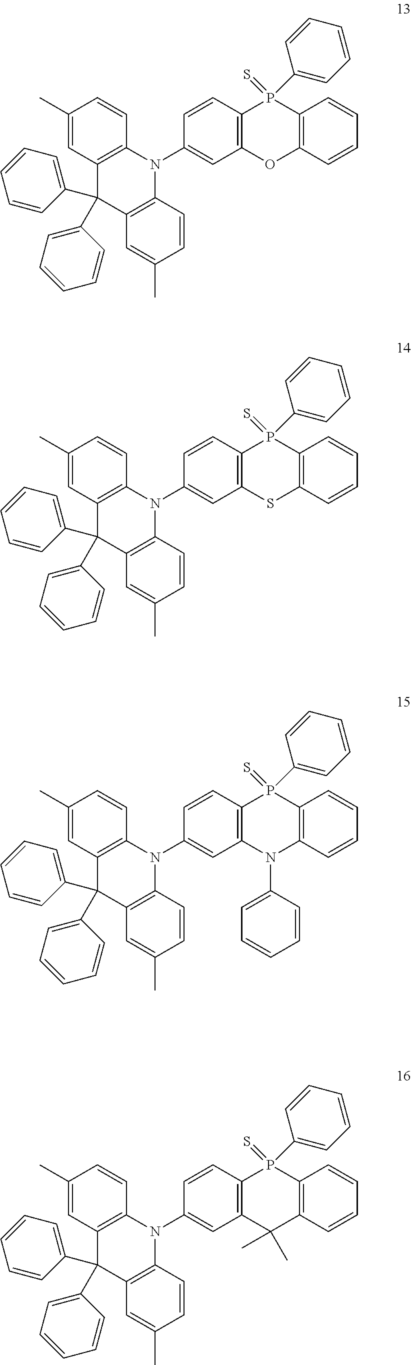 [SMILES: Cc1ccc2c(c1)C(c1ccccc1)(c1ccccc1)c1cc(C)ccc1N2c1ccc2c(c1)Oc1ccccc1P2(=S)c1ccccc1 ; Cc1ccc2c(c1)C(c1ccccc1)(c1ccccc1)c1cc(C)ccc1N2c1ccc2c(c1)Sc1ccccc1P2(=S)c1ccccc1 ; Cc1ccc2c(c1)C(c1ccccc1)(c1ccccc1)c1cc(C)ccc1N2c1ccc2c(c1)N(c1ccccc1)c1ccccc1P2(=S)c1ccccc1 ; Cc1ccc2c(c1)C(c1ccccc1)(c1ccccc1)c1cc(C)ccc1N2c1ccc2c(c1)C(C)(C)c1ccccc1P2(=S)c1ccccc1]

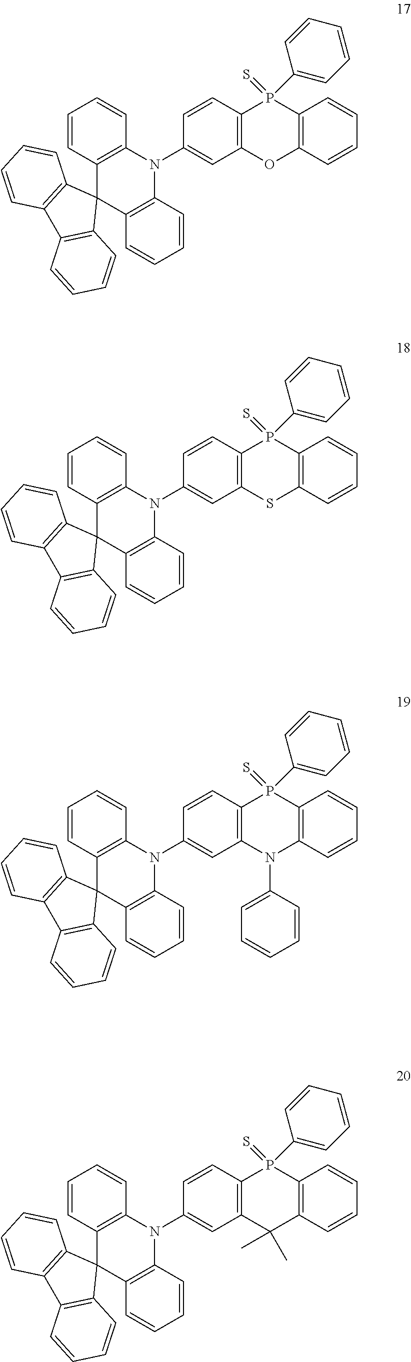 [SMILES: S=P1(c2ccccc2)c2ccccc2Oc2cc(N3c4ccccc4C4(c5ccccc5-c5ccccc54)c4ccccc43)ccc21 ; S=P1(c2ccccc2)c2ccccc2Sc2cc(N3c4ccccc4C4(c5ccccc5-c5ccccc54)c4ccccc43)ccc21 ; S=P1(c2ccccc2)c2ccccc2N(c2ccccc2)c2cc(N3c4ccccc4C4(c5ccccc5-c5ccccc54)c4ccccc43)ccc21 ; CC1(C)c2ccccc2P(=S)(c2ccccc2)c2ccc(N3c4ccccc4C4(c5ccccc5-c5ccccc54)c4ccccc43)cc21]

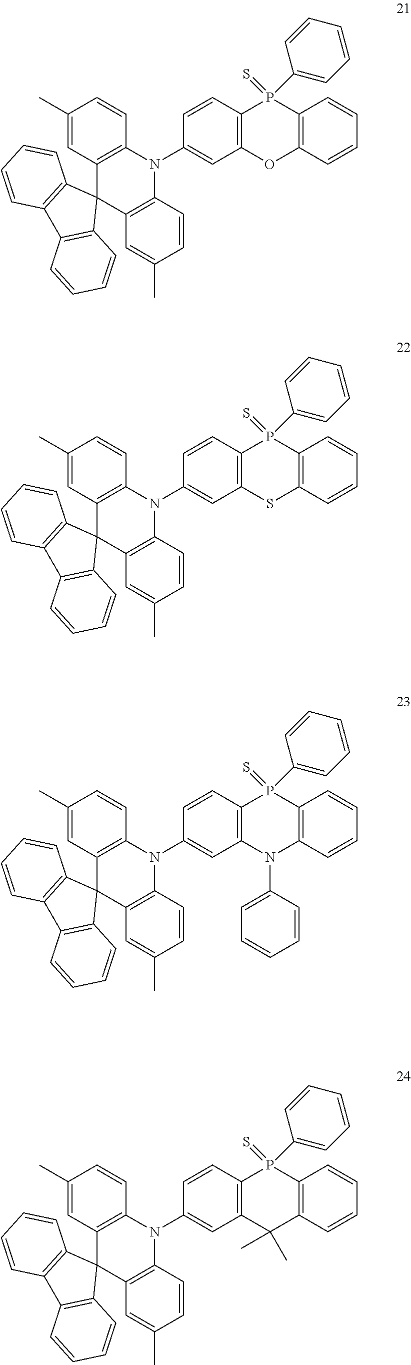 [SMILES: Cc1ccc2c(c1)C1(c3ccccc3-c3ccccc31)c1cc(C)ccc1N2c1ccc2c(c1)Oc1ccccc1P2(=S)c1ccccc1 ; Cc1ccc2c(c1)C1(c3ccccc3-c3ccccc31)c1cc(C)ccc1N2c1ccc2c(c1)Sc1ccccc1P2(=S)c1ccccc1 ; Cc1ccc2c(c1)C1(c3ccccc3-c3ccccc31)c1cc(C)ccc1N2c1ccc2c(c1)N(c1ccccc1)c1ccccc1P2(=S)c1ccccc1 ; Cc1ccc2c(c1)C1(c3ccccc3-c3ccccc31)c1cc(C)ccc1N2c1ccc2c(c1)C(C)(C)c1ccccc1P2(=S)c1ccccc1]

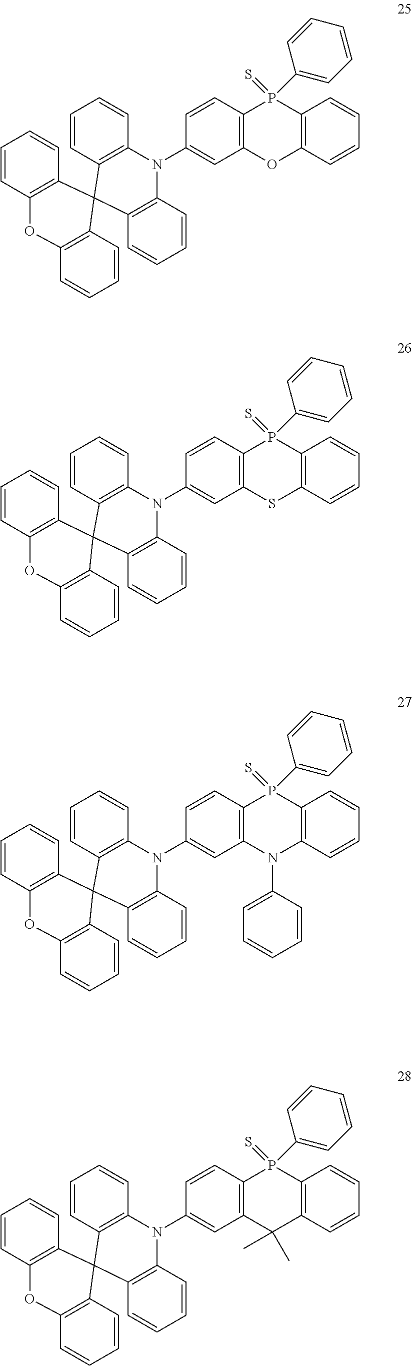 [SMILES: S=P1(c2ccccc2)c2ccccc2Oc2cc(N3c4ccccc4C4(c5ccccc5Oc5ccccc54)c4ccccc43)ccc21 ; S=P1(c2ccccc2)c2ccccc2Sc2cc(N3c4ccccc4C4(c5ccccc5Oc5ccccc54)c4ccccc43)ccc21 ; S=P1(c2ccccc2)c2ccccc2N(c2ccccc2)c2cc(N3c4ccccc4C4(c5ccccc5Oc5ccccc54)c4ccccc43)ccc21 ; CC1(C)c2ccccc2P(=S)(c2ccccc2)c2ccc(N3c4ccccc4C4(c5ccccc5Oc5ccccc54)c4ccccc43)cc21]

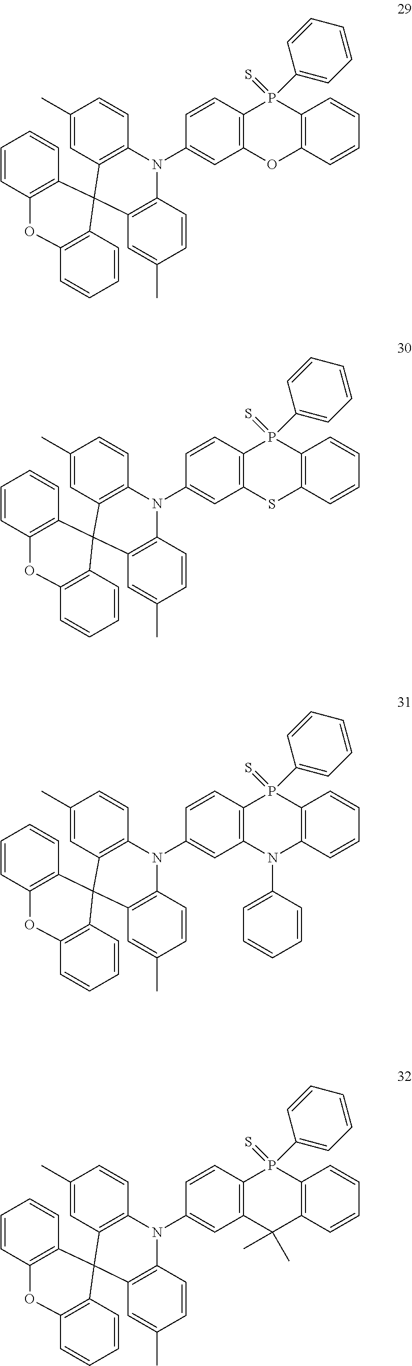 [SMILES: Cc1ccc2c(c1)C1(c3ccccc3Oc3ccccc31)c1cc(C)ccc1N2c1ccc2c(c1)Oc1ccccc1P2(=S)c1ccccc1 ; Cc1ccc2c(c1)C1(c3ccccc3Oc3ccccc31)c1cc(C)ccc1N2c1ccc2c(c1)Sc1ccccc1P2(=S)c1ccccc1 ; Cc1ccc2c(c1)C1(c3ccccc3Oc3ccccc31)c1cc(C)ccc1N2c1ccc2c(c1)N(c1ccccc1)c1ccccc1P2(=S)c1ccccc1 ; Cc1ccc2c(c1)C1(c3ccccc3Oc3ccccc31)c1cc(C)ccc1N2c1ccc2c(c1)C(C)(C)c1ccccc1P2(=S)c1ccccc1]

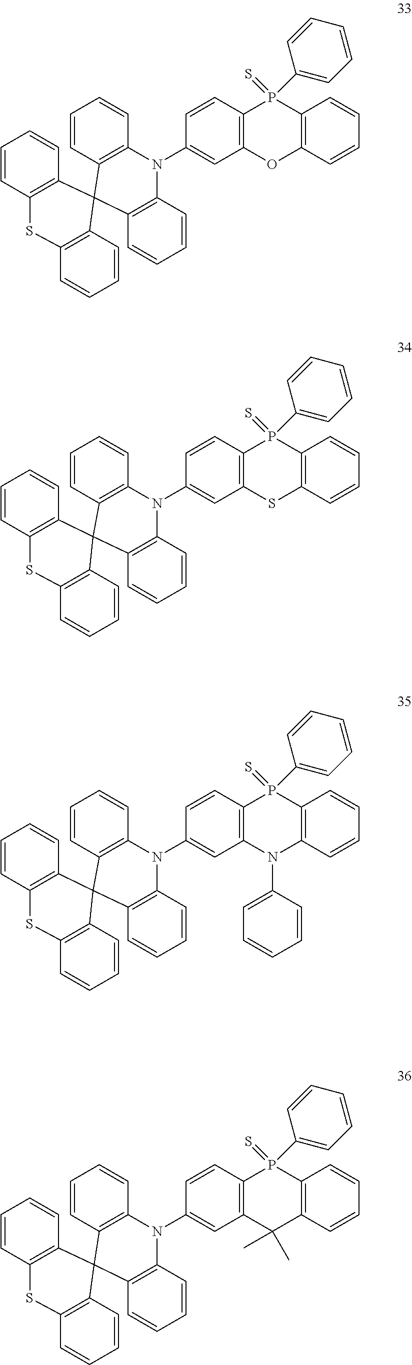 [SMILES: S=P1(c2ccccc2)c2ccccc2Oc2cc(N3c4ccccc4C4(c5ccccc5Sc5ccccc54)c4ccccc43)ccc21 ; S=P1(c2ccccc2)c2ccccc2Sc2cc(N3c4ccccc4C4(c5ccccc5Sc5ccccc54)c4ccccc43)ccc21 ; S=P1(c2ccccc2)c2ccccc2N(c2ccccc2)c2cc(N3c4ccccc4C4(c5ccccc5Sc5ccccc54)c4ccccc43)ccc21 ; CC1(C)c2ccccc2P(=S)(c2ccccc2)c2ccc(N3c4ccccc4C4(c5ccccc5Sc5ccccc54)c4ccccc43)cc21]

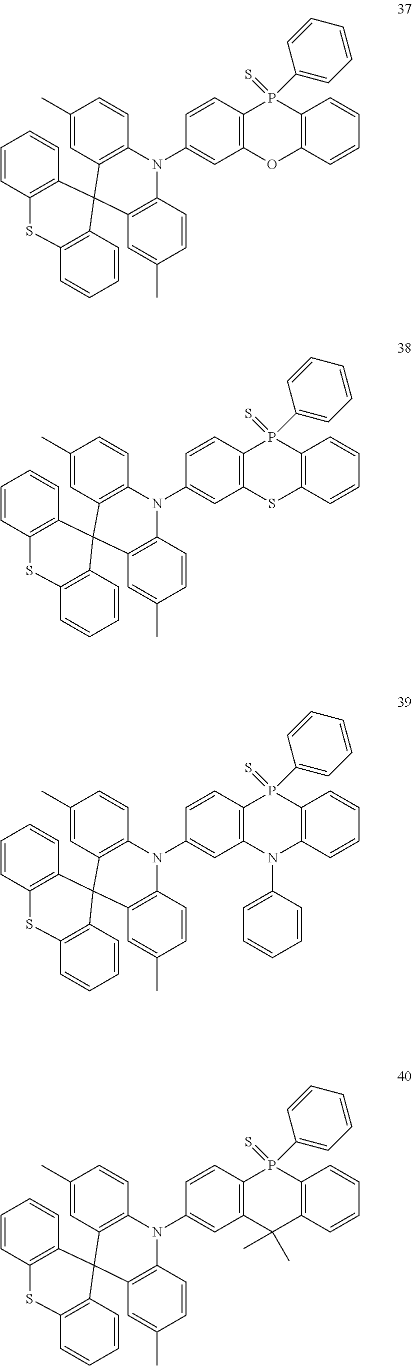 [SMILES: Cc1ccc2c(c1)C1(c3ccccc3Sc3ccccc31)c1cc(C)ccc1N2c1ccc2c(c1)Oc1ccccc1P2(=S)c1ccccc1 ; Cc1ccc2c(c1)C1(c3ccccc3Sc3ccccc31)c1cc(C)ccc1N2c1ccc2c(c1)Sc1ccccc1P2(=S)c1ccccc1 ; Cc1ccc2c(c1)C1(c3ccccc3Sc3ccccc31)c1cc(C)ccc1N2c1ccc2c(c1)N(c1ccccc1)c1ccccc1P2(=S)c1ccccc1 ; Cc1ccc2c(c1)C1(c3ccccc3Sc3ccccc31)c1cc(C)ccc1N2c1ccc2c(c1)C(C)(C)c1ccccc1P2(=S)c1ccccc1]

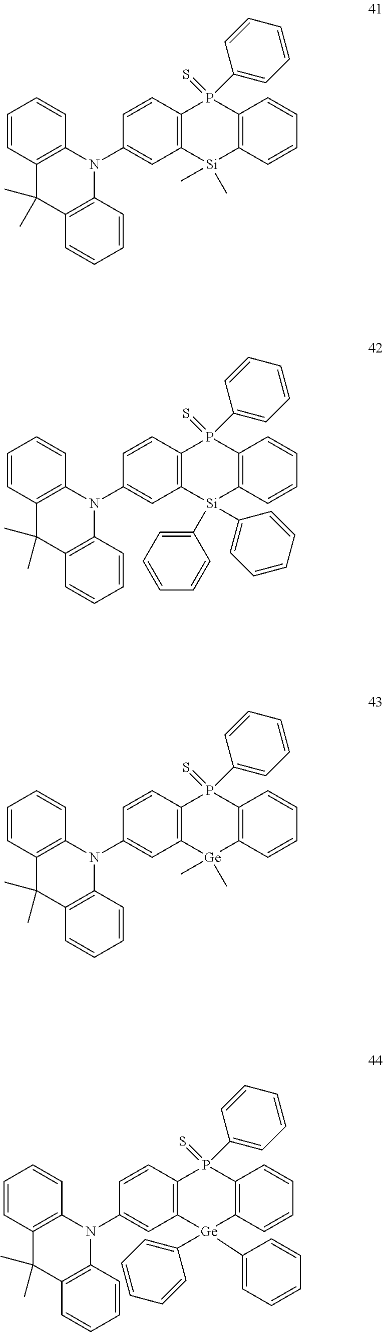

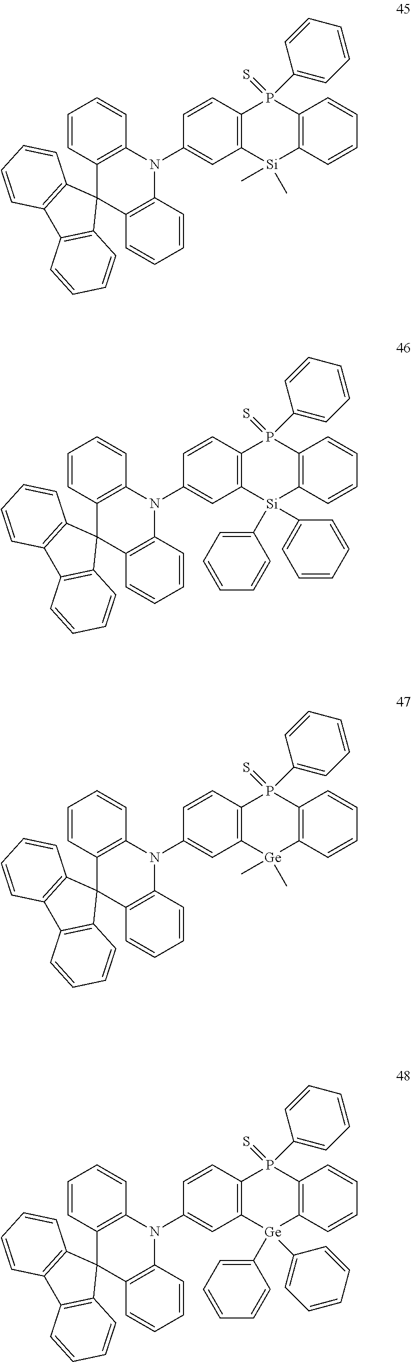

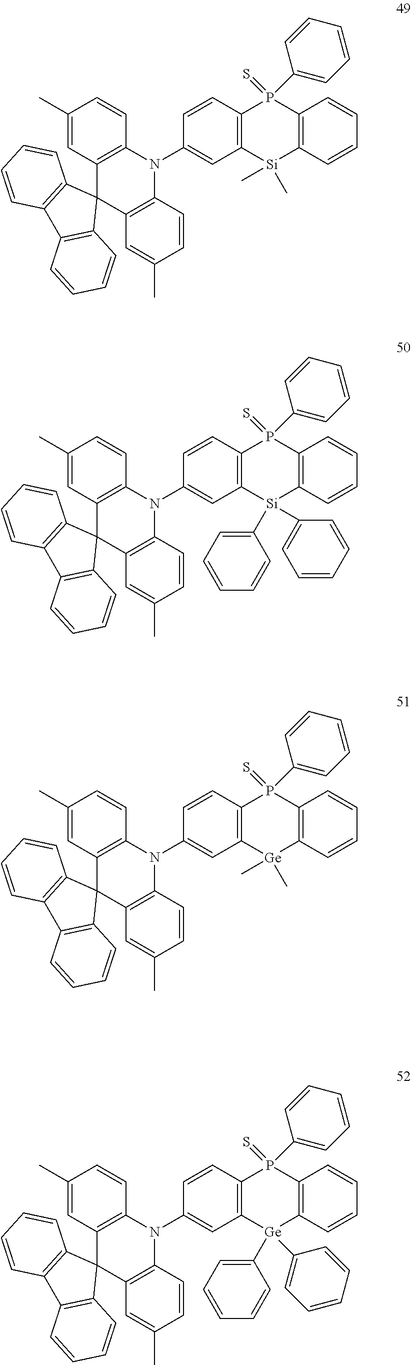

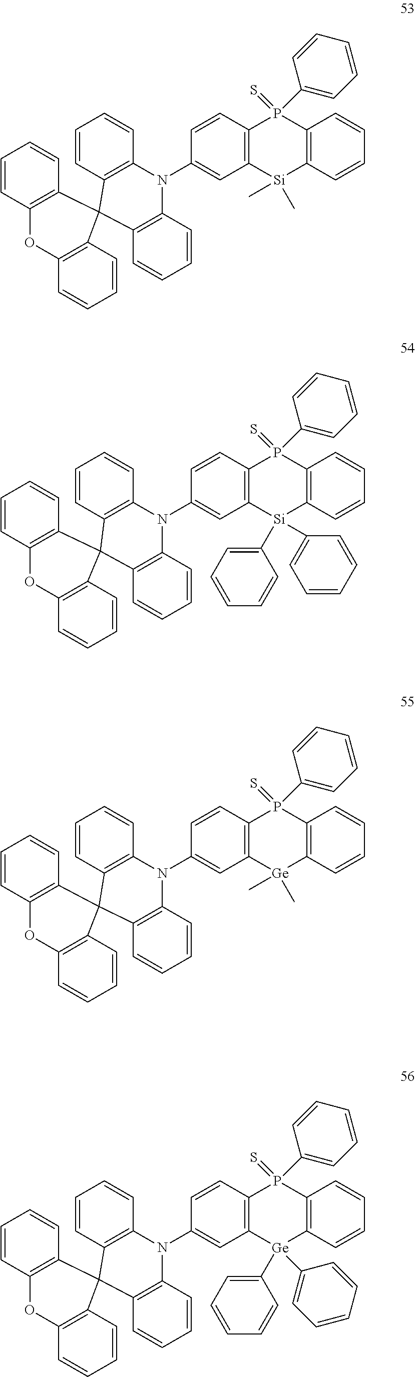

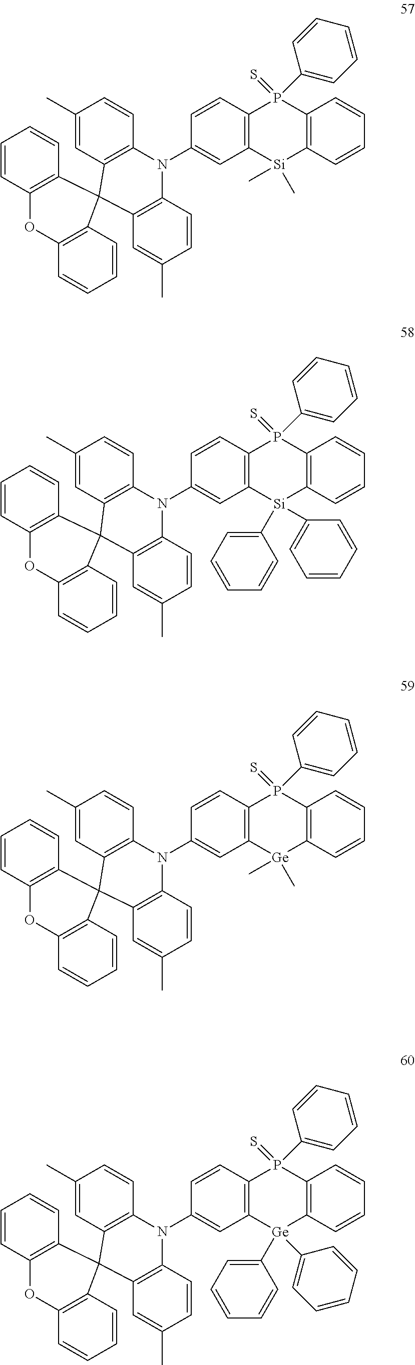

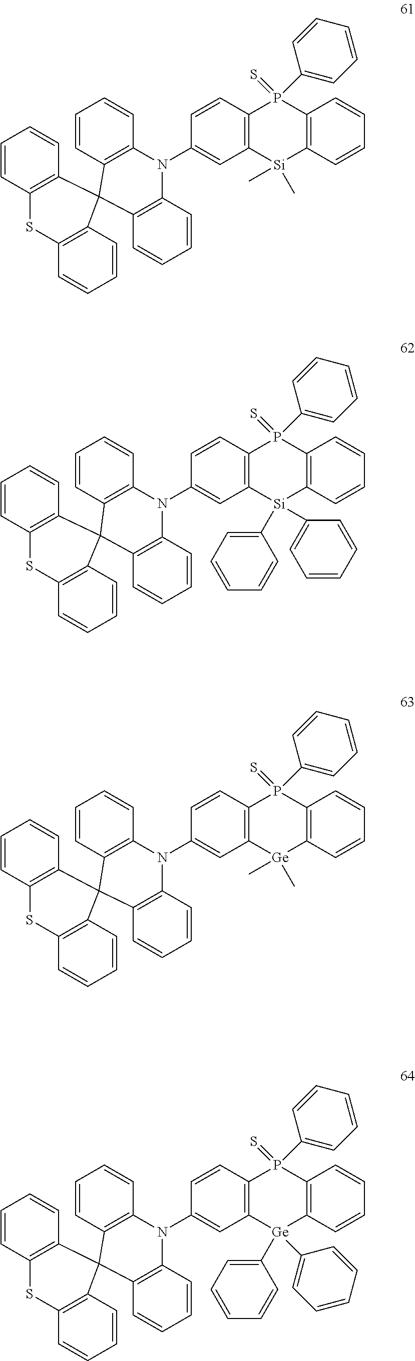

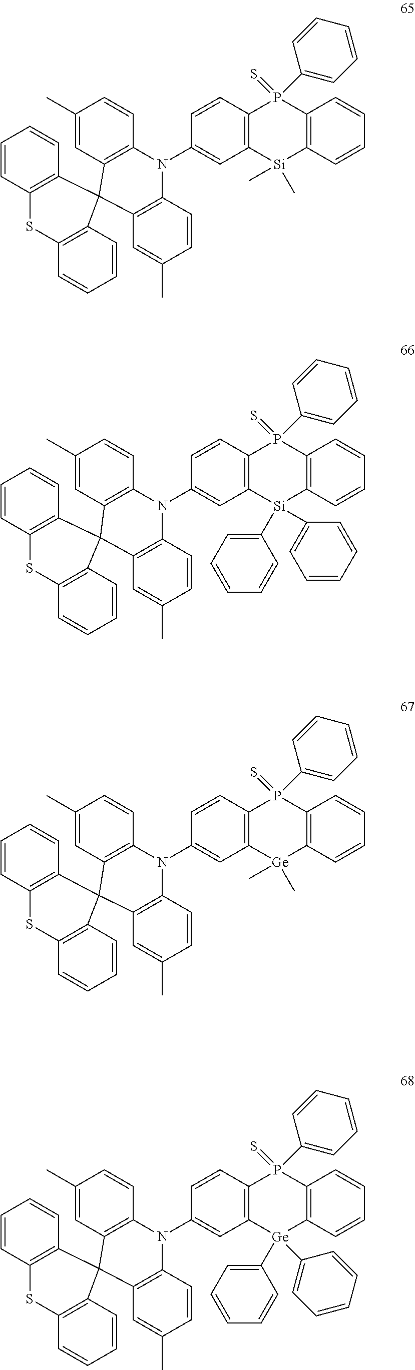

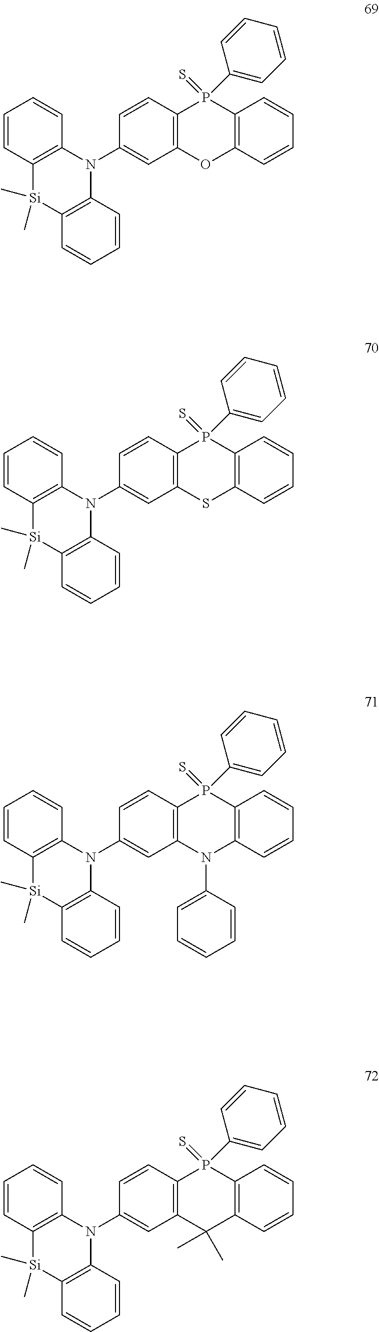 [SMILES: C[Si]1(C)c2ccccc2N(c2ccc3c(c2)Oc2ccccc2P3(=S)c2ccccc2)c2ccccc21 ; C[Si]1(C)c2ccccc2N(c2ccc3c(c2)Sc2ccccc2P3(=S)c2ccccc2)c2ccccc21 ; C[Si]1(C)c2ccccc2N(c2ccc3c(c2)N(c2ccccc2)c2ccccc2P3(=S)c2ccccc2)c2ccccc21 ; CC1(C)c2ccccc2P(=S)(c2ccccc2)c2ccc(N3c4ccccc4[Si](C)(C)c4ccccc43)cc21]

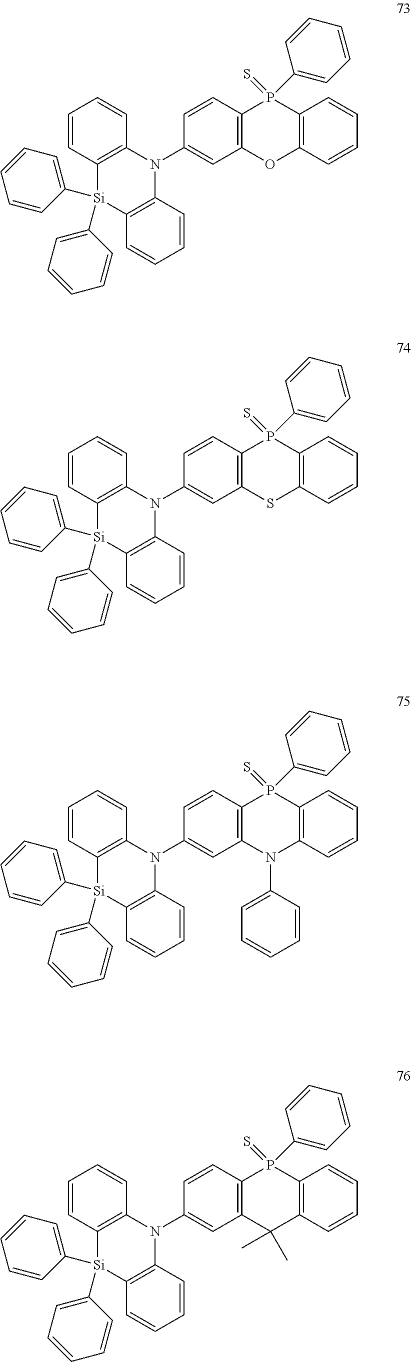 [SMILES: S=P1(c2ccccc2)c2ccccc2Oc2cc(N3c4ccccc4[Si](c4ccccc4)(c4ccccc4)c4ccccc43)ccc21 ; S=P1(c2ccccc2)c2ccccc2Sc2cc(N3c4ccccc4[Si](c4ccccc4)(c4ccccc4)c4ccccc43)ccc21 ; S=P1(c2ccccc2)c2ccccc2N(c2ccccc2)c2cc(N3c4ccccc4[Si](c4ccccc4)(c4ccccc4)c4ccccc43)ccc21 ; CC1(C)c2ccccc2P(=S)(c2ccccc2)c2ccc(N3c4ccccc4[Si](c4ccccc4)(c4ccccc4)c4ccccc43)cc21]

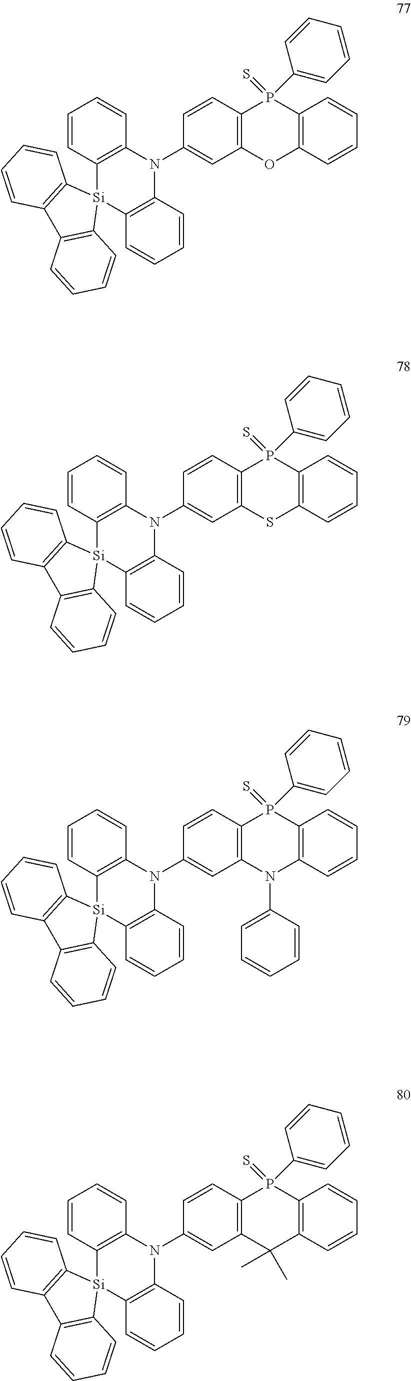 [SMILES: S=P1(c2ccccc2)c2ccccc2Oc2cc(N3c4ccccc4[Si]4(c5ccccc5-c5ccccc54)c4ccccc43)ccc21 ; S=P1(c2ccccc2)c2ccccc2Sc2cc(N3c4ccccc4[Si]4(c5ccccc5-c5ccccc54)c4ccccc43)ccc21 ; S=P1(c2ccccc2)c2ccccc2N(c2ccccc2)c2cc(N3c4ccccc4[Si]4(c5ccccc5-c5ccccc54)c4ccccc43)ccc21 ; CC1(C)c2ccccc2P(=S)(c2ccccc2)c2ccc(N3c4ccccc4[Si]4(c5ccccc5-c5ccccc54)c4ccccc43)cc21]

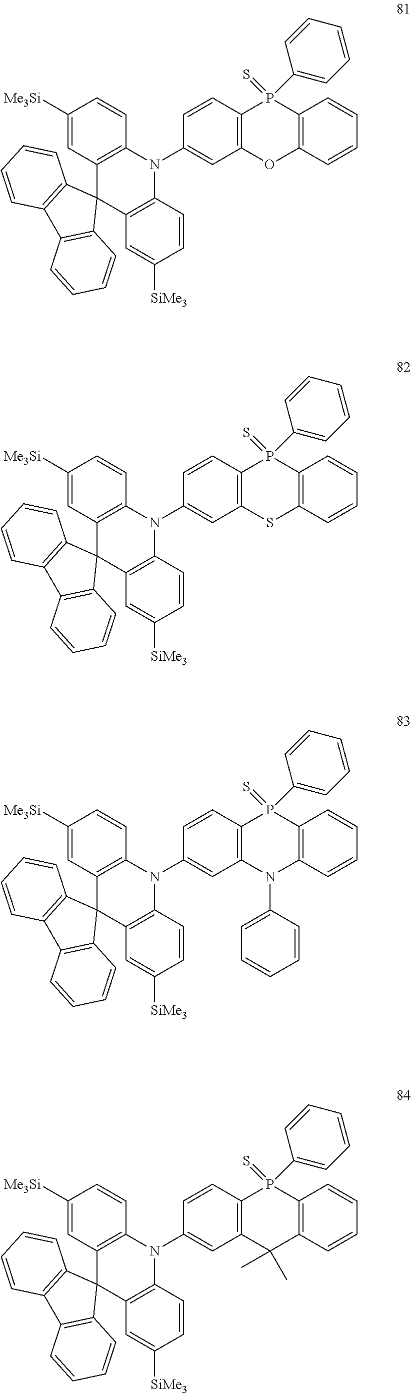 [SMILES: C[Si](C)(C)c1ccc2c(c1)C1(c3ccccc3-c3ccccc31)c1cc([Si](C)(C)C)ccc1N2c1ccc2c(c1)Oc1ccccc1P2(=S)c1ccccc1 ; C[Si](C)(C)c1ccc2c(c1)C1(c3ccccc3-c3ccccc31)c1cc([Si](C)(C)C)ccc1N2c1ccc2c(c1)Sc1ccccc1P2(=S)c1ccccc1 ; C[Si](C)(C)c1ccc2c(c1)C1(c3ccccc3-c3ccccc31)c1cc([Si](C)(C)C)ccc1N2c1ccc2c(c1)N(c1ccccc1)c1ccccc1P2(=S)c1ccccc1 ; CC1(C)c2ccccc2P(=S)(c2ccccc2)c2ccc(N3c4ccc([Si](C)(C)C)cc4C4(c5ccccc5-c5ccccc54)c4cc([Si](C)(C)C)ccc43)cc21]

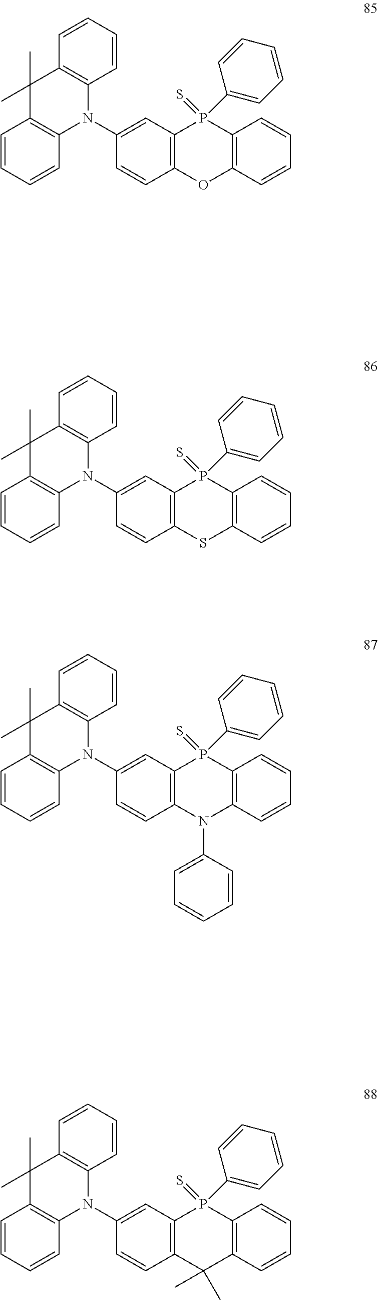 [SMILES: CC1(C)c2ccccc2N(c2ccc3c(c2)P(=S)(c2ccccc2)c2ccccc2O3)c2ccccc21 ; CC1(C)c2ccccc2N(c2ccc3c(c2)P(=S)(c2ccccc2)c2ccccc2S3)c2ccccc21 ; CC1(C)c2ccccc2N(c2ccc3c(c2)P(=S)(c2ccccc2)c2ccccc2N3c2ccccc2)c2ccccc21 ; CC1(C)c2ccccc2N(c2ccc3c(c2)P(=S)(c2ccccc2)c2ccccc2C3(C)C)c2ccccc21]

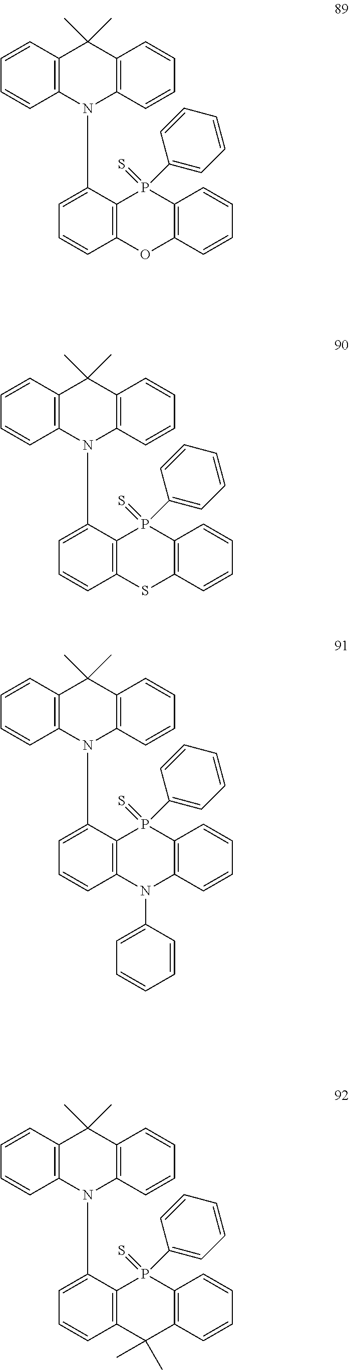 [SMILES: CC1(C)c2ccccc2N(c2cccc3c2P(=S)(c2ccccc2)c2ccccc2O3)c2ccccc21 ; CC1(C)c2ccccc2N(c2cccc3c2P(=S)(c2ccccc2)c2ccccc2S3)c2ccccc21 ; CC1(C)c2ccccc2N(c2cccc3c2P(=S)(c2ccccc2)c2ccccc2N3c2ccccc2)c2ccccc21 ; CC1(C)c2ccccc2N(c2cccc3c2P(=S)(c2ccccc2)c2ccccc2C3(C)C)c2ccccc21]

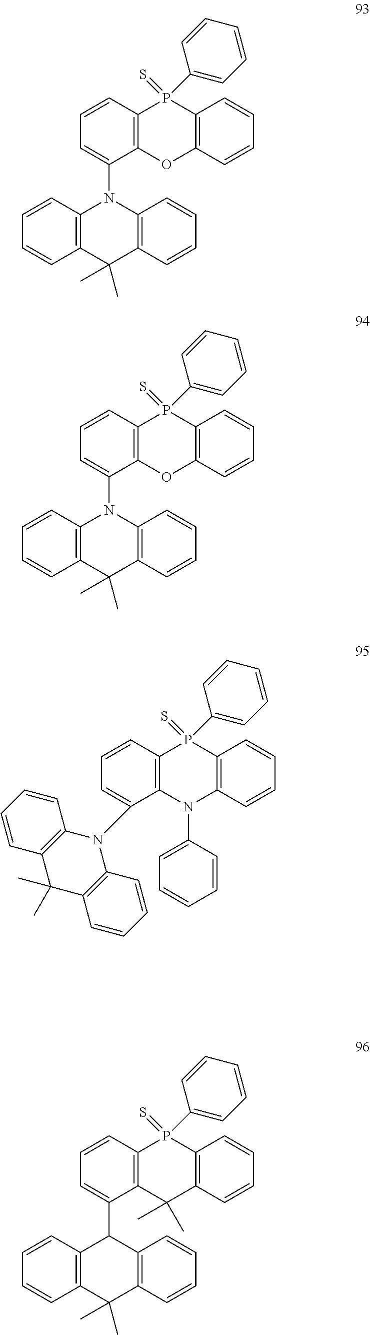 [SMILES: CC1(C)c2ccccc2N(c2cccc3c2Oc2ccccc2P3(=S)c2ccccc2)c2ccccc21 ; CC1(C)c2ccccc2N(c2cccc3c2Oc2ccccc2P3(=S)c2ccccc2)c2ccccc21 ; CC1(C)c2ccccc2N(c2cccc3c2N(c2ccccc2)c2ccccc2P3(=S)c2ccccc2)c2ccccc21 ; CC1(C)c2ccccc2C(c2cccc3c2C(C)(C)c2ccccc2P3(=S)c2ccccc2)c2ccccc21]

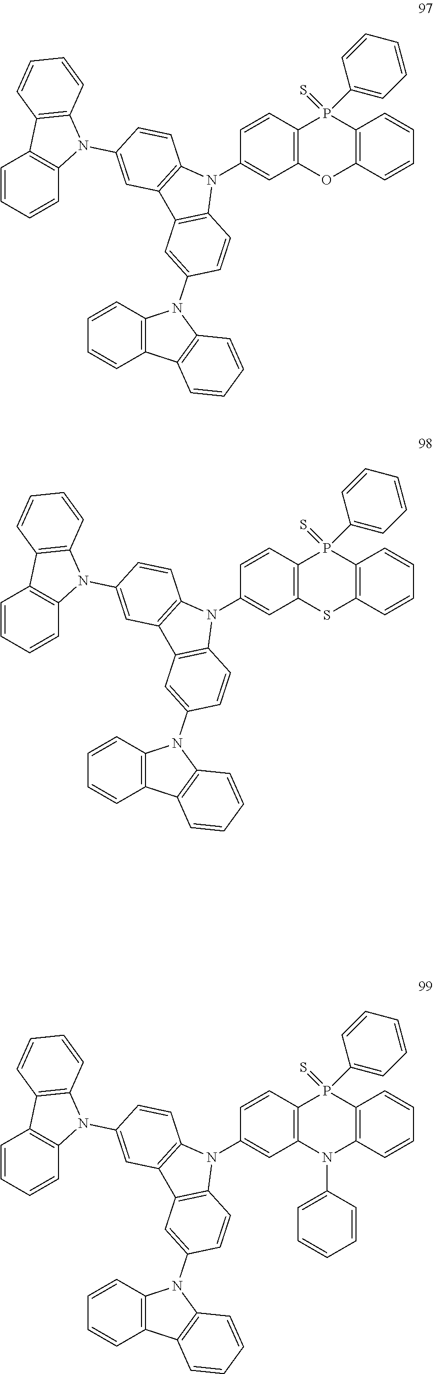 [SMILES: S=P1(c2ccccc2)c2ccccc2Oc2cc(-n3c4ccc(-n5c6ccccc6c6ccccc65)cc4c4cc(-n5c6ccccc6c6ccccc65)ccc43)ccc21 ; S=P1(c2ccccc2)c2ccccc2Sc2cc(-n3c4ccc(-n5c6ccccc6c6ccccc65)cc4c4cc(-n5c6ccccc6c6ccccc65)ccc43)ccc21 ; S=P1(c2ccccc2)c2ccccc2N(c2ccccc2)c2cc(-n3c4ccc(-n5c6ccccc6c6ccccc65)cc4c4cc(-n5c6ccccc6c6ccccc65)ccc43)ccc21]

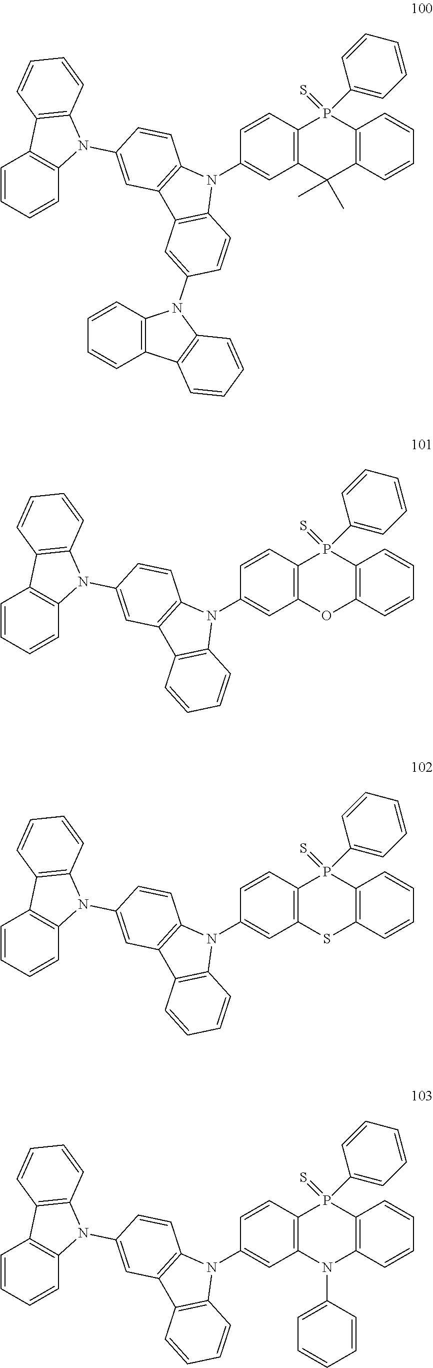 [SMILES: CC1(C)c2ccccc2P(=S)(c2ccccc2)c2ccc(-n3c4ccc(-n5c6ccccc6c6ccccc65)cc4c4cc(-n5c6ccccc6c6ccccc65)ccc43)cc21 ; S=P1(c2ccccc2)c2ccccc2Oc2cc(-n3c4ccccc4c4cc(-n5c6ccccc6c6ccccc65)ccc43)ccc21 ; S=P1(c2ccccc2)c2ccccc2Sc2cc(-n3c4ccccc4c4cc(-n5c6ccccc6c6ccccc65)ccc43)ccc21 ; S=P1(c2ccccc2)c2ccccc2N(c2ccccc2)c2cc(-n3c4ccccc4c4cc(-n5c6ccccc6c6ccccc65)ccc43)ccc21]

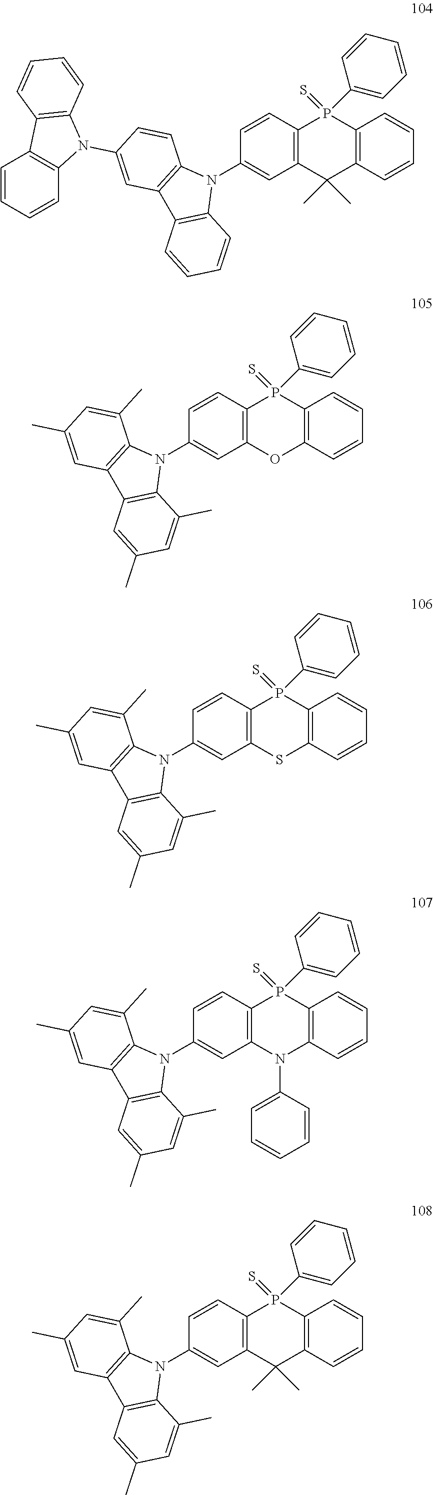 [SMILES: CC1(C)c2ccccc2P(=S)(c2ccccc2)c2ccc(-n3c4ccccc4c4cc(-n5c6ccccc6c6ccccc65)ccc43)cc21 ; Cc1cc(C)c2c(c1)c1cc(C)cc(C)c1n2-c1ccc2c(c1)Oc1ccccc1P2(=S)c1ccccc1 ; Cc1cc(C)c2c(c1)c1cc(C)cc(C)c1n2-c1ccc2c(c1)Sc1ccccc1P2(=S)c1ccccc1 ; Cc1cc(C)c2c(c1)c1cc(C)cc(C)c1n2-c1ccc2c(c1)N(c1ccccc1)c1ccccc1P2(=S)c1ccccc1 ; Cc1cc(C)c2c(c1)c1cc(C)cc(C)c1n2-c1ccc2c(c1)C(C)(C)c1ccccc1P2(=S)c1ccccc1]

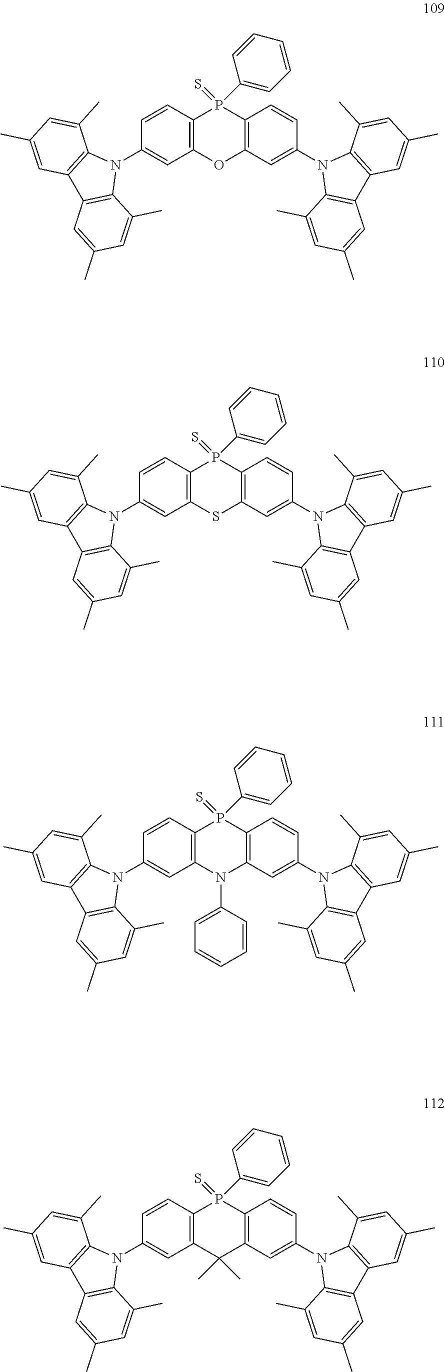

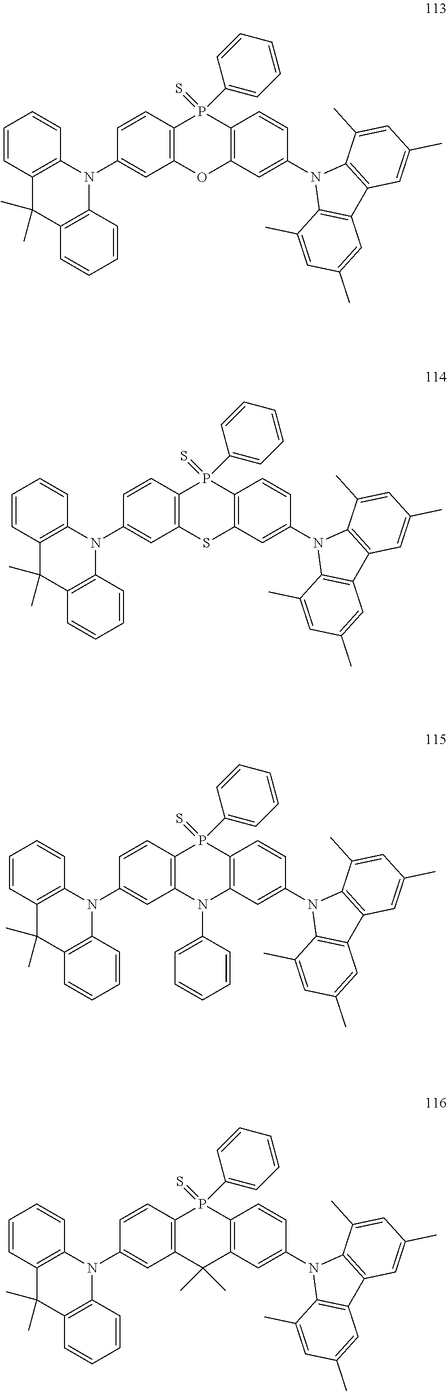

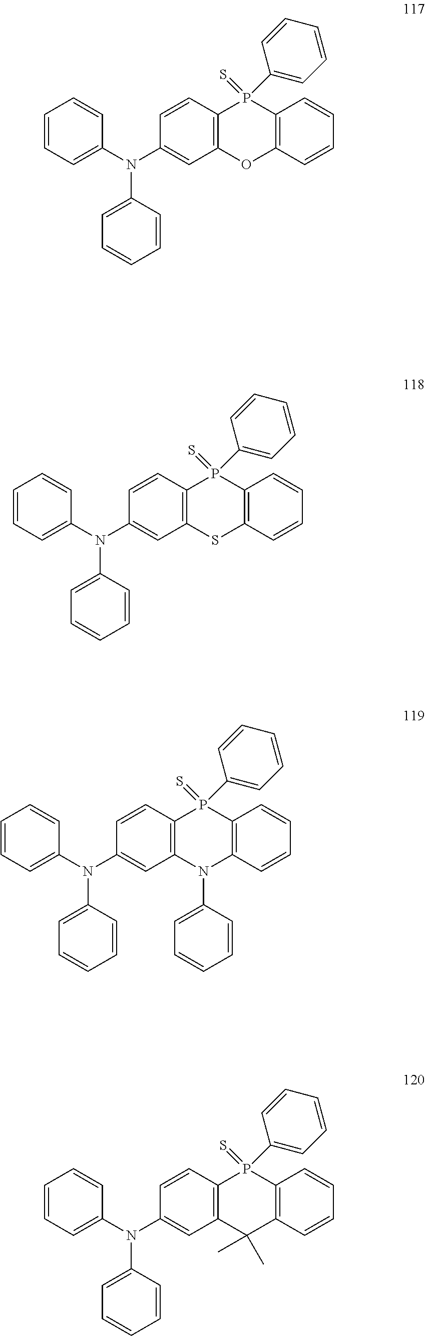 [SMILES: S=P1(c2ccccc2)c2ccccc2Oc2cc(N(c3ccccc3)c3ccccc3)ccc21 ; S=P1(c2ccccc2)c2ccccc2Sc2cc(N(c3ccccc3)c3ccccc3)ccc21 ; S=P1(c2ccccc2)c2ccccc2N(c2ccccc2)c2cc(N(c3ccccc3)c3ccccc3)ccc21 ; CC1(C)c2ccccc2P(=S)(c2ccccc2)c2ccc(N(c3ccccc3)c3ccccc3)cc21]

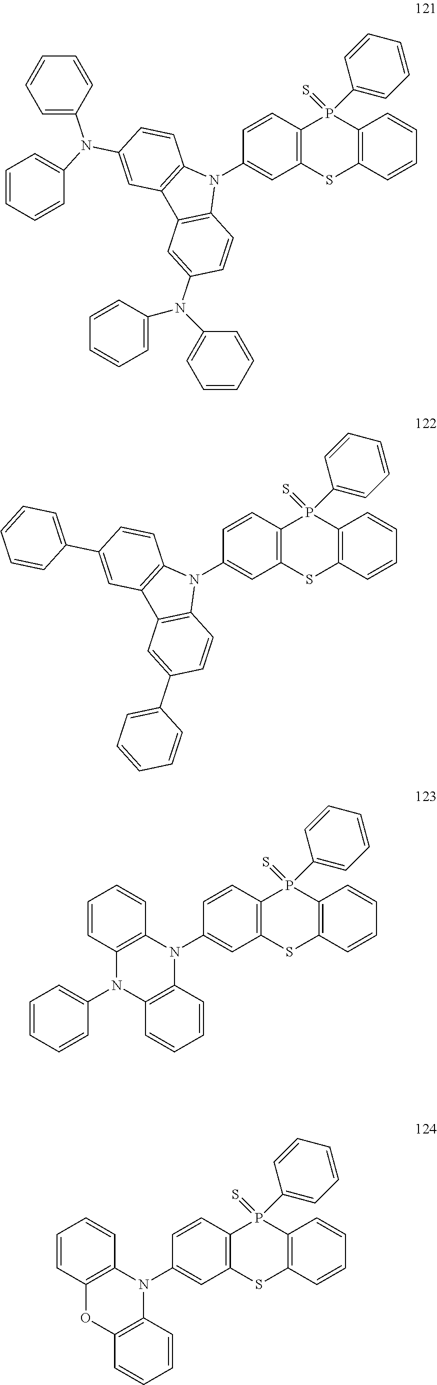 [SMILES: S=P1(c2ccccc2)c2ccccc2Sc2cc(-n3c4ccc(N(c5ccccc5)c5ccccc5)cc4c4cc(N(c5ccccc5)c5ccccc5)ccc43)ccc21 ; S=P1(c2ccccc2)c2ccccc2Sc2cc(-n3c4ccc(-c5ccccc5)cc4c4cc(-c5ccccc5)ccc43)ccc21 ; S=P1(c2ccccc2)c2ccccc2Sc2cc(N3c4ccccc4N(c4ccccc4)c4ccccc43)ccc21 ; S=P1(c2ccccc2)c2ccccc2Sc2cc(N3c4ccccc4Oc4ccccc43)ccc21]

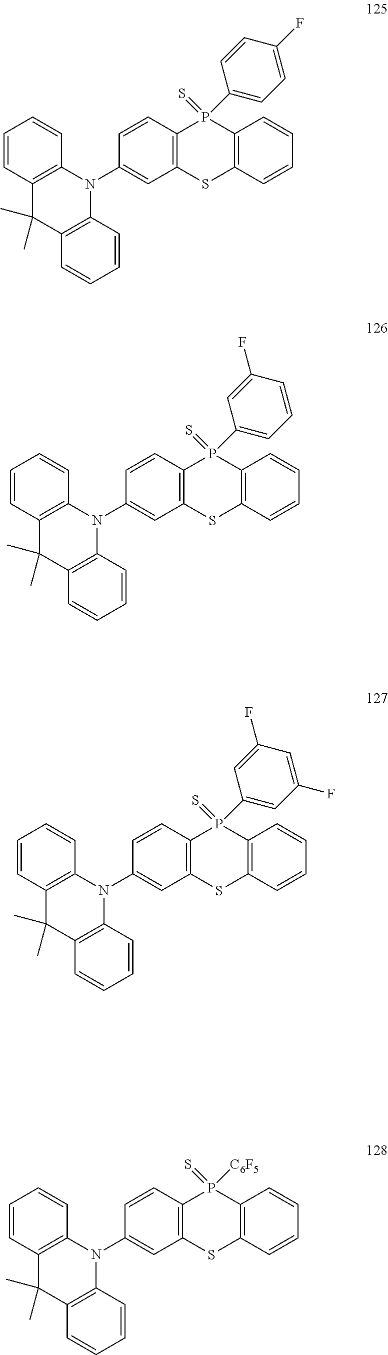

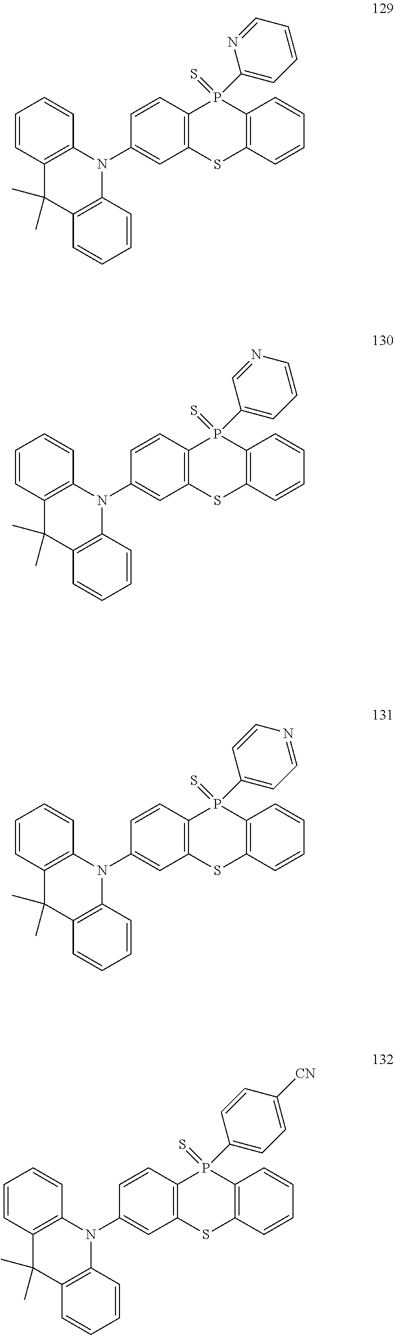 [SMILES: CC1(C)c2ccccc2N(c2ccc3c(c2)Sc2ccccc2P3(=S)c2ccccn2)c2ccccc21 ; CC1(C)c2ccccc2N(c2ccc3c(c2)Sc2ccccc2P3(=S)c2cccnc2)c2ccccc21 ; CC1(C)c2ccccc2N(c2ccc3c(c2)Sc2ccccc2P3(=S)c2ccncc2)c2ccccc21 ; CC1(C)c2ccccc2N(c2ccc3c(c2)Sc2ccccc2P3(=S)c2ccc(C#N)cc2)c2ccccc21]

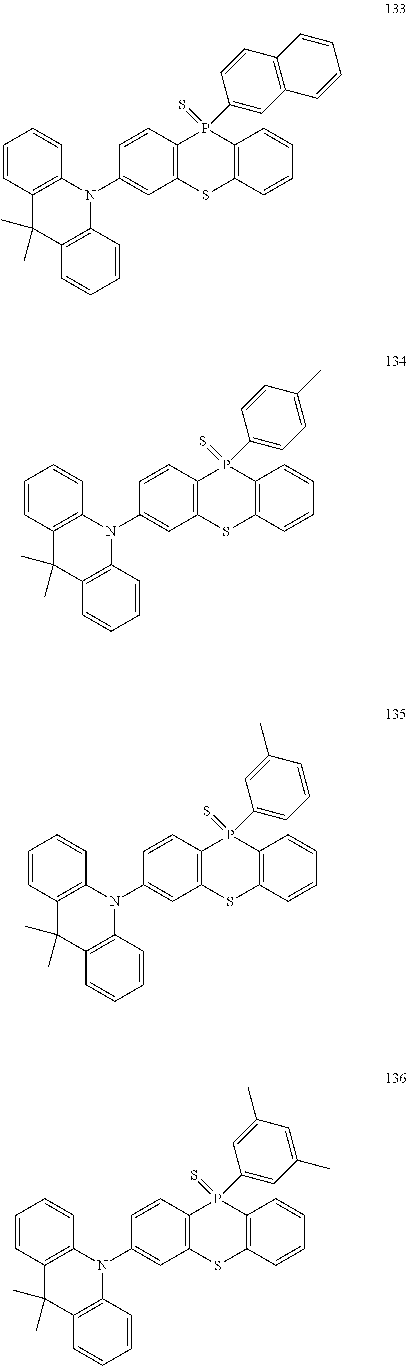

In an implementation, the emission layer EML may further include a suitable material other than the phosphorus-containing compound according to an embodiment. In an implementation, the emission layer EML may further include a fluorescence material, e.g., spiro-DPVBi, 2,2′,7,7′-tetrakis(biphenyl-4-yl)-9,9′-spirobifluorene(spiro-sexiphenyl) (spiro-6P), distyryl-benzene (DSB), distyryl-arylene (DSA), a polyfluorene (PFO)-based polymer, and a poly(p-phenylene vinylene) (PPV)-based polymer.

In an implementation, the phosphorus-containing compound according to an embodiment may be included in the emission layer EML and may radiate delayed fluorescence. For example, the phosphorus-containing compound of an embodiment may be a delayed fluorescence material. The phosphorus-containing compound represented by Formula 1 according to an embodiment may be a material for thermally activated delayed fluorescence (TADF).

In order to radiate delayed fluorescence, the phosphorus-containing compound according to an embodiment may include an electron acceptor moiety and an electron donor moiety. For example, in the phosphorus-containing compound of an embodiment, a

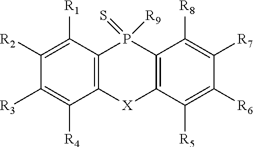

moiety may correspond to an electron acceptor, and a

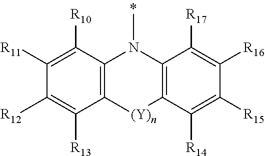

moiety (which is one of R₁ to R₈) may correspond to an electron donor.

The organic electroluminescence device 10 according to an embodiment may include the phosphorus-containing compound represented by Formula 1 and may help improve emission efficiency. The organic electroluminescence device 10 of an embodiment, including the phosphorus-containing compound may exhibit a low driving voltage at a high current density region (for example, 10 mA/cm² or more).

The organic electroluminescence device 10 according to an embodiment may include the phosphorus-containing compound represented by Formula 1 in the emission layer EML, and may have a decreased full width at half maximum of light emission, improved color purity, and a low driving voltage, especially at a high current density, thereby expanding the application range of an organic electroluminescence device.

For example, the phosphorus-containing compound of an embodiment may be a thermally activated delayed fluorescence material emitting blue light. Accordingly, the emission layer EML of the organic electroluminescence device 10 of an embodiment, including the phosphorus-containing compound may emit blue light. In an implementation, the phosphorus-containing compound of an embodiment may be a thermally activated delayed fluorescence material emitting green light or red light.

The phosphorus-containing compound according to an embodiment may be included as a dopant material of the emission layer EML.

The emission layer EML may further include a host. The host may include a suitable host material, e.g., tris(8-hydroxyquinolino)aluminum (Alq3), 4,4′-bis(N-carbazolyl)-1,1′-biphenyl (CBP), poly(N-vinylcarbazole) (PVK), 9,10-di(naphthaline-2-yl)anthracene (ADN), 4,4′,4″-tris(carbazol-9-yl)-triphenylamine (TCTA), 1,3,5-tris(N-phenylbenzimidazole-2-yl)benzene (TPBi), 3-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), bis[2-(diphenylphosphino)phenyl] ether oxide (DPEPO), hexaphenyl cyclotriphosphazene (CPI), 1,4-bis(triphenylsilyl)benzene (UGH2), hexaphenylcyclotrisiloxane (DPSiO₃), octaphenylcyclotetrasiloxane (DPSiO₄), 2,8-bis(diphenylphosphoryl)dibenzofuran (PPF), etc.

The electron transport region ETR may be provided on the emission layer EML. In an implementation, the electron transport region ETR may include at least one of an electron blocking layer, an electron transport layer ETL or an electron injection layer EIL.

The electron transport region ETR may have a single layer formed using a single material, a single layer formed using a plurality of different materials, or a multilayer structure having a plurality of layers formed using a plurality of different materials.

In an implementation, the electron transport region ETR may have a single layer structure of the electron injection layer EIL or the electron transport layer ETL, or a single layer structure formed using an electron injection material and an electron transport material. In an implementation, the electron transport region ETR may have a single layer structure having a plurality of different materials, or a structure laminated from the first electrode EL1 of electron transport layer ETL/electron injection layer EIL, or hole blocking layer/electron transport layer ETL/electron injection layer EIL. The thickness of the electron transport region ETR may be, e.g., from about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

In the case where the electron transport region ETR includes the electron transport layer ETL, the electron transport region ETR may include a suitable material. In an implementation, the electron transport region ETR may include tris(8-hydroxyquinolinato)aluminum (Alq3), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,08)-(1,1′-biphenyl-4-olato)aluminum (BAlq), berylliumbis(benzoquinolin-10-olate (Bebq2), 9,10-di(naphthalene-2-yl)anthracene (ADN), or a mixture thereof.

In the case where the electron transport region ETR includes the electron transport layer ETL, the thickness of the electron transport layer ETL may be from about 100 Å to about 1,000 Å, e.g., from about 150 Å to about 500 Å. If the thickness of the electron transport layer ETL satisfies the above-described range, satisfactory electron transport properties may be obtained without substantial increase of a driving voltage.

When the electron transport region ETR includes the electron injection layer EIL, the electron transport region ETR may include a suitable material. In an implementation, the electron transport region ETR may include LiF, lithium quinolate (LiQ), Li₂O, BaO, NaCl, CsF, a metal in lanthanoides such as Yb. or a metal halide such as RbCl and RbI. In an implementation, the electron injection layer EIL also may be formed using a mixed material of an electron transport material and an insulating organo metal salt. The organo metal salt may include a material having an energy band gap of about 4 eV or more. In an implementation, the organo metal salt may include, e.g., metal acetates, metal benzoates, metal acetoacetates, metal acetylacetonates, or metal stearates.

In the case where the electron transport region ETR includes the electron injection layer EIL, the thickness of the electron injection layer EIL may be from about 1 Å to about 100 Å, e.g., about 3 Å to about 90 Å. In the case where the thickness of the electron injection layer EIL satisfies the above described range, satisfactory electron injection properties may be obtained without inducing the substantial increase of a driving voltage.

The electron transport region ETR may include a hole blocking layer as described above. In an implementation, the hole blocking layer may include, e.g., 2,9-dimethyl-4,7-diphenyl-1,10-phenanthroline (BCP), or 4,7-diphenyl-1,10-phenanthroline (Bphen).

The second electrode EL2 may be provided on the electron transport region ETR. The second electrode EL2 has conductivity. The second electrode EL2 may be formed using a metal alloy or a conductive compound. The second electrode EL2 may be a cathode. The second electrode EL2 may be a transmissive electrode, a transflective electrode or a reflective electrode. In the case where the second electrode EL2 is the transmissive electrode, the second electrode EL2 may include a transparent metal oxide, for example, ITO, IZO, ZnO, ITZO, etc.

In the case where the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, a compound thereof, or a mixture thereof (for example, a mixture of Ag and Mg). The second electrode EL2 may have a multilayered structure including a reflective layer or a transflective layer formed using the above-described materials and a transparent conductive layer formed using ITO, IZO, ZnO, ITZO, etc.

In an implementation, the second electrode EL2 may be connected with an auxiliary electrode. In the case where the second electrode EL2 is connected with the auxiliary electrode, the resistance of the second electrode EL2 may decrease.

In the organic electroluminescence device 10, according to the application of a voltage to each of the first electrode EL1 and second electrode EL2, holes injected from the first electrode EL1 may move via the hole transport region HTR to the emission layer EML, and electrons injected from the second electrode EL2 may move via the electron transport region ETR to the emission layer EML. The electrons and the holes are recombined in the emission layer EML to produce excitons, and the excitons may emit light via transition from an excited state to a ground state.

In the case where the organic electroluminescence device 10 is a top emission type, the first electrode EL1 may be a reflective electrode and the second electrode EL2 may be a transmissive electrode or a transflective electrode. In the case where the organic electroluminescence device 10 is a bottom emission type, the first electrode EL1 may be a transmissive electrode or a transflective electrode and the second electrode EL2 may be a reflective electrode.

An organic electroluminescence device according to an embodiment may include the phosphorus-containing compound, thereby having improved emission efficiency. In an implementation, the organic electroluminescence device according to an embodiment includes the phosphorus-containing compound in an emission layer so that the phosphorus-containing compound emits light via a thermally activated delayed fluorescence process, thereby attaining high efficiency. For example, the organic electroluminescence device according to an embodiment may include the phosphorus-containing compound in an emission layer, thereby attaining a low driving voltage in a high current density region.

Hereinafter a phosphorus-containing compound according to an embodiment and an organic electroluminescence device including the phosphorus-containing compound according to an embodiment will be explained in more detail with reference to embodiments and comparative embodiments.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Examples

1. Synthesis of Phosphorus-Containing Compound

First, a synthetic method of a phosphorus-containing compound according to an embodiment will be explained in detail referring to synthetic methods of Compound 21, Compound 22, and Compound 23 of Compound Group 1. In addition, the following synthetic methods of the phosphorus-containing compounds are for illustrations, and the synthetic method of the phosphorus-containing compound according to an embodiment may be according to any suitable method.

(Synthesis of Compound 21)

Compound 21 was synthesized by the following Reaction 1.

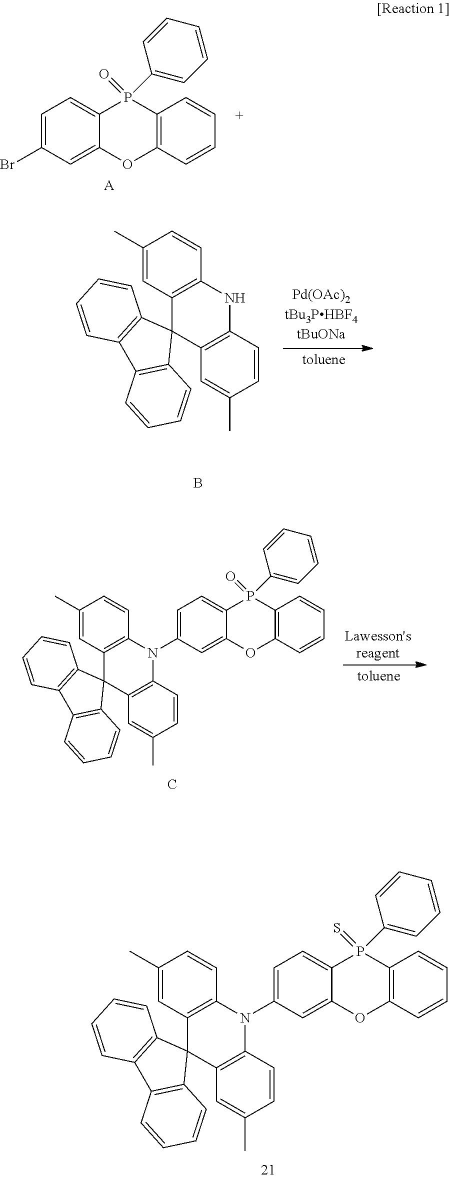

Under a nitrogen atmosphere, 2.91 g of Compound B, 3.00 g of Compound A, 0.05 g of palladium acetate, 0.35 g of tri-tert-butylphosphonium tetrafluoroborate (tBu₃P.HBF₄), and 1.86 g of sodium tert-butoxide were added to a 300 ml, three-necked flask, and then heated and refluxed in 100 ml of a toluene solvent at 110° C. for a day to obtain 1.56 g of a solid compound. Then, under a nitrogen atmosphere, 1.00 g of Compound C, and 1.25 g of Lawesson's reagent were added to a 300 ml, three-necked flask, and heated and refluxed in 100 ml of a toluene solvent at 110° C. for a day. The residual product thus obtained was separated by silica gel column chromatography (using a mixed solvent of chloroform and hexane), and recrystallized using a mixed solvent of dichloromethane and hexane to obtain 0.76 g of a yellow solid compound (yield 75%).

The chemical shift values (8) of the compound measured by ¹H NMR were ¹H NMR (400 MHz, DMSO, δ): 8.18 (d, J=8.0 Hz, 0.5H), 8.14 (d, J=8.0 Hz, 0.5H), 7.97 (d, J=7.6 Hz, 2H), 7.90-7.84 (m, 1H), 7.79-7.72 (m, 4H), 7.58-7.56 (m, 4H), 7.54-7.41 (m, 4H), 7.37 (d, J=7.6 Hz, 2H), 7.31 (td, J=7.4 Hz, 0.8 Hz, 2H), 6.79 (dd, J=8.8 Hz, 2.0 Hz, 2H), 6.29 (d, J=8.0 Hz, 2H), 6.03 (d, J=2.0 Hz, 2H), 1.88 (s, 6H). From the result, the yellow solid compound was identified as Compound 21.

(Synthesis of Compound 22)

Compound 22 was synthesized by the following Reaction 2.

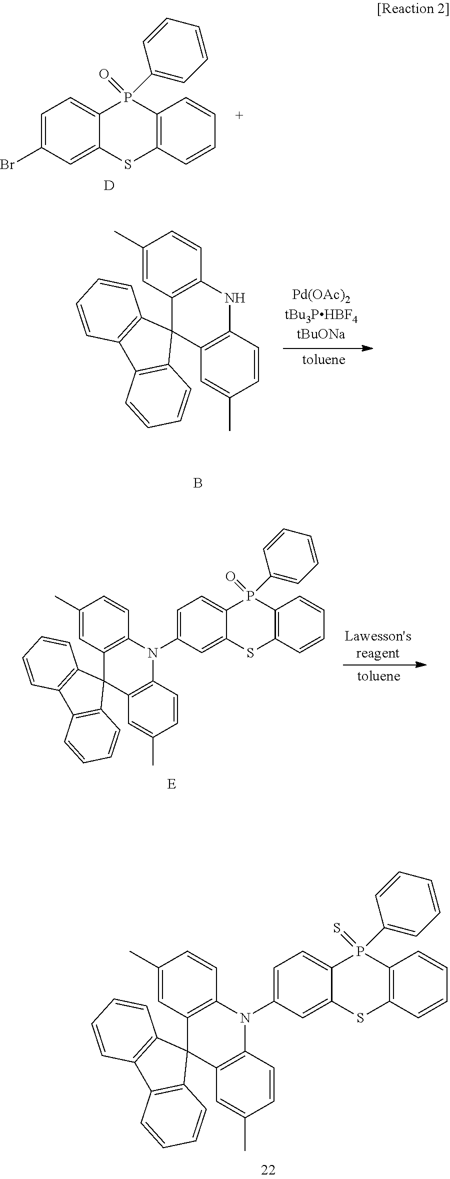

Under a nitrogen atmosphere, 4.32 g of Compound B, 4.65 g of Compound D, 0.08 g of palladium acetate, 0.52 g of tBu₃P.HBF₄, and 2.77 g of sodium tert-butoxide were added to a 300 ml, three-necked flask, and then heated and refluxed in 150 ml of a toluene solvent at 110° C. for a day to obtain 3.94 g of a solid compound. Then, under a nitrogen atmosphere, 2.50 g of Compound E, and 3.04 g of Lawesson's reagent were added to a 300 ml, three-necked flask, and heated and refluxed in 150 ml of a toluene solvent at 110° C. for a day. The residual product thus obtained was separated by silica gel column chromatography (using a mixed solvent of chloroform and hexane), and recrystallized using a mixed solvent of dichloromethane and hexane to obtain 1.76 g of a yellow solid compound (yield 69%).

The chemical shift values (8) of the compound measured by ¹H NMR were ¹H NMR (400 MHz, DMSO, δ): 8.75 (d, J=8.0 Hz, 0.5H), 8.72 (d, J=8.0 Hz, 0.5H), 8.49-8.43 (m, 1H), 8.04 (dd, J=4.0 Hz, 2.0 Hz, 1H), 7.97 (d, J=7.2 Hz, 2H), 7.90 (dt, J=8.0 Hz, 1.7 Hz, 1H), 7.83-7.72 (m, 3H), 7.55-7.51 (m, 1H), 7.49-7.41 (m, 4H), 7.38 (t, J=7.2 Hz, 2H), 7.34-7.28 (m, 4H), 6.79 (dd, J=9.0 Hz, 1.8 Hz, 2H), 6.22 (d, J=8.4 Hz, 2H), 6.02 (d, J=2.0 Hz, 2H), 1.88 (s, 6H).). From the result, the yellow solid compound was identified as Compound 22.

(Synthesis of Compound 23)

Compound 23 was synthesized by the following Reaction 3.

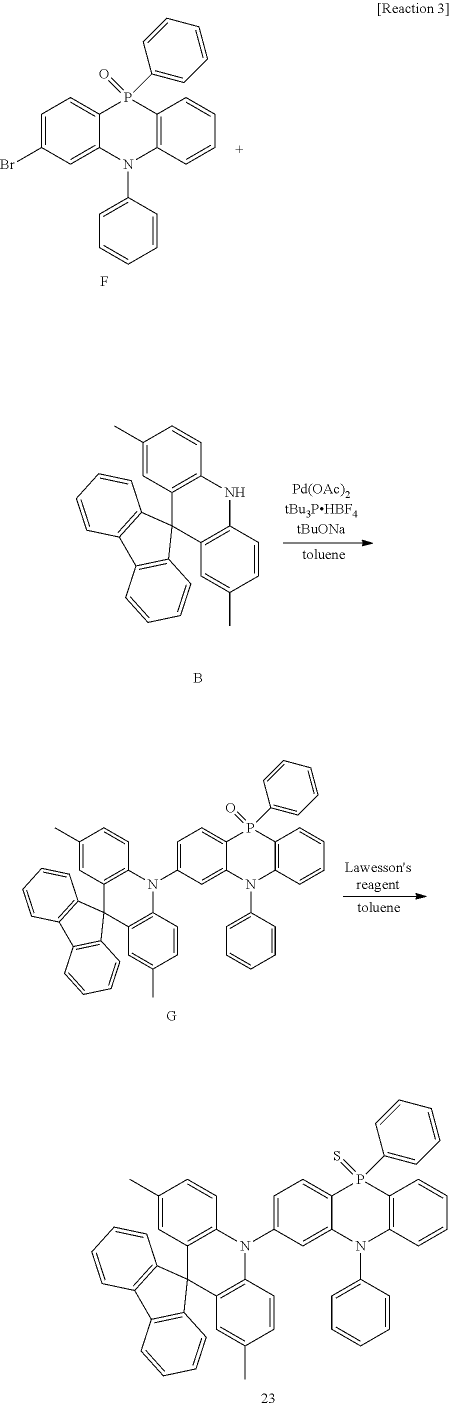

Under a nitrogen atmosphere, 2.42 g of Compound B, 3.00 g of Compound F, 0.05 g of palladium acetate, 0.29 g of tBu₃P.HBF₄, and 1.55 g of sodium tert-butoxide were added to a 300 ml, three-necked flask, and then heated and refluxed in 100 ml of a toluene solvent at 110° C. for a day to obtain 1.62 g of a solid compound. Then, under a nitrogen atmosphere, 1.10 g of Compound G, and 1.23 g of Lawesson's reagent were added to a 300 ml, three-necked flask, and heated and refluxed in 100 ml of a toluene solvent at 110° C. for a day. The residual product thus obtained was separated by silica gel column chromatography (using a mixed solvent of chloroform and hexane), and recrystallized using a toluene solvent to obtain 0.78 g of a yellow solid compound (yield 70%).

The chemical shift values (8) of the compound measured by ¹H NMR were ¹H NMR (400 MHz, DMSO, δ): 8.29 (d, J=8.0 Hz, 0.5H), 8.26 (d, J=8.0 Hz, 0.5H), 8.01-7.94 (m, 3H), 7.79-7.73 (m, 4H), 7.69 (tt, J=7.4 Hz, 1.5 Hz, 1H), 7.62-7.55 (m, 5H), 7.48 (td, J=7.9 Hz, 1.0 Hz, 1H), 7.42 (td, J=7.4 Hz, 0.9 Hz, 3H), 7.27 (t, J=7.2 Hz, 1H), 7.22 (td, J=7.5 Hz, 1.1 Hz, 2H), 7.11 (d, J=7.2 Hz, 2H), 6.77 (dd, J=8.8 Hz, 1.6 Hz, 2H), 6.55-6.48 (m, 2H), 6.22 (d, J=8.4 Hz, 2H), 5.99 (d, J=1.6 Hz, 2H), 1.87 (s, 6H). From the result, the yellow solid compound was identified as Compound 23.

2. Manufacture and Evaluation of Organic Electroluminescence Device Including Phosphorus-Containing Compound

(Manufacture of Organic Electroluminescence Device)

An organic electroluminescence device according to an embodiment, including a phosphorus-containing compound according to an embodiment in an emission layer was manufactured by the following method. Organic electroluminescence devices of Example 1 and Example 2 were manufactured using the phosphorus-containing compounds of Compound 21 and Compound 22, respectively, as materials of an emission layer. In Comparative Example 1, an organic electroluminescence device was manufactured using the following Comparative Compound C1 as a material of an emission layer.

The compounds used for forming an emission layer in Examples 1 and 2 and Comparative Example 1 are listed in Table 1 below.

TABLE 1

| | |
|---|---|
| Compound 21 | 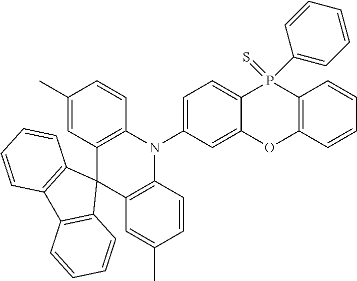 [SMILES: Cc1ccc2c(c1)C1(c3ccccc3-c3ccccc31)c1cc(C)ccc1N2c1ccc2c(c1)Oc1ccccc1P2(=S)c1ccccc1] |
| | 21 |
| Compound 22 | 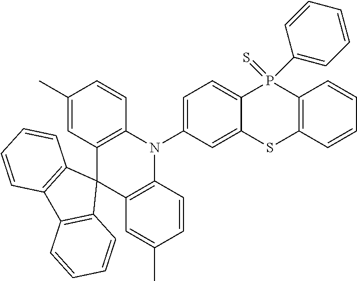 [SMILES: Cc1ccc2c(c1)C1(c3ccccc3-c3ccccc31)c1cc(C)ccc1N2c1ccc2c(c1)Sc1ccccc1P2(=S)c1ccccc1] |
| | 22 |
| Comparative Compound C1 | 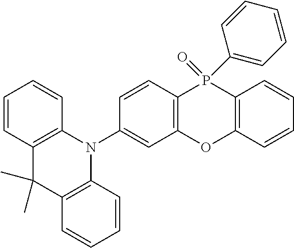 [SMILES: CC1(C)c2ccccc2N(c2ccc3c(c2)Oc2ccccc2P3(=O)c2ccccc2)c2ccccc21] |
| | C1 |

The organic electroluminescence devices of the Examples and Comparative Example were manufactured by the following method.

The Examples were prepared as follows. On a glass substrate. ITO was patterned to a thickness of about 1,500 Å, washed with pure water and UV ozone treated for 10 minutes. Then, a hole injection layer was formed using HAT-CN to a thickness of about 100 Å, and a hole transport layer was formed using NPB to a thickness of about 800 Å.

Then, an emission layer was formed using a mixture of the phosphorus-containing compound (Compound 21 or Compound 22) and DPEPO in a ratio of 24:76. The thickness of the emission layer was about 200 Å. On the emission layer, an electron transport layer was formed using TPBi to a thickness of about 300 Å, and an electron injection layer was formed using LiF to a thickness of about 5 Å. Then, a second electrode was formed using aluminum (Al) to a thickness of about 1,000 Å.

The hole injection layer, the hole transport layer, the emission layer, the electron transport layer, the electron injection layer and the second electrode were formed by using a vacuum deposition apparatus.

In Comparative Example 1, an organic electroluminescence device was manufactured by performing the same manufacturing method of the organic electroluminescence device of the Examples, except for forming an emission layer by mixing Comparative Compound C1 and DPEPO in a ratio of 24:76.

(Evaluation of Properties of Organic Electroluminescence Device)

In order to evaluate the properties of the organic electroluminescence devices according to the Examples and the Comparative Example, a maximum value of external quantum efficiency and an external quantum efficiency value at a current density of 10 mA/cm² were evaluated. The voltage and current density of an organic electroluminescence device were measured using a source meter (Keithley Instrument Co., 2400 series), and luminance and external quantum efficiency were measured using a C9920-12 measurement apparatus of external quantum efficiency of Hamamatsu Photonics Co.

In addition, full widths at half maximum of light emission of the Examples and the Comparative Example were measured. The full width at half maximum of light emission is represented by a difference between wavelength λ₂ at a long wavelength side and a wavelength λ₁ at a short wavelength side among wavelengths in which luminance is a half of maximum luminance in an emission spectrum at a current density of 10 mA/cm² when measured using a C9920-12 measurement apparatus of external quantum efficiency. That is, the full width at half maximum of light emission is obtained by the following equation.

Full width at half maximum (nm)=λ₂−λ₁

Evaluation results of the properties of the organic electroluminescence devices are shown in Table 2.

TABLE 2

| | | Voltage | Full width at | Maximum value |
|---|---|---|---|---|
| | Dopant of | @10 | half maximum | of external |
| | emission | mA/cm² | of light | quantum |
| Division | layer | (V) | emission (nm) | efficiency (%) |
| Example 1 | Compound 21 | 6.4 | 65 | 4.7 |
| Example 2 | Compound 22 | 6.5 | 66 | 10.2 |
| Comparative | Comparative | 13.5 | 90 | 12.3 |
| Example 1 | Compound | | | |
| | C1 | | | |

Examples 1 and 2 correspond to organic electroluminescence devices including Compound 21 and Compound 22, respectively, as a dopant in an emission layer. Comparative Example 1 corresponds to an organic electroluminescence device including Comparative Compound C1 as a dopant in an emission layer.

Referring to Table 2, it may be seen that the organic electroluminescence devices of Examples 1 and 2 exhibited a lower voltage at a current density of 10 mA/cm², which corresponds to a high current density, than the organic electroluminescence device of Comparative Example 1. For example, Examples 1 and 2 exhibited improved driving voltage properties at a high current density when compared to Comparative Example 1.

In addition, referring to the results in Table 2, the organic electroluminescence devices of Examples 1 and 2 exhibited a narrower full width at half maximum of light emission when compared to the organic electroluminescence device of Comparative Example 1. For example, Examples 1 and 2 showed a narrower full width at half maximum of light emission than Comparative Example 1, and an organic electroluminescence device having high color purity may be attained.

The organic electroluminescence device according to an embodiment may include the phosphorus-containing compound in an emission layer, and a low driving voltage and high color purity may be attained. The phosphorus-containing compound according to an embodiment may be used as a thermally activated delayed fluorescence emission material, emission efficiency of the organic electroluminescence device may be improved, and emission properties of the organic electroluminescence device specifically at a high current density may be improved.

A phosphorus-containing compound according to an embodiment may help decrease the driving voltage and improve the color purity of an organic electroluminescence device.

An organic electroluminescence device according to an embodiment may include a phosphorus-containing compound according to an embodiment in an emission layer and may attain high efficiency by decreasing a driving voltage and improving color purity.

By way of summation and review, in the application of an organic electroluminescence device to a display device, a decrease of the driving voltage, and an increase of the emission efficiency and the life of the organic electroluminescence device may be desirable, and materials for an organic electroluminescence device stably attaining the requirements may be considered.

In an effort to obtain an organic electroluminescence device having high efficiency, technique on phosphorescence emission using energy in a triplet state or a delayed fluorescence emission using a phenomenon of producing singlet excitons by the collision of triplet excitons (triplet-triplet annihilation, TTA) may be considered.

For example, a thermally activated delayed fluorescence (TADF) material may be considered as a technique that is capable of attaining internal quantum efficiency of up to about 100%.

The embodiments may provide a phosphorus-containing compound for an organic electroluminescence device having high efficiency.

The embodiments may provide an organic electroluminescence device including a phosphorus-containing compound in an emission layer and having high efficiency.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A phosphorus-containing compound represented by the following Formula 1: 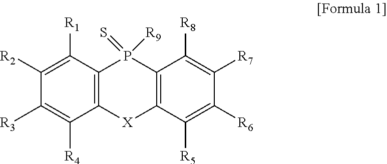
wherein, in Formula 1,
X is O, S, NRₐ, CR_{b}R_{c}, SiR_{d}Rₑ, or GeR_{f}R_{g},
R₁ to R₈ are each independently a hydrogen atom, a deuterium atom, a halogen atom, a substituted or unsubstituted silyl group, a substituted or unsubstituted amino group, a substituted or unsubstituted alkyl group having 1 to 20 carbon atoms, a substituted or unsubstituted aryl group having 6 to 30 ring carbon atoms, or a substituted or unsubstituted heteroaryl group having 4 to 30 ring carbon atoms,
R₉ is a substituted or unsubstituted alkyl group having 1 to 20 carbon atoms, a substituted or unsubstituted aryl group having 6 to 30 ring carbon atoms, or a substituted or unsubstituted heteroaryl group having 4 to 30 ring carbon atoms,
Rₐ to R_{g} are each independently a hydrogen atom, a deuterium atom, a halogen atom, a substituted or unsubstituted silyl group, a substituted or unsubstituted alkyl group having 1 to 20 carbon atoms, a substituted or unsubstituted fluorenyl group, a substituted or unsubstituted aryl group having 6 to 30 ring carbon atoms, or a substituted or unsubstituted heteroaryl group having 4 to 30 ring carbon atoms,
Rₐ to R_{g} are separate or combined with an adjacent group to form a ring, and
at least one of R₁ to R₈ is a group represented by the following Formula 2: 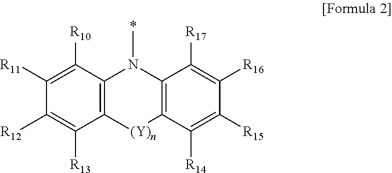
wherein, in Formula 2,
n is 0 or 1,
Y is direct linkage, O, S, CRₕRᵢ, SiRⱼRₖ, or GeRₗRₘ,
R₁₀ to R₁₇ are each independently a hydrogen atom, a deuterium atom, a halogen atom, a substituted or unsubstituted silyl group, a substituted or unsubstituted amino group, a substituted or unsubstituted alkyl group having 1 to 20 carbon atoms, a substituted or unsubstituted aryl group having 6 to 30 ring carbon atoms, or a substituted or unsubstituted heteroaryl group having 4 to 30 ring carbon atoms,
Rₕ to Rₘ are each independently a hydrogen atom, a deuterium atom, a halogen atom, a substituted or unsubstituted silyl group, a substituted or unsubstituted alkyl group having 1 to 20 carbon atoms, a substituted or unsubstituted fluorenyl group, a substituted or unsubstituted aryl group having 6 to 30 ring carbon atoms, or a substituted or unsubstituted heteroaryl group having 4 to 30 ring carbon atoms, and
Rₕ to Rₘ are separate or combined with an adjacent group to form a ring.

2. The phosphorus-containing compound as claimed in claim 1, wherein R₉ is a substituted or unsubstituted phenyl group.

3. The phosphorus-containing compound as claimed in claim 1, wherein R₉ is a substituted or unsubstituted pyridyl group or a substituted or unsubstituted naphthyl group.

4. The phosphorus-containing compound as claimed in claim 1, wherein one of R₁ to R₈ is a group represented by Formula 2 and the remainder thereof are each a hydrogen atom.

5. The phosphorus-containing compound as claimed in claim 1, wherein the compound represented by Formula 1 is represented by the following Formula 3: 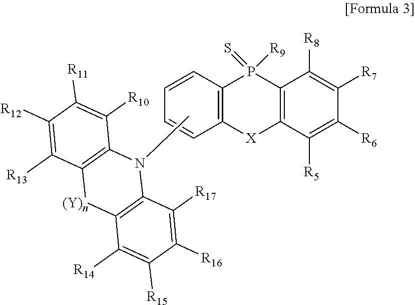
wherein, in Formula 3, R₅ to R₁₇, X, Y and n are defined the same as those of Formulae 1 and 2.

6. The phosphorus-containing compound as claimed in claim 1, wherein the compound represented by Formula 1 is represented by one of the following Formulae 1-1 to 1-6: 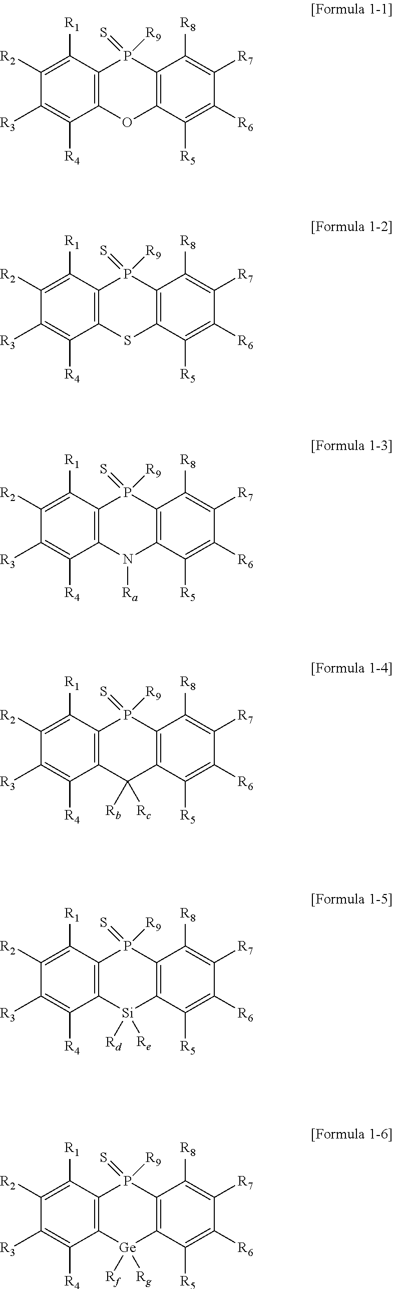
wherein, in Formulae 1-1 to 1-6, R₁ to R₉, and Rₐ to R_{g} are defined the same as those of Formula 1.

7. The phosphorus-containing compound as claimed in claim 6, wherein:
Rₐ is a substituted or unsubstituted aryl group having 6 to 30 ring carbon atoms, and
R_{b} to R_{g} are a substituted or unsubstituted alkyl group having 1 to 20 carbon atoms or a substituted or unsubstituted aryl group having 6 to 30 ring carbon atoms.

8. The phosphorus-containing compound as claimed in claim 1, wherein the group represented by Formula 2 is a group represented by one of the following Formulae 2-1 to 2-9: 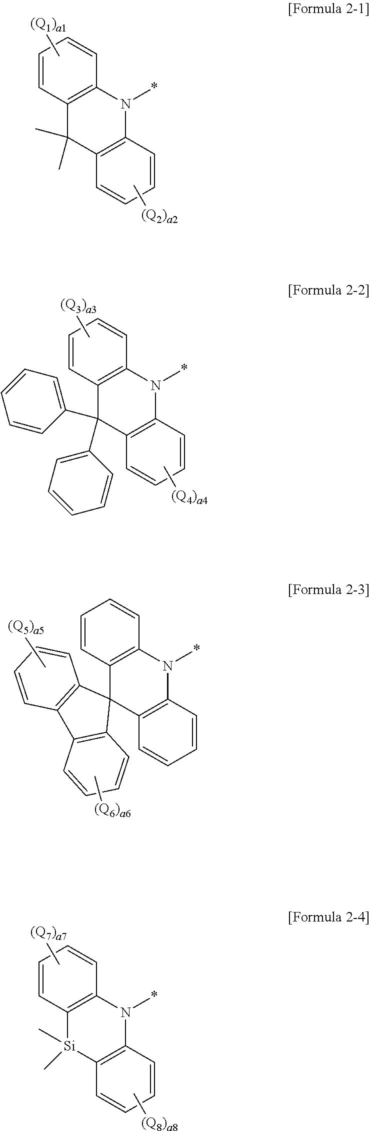 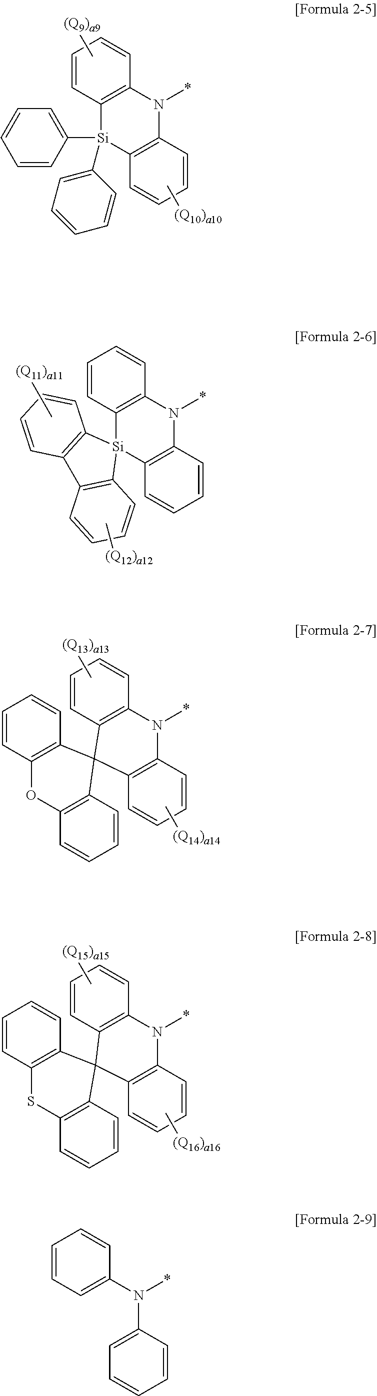
wherein, in Formulae 2-1 to 2-9,
Q₁ to Q₁₆ are each independently a hydrogen atom, a deuterium atom, a halogen atom, a substituted or unsubstituted silyl group, or a substituted or unsubstituted alkyl group having 1 to 20 carbon atoms, and
a₁ to a₁₆ are each independently an integer of 0 to 4.

9. The phosphorus-containing compound as claimed in claim 1, wherein the phosphorus-containing compound represented by Formula 1 is a compound of the following Compound Group 1:

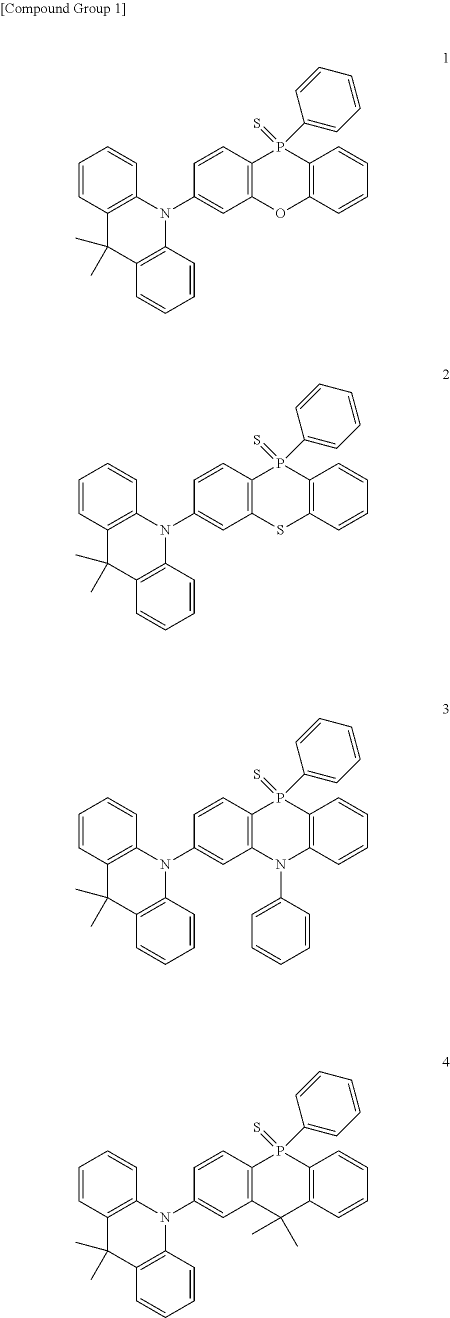 [SMILES: CC1(C)c2ccccc2N(c2ccc3c(c2)Oc2ccccc2P3(=S)c2ccccc2)c2ccccc21 ; CC1(C)c2ccccc2N(c2ccc3c(c2)Sc2ccccc2P3(=S)c2ccccc2)c2ccccc21 ; CC1(C)c2ccccc2N(c2ccc3c(c2)N(c2ccccc2)c2ccccc2P3(=S)c2ccccc2)c2ccccc21 ; CC1(C)c2ccccc2N(c2ccc3c(c2)C(C)(C)c2ccccc2P3(=S)c2ccccc2)c2ccccc21]

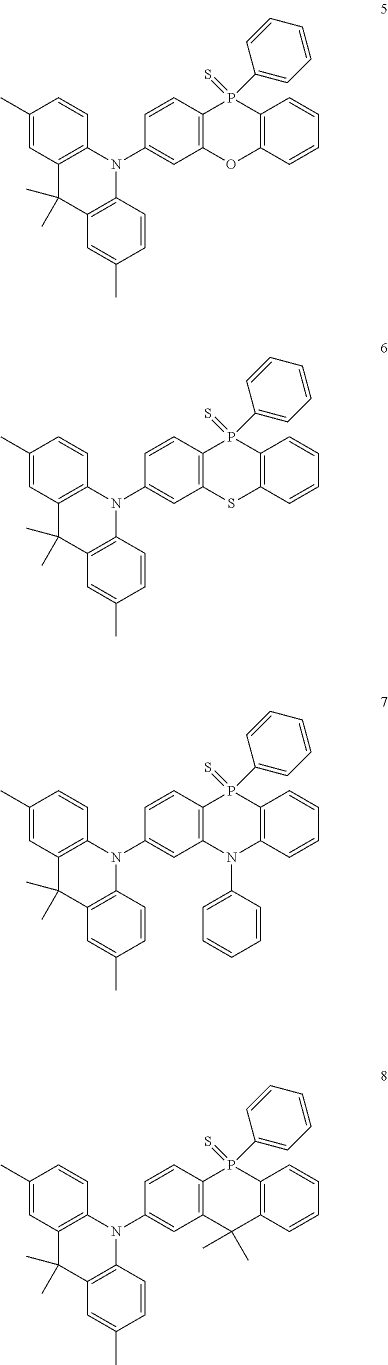 [SMILES: Cc1ccc2c(c1)C(C)(C)c1cc(C)ccc1N2c1ccc2c(c1)Oc1ccccc1P2(=S)c1ccccc1 ; Cc1ccc2c(c1)C(C)(C)c1cc(C)ccc1N2c1ccc2c(c1)Sc1ccccc1P2(=S)c1ccccc1 ; Cc1ccc2c(c1)C(C)(C)c1cc(C)ccc1N2c1ccc2c(c1)N(c1ccccc1)c1ccccc1P2(=S)c1ccccc1 ; Cc1ccc2c(c1)C(C)(C)c1cc(C)ccc1N2c1ccc2c(c1)C(C)(C)c1ccccc1P2(=S)c1ccccc1]

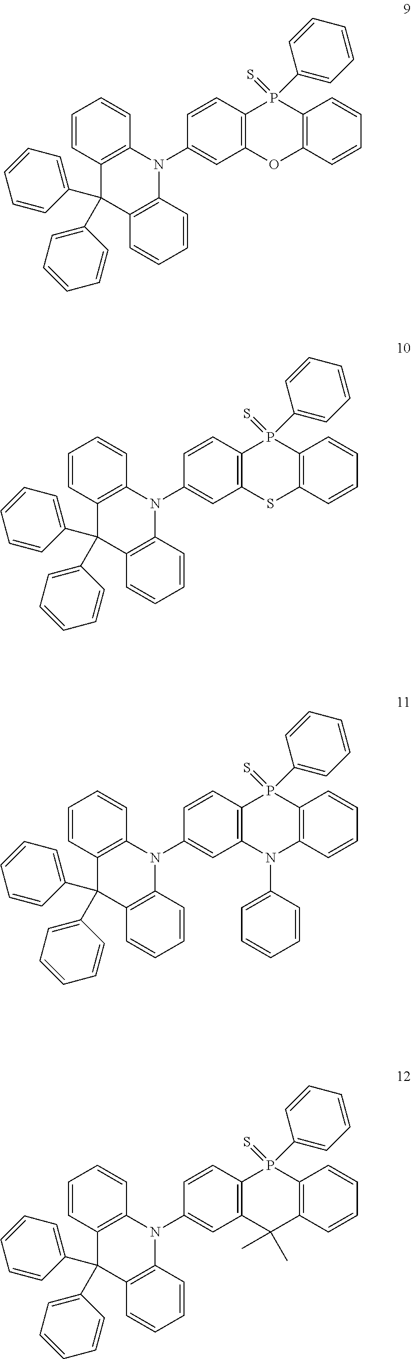 [SMILES: S=P1(c2ccccc2)c2ccccc2Oc2cc(N3c4ccccc4C(c4ccccc4)(c4ccccc4)c4ccccc43)ccc21 ; S=P1(c2ccccc2)c2ccccc2Sc2cc(N3c4ccccc4C(c4ccccc4)(c4ccccc4)c4ccccc43)ccc21 ; S=P1(c2ccccc2)c2ccccc2N(c2ccccc2)c2cc(N3c4ccccc4C(c4ccccc4)(c4ccccc4)c4ccccc43)ccc21 ; CC1(C)c2ccccc2P(=S)(c2ccccc2)c2ccc(N3c4ccccc4C(c4ccccc4)(c4ccccc4)c4ccccc43)cc21]

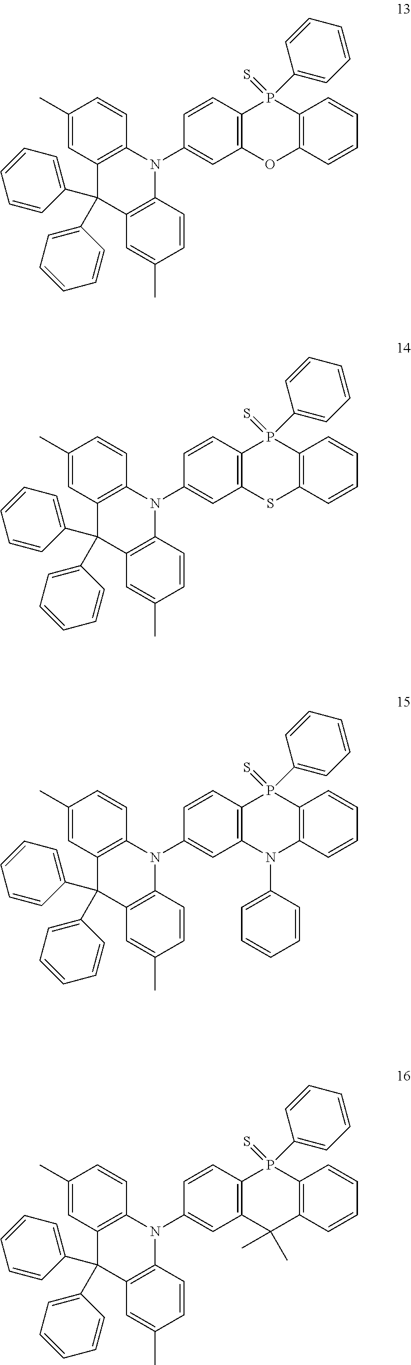 [SMILES: Cc1ccc2c(c1)C(c1ccccc1)(c1ccccc1)c1cc(C)ccc1N2c1ccc2c(c1)Oc1ccccc1P2(=S)c1ccccc1 ; Cc1ccc2c(c1)C(c1ccccc1)(c1ccccc1)c1cc(C)ccc1N2c1ccc2c(c1)Sc1ccccc1P2(=S)c1ccccc1 ; Cc1ccc2c(c1)C(c1ccccc1)(c1ccccc1)c1cc(C)ccc1N2c1ccc2c(c1)N(c1ccccc1)c1ccccc1P2(=S)c1ccccc1 ; Cc1ccc2c(c1)C(c1ccccc1)(c1ccccc1)c1cc(C)ccc1N2c1ccc2c(c1)C(C)(C)c1ccccc1P2(=S)c1ccccc1]

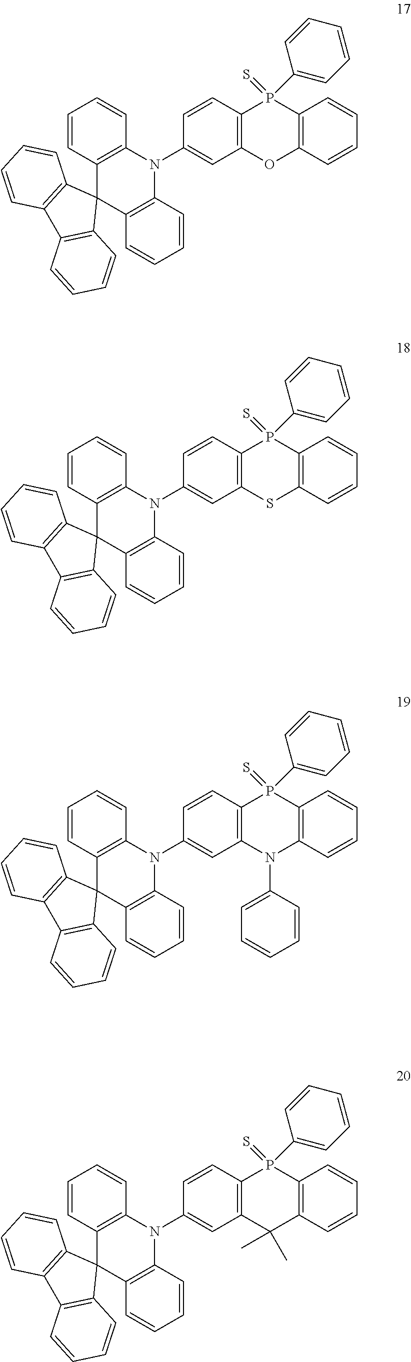 [SMILES: S=P1(c2ccccc2)c2ccccc2Oc2cc(N3c4ccccc4C4(c5ccccc5-c5ccccc54)c4ccccc43)ccc21 ; S=P1(c2ccccc2)c2ccccc2Sc2cc(N3c4ccccc4C4(c5ccccc5-c5ccccc54)c4ccccc43)ccc21 ; S=P1(c2ccccc2)c2ccccc2N(c2ccccc2)c2cc(N3c4ccccc4C4(c5ccccc5-c5ccccc54)c4ccccc43)ccc21 ; CC1(C)c2ccccc2P(=S)(c2ccccc2)c2ccc(N3c4ccccc4C4(c5ccccc5-c5ccccc54)c4ccccc43)cc21]

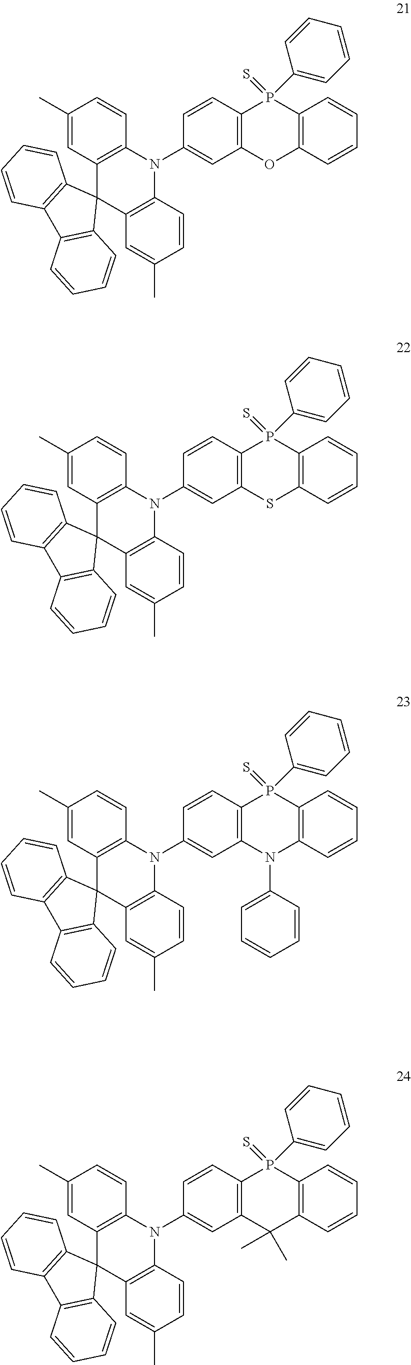 [SMILES: Cc1ccc2c(c1)C1(c3ccccc3-c3ccccc31)c1cc(C)ccc1N2c1ccc2c(c1)Oc1ccccc1P2(=S)c1ccccc1 ; Cc1ccc2c(c1)C1(c3ccccc3-c3ccccc31)c1cc(C)ccc1N2c1ccc2c(c1)Sc1ccccc1P2(=S)c1ccccc1 ; Cc1ccc2c(c1)C1(c3ccccc3-c3ccccc31)c1cc(C)ccc1N2c1ccc2c(c1)N(c1ccccc1)c1ccccc1P2(=S)c1ccccc1 ; Cc1ccc2c(c1)C1(c3ccccc3-c3ccccc31)c1cc(C)ccc1N2c1ccc2c(c1)C(C)(C)c1ccccc1P2(=S)c1ccccc1]

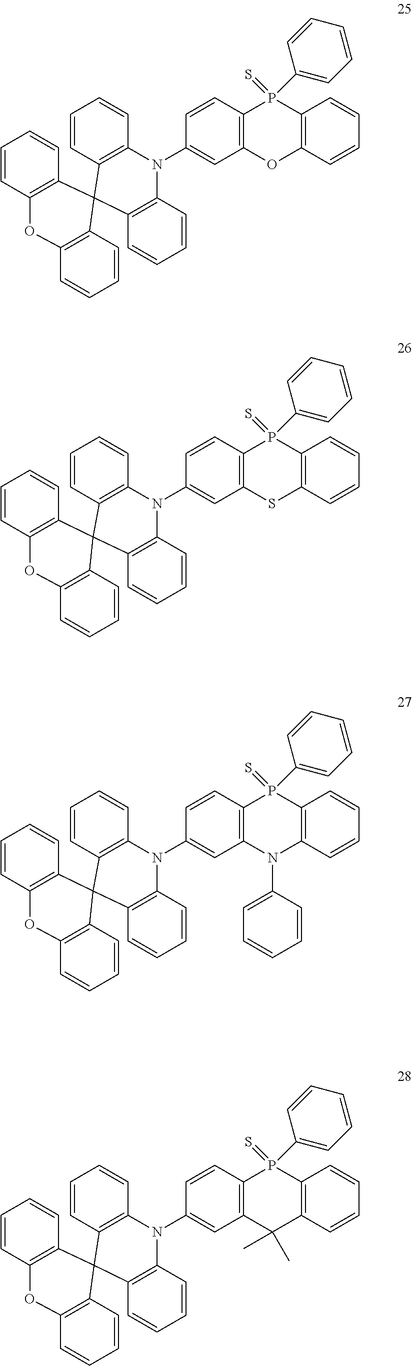 [SMILES: S=P1(c2ccccc2)c2ccccc2Oc2cc(N3c4ccccc4C4(c5ccccc5Oc5ccccc54)c4ccccc43)ccc21 ; S=P1(c2ccccc2)c2ccccc2Sc2cc(N3c4ccccc4C4(c5ccccc5Oc5ccccc54)c4ccccc43)ccc21 ; S=P1(c2ccccc2)c2ccccc2N(c2ccccc2)c2cc(N3c4ccccc4C4(c5ccccc5Oc5ccccc54)c4ccccc43)ccc21 ; CC1(C)c2ccccc2P(=S)(c2ccccc2)c2ccc(N3c4ccccc4C4(c5ccccc5Oc5ccccc54)c4ccccc43)cc21]

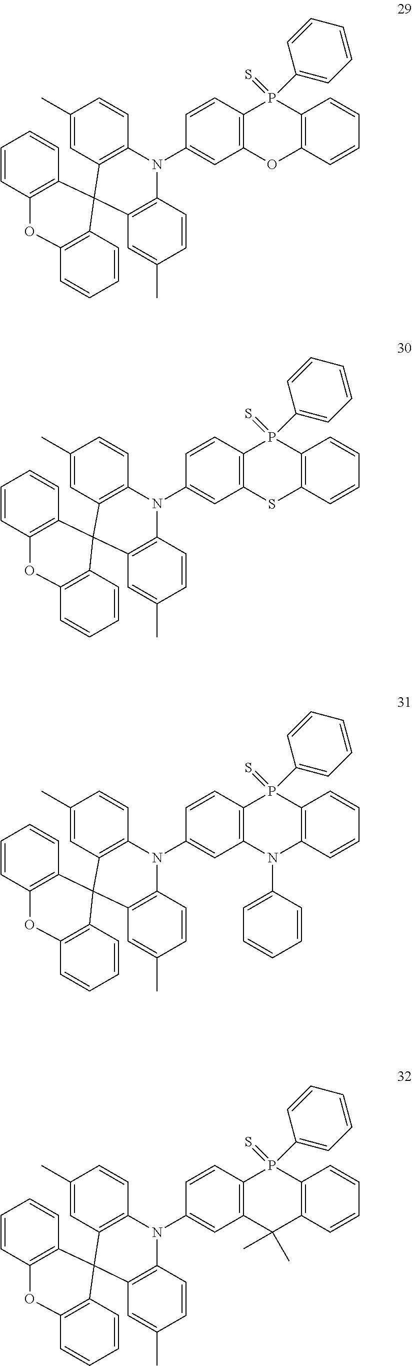 [SMILES: Cc1ccc2c(c1)C1(c3ccccc3Oc3ccccc31)c1cc(C)ccc1N2c1ccc2c(c1)Oc1ccccc1P2(=S)c1ccccc1 ; Cc1ccc2c(c1)C1(c3ccccc3Oc3ccccc31)c1cc(C)ccc1N2c1ccc2c(c1)Sc1ccccc1P2(=S)c1ccccc1 ; Cc1ccc2c(c1)C1(c3ccccc3Oc3ccccc31)c1cc(C)ccc1N2c1ccc2c(c1)N(c1ccccc1)c1ccccc1P2(=S)c1ccccc1 ; Cc1ccc2c(c1)C1(c3ccccc3Oc3ccccc31)c1cc(C)ccc1N2c1ccc2c(c1)C(C)(C)c1ccccc1P2(=S)c1ccccc1]

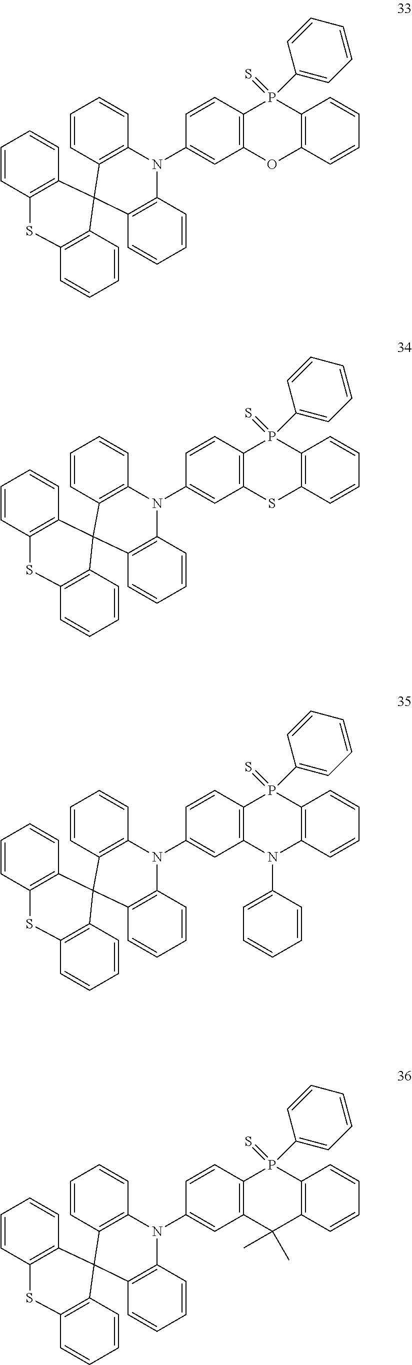 [SMILES: S=P1(c2ccccc2)c2ccccc2Oc2cc(N3c4ccccc4C4(c5ccccc5Sc5ccccc54)c4ccccc43)ccc21 ; S=P1(c2ccccc2)c2ccccc2Sc2cc(N3c4ccccc4C4(c5ccccc5Sc5ccccc54)c4ccccc43)ccc21 ; S=P1(c2ccccc2)c2ccccc2N(c2ccccc2)c2cc(N3c4ccccc4C4(c5ccccc5Sc5ccccc54)c4ccccc43)ccc21 ; CC1(C)c2ccccc2P(=S)(c2ccccc2)c2ccc(N3c4ccccc4C4(c5ccccc5Sc5ccccc54)c4ccccc43)cc21]

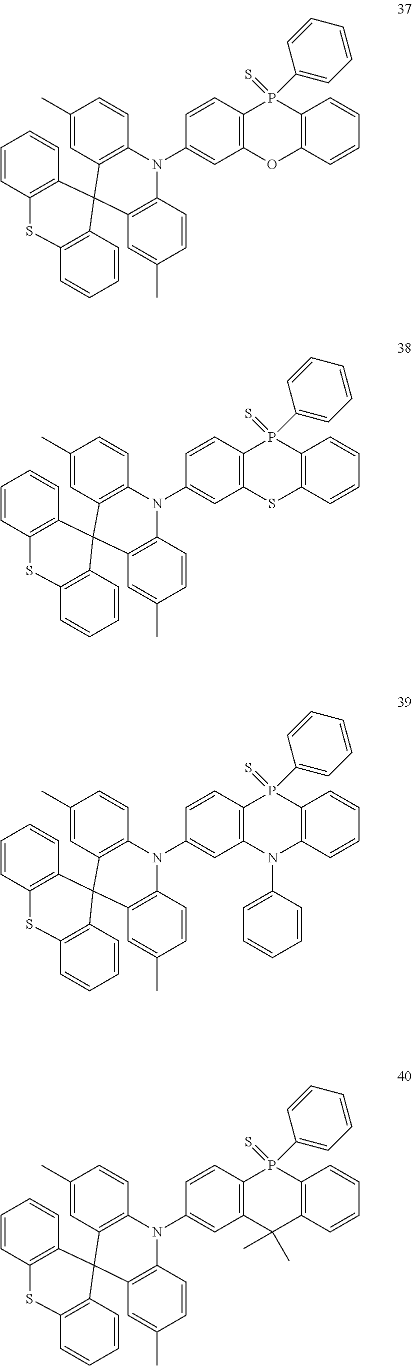 [SMILES: Cc1ccc2c(c1)C1(c3ccccc3Sc3ccccc31)c1cc(C)ccc1N2c1ccc2c(c1)Oc1ccccc1P2(=S)c1ccccc1 ; Cc1ccc2c(c1)C1(c3ccccc3Sc3ccccc31)c1cc(C)ccc1N2c1ccc2c(c1)Sc1ccccc1P2(=S)c1ccccc1 ; Cc1ccc2c(c1)C1(c3ccccc3Sc3ccccc31)c1cc(C)ccc1N2c1ccc2c(c1)N(c1ccccc1)c1ccccc1P2(=S)c1ccccc1 ; Cc1ccc2c(c1)C1(c3ccccc3Sc3ccccc31)c1cc(C)ccc1N2c1ccc2c(c1)C(C)(C)c1ccccc1P2(=S)c1ccccc1]

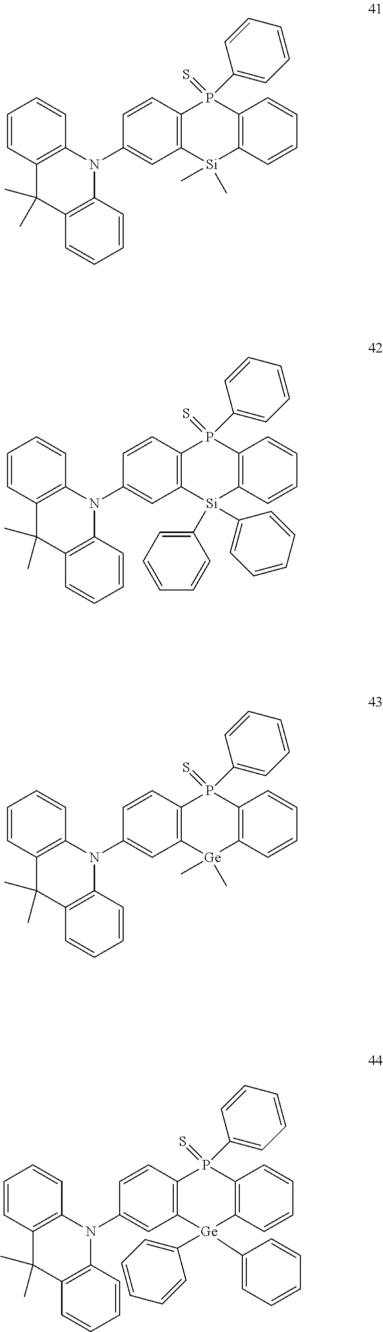

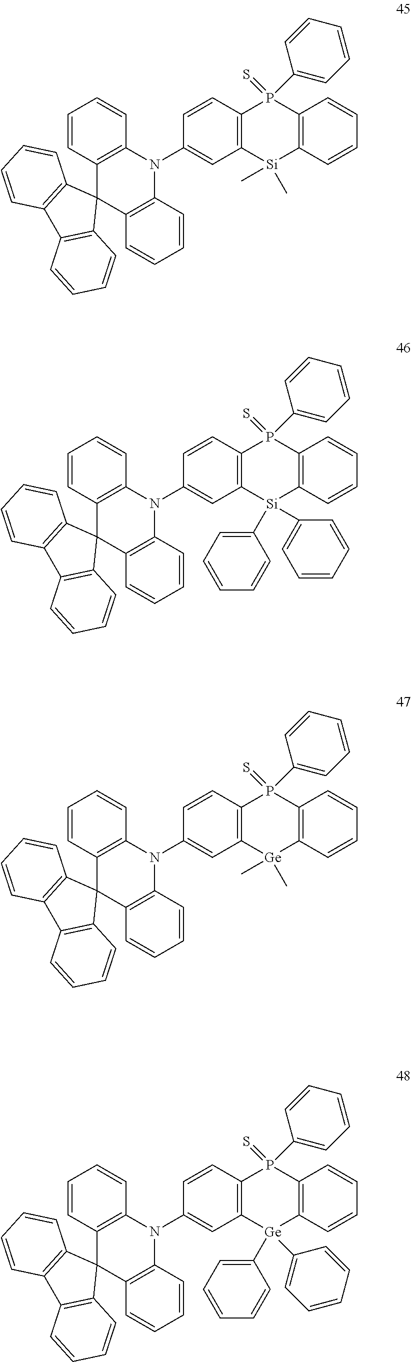

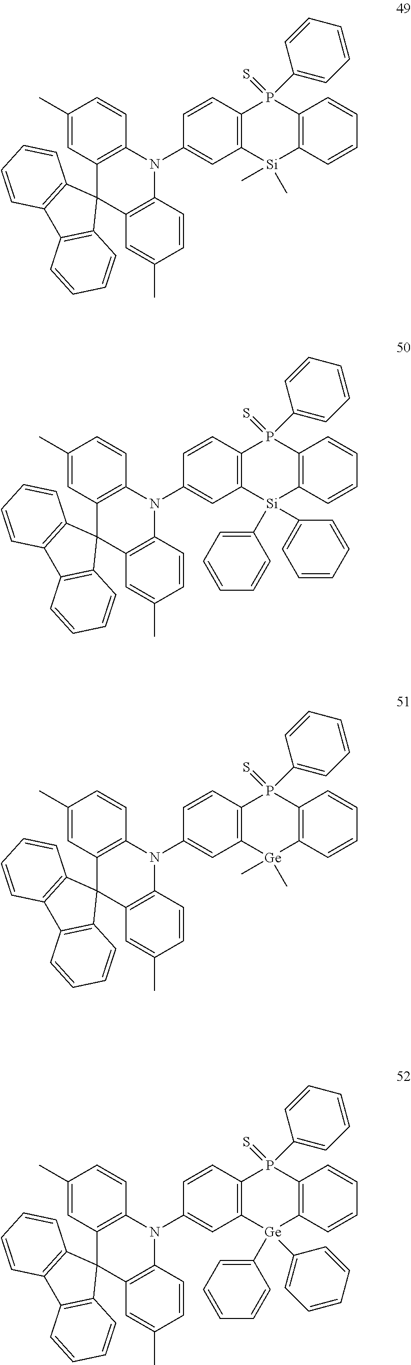

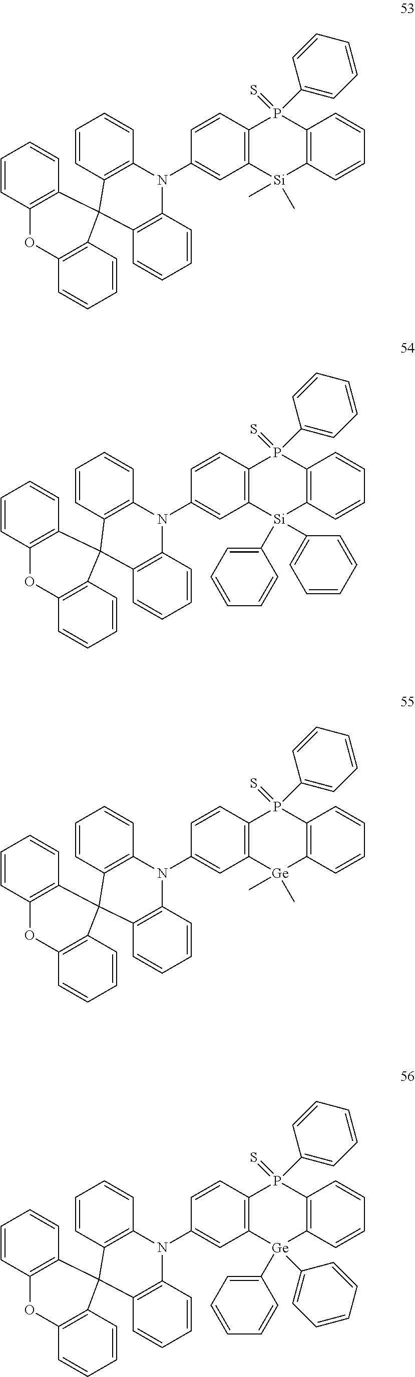

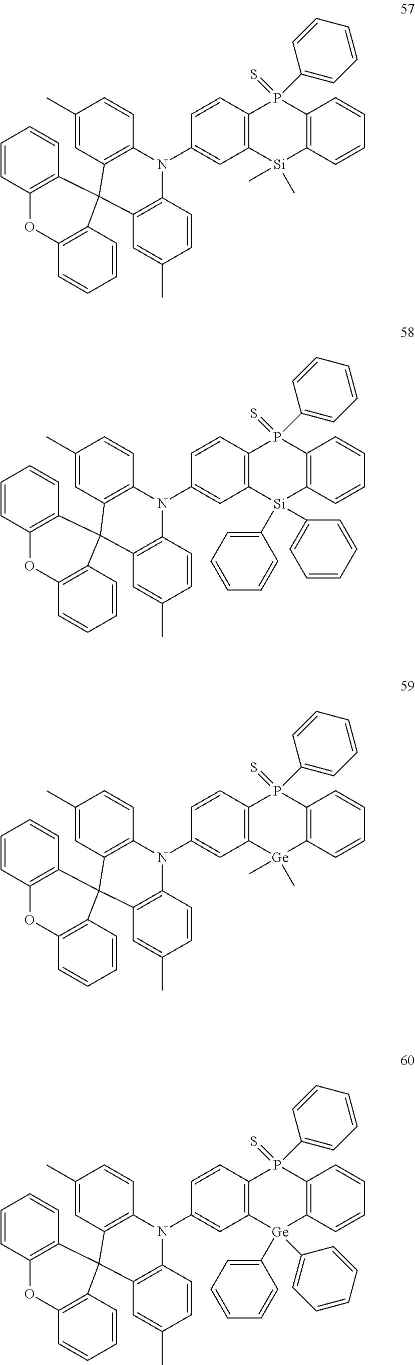

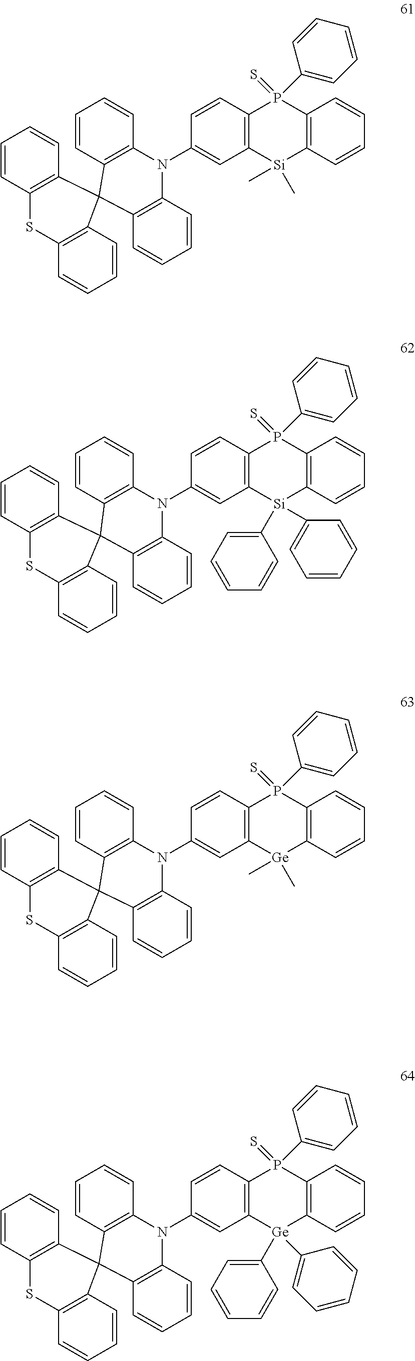

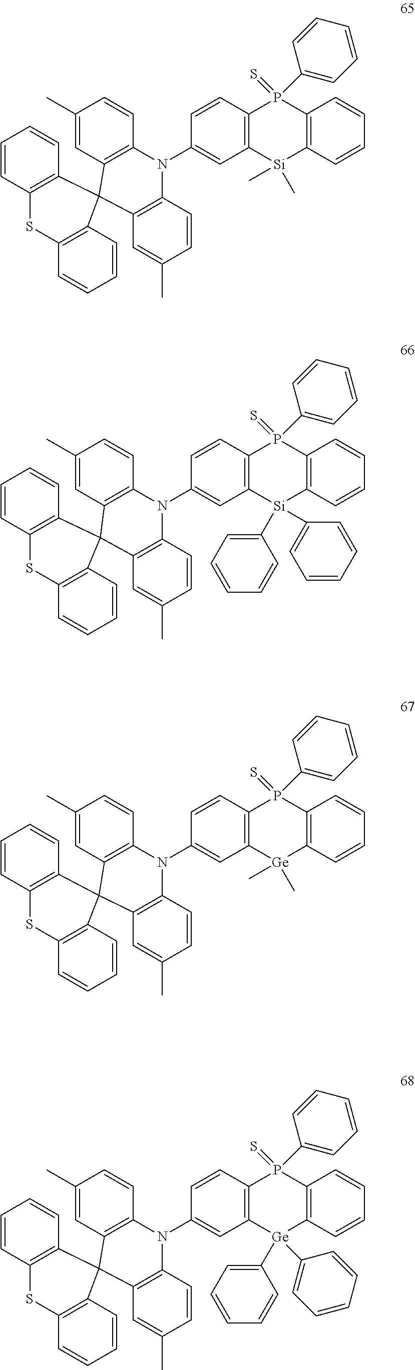

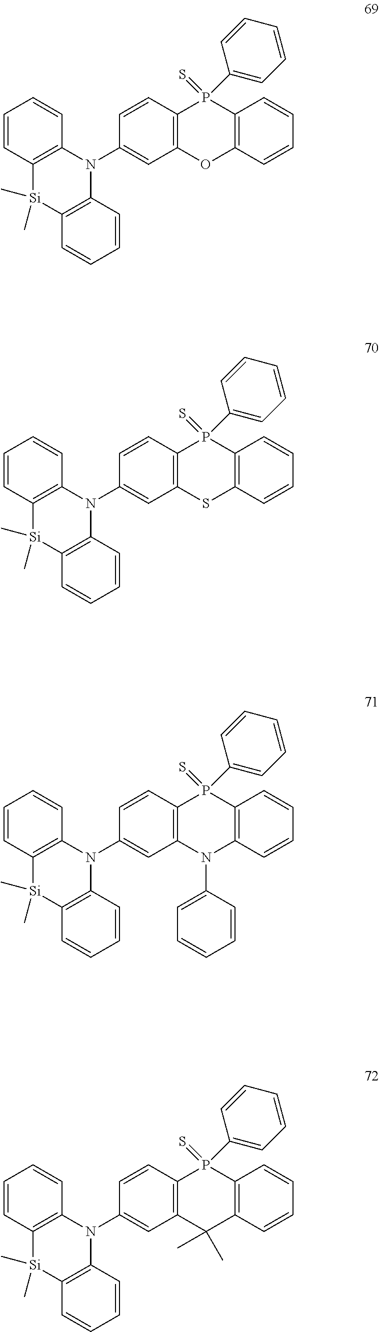 [SMILES: C[Si]1(C)c2ccccc2N(c2ccc3c(c2)Oc2ccccc2P3(=S)c2ccccc2)c2ccccc21 ; C[Si]1(C)c2ccccc2N(c2ccc3c(c2)Sc2ccccc2P3(=S)c2ccccc2)c2ccccc21 ; C[Si]1(C)c2ccccc2N(c2ccc3c(c2)N(c2ccccc2)c2ccccc2P3(=S)c2ccccc2)c2ccccc21 ; CC1(C)c2ccccc2P(=S)(c2ccccc2)c2ccc(N3c4ccccc4[Si](C)(C)c4ccccc43)cc21]

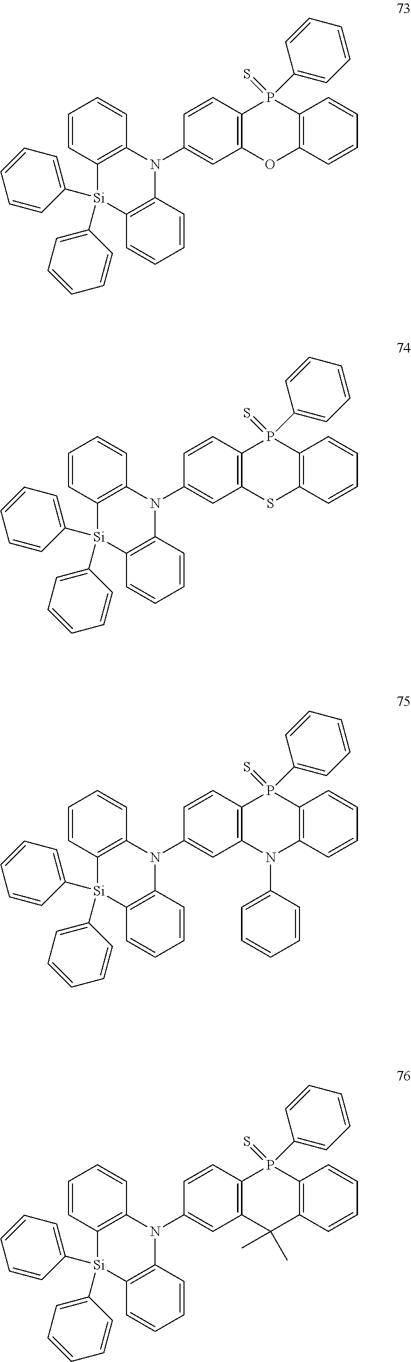 [SMILES: S=P1(c2ccccc2)c2ccccc2Oc2cc(N3c4ccccc4[Si](c4ccccc4)(c4ccccc4)c4ccccc43)ccc21 ; S=P1(c2ccccc2)c2ccccc2Sc2cc(N3c4ccccc4[Si](c4ccccc4)(c4ccccc4)c4ccccc43)ccc21 ; S=P1(c2ccccc2)c2ccccc2N(c2ccccc2)c2cc(N3c4ccccc4[Si](c4ccccc4)(c4ccccc4)c4ccccc43)ccc21 ; CC1(C)c2ccccc2P(=S)(c2ccccc2)c2ccc(N3c4ccccc4[Si](c4ccccc4)(c4ccccc4)c4ccccc43)cc21]

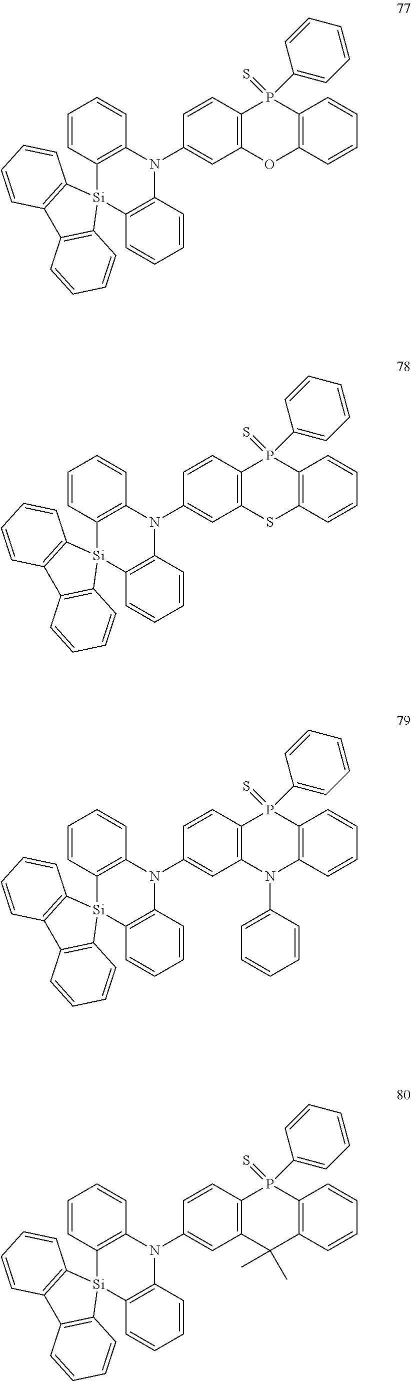 [SMILES: S=P1(c2ccccc2)c2ccccc2Oc2cc(N3c4ccccc4[Si]4(c5ccccc5-c5ccccc54)c4ccccc43)ccc21 ; S=P1(c2ccccc2)c2ccccc2Sc2cc(N3c4ccccc4[Si]4(c5ccccc5-c5ccccc54)c4ccccc43)ccc21 ; S=P1(c2ccccc2)c2ccccc2N(c2ccccc2)c2cc(N3c4ccccc4[Si]4(c5ccccc5-c5ccccc54)c4ccccc43)ccc21 ; CC1(C)c2ccccc2P(=S)(c2ccccc2)c2ccc(N3c4ccccc4[Si]4(c5ccccc5-c5ccccc54)c4ccccc43)cc21]

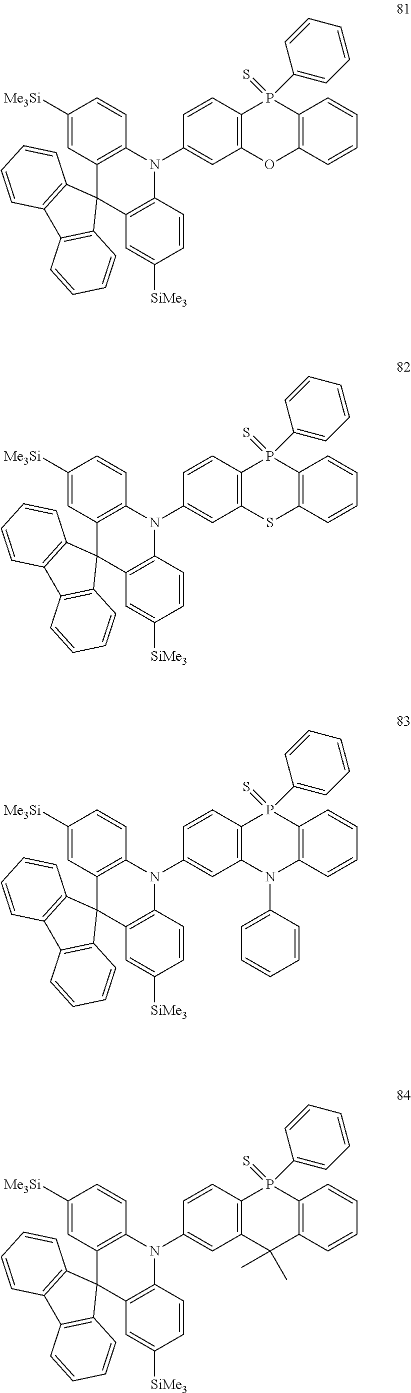 [SMILES: C[Si](C)(C)c1ccc2c(c1)C1(c3ccccc3-c3ccccc31)c1cc([Si](C)(C)C)ccc1N2c1ccc2c(c1)Oc1ccccc1P2(=S)c1ccccc1 ; C[Si](C)(C)c1ccc2c(c1)C1(c3ccccc3-c3ccccc31)c1cc([Si](C)(C)C)ccc1N2c1ccc2c(c1)Sc1ccccc1P2(=S)c1ccccc1 ; C[Si](C)(C)c1ccc2c(c1)C1(c3ccccc3-c3ccccc31)c1cc([Si](C)(C)C)ccc1N2c1ccc2c(c1)N(c1ccccc1)c1ccccc1P2(=S)c1ccccc1 ; CC1(C)c2ccccc2P(=S)(c2ccccc2)c2ccc(N3c4ccc([Si](C)(C)C)cc4C4(c5ccccc5-c5ccccc54)c4cc([Si](C)(C)C)ccc43)cc21]

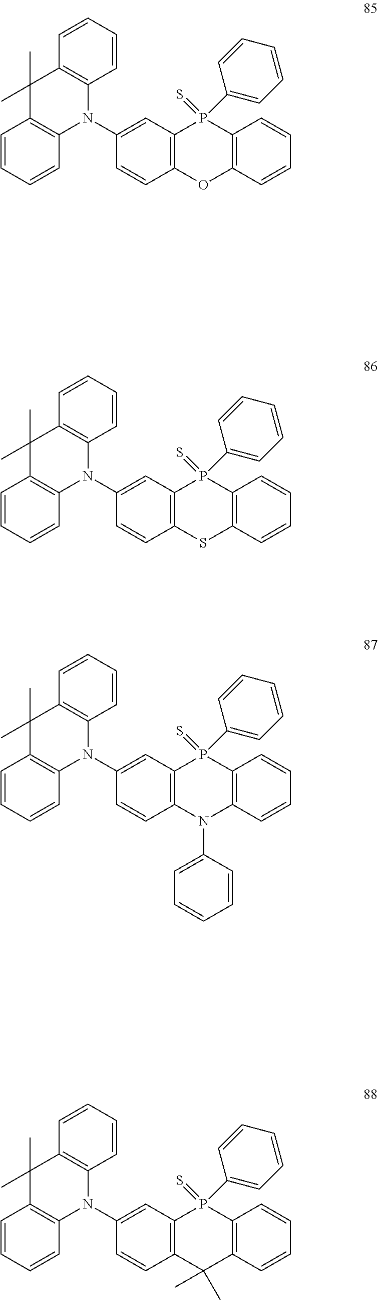 [SMILES: CC1(C)c2ccccc2N(c2ccc3c(c2)P(=S)(c2ccccc2)c2ccccc2O3)c2ccccc21 ; CC1(C)c2ccccc2N(c2ccc3c(c2)P(=S)(c2ccccc2)c2ccccc2S3)c2ccccc21 ; CC1(C)c2ccccc2N(c2ccc3c(c2)P(=S)(c2ccccc2)c2ccccc2N3c2ccccc2)c2ccccc21 ; CC1(C)c2ccccc2N(c2ccc3c(c2)P(=S)(c2ccccc2)c2ccccc2C3(C)C)c2ccccc21]

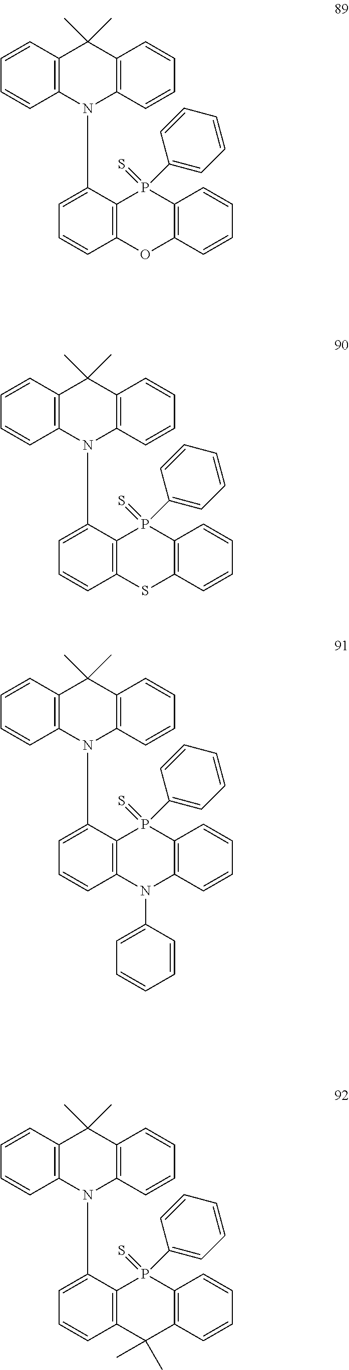 [SMILES: CC1(C)c2ccccc2N(c2cccc3c2P(=S)(c2ccccc2)c2ccccc2O3)c2ccccc21 ; CC1(C)c2ccccc2N(c2cccc3c2P(=S)(c2ccccc2)c2ccccc2S3)c2ccccc21 ; CC1(C)c2ccccc2N(c2cccc3c2P(=S)(c2ccccc2)c2ccccc2N3c2ccccc2)c2ccccc21 ; CC1(C)c2ccccc2N(c2cccc3c2P(=S)(c2ccccc2)c2ccccc2C3(C)C)c2ccccc21]

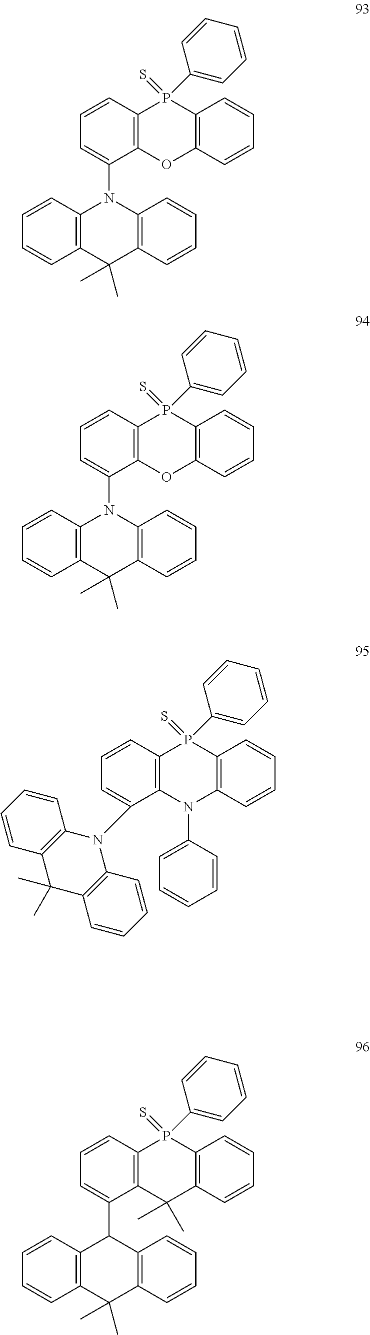 [SMILES: CC1(C)c2ccccc2N(c2cccc3c2Oc2ccccc2P3(=S)c2ccccc2)c2ccccc21 ; CC1(C)c2ccccc2N(c2cccc3c2Oc2ccccc2P3(=S)c2ccccc2)c2ccccc21 ; CC1(C)c2ccccc2N(c2cccc3c2N(c2ccccc2)c2ccccc2P3(=S)c2ccccc2)c2ccccc21 ; CC1(C)c2ccccc2C(c2cccc3c2C(C)(C)c2ccccc2P3(=S)c2ccccc2)c2ccccc21]

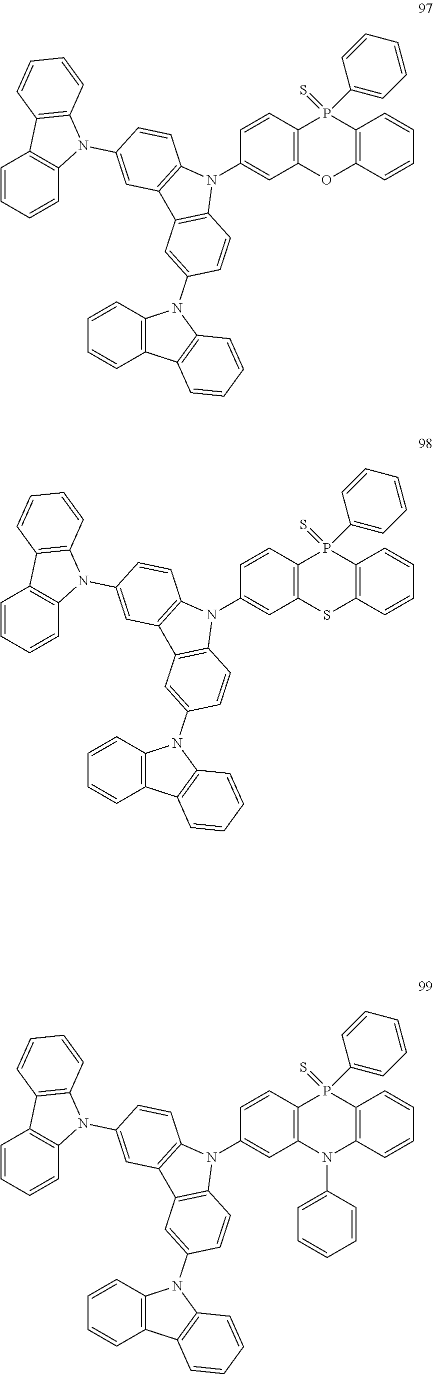 [SMILES: S=P1(c2ccccc2)c2ccccc2Oc2cc(-n3c4ccc(-n5c6ccccc6c6ccccc65)cc4c4cc(-n5c6ccccc6c6ccccc65)ccc43)ccc21 ; S=P1(c2ccccc2)c2ccccc2Sc2cc(-n3c4ccc(-n5c6ccccc6c6ccccc65)cc4c4cc(-n5c6ccccc6c6ccccc65)ccc43)ccc21 ; S=P1(c2ccccc2)c2ccccc2N(c2ccccc2)c2cc(-n3c4ccc(-n5c6ccccc6c6ccccc65)cc4c4cc(-n5c6ccccc6c6ccccc65)ccc43)ccc21]

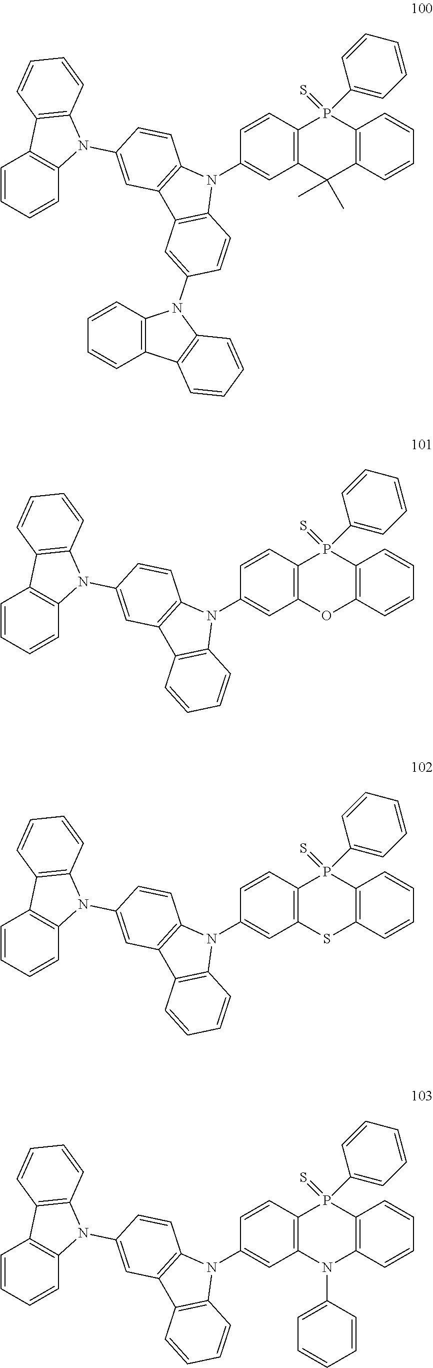 [SMILES: CC1(C)c2ccccc2P(=S)(c2ccccc2)c2ccc(-n3c4ccc(-n5c6ccccc6c6ccccc65)cc4c4cc(-n5c6ccccc6c6ccccc65)ccc43)cc21 ; S=P1(c2ccccc2)c2ccccc2Oc2cc(-n3c4ccccc4c4cc(-n5c6ccccc6c6ccccc65)ccc43)ccc21 ; S=P1(c2ccccc2)c2ccccc2Sc2cc(-n3c4ccccc4c4cc(-n5c6ccccc6c6ccccc65)ccc43)ccc21 ; S=P1(c2ccccc2)c2ccccc2N(c2ccccc2)c2cc(-n3c4ccccc4c4cc(-n5c6ccccc6c6ccccc65)ccc43)ccc21]

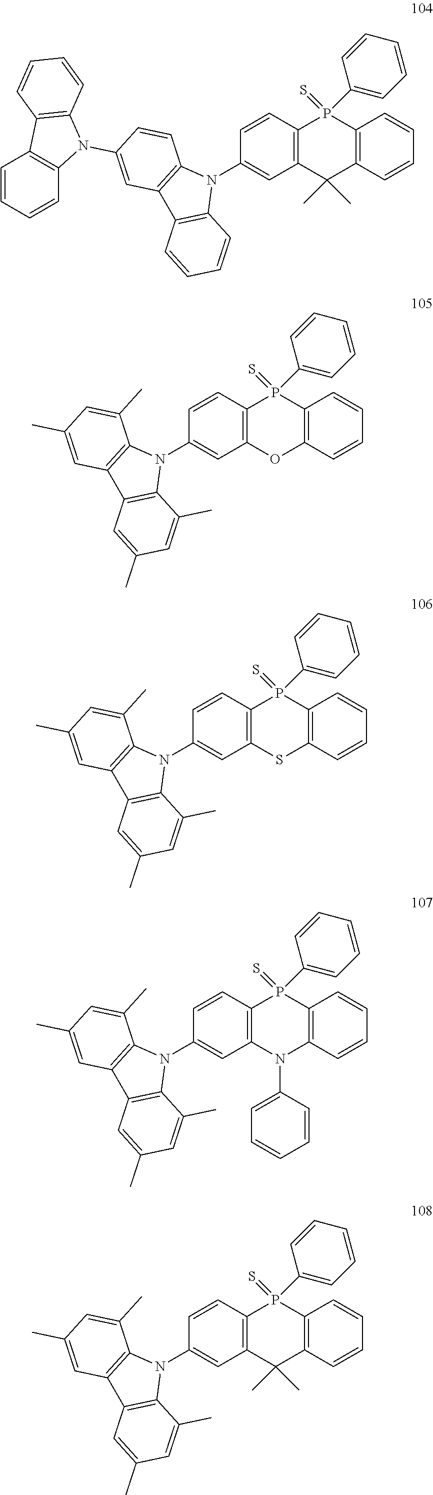 [SMILES: CC1(C)c2ccccc2P(=S)(c2ccccc2)c2ccc(-n3c4ccccc4c4cc(-n5c6ccccc6c6ccccc65)ccc43)cc21 ; Cc1cc(C)c2c(c1)c1cc(C)cc(C)c1n2-c1ccc2c(c1)Oc1ccccc1P2(=S)c1ccccc1 ; Cc1cc(C)c2c(c1)c1cc(C)cc(C)c1n2-c1ccc2c(c1)Sc1ccccc1P2(=S)c1ccccc1 ; Cc1cc(C)c2c(c1)c1cc(C)cc(C)c1n2-c1ccc2c(c1)N(c1ccccc1)c1ccccc1P2(=S)c1ccccc1 ; Cc1cc(C)c2c(c1)c1cc(C)cc(C)c1n2-c1ccc2c(c1)C(C)(C)c1ccccc1P2(=S)c1ccccc1]

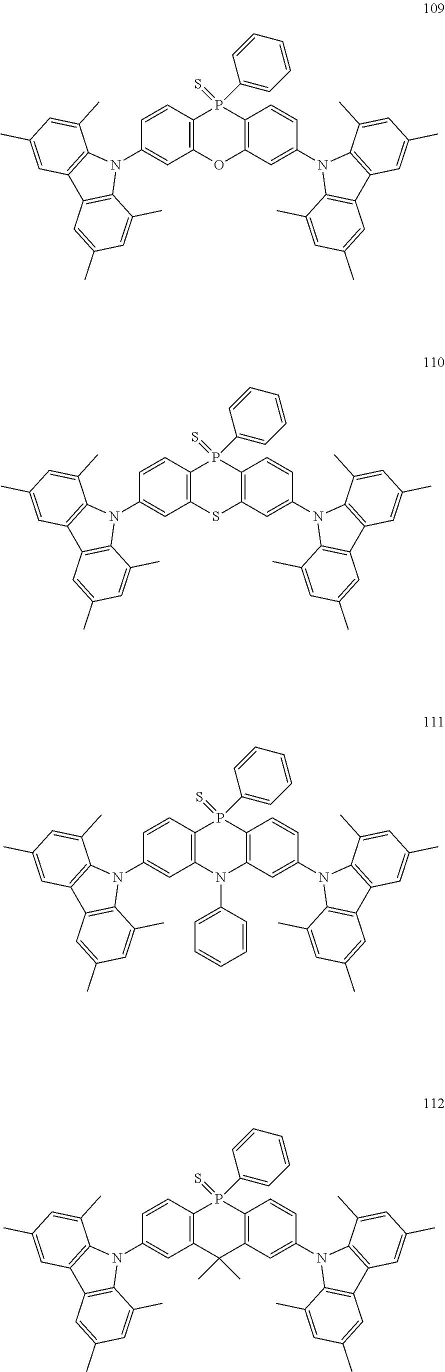

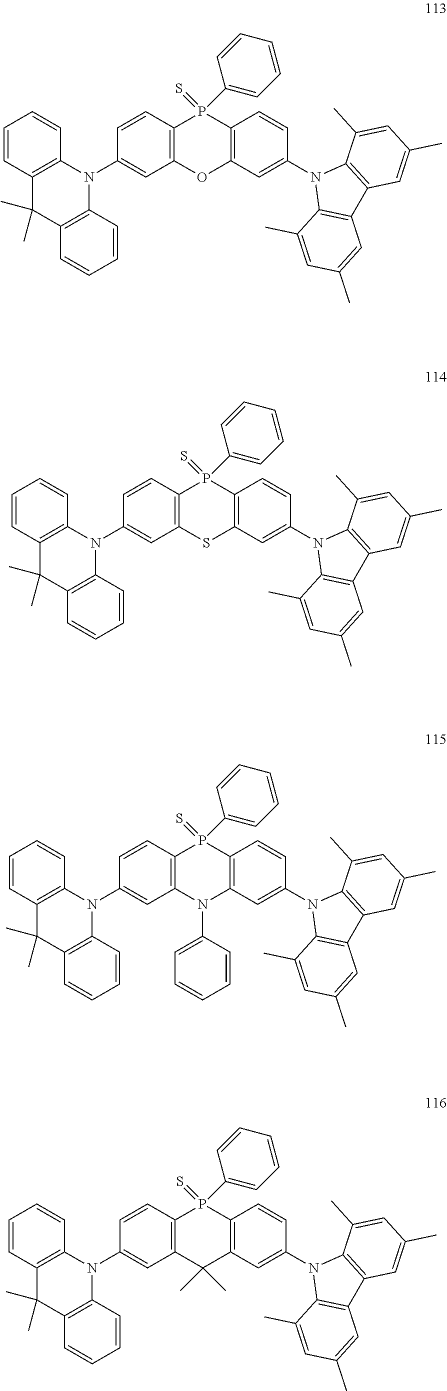

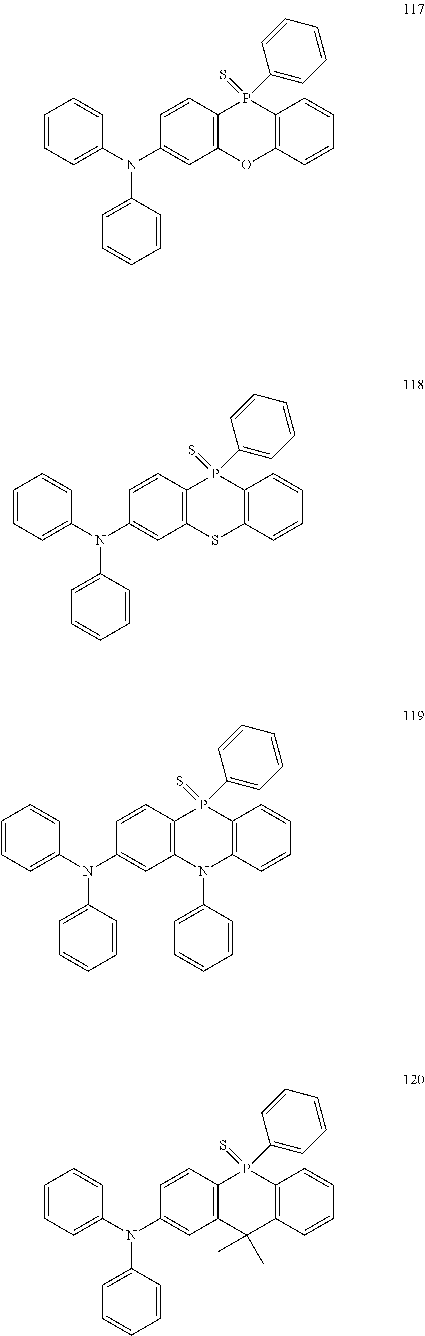 [SMILES: S=P1(c2ccccc2)c2ccccc2Oc2cc(N(c3ccccc3)c3ccccc3)ccc21 ; S=P1(c2ccccc2)c2ccccc2Sc2cc(N(c3ccccc3)c3ccccc3)ccc21 ; S=P1(c2ccccc2)c2ccccc2N(c2ccccc2)c2cc(N(c3ccccc3)c3ccccc3)ccc21 ; CC1(C)c2ccccc2P(=S)(c2ccccc2)c2ccc(N(c3ccccc3)c3ccccc3)cc21]

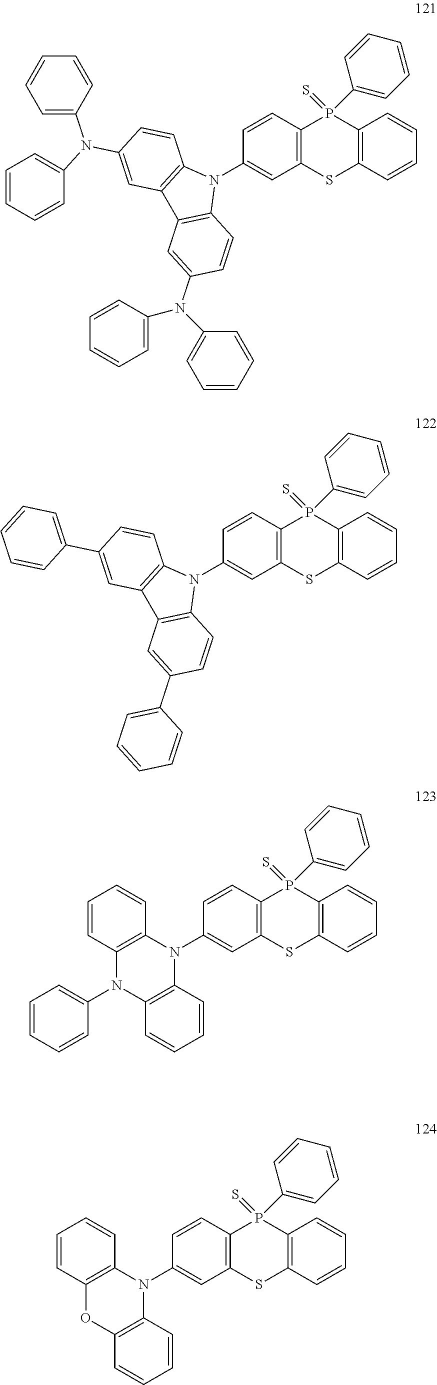 [SMILES: S=P1(c2ccccc2)c2ccccc2Sc2cc(-n3c4ccc(N(c5ccccc5)c5ccccc5)cc4c4cc(N(c5ccccc5)c5ccccc5)ccc43)ccc21 ; S=P1(c2ccccc2)c2ccccc2Sc2cc(-n3c4ccc(-c5ccccc5)cc4c4cc(-c5ccccc5)ccc43)ccc21 ; S=P1(c2ccccc2)c2ccccc2Sc2cc(N3c4ccccc4N(c4ccccc4)c4ccccc43)ccc21 ; S=P1(c2ccccc2)c2ccccc2Sc2cc(N3c4ccccc4Oc4ccccc43)ccc21]

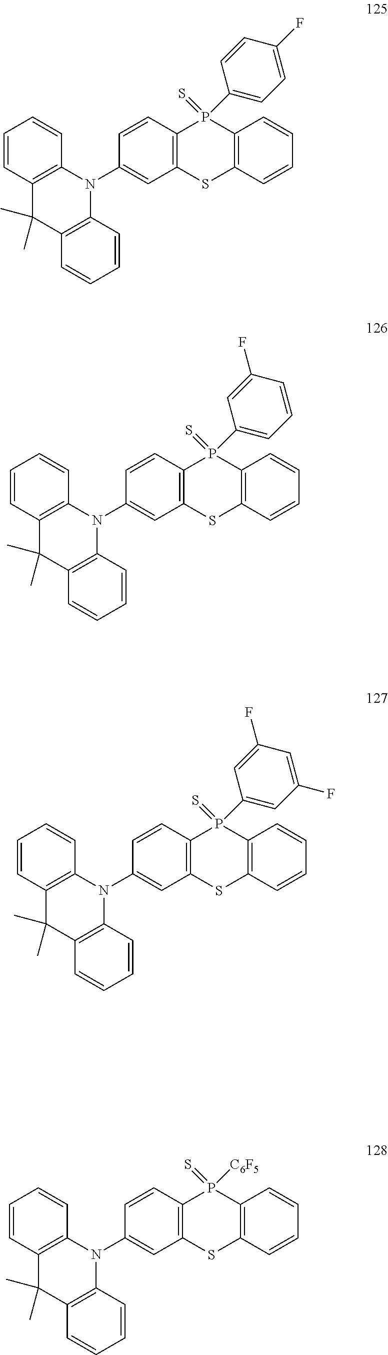

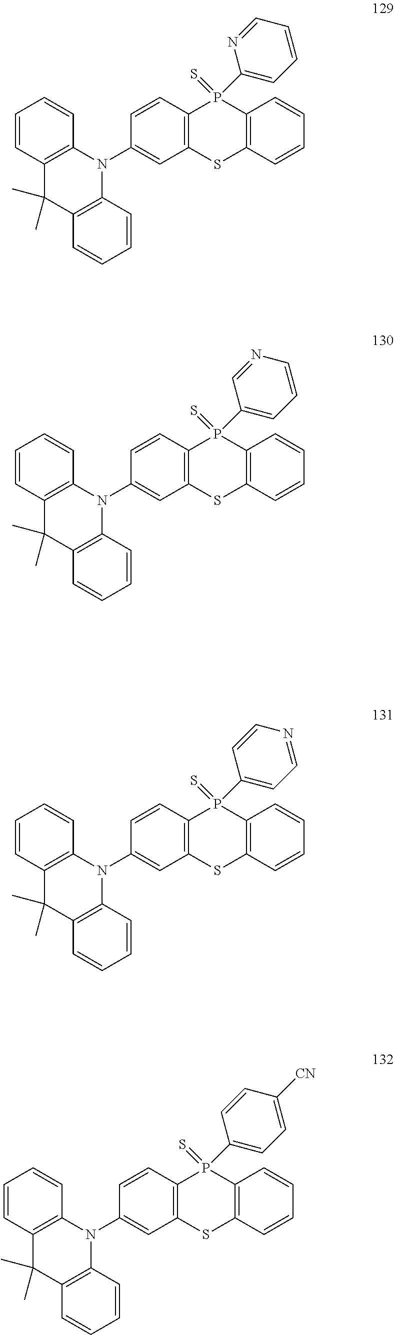 [SMILES: CC1(C)c2ccccc2N(c2ccc3c(c2)Sc2ccccc2P3(=S)c2ccccn2)c2ccccc21 ; CC1(C)c2ccccc2N(c2ccc3c(c2)Sc2ccccc2P3(=S)c2cccnc2)c2ccccc21 ; CC1(C)c2ccccc2N(c2ccc3c(c2)Sc2ccccc2P3(=S)c2ccncc2)c2ccccc21 ; CC1(C)c2ccccc2N(c2ccc3c(c2)Sc2ccccc2P3(=S)c2ccc(C#N)cc2)c2ccccc21]

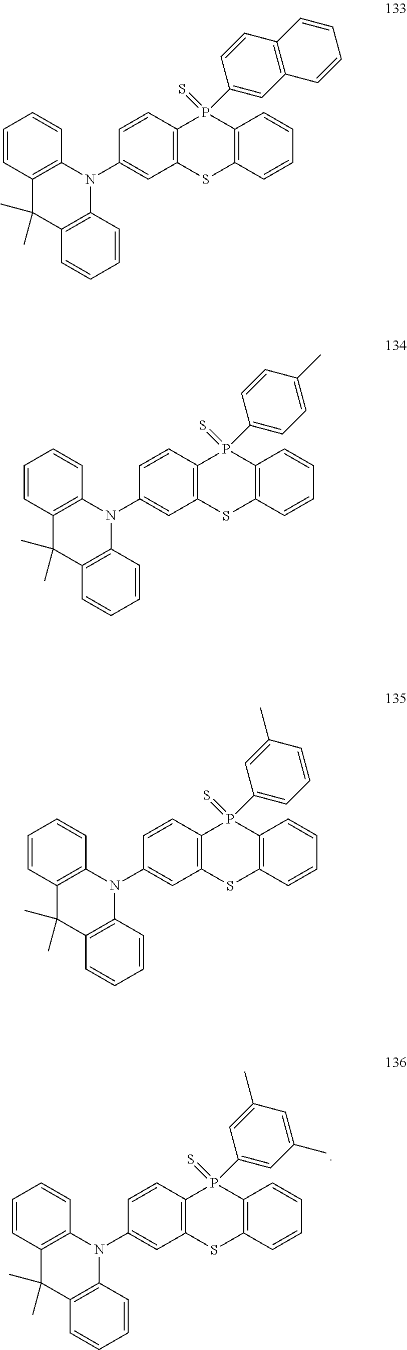

10. An organic electroluminescence device, comprising:
a first electrode;
a hole transport region on the first electrode;
an emission layer on the hole transport region;
an electron transport region on the emission layer; and
a second electrode on the electron transport region,
wherein the emission layer includes a phosphorus-containing compound represented by the following Formula 1: 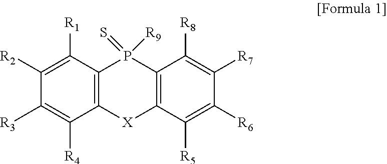
wherein, in Formula 1,
X is O, S, NRₐ, CR_{b}R_{c}, SiR_{d}Rₑ, or GeR_{f}R_{g},
R₁ to R₈ are each independently a hydrogen atom, a deuterium atom, a halogen atom, a substituted or unsubstituted silyl group, a substituted or unsubstituted amino group, a substituted or unsubstituted alkyl group having 1 to 20 carbon atoms, a substituted or unsubstituted aryl group having 6 to 30 ring carbon atoms, or a substituted or unsubstituted heteroaryl group having 4 to 30 ring carbon atoms,
R₉ is a substituted or unsubstituted alkyl group having 1 to 20 carbon atoms, a substituted or unsubstituted aryl group having 6 to 30 ring carbon atoms, or a substituted or unsubstituted heteroaryl group having 4 to 30 ring carbon atoms,
Rₐ to R_{g} are each independently a hydrogen atom, a deuterium atom, a halogen atom, a substituted or unsubstituted silyl group, a substituted or unsubstituted alkyl group having 1 to 20 carbon atoms, a substituted or unsubstituted fluorenyl group, a substituted or unsubstituted aryl group having 6 to 30 ring carbon atoms, or a substituted or unsubstituted heteroaryl group having 4 to 30 ring carbon atoms,
Rₐ to R_{g} are separate or combined with an adjacent group to form a ring, and
at least one of R₁ to R₈ is a group represented by the following Formula 2: 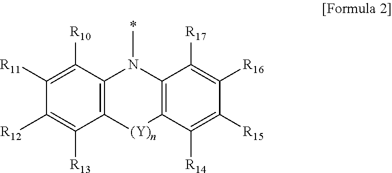
wherein, in Formula 2,
n is 0 or 1,
Y is direct linkage, O, S, CRₕRᵢ, SiRⱼRₖ, or GeRₗRₘ,
R₁₀ to R₁₇ are each independently a hydrogen atom, a deuterium atom, a halogen atom, a substituted or unsubstituted silyl group, a substituted or unsubstituted amino group, a substituted or unsubstituted alkyl group having 1 to 20 carbon atoms, a substituted or unsubstituted aryl group having 6 to 30 ring carbon atoms, or a substituted or unsubstituted heteroaryl group having 4 to 30 ring carbon atoms,
Rₕ to Rₘ are each independently a hydrogen atom, a deuterium atom, a halogen atom, a substituted or unsubstituted silyl group, a substituted or unsubstituted alkyl group having 1 to 20 carbon atoms, a substituted or unsubstituted fluorenyl group, a substituted or unsubstituted aryl group having 6 to 30 ring carbon atoms, or a substituted or unsubstituted heteroaryl group having 4 to 30 ring carbon atoms, and
Rₕ to Rₘ are separate or combined with an adjacent group to form a ring.

11. The organic electroluminescence device as claimed in claim 10, wherein the phosphorus-containing compound is a thermally activated delayed fluorescence material.

12. The organic electroluminescence device as claimed in claim 10, wherein the compound represented by Formula 1 is represented by the following Formula 3: 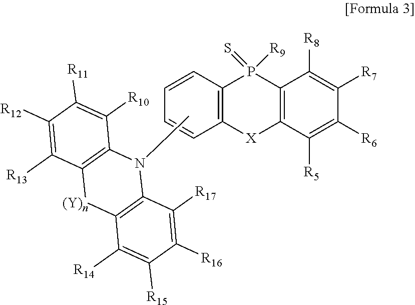
wherein, in Formula 3, R₅ to R₁₇, X, Y and n are defined the same as those of Formulae 1 and 2.

13. The organic electroluminescence device as claimed in claim 10, wherein R₉ is a substituted or unsubstituted phenyl group, a substituted or unsubstituted pyridyl group, or a substituted or unsubstituted naphthyl group.

14. The organic electroluminescence device as claimed in claim 10, wherein the group represented by Formula 2 is a group represented by one of the following Formulae 2-1 to 2-9: 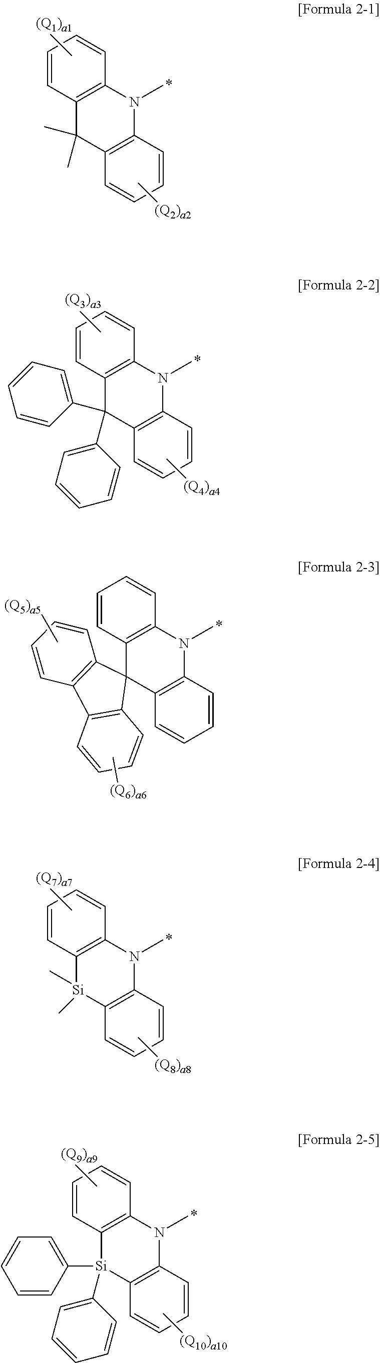 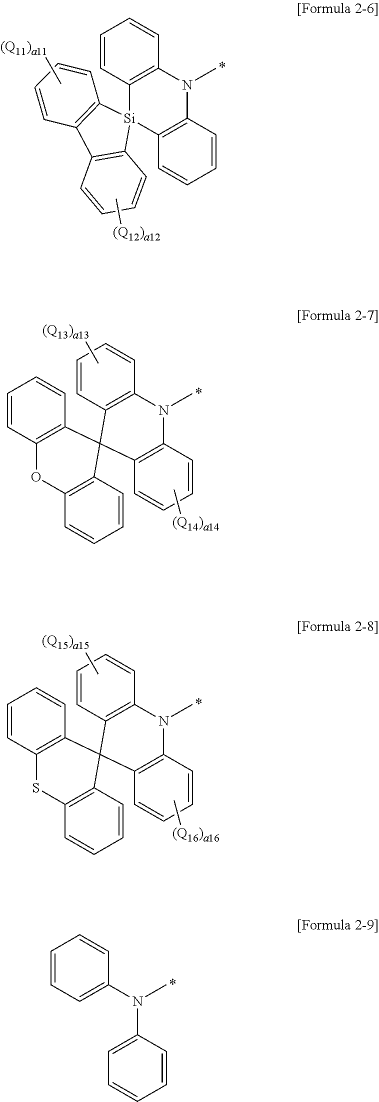
wherein, in Formulae 2-1 to 2-9,
Q₁ to Q₁₆ are each independently a hydrogen atom, a deuterium atom, a halogen atom, a substituted or unsubstituted silyl group, or a substituted or unsubstituted alkyl group having 1 to 20 carbon atoms, and
a₁ to a₁₆ are each independently an integer of 0 to 4.

15. The organic electroluminescence device as claimed in claim 10, wherein the phosphorus-containing compound represented by Formula 1 is a compound of the following Compound Group 1: 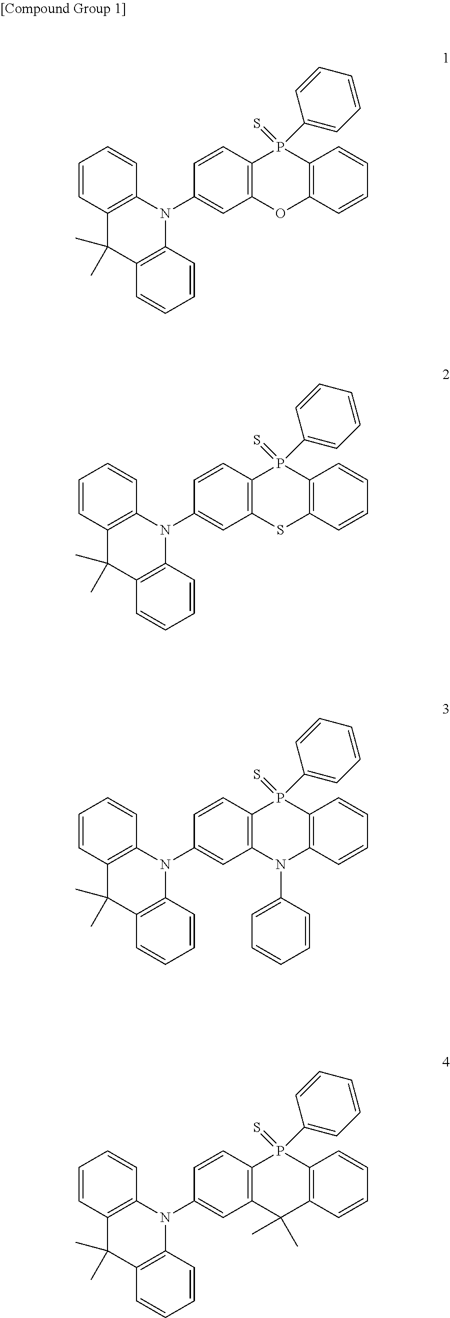 [SMILES: CC1(C)c2ccccc2N(c2ccc3c(c2)Oc2ccccc2P3(=S)c2ccccc2)c2ccccc21 ; CC1(C)c2ccccc2N(c2ccc3c(c2)Sc2ccccc2P3(=S)c2ccccc2)c2ccccc21 ; CC1(C)c2ccccc2N(c2ccc3c(c2)N(c2ccccc2)c2ccccc2P3(=S)c2ccccc2)c2ccccc21 ; CC1(C)c2ccccc2N(c2ccc3c(c2)C(C)(C)c2ccccc2P3(=S)c2ccccc2)c2ccccc21] 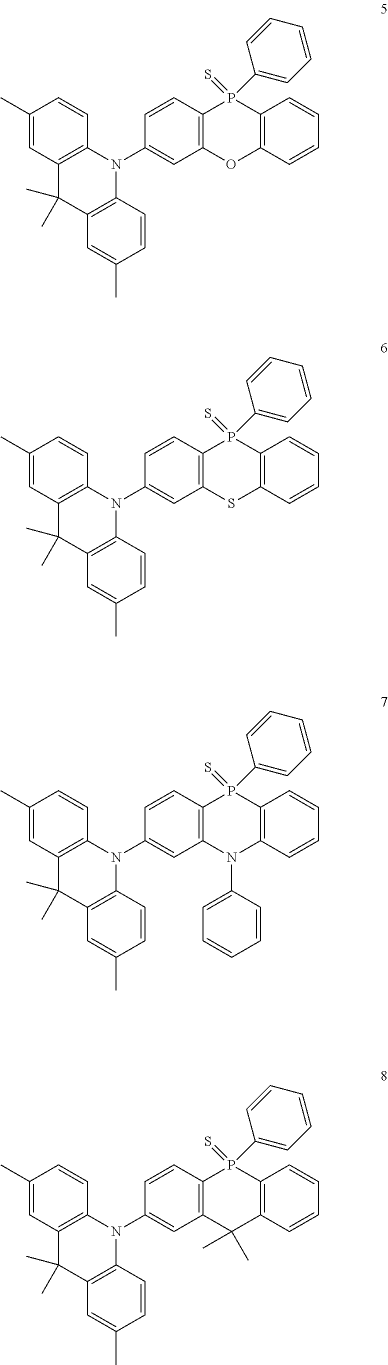 [SMILES: Cc1ccc2c(c1)C(C)(C)c1cc(C)ccc1N2c1ccc2c(c1)Oc1ccccc1P2(=S)c1ccccc1 ; Cc1ccc2c(c1)C(C)(C)c1cc(C)ccc1N2c1ccc2c(c1)Sc1ccccc1P2(=S)c1ccccc1 ; Cc1ccc2c(c1)C(C)(C)c1cc(C)ccc1N2c1ccc2c(c1)N(c1ccccc1)c1ccccc1P2(=S)c1ccccc1 ; Cc1ccc2c(c1)C(C)(C)c1cc(C)ccc1N2c1ccc2c(c1)C(C)(C)c1ccccc1P2(=S)c1ccccc1] 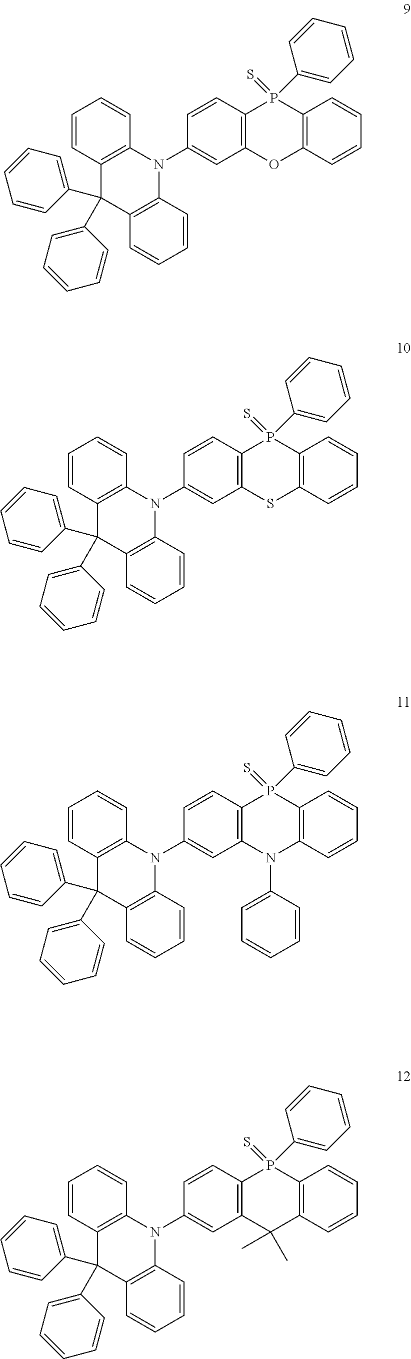 [SMILES: S=P1(c2ccccc2)c2ccccc2Oc2cc(N3c4ccccc4C(c4ccccc4)(c4ccccc4)c4ccccc43)ccc21 ; S=P1(c2ccccc2)c2ccccc2Sc2cc(N3c4ccccc4C(c4ccccc4)(c4ccccc4)c4ccccc43)ccc21 ; S=P1(c2ccccc2)c2ccccc2N(c2ccccc2)c2cc(N3c4ccccc4C(c4ccccc4)(c4ccccc4)c4ccccc43)ccc21 ; CC1(C)c2ccccc2P(=S)(c2ccccc2)c2ccc(N3c4ccccc4C(c4ccccc4)(c4ccccc4)c4ccccc43)cc21] 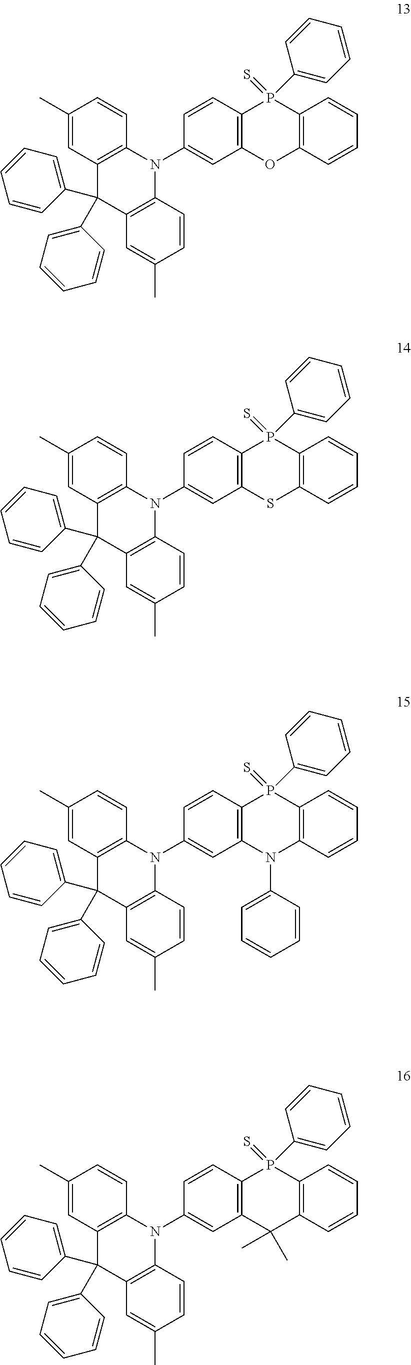 [SMILES: Cc1ccc2c(c1)C(c1ccccc1)(c1ccccc1)c1cc(C)ccc1N2c1ccc2c(c1)Oc1ccccc1P2(=S)c1ccccc1 ; Cc1ccc2c(c1)C(c1ccccc1)(c1ccccc1)c1cc(C)ccc1N2c1ccc2c(c1)Sc1ccccc1P2(=S)c1ccccc1 ; Cc1ccc2c(c1)C(c1ccccc1)(c1ccccc1)c1cc(C)ccc1N2c1ccc2c(c1)N(c1ccccc1)c1ccccc1P2(=S)c1ccccc1 ; Cc1ccc2c(c1)C(c1ccccc1)(c1ccccc1)c1cc(C)ccc1N2c1ccc2c(c1)C(C)(C)c1ccccc1P2(=S)c1ccccc1] 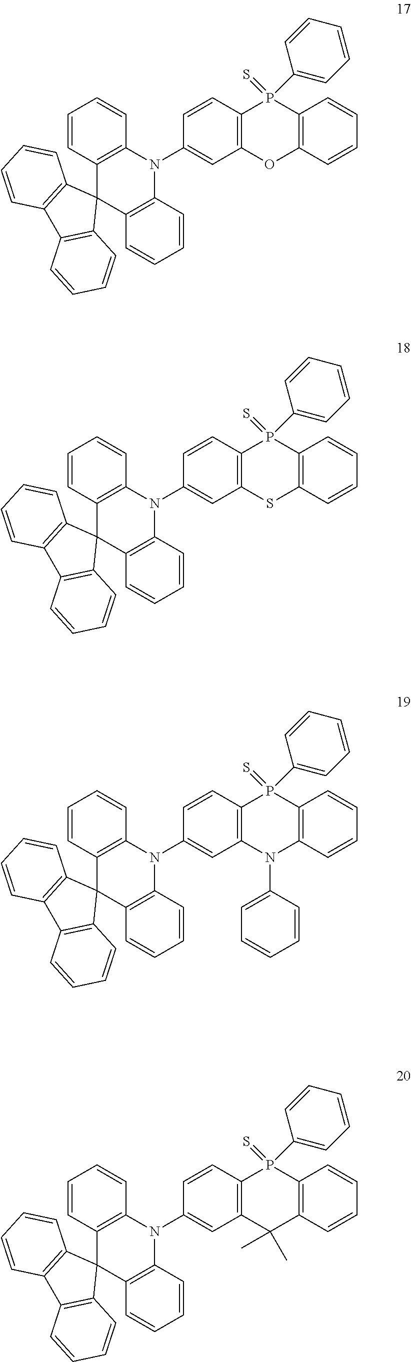 [SMILES: S=P1(c2ccccc2)c2ccccc2Oc2cc(N3c4ccccc4C4(c5ccccc5-c5ccccc54)c4ccccc43)ccc21 ; S=P1(c2ccccc2)c2ccccc2Sc2cc(N3c4ccccc4C4(c5ccccc5-c5ccccc54)c4ccccc43)ccc21 ; S=P1(c2ccccc2)c2ccccc2N(c2ccccc2)c2cc(N3c4ccccc4C4(c5ccccc5-c5ccccc54)c4ccccc43)ccc21 ; CC1(C)c2ccccc2P(=S)(c2ccccc2)c2ccc(N3c4ccccc4C4(c5ccccc5-c5ccccc54)c4ccccc43)cc21] 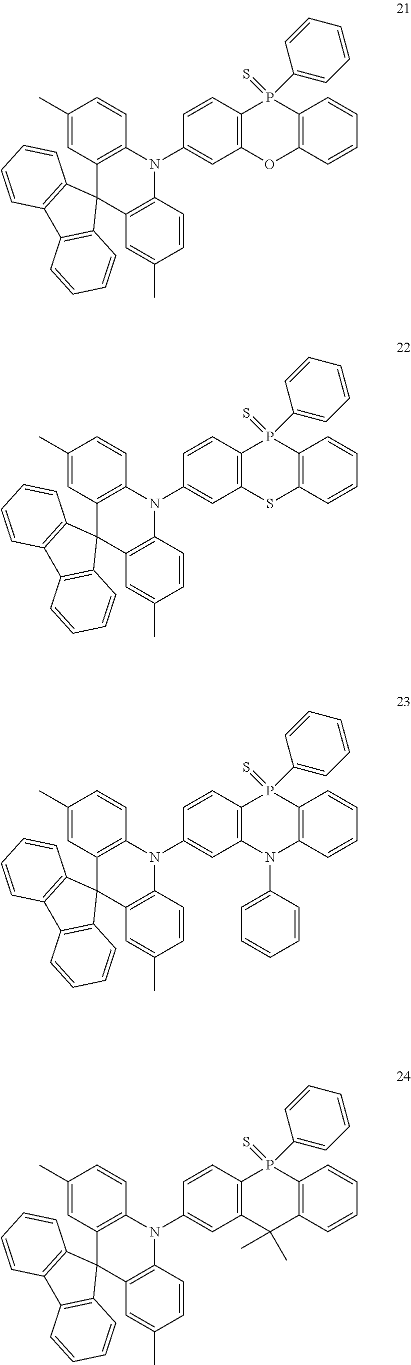 [SMILES: Cc1ccc2c(c1)C1(c3ccccc3-c3ccccc31)c1cc(C)ccc1N2c1ccc2c(c1)Oc1ccccc1P2(=S)c1ccccc1 ; Cc1ccc2c(c1)C1(c3ccccc3-c3ccccc31)c1cc(C)ccc1N2c1ccc2c(c1)Sc1ccccc1P2(=S)c1ccccc1 ; Cc1ccc2c(c1)C1(c3ccccc3-c3ccccc31)c1cc(C)ccc1N2c1ccc2c(c1)N(c1ccccc1)c1ccccc1P2(=S)c1ccccc1 ; Cc1ccc2c(c1)C1(c3ccccc3-c3ccccc31)c1cc(C)ccc1N2c1ccc2c(c1)C(C)(C)c1ccccc1P2(=S)c1ccccc1] 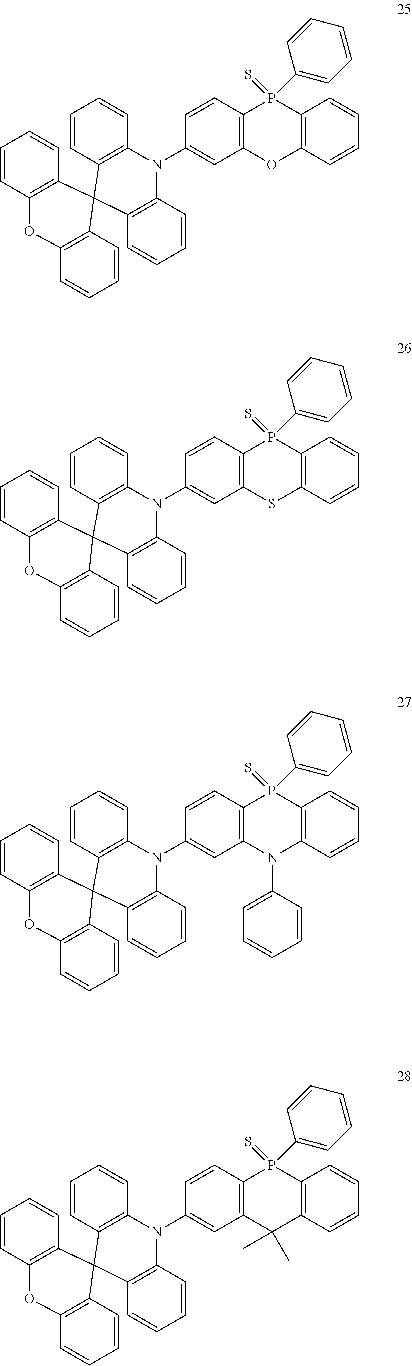 [SMILES: S=P1(c2ccccc2)c2ccccc2Oc2cc(N3c4ccccc4C4(c5ccccc5Oc5ccccc54)c4ccccc43)ccc21 ; S=P1(c2ccccc2)c2ccccc2Sc2cc(N3c4ccccc4C4(c5ccccc5Oc5ccccc54)c4ccccc43)ccc21 ; S=P1(c2ccccc2)c2ccccc2N(c2ccccc2)c2cc(N3c4ccccc4C4(c5ccccc5Oc5ccccc54)c4ccccc43)ccc21 ; CC1(C)c2ccccc2P(=S)(c2ccccc2)c2ccc(N3c4ccccc4C4(c5ccccc5Oc5ccccc54)c4ccccc43)cc21] 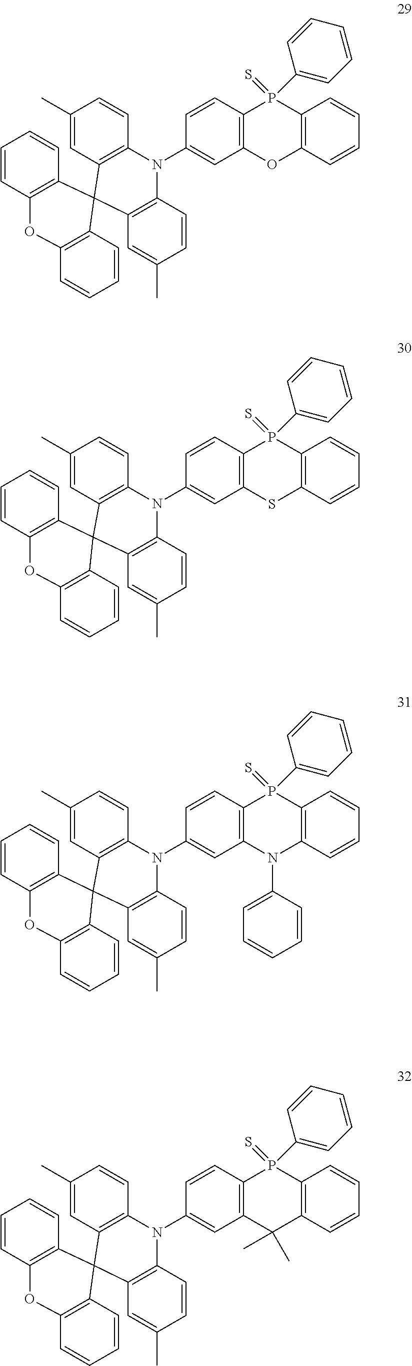 [SMILES: Cc1ccc2c(c1)C1(c3ccccc3Oc3ccccc31)c1cc(C)ccc1N2c1ccc2c(c1)Oc1ccccc1P2(=S)c1ccccc1 ; Cc1ccc2c(c1)C1(c3ccccc3Oc3ccccc31)c1cc(C)ccc1N2c1ccc2c(c1)Sc1ccccc1P2(=S)c1ccccc1 ; Cc1ccc2c(c1)C1(c3ccccc3Oc3ccccc31)c1cc(C)ccc1N2c1ccc2c(c1)N(c1ccccc1)c1ccccc1P2(=S)c1ccccc1 ; Cc1ccc2c(c1)C1(c3ccccc3Oc3ccccc31)c1cc(C)ccc1N2c1ccc2c(c1)C(C)(C)c1ccccc1P2(=S)c1ccccc1] 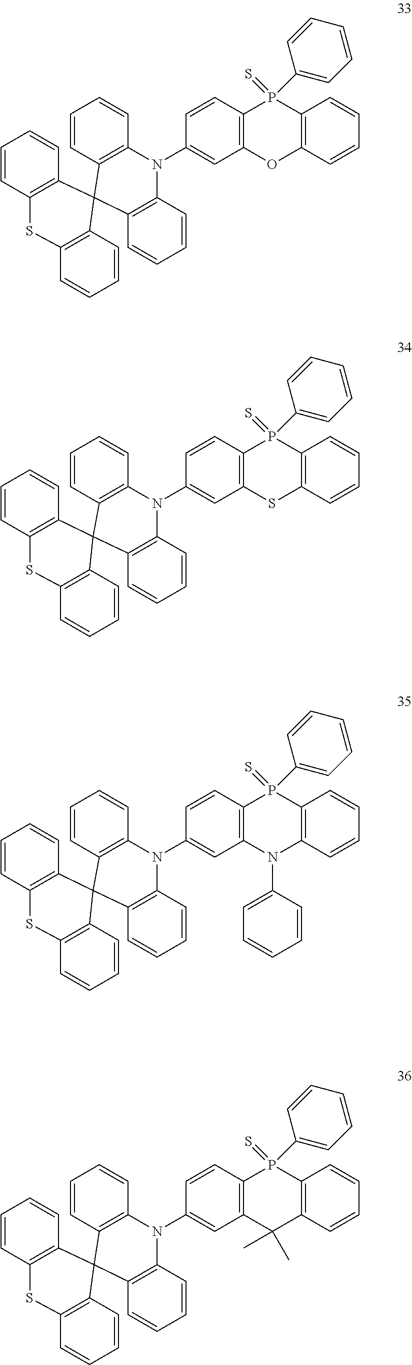 [SMILES: S=P1(c2ccccc2)c2ccccc2Oc2cc(N3c4ccccc4C4(c5ccccc5Sc5ccccc54)c4ccccc43)ccc21 ; S=P1(c2ccccc2)c2ccccc2Sc2cc(N3c4ccccc4C4(c5ccccc5Sc5ccccc54)c4ccccc43)ccc21 ; S=P1(c2ccccc2)c2ccccc2N(c2ccccc2)c2cc(N3c4ccccc4C4(c5ccccc5Sc5ccccc54)c4ccccc43)ccc21 ; CC1(C)c2ccccc2P(=S)(c2ccccc2)c2ccc(N3c4ccccc4C4(c5ccccc5Sc5ccccc54)c4ccccc43)cc21] 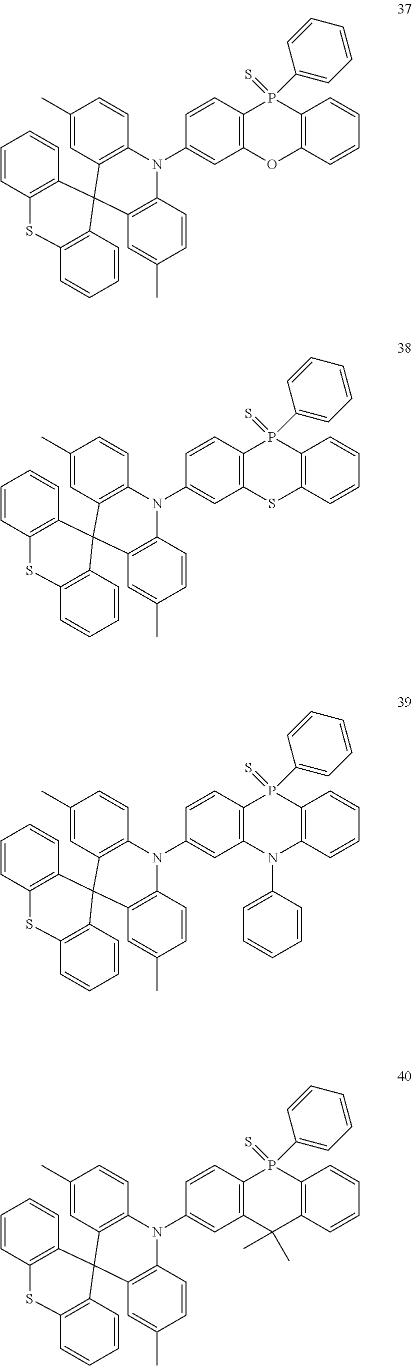 [SMILES: Cc1ccc2c(c1)C1(c3ccccc3Sc3ccccc31)c1cc(C)ccc1N2c1ccc2c(c1)Oc1ccccc1P2(=S)c1ccccc1 ; Cc1ccc2c(c1)C1(c3ccccc3Sc3ccccc31)c1cc(C)ccc1N2c1ccc2c(c1)Sc1ccccc1P2(=S)c1ccccc1 ; Cc1ccc2c(c1)C1(c3ccccc3Sc3ccccc31)c1cc(C)ccc1N2c1ccc2c(c1)N(c1ccccc1)c1ccccc1P2(=S)c1ccccc1 ; Cc1ccc2c(c1)C1(c3ccccc3Sc3ccccc31)c1cc(C)ccc1N2c1ccc2c(c1)C(C)(C)c1ccccc1P2(=S)c1ccccc1] 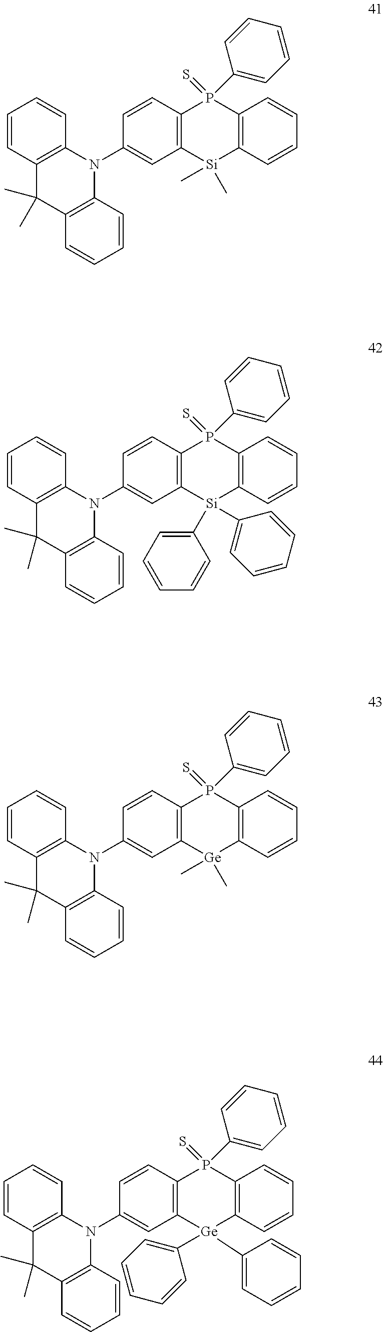 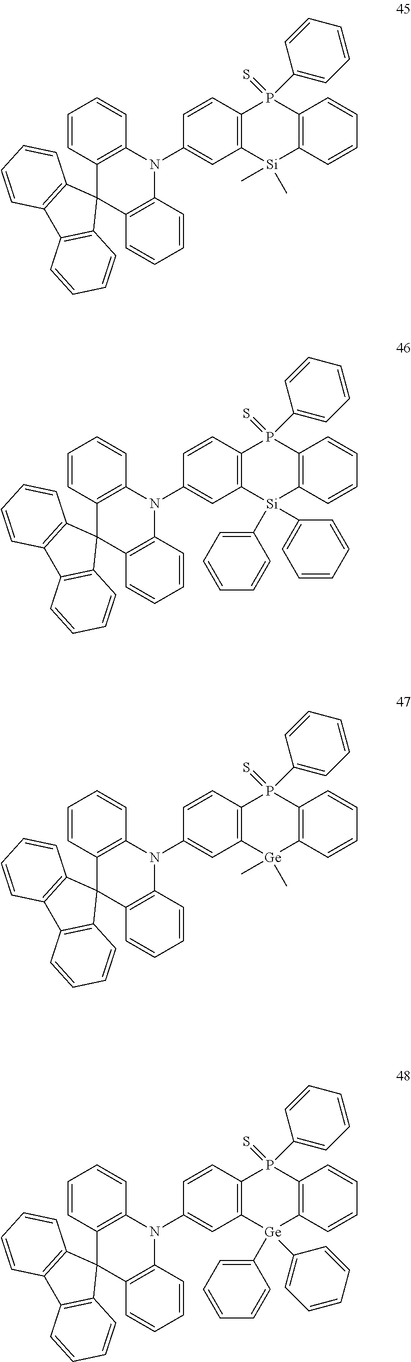 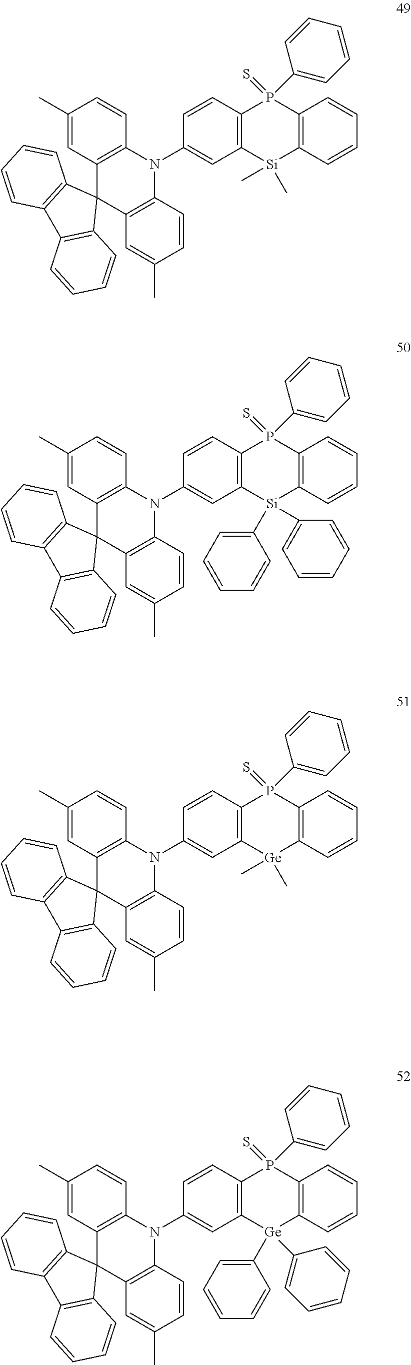 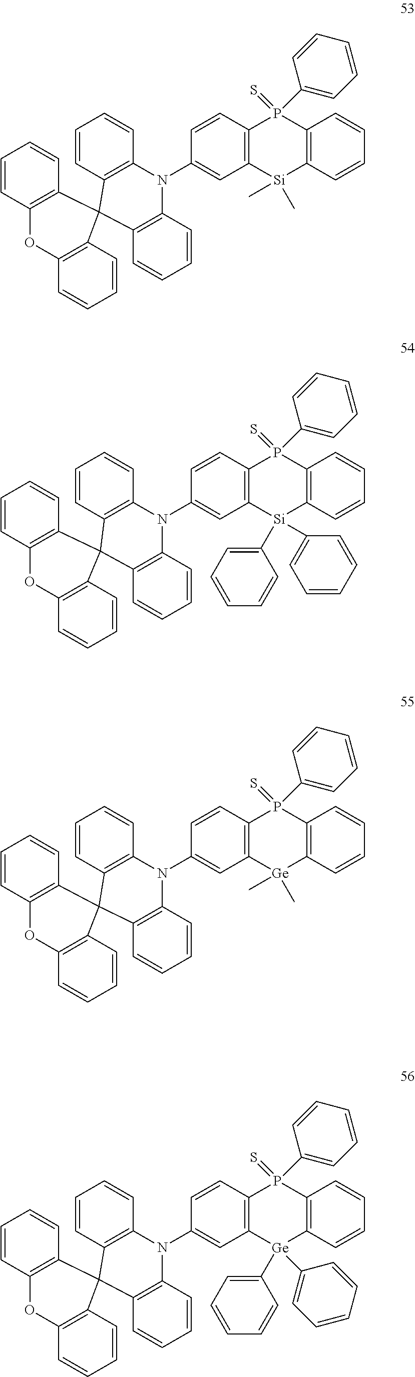 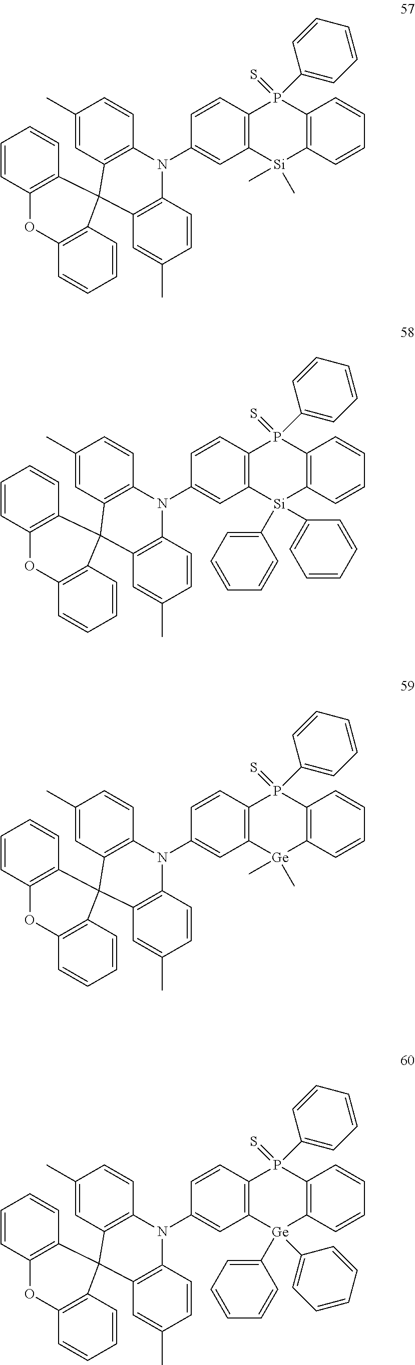 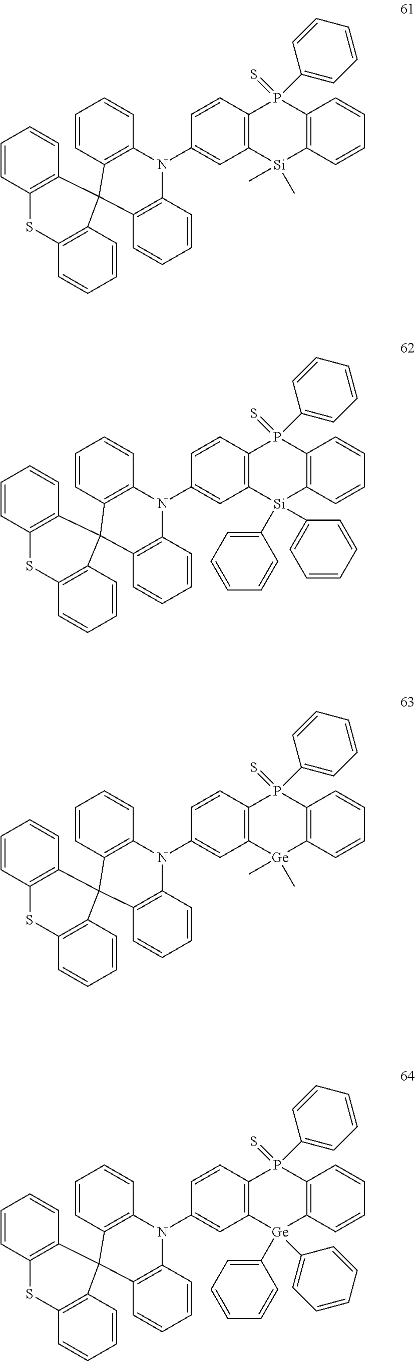 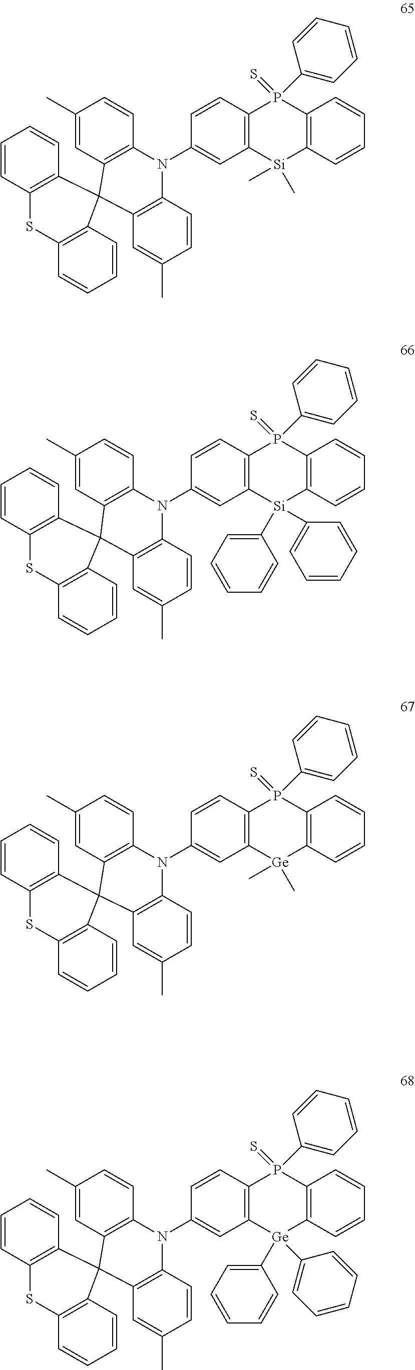 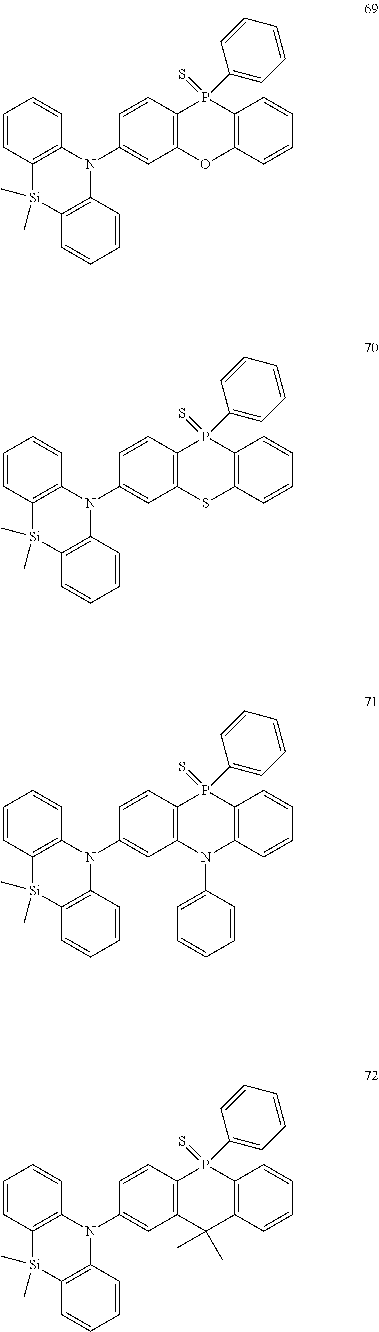 [SMILES: C[Si]1(C)c2ccccc2N(c2ccc3c(c2)Oc2ccccc2P3(=S)c2ccccc2)c2ccccc21 ; C[Si]1(C)c2ccccc2N(c2ccc3c(c2)Sc2ccccc2P3(=S)c2ccccc2)c2ccccc21 ; C[Si]1(C)c2ccccc2N(c2ccc3c(c2)N(c2ccccc2)c2ccccc2P3(=S)c2ccccc2)c2ccccc21 ; CC1(C)c2ccccc2P(=S)(c2ccccc2)c2ccc(N3c4ccccc4[Si](C)(C)c4ccccc43)cc21] 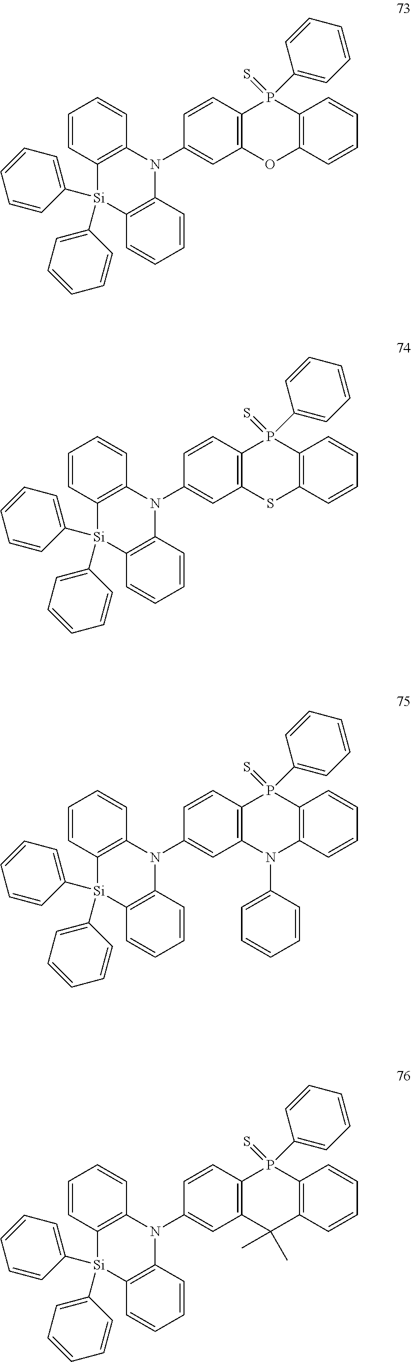 [SMILES: S=P1(c2ccccc2)c2ccccc2Oc2cc(N3c4ccccc4[Si](c4ccccc4)(c4ccccc4)c4ccccc43)ccc21 ; S=P1(c2ccccc2)c2ccccc2Sc2cc(N3c4ccccc4[Si](c4ccccc4)(c4ccccc4)c4ccccc43)ccc21 ; S=P1(c2ccccc2)c2ccccc2N(c2ccccc2)c2cc(N3c4ccccc4[Si](c4ccccc4)(c4ccccc4)c4ccccc43)ccc21 ; CC1(C)c2ccccc2P(=S)(c2ccccc2)c2ccc(N3c4ccccc4[Si](c4ccccc4)(c4ccccc4)c4ccccc43)cc21] 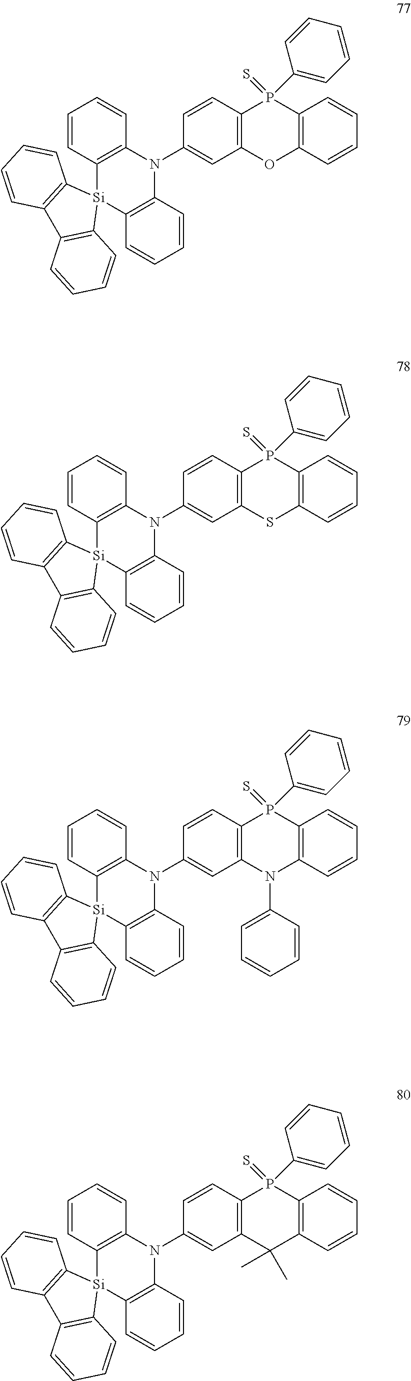 [SMILES: S=P1(c2ccccc2)c2ccccc2Oc2cc(N3c4ccccc4[Si]4(c5ccccc5-c5ccccc54)c4ccccc43)ccc21 ; S=P1(c2ccccc2)c2ccccc2Sc2cc(N3c4ccccc4[Si]4(c5ccccc5-c5ccccc54)c4ccccc43)ccc21 ; S=P1(c2ccccc2)c2ccccc2N(c2ccccc2)c2cc(N3c4ccccc4[Si]4(c5ccccc5-c5ccccc54)c4ccccc43)ccc21 ; CC1(C)c2ccccc2P(=S)(c2ccccc2)c2ccc(N3c4ccccc4[Si]4(c5ccccc5-c5ccccc54)c4ccccc43)cc21] 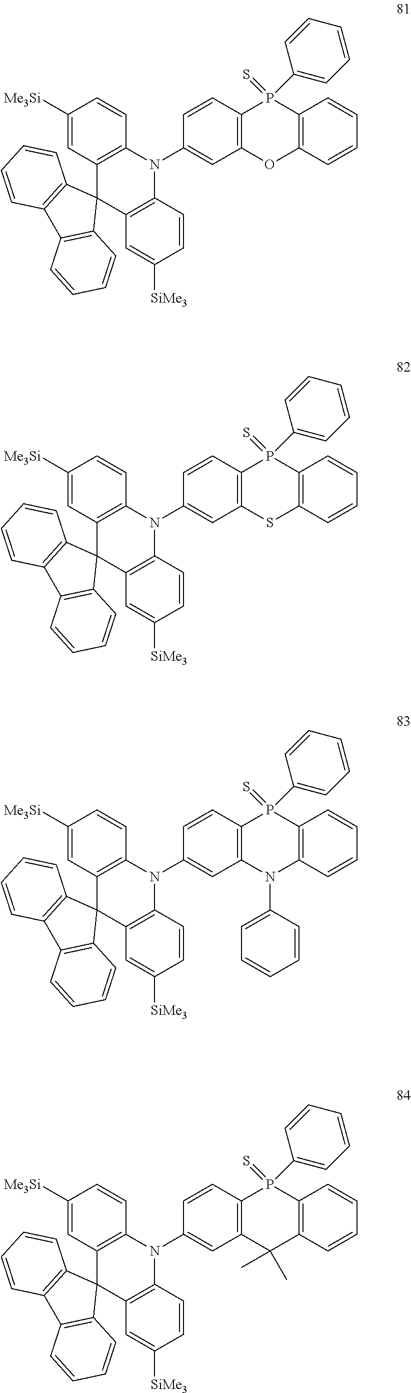 [SMILES: C[Si](C)(C)c1ccc2c(c1)C1(c3ccccc3-c3ccccc31)c1cc([Si](C)(C)C)ccc1N2c1ccc2c(c1)Oc1ccccc1P2(=S)c1ccccc1 ; C[Si](C)(C)c1ccc2c(c1)C1(c3ccccc3-c3ccccc31)c1cc([Si](C)(C)C)ccc1N2c1ccc2c(c1)Sc1ccccc1P2(=S)c1ccccc1 ; C[Si](C)(C)c1ccc2c(c1)C1(c3ccccc3-c3ccccc31)c1cc([Si](C)(C)C)ccc1N2c1ccc2c(c1)N(c1ccccc1)c1ccccc1P2(=S)c1ccccc1 ; CC1(C)c2ccccc2P(=S)(c2ccccc2)c2ccc(N3c4ccc([Si](C)(C)C)cc4C4(c5ccccc5-c5ccccc54)c4cc([Si](C)(C)C)ccc43)cc21] 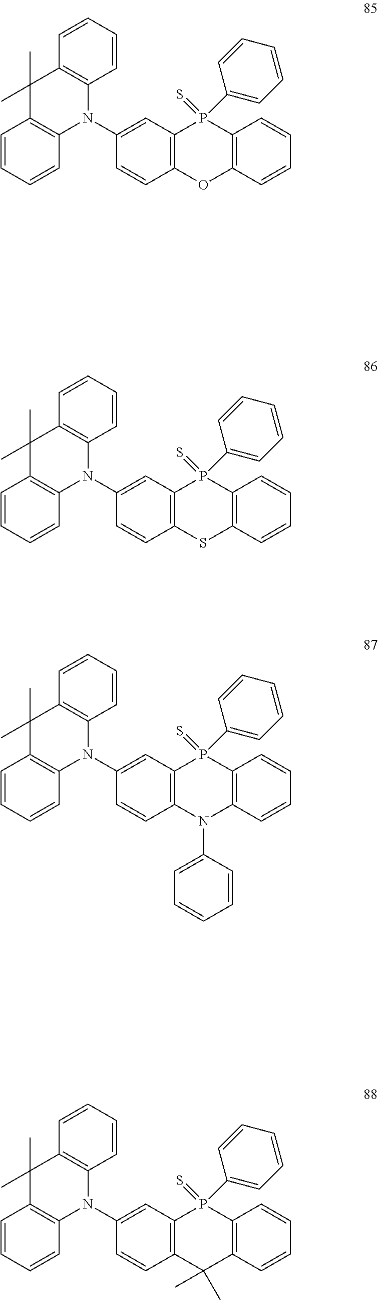 [SMILES: CC1(C)c2ccccc2N(c2ccc3c(c2)P(=S)(c2ccccc2)c2ccccc2O3)c2ccccc21 ; CC1(C)c2ccccc2N(c2ccc3c(c2)P(=S)(c2ccccc2)c2ccccc2S3)c2ccccc21 ; CC1(C)c2ccccc2N(c2ccc3c(c2)P(=S)(c2ccccc2)c2ccccc2N3c2ccccc2)c2ccccc21 ; CC1(C)c2ccccc2N(c2ccc3c(c2)P(=S)(c2ccccc2)c2ccccc2C3(C)C)c2ccccc21] 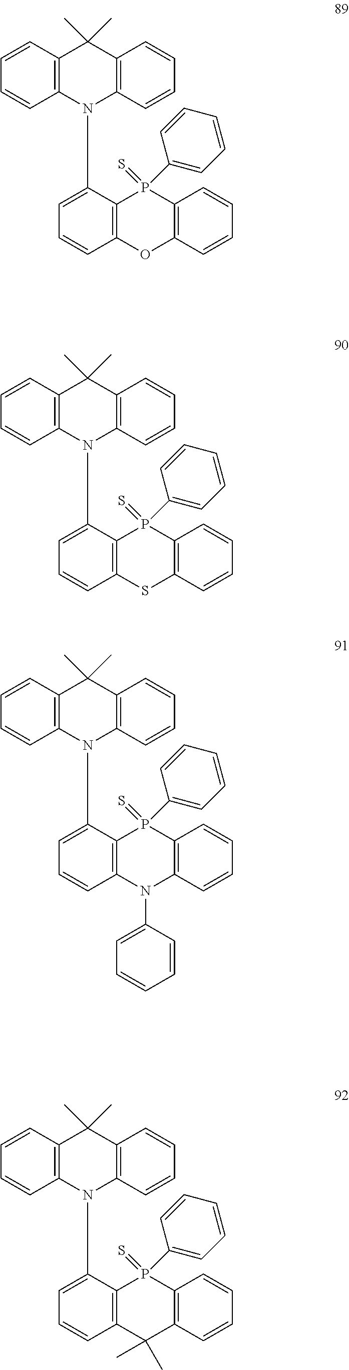 [SMILES: CC1(C)c2ccccc2N(c2cccc3c2P(=S)(c2ccccc2)c2ccccc2O3)c2ccccc21 ; CC1(C)c2ccccc2N(c2cccc3c2P(=S)(c2ccccc2)c2ccccc2S3)c2ccccc21 ; CC1(C)c2ccccc2N(c2cccc3c2P(=S)(c2ccccc2)c2ccccc2N3c2ccccc2)c2ccccc21 ; CC1(C)c2ccccc2N(c2cccc3c2P(=S)(c2ccccc2)c2ccccc2C3(C)C)c2ccccc21] 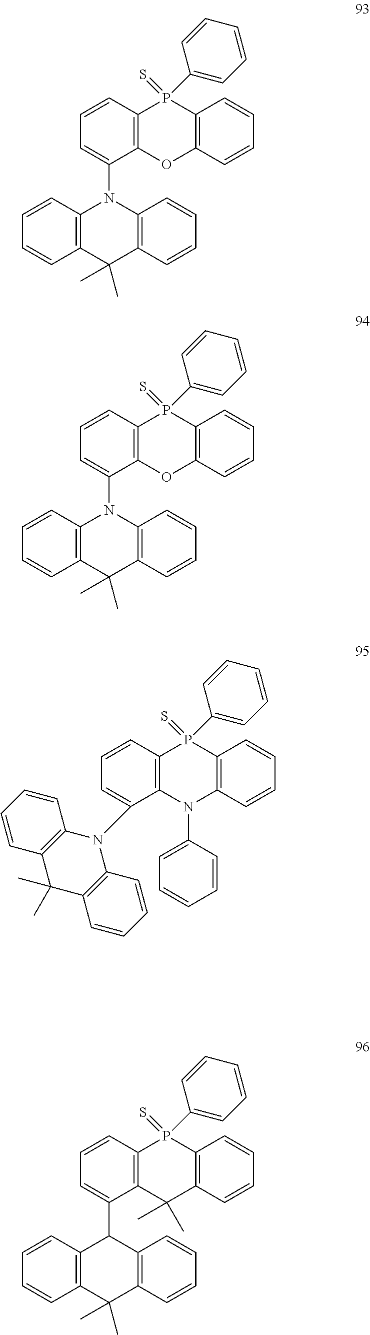 [SMILES: CC1(C)c2ccccc2N(c2cccc3c2Oc2ccccc2P3(=S)c2ccccc2)c2ccccc21 ; CC1(C)c2ccccc2N(c2cccc3c2Oc2ccccc2P3(=S)c2ccccc2)c2ccccc21 ; CC1(C)c2ccccc2N(c2cccc3c2N(c2ccccc2)c2ccccc2P3(=S)c2ccccc2)c2ccccc21 ; CC1(C)c2ccccc2C(c2cccc3c2C(C)(C)c2ccccc2P3(=S)c2ccccc2)c2ccccc21] 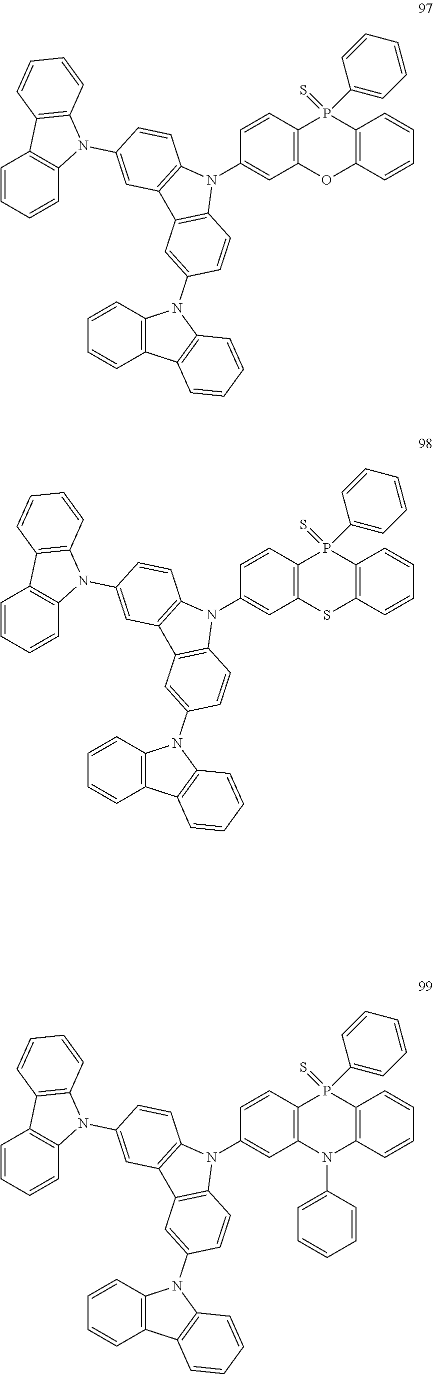 [SMILES: S=P1(c2ccccc2)c2ccccc2Oc2cc(-n3c4ccc(-n5c6ccccc6c6ccccc65)cc4c4cc(-n5c6ccccc6c6ccccc65)ccc43)ccc21 ; S=P1(c2ccccc2)c2ccccc2Sc2cc(-n3c4ccc(-n5c6ccccc6c6ccccc65)cc4c4cc(-n5c6ccccc6c6ccccc65)ccc43)ccc21 ; S=P1(c2ccccc2)c2ccccc2N(c2ccccc2)c2cc(-n3c4ccc(-n5c6ccccc6c6ccccc65)cc4c4cc(-n5c6ccccc6c6ccccc65)ccc43)ccc21] 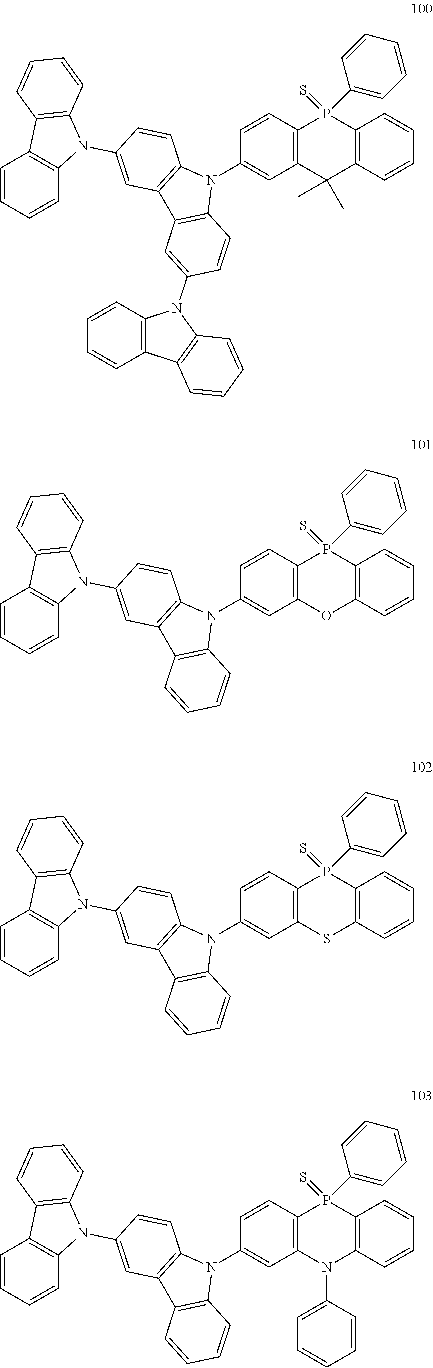 [SMILES: CC1(C)c2ccccc2P(=S)(c2ccccc2)c2ccc(-n3c4ccc(-n5c6ccccc6c6ccccc65)cc4c4cc(-n5c6ccccc6c6ccccc65)ccc43)cc21 ; S=P1(c2ccccc2)c2ccccc2Oc2cc(-n3c4ccccc4c4cc(-n5c6ccccc6c6ccccc65)ccc43)ccc21 ; S=P1(c2ccccc2)c2ccccc2Sc2cc(-n3c4ccccc4c4cc(-n5c6ccccc6c6ccccc65)ccc43)ccc21 ; S=P1(c2ccccc2)c2ccccc2N(c2ccccc2)c2cc(-n3c4ccccc4c4cc(-n5c6ccccc6c6ccccc65)ccc43)ccc21] 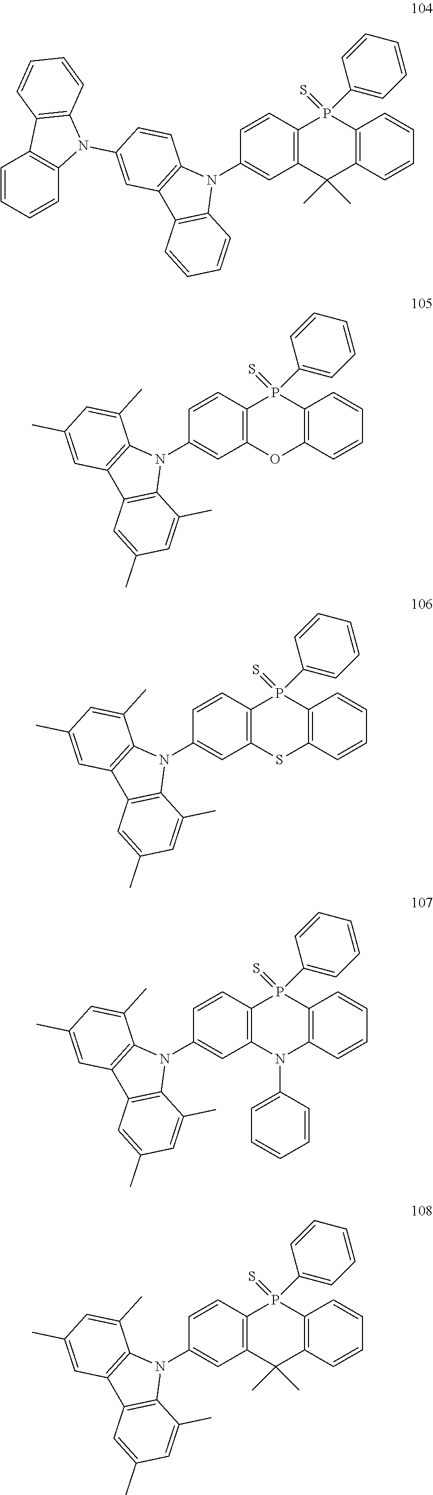 [SMILES: CC1(C)c2ccccc2P(=S)(c2ccccc2)c2ccc(-n3c4ccccc4c4cc(-n5c6ccccc6c6ccccc65)ccc43)cc21 ; Cc1cc(C)c2c(c1)c1cc(C)cc(C)c1n2-c1ccc2c(c1)Oc1ccccc1P2(=S)c1ccccc1 ; Cc1cc(C)c2c(c1)c1cc(C)cc(C)c1n2-c1ccc2c(c1)Sc1ccccc1P2(=S)c1ccccc1 ; Cc1cc(C)c2c(c1)c1cc(C)cc(C)c1n2-c1ccc2c(c1)N(c1ccccc1)c1ccccc1P2(=S)c1ccccc1 ; Cc1cc(C)c2c(c1)c1cc(C)cc(C)c1n2-c1ccc2c(c1)C(C)(C)c1ccccc1P2(=S)c1ccccc1] 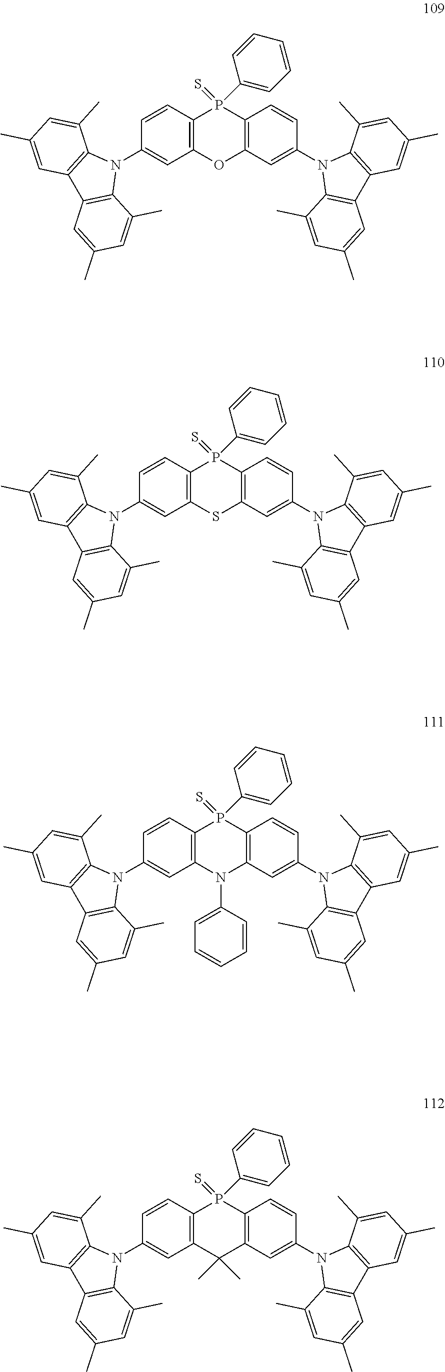 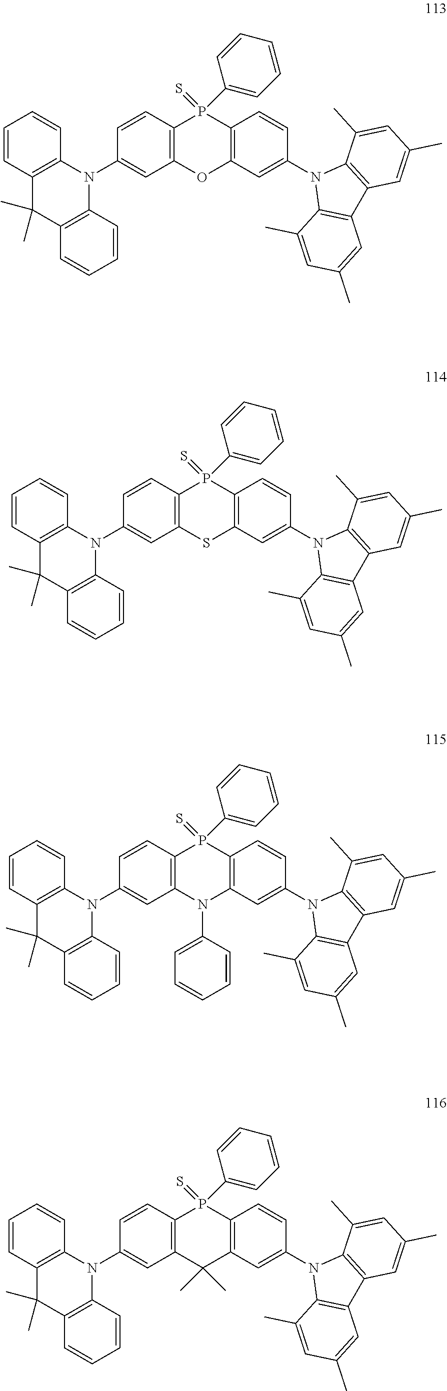 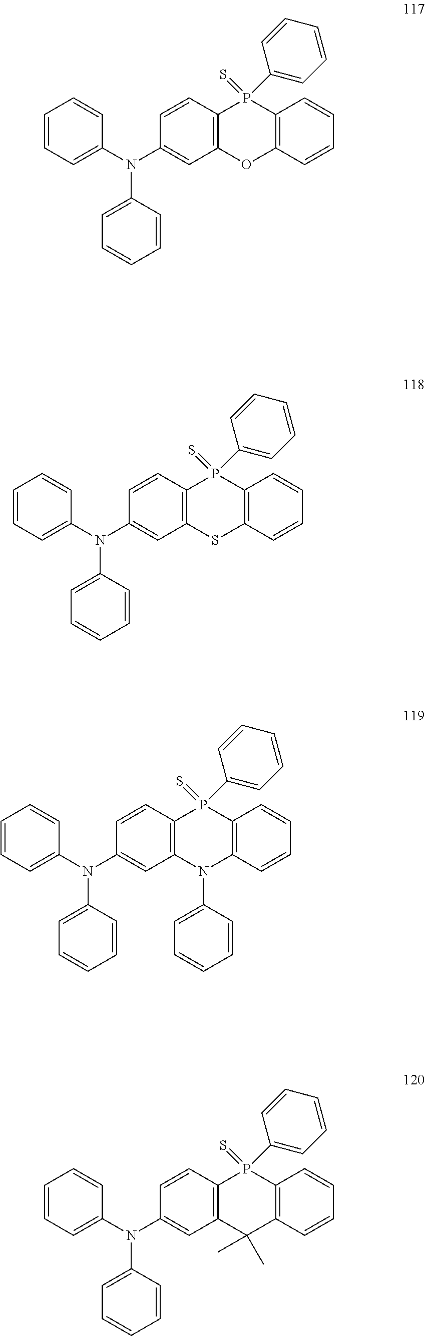 [SMILES: S=P1(c2ccccc2)c2ccccc2Oc2cc(N(c3ccccc3)c3ccccc3)ccc21 ; S=P1(c2ccccc2)c2ccccc2Sc2cc(N(c3ccccc3)c3ccccc3)ccc21 ; S=P1(c2ccccc2)c2ccccc2N(c2ccccc2)c2cc(N(c3ccccc3)c3ccccc3)ccc21 ; CC1(C)c2ccccc2P(=S)(c2ccccc2)c2ccc(N(c3ccccc3)c3ccccc3)cc21] 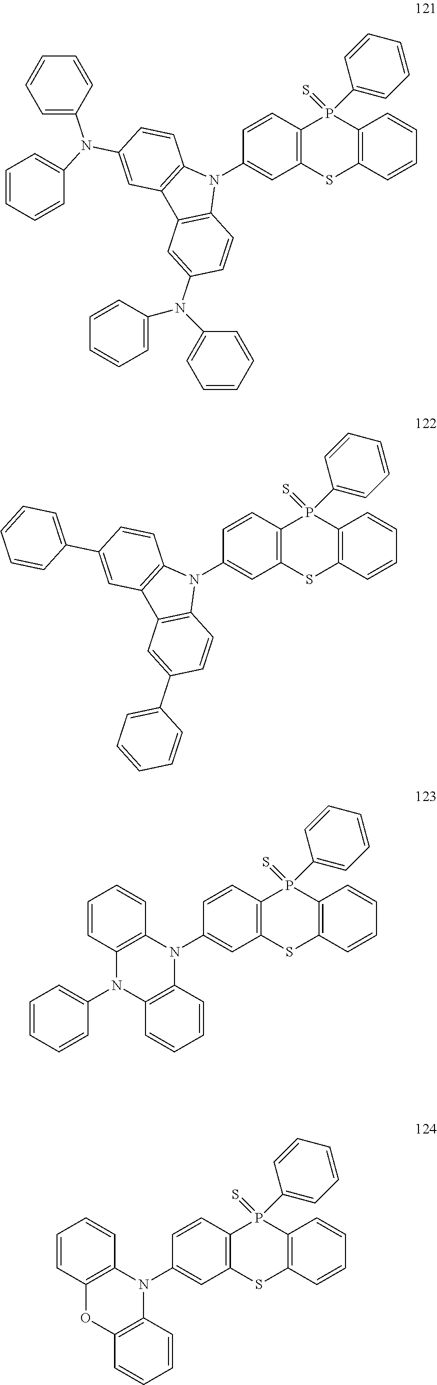 [SMILES: S=P1(c2ccccc2)c2ccccc2Sc2cc(-n3c4ccc(N(c5ccccc5)c5ccccc5)cc4c4cc(N(c5ccccc5)c5ccccc5)ccc43)ccc21 ; S=P1(c2ccccc2)c2ccccc2Sc2cc(-n3c4ccc(-c5ccccc5)cc4c4cc(-c5ccccc5)ccc43)ccc21 ; S=P1(c2ccccc2)c2ccccc2Sc2cc(N3c4ccccc4N(c4ccccc4)c4ccccc43)ccc21 ; S=P1(c2ccccc2)c2ccccc2Sc2cc(N3c4ccccc4Oc4ccccc43)ccc21] 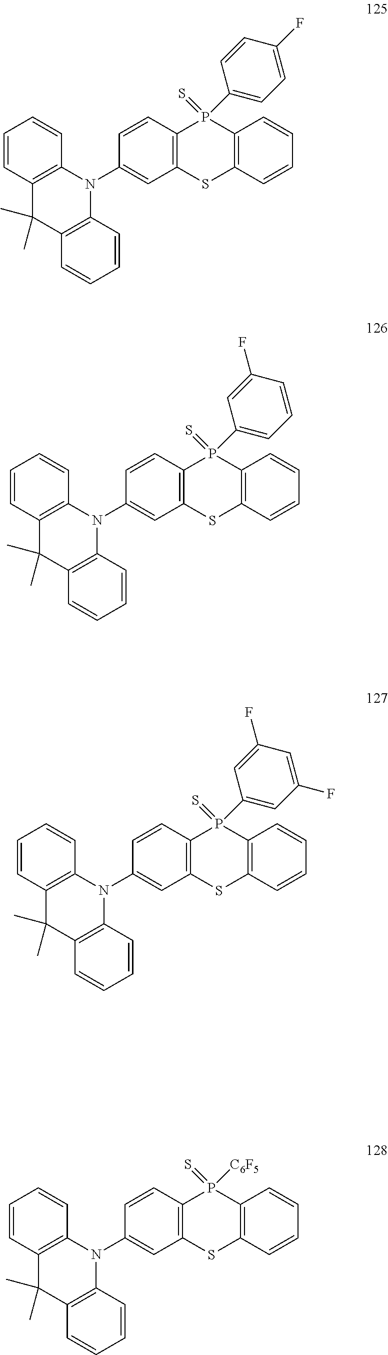 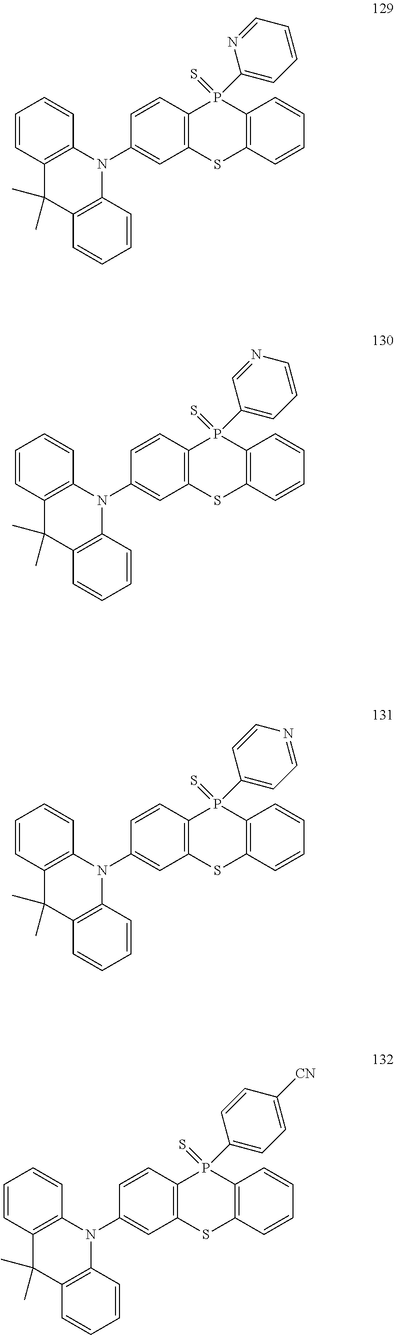 [SMILES: CC1(C)c2ccccc2N(c2ccc3c(c2)Sc2ccccc2P3(=S)c2ccccn2)c2ccccc21 ; CC1(C)c2ccccc2N(c2ccc3c(c2)Sc2ccccc2P3(=S)c2cccnc2)c2ccccc21 ; CC1(C)c2ccccc2N(c2ccc3c(c2)Sc2ccccc2P3(=S)c2ccncc2)c2ccccc21 ; CC1(C)c2ccccc2N(c2ccc3c(c2)Sc2ccccc2P3(=S)c2ccc(C#N)cc2)c2ccccc21] [chemical structure]
